(19) United States
(12) Patent Application Publication
(10) Pub. No.: US 2024/0065082 A1
(43) Pub. Date: Feb. 22, 2024

(54) OPTO-ELECTRONIC DEVICE INCLUDING PATTERNED EM RADIATION-ABSORBING LAYER

(71) Applicant: OTI Lumionics, Inc., Mississauga (CA)

(72) Inventors: Zhibin WANG, Mississauga (CA); Qi WANG, Mississauga (CA); Yi-Lu CHANG, Mississauga (CA); Michael HELANDER, Mississauga (CA)

(73) Assignee: OTI Lumionics, Inc., Mississauga (CA)

(21) Appl. No.: 18/468,641

(22) Filed: Sep. 15, 2023

Related U.S. Application Data
(63) Continuation of application No. 18/044,774, filed on Mar. 9, 2023.
(60) Provisional application No. 63/077,247, filed on Sep. 11, 2020.
(60) Provisional application No. 63/107,393, filed on Oct. 29, 2020.
(60) Provisional application No. 63/122,421, filed on Dec. 7, 2020.
(60) Provisional application No. 63/129,163, filed on Dec. 22, 2020.
(60) Provisional application No. 63/141,857, filed on Jan. 26, 2021.
(60) Provisional application No. 63/153,834, filed on Feb. 25, 2021.
(60) Provisional application No. 63/163,453, filed on Mar. 19, 2021.
(60) Provisional application No. 63/181,100, filed on Apr. 28, 2021.

(51) Int. Cl. H10K 59/80; H10K 59/12

(52) U.S. Cl. CPC H10K 59/8792; H10K 59/1201; H10K 2102/331

(57) ABSTRACT

A semiconductor device that facilitates absorption of EM radiation thereon and a method manufacturing same. The device extends in at least one lateral aspect. An EM radiation-absorbing layer comprising a discontinuous layer of at least one particle structure comprising a deposited material is deposited on a first layer surface. The particle structures facilitate absorption of EM radiation incident thereon and may comprise a seed about which the deposited material may tend to coalesce, and/or comprise the deposited material co-deposited with a co-deposited dielectric material. The EM radiation-absorbing layer may be disposed on a supporting dielectric layer and/or be covered by a covering dielectric layer. A patterning coating having an initial sticking probability against deposition of the deposited and/or a seed material, on a surface of the patterning coating is less than the initial sticking probability against deposition of the deposited and/or seed material on the second layer surface.

### RELATED APPLICATIONS

The present application is a continuation of U.S. patent application Ser. No. 18/044,774, filed 9 Mar. 2023, which is a National Stage Entry under 35 U.S.C. § 371 of International Application No. PCT/IB2021/058323, filed 13 Sep. 2021, which claims the benefit of priority to: U.S. Provisional Patent Application No. 63/077,247 filed 11 Sep. 2020, U.S. Provisional Patent Application No. 63/107,393 filed 29 Oct. 2020, U.S. Provisional Patent Application No. 63/122,421 filed 7 Dec. 2020, U.S. 63/129,163 filed 22 Dec. 2020, U.S. Provisional Patent Application No. 63/141,857 filed 26 Jan. 2021, U.S. Provisional Patent Application No. 63/153,834 filed 25 Feb. 2021, U.S. Provisional Patent Application No. 63/163,453 filed 19 Mar. 2021, and U.S. Provisional Patent Application No. 63/181,100 filed 28 Apr. 2021, the contents of each of which are incorporated herein by reference in their entirety.

### TECHNICAL FIELD

The present disclosure relates to layered semiconductor devices and in particular to an opto-electronic device having first and second electrodes separated by a semiconductor layer and having a conductive deposited material deposited thereon, patterned using a patterning coating, which may act as and/or be a nucleation-inhibiting coating (NIC) and/or such NIC.

### BACKGROUND

In an opto-electronic device such as an organic light-emitting diode (OLED), at least one semiconducting layer is disposed between a pair of electrodes, such as an anode and a cathode. The anode and cathode are electrically coupled with a power source and respectively generate holes and electrons that migrate toward each other through the at least one semiconducting layer. When a pair of holes and electrons combine, a photon may be emitted.

OLED display panels may comprise a plurality of (sub-) pixels, each of which has an associated pair of electrodes. Various layers and coatings of such panels are typically formed by vacuum-based deposition processes.

In some applications, there may be an aim to provide a photon-absorbing layer or coating in certain regions of the panel. In some applications, such photon-absorbing layer may be referred to as a black matrix (BM) layer, especially if the regions lie around but not over each (sub-) pixel of the panel. The photon-absorbing layer absorbs external light incident thereon and reduces reflection by the panel of such light. As such, the existence of a photon-absorbing layer may reduce the intrusion of external light incident thereon from entering the panel and thus reduce internally reflected light therefrom that otherwise might be compensated for by implementation of a polarizer over the panel. Such a photon-absorbing layer may be shaped to avoid covering emissive regions of the panel so that emitted light is not absorbed thereby and precluded from exiting the panel.

In some applications, there may be an aim to provide a conductive deposited material in a pattern for each (sub-) pixel of the panel across either, or both of, a lateral and a cross-sectional aspect thereof, by selective deposition to form a device feature, such as, without limitation, an electrode and/or a conductive element electrically coupled therewith, and/or an EM radiation absorbing layer, during the OLED manufacturing process.

One method for doing so, in some non-limiting application, involves the interposition of a fine metal mask (FMM) during deposition of a deposited material, including as an electrode and/or a conductive element electrically coupled therewith, and/or an EM radiation-absorbing layer. However, such deposited material typically has relatively high evaporation temperatures, which impacts the ability to re-use the FMM and/or the accuracy of the pattern that may be achieved, with attendant increases in cost, effort, and complexity.

One method for doing so, in some non-limiting examples, involves depositing the deposited material and thereafter removing, including by a laser drilling process, unwanted regions thereof to form the pattern. However, the removal process often involves the creation and/or presence of debris, which may affect the yield of the manufacturing process.

Further, such methods may not be suitable for use in some applications and/or with some devices with certain topographical features.

In some non-limiting applications, there may be an aim to provide an improved mechanism for providing selective deposition of a conductive coating.

### BRIEF DESCRIPTION OF THE DRAWINGS

Examples of the present disclosure will now be described by reference to the following figures, in which identical reference numerals in different figures indicate identical and/or in some non-limiting examples, analogous and/or corresponding elements and in which:

FIG. 1 is a simplified block diagram from a cross-sectional aspect, of an example device having a plurality of layers in a lateral aspect, comprising a discontinuous layer of particle structures on an exposed layer surface of the device, that comprises an EM radiation-absorbing layer according to an example in the present disclosure;

FIG. 2 is a simplified block diagram showing a version of the device of FIG. 1 with additional optional layers shown according to an example in the present disclosure;

FIG. 3A is a schematic diagram showing the EM radiation-absorbing layer of FIG. 1 proximate to an emissive region of the device of FIG. 1 formed by deposition of a patterning coating subsequent to deposition of a plurality of seeds for forming the particle structures according to an example in the present disclosure;

FIG. 3B is a schematic diagram showing a version of the EM radiation-absorbing layer of FIG. 3A, formed by deposition of the patterning coating prior to deposition of the plurality of seeds, according to an example in the present disclosure;

FIG. 4 is a simplified block diagram from a cross-sectional aspect, of an example device having a plurality of layers in a lateral aspect, formed by selective deposition of a patterning coating in a first portion of the lateral aspect, followed by deposition of a closed coating of deposited material in a second portion thereof, according to an example in the present disclosure;

FIG. 5 is a schematic diagram showing an example process for depositing a patterning coating in a pattern on an exposed layer surface of an underlying layer in an example version of the device of FIG. 4, according to an example in the present disclosure;

FIG. 6 is a schematic diagram showing an example process for depositing a deposited material in the second portion on an exposed layer surface that comprises the deposited pattern of the patterning coating of FIG. 6, where the patterning coating is a nucleation-inhibiting coating (NIC);

FIG. 7A is a schematic diagram illustrating an example version of the device of FIG. 4 in a cross-sectional view;

FIG. 7B is a schematic diagram illustrating the device of FIG. 7A in a complementary plan view;

FIG. 7C is a schematic diagram illustrating an example version of the device of FIG. 4 in a cross-sectional view;

FIG. 7D is a schematic diagram illustrating the device of FIG. 7C in a complementary plan view;

FIG. 7E is a schematic diagram illustrating an example of the device of FIG. 4 in a cross-sectional view;

FIG. 7F is a schematic diagram illustrating an example of the device of FIG. 4 in a cross-sectional view;

FIG. 7G is a schematic diagram illustrating an example of the device of FIG. 4 in a cross-sectional view;

FIGS. 8A-81 are schematic diagrams that show various potential behaviours of an NIC at a deposition interface with a deposited layer in an example version of the device of FIG. 1, according to various examples in the present disclosure;

FIG. 9 is a block diagram from a cross-sectional aspect, of an example electro-luminescent device according to an example in the present disclosure;

FIG. 10 is a cross-sectional view of the device of FIG. 4;

FIG. 11 is a schematic diagram illustrating, in plan, an example patterned electrode suitable for use in a version of the device of FIG. 10, according to an example in the present disclosure;

FIG. 12 is a schematic diagram illustrating an example cross-sectional view of the device of FIG. 11 taken along line 12-12;

FIG. 13A is a schematic diagram illustrating, in plan view, a plurality of example patterns of electrodes suitable for use in an example version of the device of FIG. 10, according to an example in the present disclosure;

FIG. 13B is a schematic diagram illustrating an example cross-sectional view, at an intermediate stage, of the device of FIG. 13A taken along line 13B-13B;

FIG. 13C is a schematic diagram illustrating an example cross-sectional view of the device of FIG. 13A taken along line 13C-13C;

FIG. 14 is a schematic diagram illustrating a cross-sectional view of an example version of the device of FIG. 10, having an example patterned auxiliary electrode according to an example in the present disclosure;

FIG. 15 is a schematic diagram illustrating, in plan view an example pattern of an auxiliary electrode overlaying at least one emissive region and at least one non-emissive region according to an example in the present disclosure;

FIG. 16A is a schematic diagram illustrating, in plan view, an example pattern of an example version of the device of FIG. 10, having a plurality of groups of emissive regions in a diamond configuration according to an example in the present disclosure;

FIG. 16B is a schematic diagram illustrating an example cross-sectional view of the device of FIG. 16A taken along line 16B-16B;

FIG. 16C is a schematic diagram illustrating an example cross-sectional view of the device of FIG. 16A taken along line 16C-16C;

FIG. 17 is a schematic diagram illustrating an example cross-sectional view of an example version of the device of FIG. 10 with additional example deposition steps according to an example in the present disclosure;

FIG. 18 is a schematic diagram illustrating an example cross-sectional view of an example version of the device of FIG. 10 with additional example deposition steps according to an example in the present disclosure;

FIG. 19 is a schematic diagram illustrating an example cross-sectional view of an example version of the device of FIG. 10 with additional example deposition steps according to an example in the present disclosure;

FIG. 20 is a schematic diagram illustrating an example cross-sectional view of an example version of the device of FIG. 10 with additional example deposition steps according to an example in the present disclosure;

FIG. 21A is a schematic diagram illustrating, in plan view, an example of a transparent version of the device of FIG. 10 comprising at least one example pixel region and at least one example light-transmissive region, with at least one auxiliary electrode according to an example in the present disclosure;

FIG. 21B is a schematic diagram illustrating an example cross-sectional view of the device of FIG. 21A taken along line 2B-21B;

FIG. 22A is a schematic diagram illustrating, in plan view, an example of a transparent version of the device of FIG. 10 comprising at least one example pixel region and at least one example light-transmissive region according to an example in the present disclosure;

FIG. 22B is a schematic diagram illustrating an example cross-sectional view of the device of FIG. 22A taken along line 22-22;

FIG. 22C is a schematic diagram illustrating an example cross-sectional view of the device of FIG. 22A taken along line 22-22;

FIG. 23 is a schematic diagram that may show example stages of an example process for manufacturing an example version of the device of FIG. 10 having sub-pixel regions having a second electrode of different thickness according to an example in the present disclosure;

FIG. 24 is a schematic diagram illustrating an example cross-sectional view of an example version of the device of FIG. 10 in which a second electrode is coupled with an auxiliary electrode according to an example in the present disclosure;

FIG. 25 is a schematic diagram illustrating an example cross-sectional view of an example version of the device of FIG. 10 having a partition and a sheltered region, such as a recess, in a non-emissive region thereof according to an example in the present disclosure;

FIGS. 26A-26B are schematic diagrams that show example cross-sectional views of an example version of the device of FIG. 10 having a partition and a sheltered region, such as an aperture, in a non-emissive region, according to various examples in the present disclosure;

FIG. 27 is a schematic diagram illustrating an example cross-sectional view of an example display panel having a plurality of layers, comprising at least one aperture therewithin, according to an example in the present disclosure;

FIGS. 28A-28C are schematic diagrams that show example stages of an example process for depositing a deposited layer in a pattern on an exposed layer surface of an example version of the device of FIG. 9, by selective deposition and subsequent removal process, according to an example in the present disclosure;

FIG. 29 is a flow chart showing method actions according to an example;

FIG. 30 is an example energy profile illustrating relative energy states of an adatom absorbed onto a surface according to an example in the present disclosure; and

FIG. 31 is a schematic diagram illustrating the formation of a film nucleus according to an example in the present disclosure.

In the present disclosure, a reference numeral having at least one numeric value (including without limitation, in subscript) and/or lower-case alphabetic character(s) (including without limitation, in lower-case) appended thereto, may be considered to refer to a particular instance, and/or subset thereof, of the element or feature described by the reference numeral. Reference to the reference numeral without reference to the appended value(s) and/or character(s) may, as the context dictates, refer generally to the element(s) or feature(s) described by the reference numeral, and/or to the set of all instances described thereby. Similarly, a reference numeral may have the letter “x” in the place of a numeric digit. Reference to such reference numeral may, as the context dictates, refer generally to the element(s) or feature(s) described by the reference numeral, where the character “x” is replaced by a numeric digit, and/or to the set of all instances described thereby.

In the present disclosure, for purposes of explanation and not limitation, specific details are set forth to provide a thorough understanding of the present disclosure, including, without limitation, particular architectures, interfaces and/or techniques. In some instances, detailed descriptions of well-known systems, technologies, components, devices, circuits, methods, and applications are omitted to not obscure the description of the present disclosure with unnecessary detail.

Further, it will be appreciated that block diagrams reproduced herein can represent conceptual views of illustrative components embodying the principles of the technology.

Accordingly, the system and method components have been represented where appropriate by conventional symbols in the drawings, showing only those specific details that are pertinent to understanding the examples of the present disclosure, to not obscure the disclosure with details that will be readily apparent to those of ordinary skill in the art having the benefit of the description herein.

Any drawings provided herein may not be drawn to scale and may not be considered to limit the present disclosure in any way.

Any feature or action shown in dashed outline may in some examples be considered as optional.

### SUMMARY

It is an object of the present disclosure to obviate or mitigate at least one disadvantage of the prior art.

The present disclosure discloses a semiconductor device that facilitates absorption of EM radiation thereon and a method for manufacturing same. The device extends in at least one lateral aspect. An EM radiation-absorbing layer comprising a discontinuous layer of at least one particle structure comprising a deposited material is deposited on a first layer surface. The particle structures facilitate absorption of EM radiation incident thereon, and may comprise a seed about which the deposited material may tend to coalesce, and/or comprise the deposited material co-deposited with a co-deposited dielectric material. The EM radiation-absorbing layer may be disposed on a supporting dielectric layer and/or be covered by a covering dielectric layer. A patterning coating having an initial sticking probability against deposition of the deposition material and/or a seed material, on a surface of the patterning coating is less than the initial sticking probability against deposition of the deposited and/or seed material on the second layer surface.

According to a broad aspect, there is disclosed a semiconductor device having a plurality of layers deposited on a substrate and extending in at least one lateral aspect defined by a lateral axis thereof, comprising: at least one EM radiation-absorbing layer deposited on a first layer surface and comprising a discontinuous layer of at least one particle structure comprising a deposited material; wherein the at least one particle structures of the at least one EM radiation-absorbing layer facilitate absorption of EM radiation incident thereon.

In some non-limiting examples, the deposited material may be a metal.

In some non-limiting examples, the at least one particle structure may comprise at least one of a plasmonic island and a nanoparticle.

In some non-limiting examples, the at least one particle structure may have a characteristic feature selected from at least one of: a size, size distribution, shape, surface coverage, configuration, deposited density, and composition.

In some non-limiting examples, the at least one particle structure may comprise a seed about which the deposited material tends to coalesce. In some non-limiting examples, the seed may be comprised of a seed material. In some non-limiting examples, the seed material may be a metal selected from at least one of ytterbium (Yb) and silver (Ag). In some non-limiting examples, the seed material may have a high wetting property with respect to the deposited material. In some non-limiting examples, the seeds of the at least one particle structures of the at least one EM radiation-absorbing layer are deposited in a templating layer on the first layer surface.

In some non-limiting examples, the deposited material may be co-deposited with a co-deposited dielectric material. In some non-limiting examples, the co-deposited dielectric material may comprise at least one of: an organic material, a semiconductor material, and an organic semiconductor material. In some non-limiting examples, the co-deposited dielectric material may have an initial sticking probability against deposition of the deposited material that is less than 1. In some non-limiting examples, a ratio of the deposited material to the co-deposited dielectric material may be at least one of: 50:1, 45:1, 40:1, 35:1, 30:1, 25:1, 20:1, 19:1, 15:1, 12.5:1, 10:1, 7.5:1, and 5:1.

In some non-limiting examples, the device may further comprise a patterning coating disposed on a second layer surface in a first portion of the lateral aspect of the device, wherein: the second layer surface lies between the substrate and the first layer surface, the at least one EM radiation-absorbing layer is disposed in a second portion of the lateral aspect, and an initial sticking probability against deposition of the deposited material on a surface of the patterning coating is substantially less than the initial sticking probability against deposition of the deposited material onto the second layer surface, such that the patterning coating is substantially devoid of a closed coating of the deposited material.

In some non-limiting examples, the at least one particle structure may comprise a seed about which the deposited material tends to coalesce, wherein the seed is disposed between the substrate and the patterning coating. In some non-limiting examples, the at least one particle structure may comprise a seed about which the deposited material tends to coalesce, wherein the seed is comprised of a seed material such that an initial sticking probability against deposition of the seed material on a surface of the patterning material is substantially less than the initial sticking probability against deposition of the seed material onto the second layer surface.

In some non-limiting examples, the device may be an opto-electronic device and the first portion may comprise at least one emissive region thereof. In some non-limiting examples, the second portion may comprise at least a part of a non-emissive region.

In some non-limiting examples, the device may further comprise a supporting dielectric layer defining the first layer surface, wherein the supporting dielectric layer is disposed on a third layer surface. In some non-limiting examples, the supporting dielectric layer may electrically de-couple the at least one particle structure from the third layer surface. In some non-limiting examples, the supporting dielectric layer may facilitate absorption of EM radiation incident on the at least one particle structure. In some non-limiting examples, the supporting dielectric layer may comprise a capping layer of the device. In some non-limiting examples, the supporting dielectric layer may comprise a supporting dielectric material that is the same as a co-deposited dielectric material that is co-deposited with the deposited material.

In some non-limiting examples, the at least one EM radiation-absorbing layer and the supporting dielectric layer both extend in a second portion of the lateral aspect. In some non-limiting examples, the device may further comprise a patterning coating disposed on a second layer surface in a first portion of the lateral aspect, wherein the supporting dielectric layer extends into the first portion. In some non-limiting examples, the third layer surface and the first layer surface may be the same.

In some non-limiting examples, the device may further comprise a covering dielectric layer disposed on the at least one EM radiation-absorbing layer. In some non-limiting examples, the covering dielectric layer may facilitate absorption of EM radiation incident on the at least one particle structure. In some non-limiting examples, the covering dielectric layer may comprise a capping layer of the device. In some non-limiting examples, the covering dielectric layer may comprise a covering dielectric material that is the same as a co-deposited dielectric material that is co-deposited with the deposited material. In some non-limiting examples, the covering dielectric layer may comprise a covering dielectric material that is the same as a supporting dielectric material of which a supporting dielectric layer defining the first layer surface is formed.

In some non-limiting examples, the covering dielectric layer may comprise a further layer surface on which a further one of the at least one EM radiation-absorbing layers is disposed. In some non-limiting examples, the further layer surface may define a supporting dielectric layer for supporting the further one of the at least one EM radiation-absorbing layer.

In some non-limiting examples, the absorption of the at least one EM radiation-absorbing layer may be concentrated in a wavelength range of the EM spectrum. In some non-limiting examples, the wavelength range may correspond to at least one of the visible spectrum and a sub-range thereof. In some non-limiting examples, a dielectric constant of the deposited material may impact the wavelength range. In some non-limiting examples, the absorption of a first one of the at least one EM radiation-absorbing layer may be concentrated in a wavelength range that is different from the absorption of a second one of the at least one EM radiation-absorbing layer.

According to a broad aspect, there is disclosed a method for manufacturing a semiconductor device having a plurality of layers that facilitates absorption of EM radiation incident thereon, the method comprising actions of: depositing at least one particle structure comprising a deposited material in at least one EM radiation-absorbing layer on a first layer surface.

In some non-limiting examples, the action of depositing may comprise an action of: seeding the first layer surface with at least one seed about which the deposited material tends to coalesce.

In some non-limiting examples, the action of depositing may comprise actions of: disposing a patterning coating on a second layer surface in a first portion of the lateral aspect, wherein an initial sticking probability against deposition of the deposited material on a surface of the patterning coating is substantially less than the initial sticking probability against deposition of the deposited material on the second layer surface; and exposing the device to the deposited material such that the at least one particle structure is deposited in a second portion of the lateral aspect that is substantially devoid of the patterning coating.

In some non-limiting examples, the method may comprise, before the action of disposing, an action of: seeding the first layer surface with at least one seed about which the deposited material tends to coalesce, such that the at least one seed is substantially covered by the patterning coating in the first portion.

In some non-limiting examples, the method may further comprise, after the action of disposing, an action of: seeding the first layer surface with at least one seed, comprising a seed material, about which the deposited material tends to coalesce, wherein an initial sticking probability against deposition of the seed material on a surface of the patterning coating is substantially less than the initial sticking probability against deposition of the seed material onto the second layer surface, such that the first portion is substantially devoid of the seeds.

In some non-limiting examples, the action of depositing may comprise an action of: co-depositing the deposited material with a co-deposited dielectric material.

In some non-limiting examples, the method may further comprise, before the action of depositing, an action of: establishing a supporting dielectric layer as the first layer surface.

In some non-limiting examples, the method may further comprise, after the action of depositing, an action of: covering the at least one EM radiation-absorbing layer with a covering dielectric layer.

### DESCRIPTION

Layered Device

The present disclosure relates generally to layered semiconductor devices, and more specifically, to opto-electronic devices. An opto-electronic device may generally encompass any device that converts electrical signals into photons and vice versa.

Those having ordinary skill in the relevant art will appreciate that, while the present disclosure is directed to opto-electronic devices, the principles thereof may be applicable to any panel having a plurality of layers, including without limitation, at least one layer of conductive deposited material 631 (FIG. 6), including as a thin film, and in some non-limiting examples, through which electromagnetic (EM) signals may pass, entirely or partially, at an angle relative to a plane of at least one of the layers.

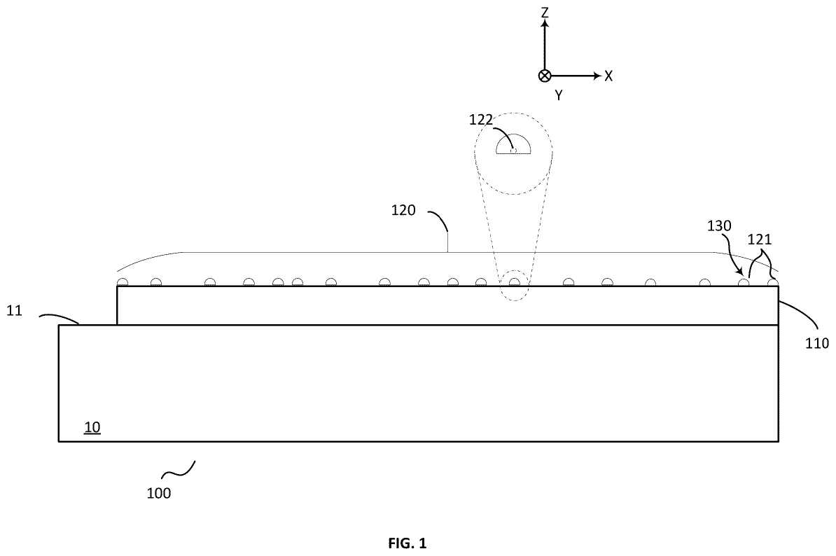

Turning now to FIG. 1, there may be shown a cross-sectional view of an example layered device 100. In some non-limiting examples, as shown in greater detail in FIG. 6, the device 100 may comprise a plurality of layers deposited upon a substrate 10, including without limitation, a first layer 110.

A lateral axis, identified as the X-axis, may be shown, together with a longitudinal axis, identified as the Z-axis. A second lateral axis, identified as the Y-axis, may be shown as being substantially transverse to both the X-axis and the Z-axis. At least one of the lateral axes may define a lateral aspect of the device 100. The longitudinal axis may define a transverse aspect of the device 100. Some figures herein may be shown in plan. In such plan view(s), a pair of lateral axes, identified as the X-axis and Y-axis respectively, which in some non-limiting examples may be substantially transverse to one another, are shown. At least one of these lateral axes may define a lateral aspect of the device 100.

The layers of the device 100 may extend in the lateral aspect substantially parallel to a plane defined by the lateral axes. Those having ordinary skill in the relevant art will appreciate that the substantially planar representation shown in FIG. 1 may be, in some non-limiting examples, an abstraction for purposes of illustration. In some non-limiting examples, there may be, across a lateral extent of the device 100, localized substantially planar strata of different thicknesses and dimension, including, in some non-limiting examples, the substantially complete absence of a layer, and/or layer(s) separated by non-planar transition regions (including lateral gaps and even discontinuities).

Thus, while for illustrative purposes, the device 100 may be shown in its cross-sectional aspect as a substantially stratified structure of substantially parallel planar layers, such display panel may illustrate locally, a diverse topography to define features, each of which may substantially exhibit the stratified profile discussed in the cross-sectional aspect.

### EM Radiation Absorption

A nanoparticle (NP) is a particle structure 121 (FIG. 1) of matter whose predominant characteristic size is of nanometer (nm) scale, generally understood to be between about: 1-300 nm. At nm scale, NPs of a given material may possess unique properties (including without limitation, optical, chemical, physical, and/or electrical) relative to the same material in bulk form.

These properties may be exploited when a plurality of NPs is formed into a layer of a layered semiconductor device, including without limitation, an opto-electronic device, to improve its performance.

Current mechanisms for introducing such a layer of NPs into a device have some drawbacks.

First, typically, such NPs are formed into a close-packed layer, and/or dispersed into a matrix material, of such device. Consequently, the thickness of such an NP layer is typically much thicker than the characteristic size of the NPs themselves. The thickness of such NP layer may impart undesirable characteristics in terms of device performance, device stability, device reliability, and/or device lifetime that may reduce or even obviate any perceived advantages provided by the unique properties of NPs.

Second, techniques to synthesize NPs, in and for use in such devices may introduce large amounts of carbon (C), oxygen (O), and/or sulfur (S) through various mechanisms.

By way of non-limiting example, wet chemical methods may be typically used to introduce NPs that have a precisely controlled characteristic size, size distribution, shape, surface coverage, configuration, and/or deposited density into a device. However, such methods typically employ an organic capping group (such as the synthesis of citrate-capped silver (Ag) NPs) to stabilize the NPs, but such organic capping groups introduce C, O, and/or S, into the synthesized NPs.

Still further, a NP layer deposited from solution may typically comprise C, O, and/or S, because of the solvents used during deposition.

Additionally, these elements may be introduced as contaminants during the wet chemical process and/or the deposition of the NP layer.

However introduced, the presence of a high amount of C, O, and/or S, in the NP layer of such a device, may erode the performance, stability, reliability, and/or lifetime of such device.

Third, when depositing an NP layer from solution, as the employed solvents dry, the NP layer tends to have non-uniform properties across the NP layer, and/or between different patterned regions of such layer. In some non-limiting examples, an edge of a given NP layer may be considerably thicker or thinner than an internal region of such NP layer, which disparities may adversely impact the device performance, stability, reliability, and/or lifetime.

Fourth, while there are other methods and/or processes, beyond wet chemical synthesis and solution deposition processes, of synthesizing and/or depositing NPs, including without limitation, a vacuum-based process such as, without limitation, PVD, existing methods tend to provide poor control of the characteristic size, size distribution, shape, surface coverage, configuration, deposited density, and/or dispersity of the NPs deposited thereby. By way of non-limiting example, in a conventional PVD process, the NPs tend to form a close-packed film as their size increases. As a result, methods such as conventional PVD methods are generally not well-suited to form an NP layer of large disperse NPs with low surface coverage. Rather, the poor control of characteristic size, size distribution, shape, surface coverage, configuration, and/or deposited density, imparted by such conventional methods may result in poor device performance, stability, reliability, and/or lifetime.

EM radiation-absorbing coatings, including without limitation, black matrices, take advantage of plasmonics, a branch of nanophotonics, which studies the resonant interaction of EM radiation with metals. Those having ordinary skill in the relevant art will appreciate that metal NPs may exhibit LSP excitations and/or coherent oscillations of free electrons, whose optical response may be tailored by varying a characteristic size, size distribution, shape, surface coverage, configuration, deposited density, and/or composition of the nanostructures. Such optical response, in respect of EM radiation-absorbing coatings, may include absorption of EM radiation incident thereon, thereby reducing reflection thereof.

Turning again to FIG. 1, in some non-limiting examples, an EM radiation-absorbing (NP) layer 120 may be employed as part of a layered semiconductor device 100, for absorbing EM radiation incident thereon, or concomitantly, for reducing reflection off the device 100.

In some non-limiting examples, an EM radiation-absorbing layer 120 may be deposited on and/or over the exposed layer surface 11, including without limitation, of an underlying layer, such as, without limitation, the first layer 110.

In some non-limiting examples, the EM radiation-absorbing layer 120 may be formed by depositing discrete metal particle structures 121, including as a discontinuous layer 130, which in some non-limiting examples, may comprise NPs, of a given characteristic size, size distribution, shape, surface coverage, configuration, deposited density, and/or composition.

In some non-limiting examples, the particle structures 121 making up the EM radiation-absorbing layer 120 may be, and/or comprise discrete metal plasmonic islands or clusters.

Those having ordinary skill in the relevant art will appreciate that, having regard to the mechanism by which materials are deposited, due to possible stacking and/or clustering of monomers and/or atoms, an actual size, height, weight, thickness, shape, profile, and/or spacing of the particle structures 121 in the EM radiation-absorbing layer 120 may be, in some non-limiting examples, substantially non-uniform. Additionally, although the particle structures 121 in the EM radiation-absorbing layer 120 are illustrated as having a given profile, this is intended to be illustrative only, and not determinative of any size, height, weight, thickness, shape, profile, and/or spacing of such particle structures 121.

In some non-limiting examples, the absorption may be concentrated in an absorption spectrum that is a range of the EM spectrum, including without limitation, the visible spectrum, and/or a sub-range thereof. In some non-limiting examples, employing an EM radiation-absorbing layer 120 as part of a layered semiconductor device 100 may reduce reliance on a polarizer therein.

Those having ordinary skill in the relevant art will appreciate that in some non-limiting examples, a plurality of EM radiation-absorbing layers 120 may be disposed on one another, whether or not separated by additional layers, with varying lateral aspects and having different absorption spectra. In this fashion, the absorption of certain regions of the device may be tuned according to one or more desired absorption spectra.

While the EM radiation-absorbing layer 120 may absorb EM radiation incident thereon from beyond the layered semiconductor device 100, thus reducing reflection, those having ordinary skill in the relevant art will appreciate that, in some non-limiting examples, the EM radiation-absorbing layer 120 may absorb EM radiation incident thereon that is emitted by the device 100.

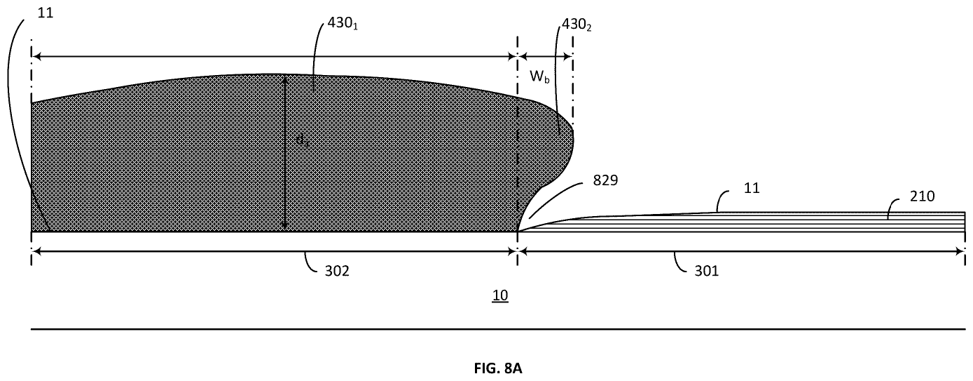

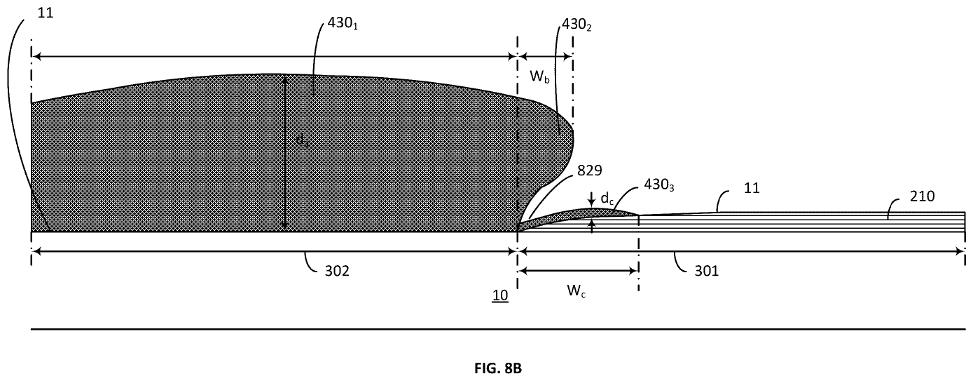

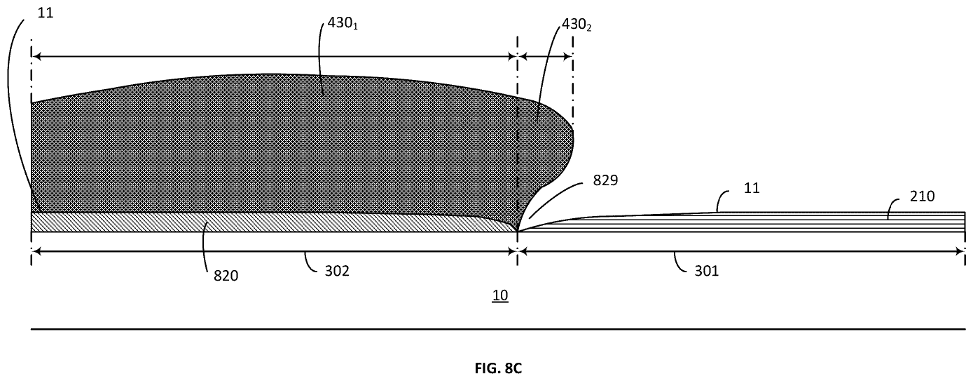

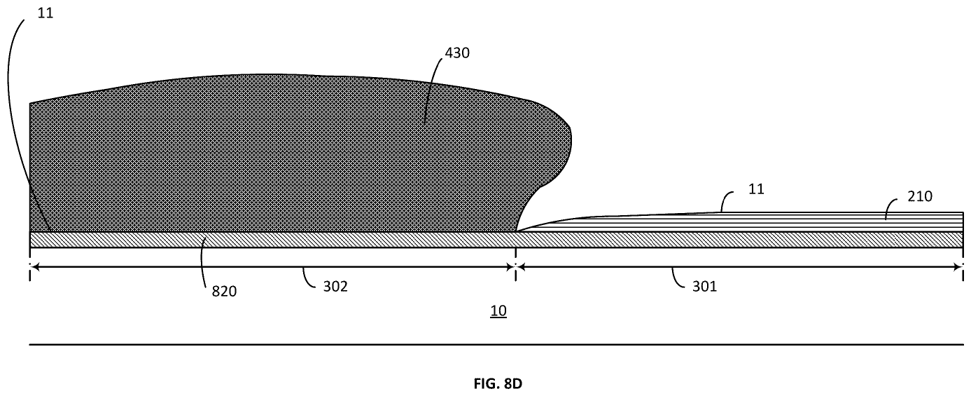

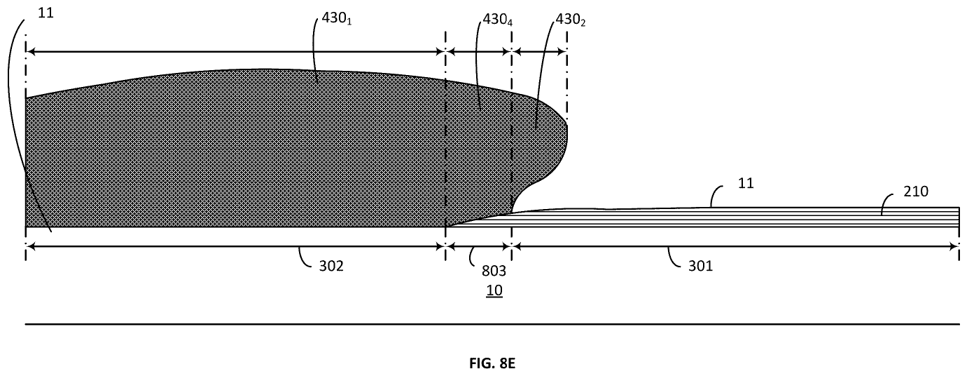

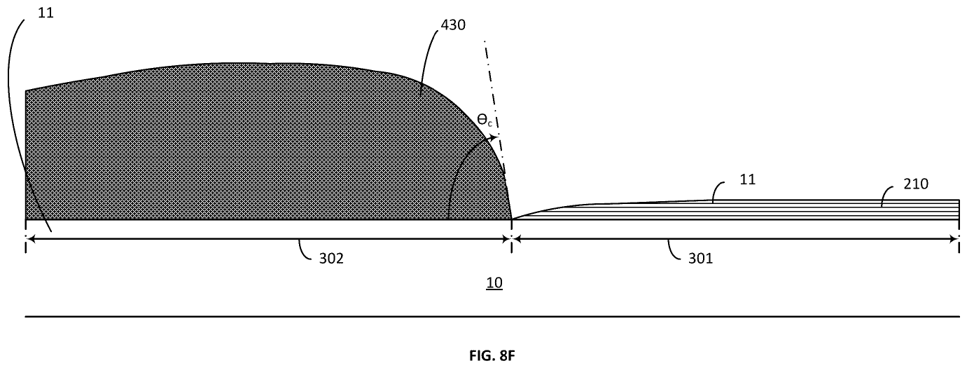

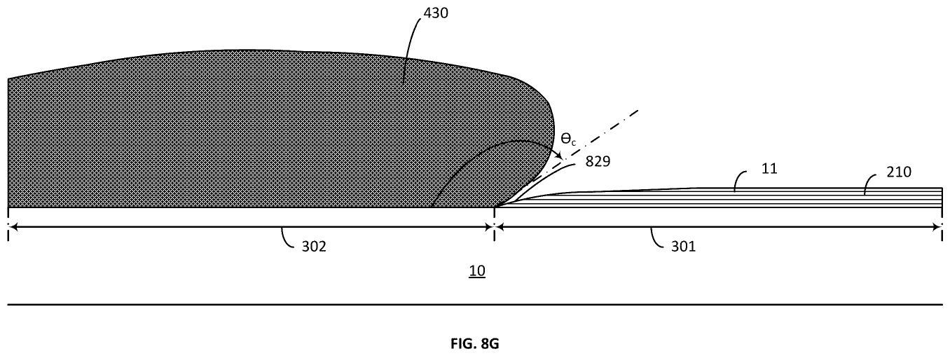

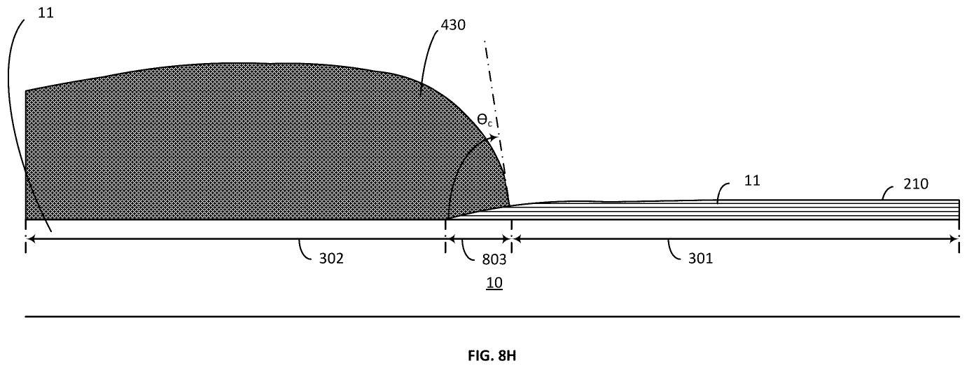

In some non-limiting examples, such particle structures 121 may be formed by depositing a scant amount (in some non-limiting examples, having an average layer thickness that may be on the order of a few, or a fraction of an angstrom), of a deposited material 631 on an exposed layer surface 11 of an underlying layer, including without limitation, the first layer 110. In some non-limiting examples, the exposed layer surface 11 may be of a nucleation promoting coating (NPC) 820 (FIG. 8C).

### Seeds

In some non-limiting examples, the size, height, weight, thickness, shape, profile, and/or spacing of the particle structures 121 in the EM radiation-absorbing layer 120 may be, to a greater or lesser extent, specified by depositing seed material, as part of the EM radiation-absorbing layer 120, in a templating layer at appropriate locations and/or at an appropriate density and/or stage of deposition. In some non-limiting examples, such seed material may act as a seed 122 or heterogeneity, to act as a nucleation site such that when a deposited material 631 is deposited thereon, the deposited material 631 may tend to coalesce around each seed 122 to form the particle structures 121.

In some non-limiting examples, the seed material may comprise a metal, including without limitation, ytterbium (Yb) or silver (Ag). In some non-limiting examples, the seed material may have a high wetting property with respect to the deposited material 631 to be deposited thereon to form the particle structures 121, providing a relatively low contact angle between the seed 122 and the deposited material 631 deposited thereon and coalescing thereto.

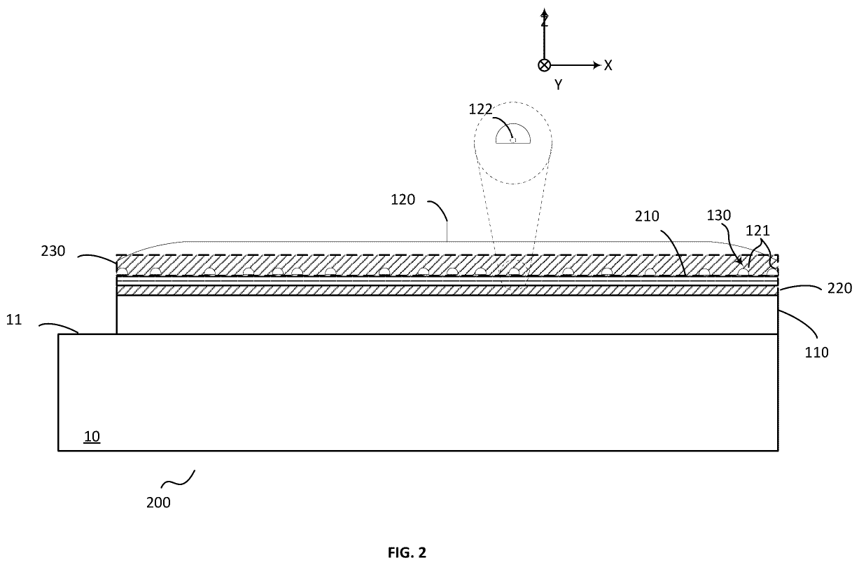

In some non-limiting examples, the seeds 122 may be deposited in the templating layer, across the exposed layer surface 11, including without limitation, of a supporting dielectric layer 220 (FIG. 2), of the device 100, in some non-limiting examples, using an open mask and/or a mask-free deposition process, of the seed material.

### Patterning Coating for Purpose of Depositing EM Radiation-Absorbing Layer

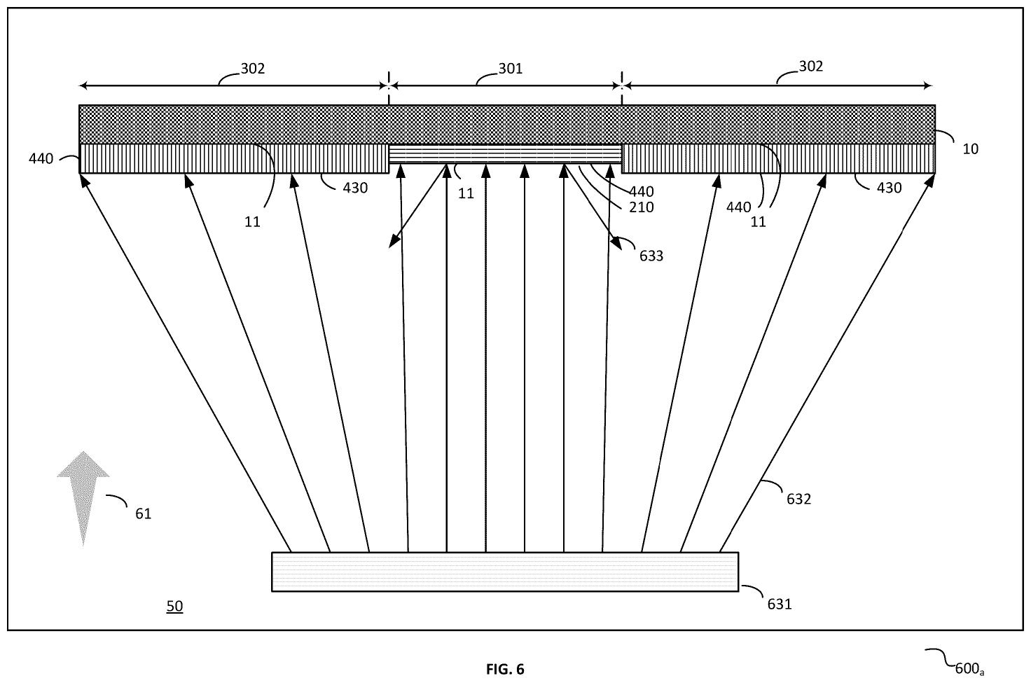

Turning now to FIG. 2, in which a version 200 of the device 100 is shown, with additional optional layers, in some non-limiting examples, a patterning coating 210 may be selectively deposited, for purposes of depositing the EM radiation-absorbing layer 120, across an underlying layer, including without limitation, the first layer 110, by the interposition, between a patterning material 511 (FIG. 5) of which the patterning coating 210 is comprised, and the exposed layer surface 11, of a shadow mask 515, which in some non-limiting examples, may be an FMM.

After selective deposition of the patterning coating 210, a deposited material 631 (FIG. 6) may be deposited over the device 200, in some non-limiting examples, using an open mask and/or a mask-free deposition process, as, and/or to form, particle structures 121 therein that comprise the EM radiation-absorbing layer 120, including without limitation, by coalescing around respective seeds 122, if any, that are not covered by the patterning coating 210.

The patterning coating 210 for purposes of depositing the EM radiation-absorbing layer 120, may provide, a surface with a relatively low initial sticking probability against the deposition of the deposited material 631, that may be substantially less than an initial sticking probability against the deposition of the deposited material 631, of the exposed layer surface 11 of the underlying layer of the device 200.

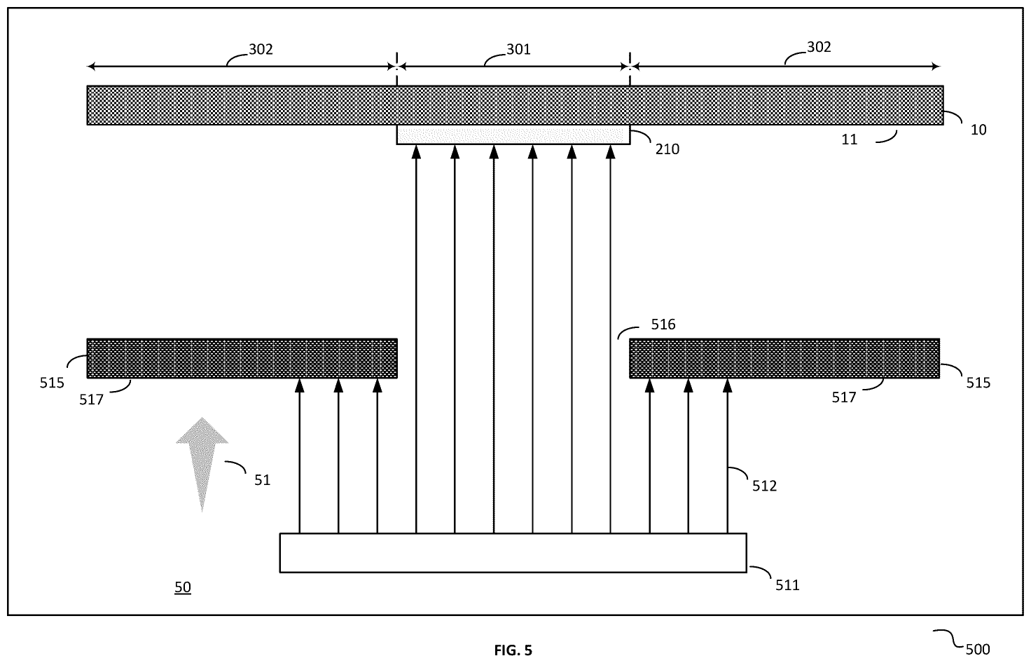

Thus, the exposed layer surface 11 of the underlying layer may be substantially devoid of a closed coating 440 (FIG. 4) of the deposited material 631 that may be deposited to form the particle structures 121, including without limitation, by coalescing around the seeds 122 not covered by the patterning coating 210.

In this fashion, the patterning coating 210 may be selectively deposited, including without limitation, using a shadow mask 515, to allow the deposited material 631 to be deposited, including without limitation, using an open mask and/or a mask-free deposition process, so as to form particle structures 121, including without limitation, by coalescing around respective seeds 122.

In some non-limiting examples, the deposited material 631 to be deposited over the exposed layer surface 11 of the device 200 may have a dielectric constant property that may, in some non-limiting examples, have been chosen to facilitate and/or increase the absorption, by the EM radiation-absorbing layer 120, of EM radiation generally, or in some non-limiting examples, in a wavelength range of the EM spectrum, including without limitation, the visible spectrum, and/or a sub-range and/or wavelength thereof, including without limitation, corresponding to a specific colour.

In some non-limiting examples, a patterning coating 210 for purposes of depositing the EM radiation-absorbing layer 120 may comprise a patterning material 511 that exhibits a relatively low initial sticking probability with respect to the seed material and/or the deposited material 631 such that the surface of such patterning coating 210 may exhibit an increased propensity to cause the deposited material 631 (and/or the seed material) to be deposited as particle structures 121, in some examples, relative to patterning coatings 210 and/or patterning materials 511 of which they may be comprised, used for purposes of inhibiting deposition of a closed coating 440 of the deposited material, including for applications discussed herein other than the formation of the EM radiation-absorbing layer 120.

In some non-limiting examples, a patterning coating 210 for purposes of depositing the EM radiation-absorbing layer 120 may comprise a plurality of materials, wherein at least one material thereof is a patterning material 511, including without limitation, a patterning material 511 that exhibits such a relatively low initial sticking probability with respect to the seed material and/or the deposited material 631 as discussed above.

In some non-limiting examples, a first one of the plurality of materials may be a patterning material 511 that has a first initial sticking probability against deposition of the deposited material 631 and/or the seed material and a second one of the plurality of materials may be a patterning material 511 that has a second initial sticking probability against deposition of the deposited material 631 and/or the seed material, wherein the second initial sticking probability exceeds the first initial sticking probability.

In some non-limiting examples, the first initial sticking probability and the second initial sticking probability may be measured using substantially identical conditions and parameters.

In some non-limiting examples, the first one of the plurality of materials may be doped, covered, and/or supplemented with the second one of the plurality of materials, such that the second material may act as a seed or heterogeneity, to act as a nucleation site for the deposited material 631 and/or the seed material.

In some non-limiting examples, the second one of the plurality of materials may comprise an NPC 820. In some non-limiting examples, the second one of the plurality of materials may comprise an organic material, including without limitation, a polycyclic aromatic compound, and/or a material comprising a non-metallic element including without limitation, O, S, nitrogen (N), or C, whose presence might otherwise be considered to be a contaminant in the source material, equipment used for deposition, and/or the vacuum chamber environment. In some non-limiting examples, the second one of the plurality of materials may be deposited in a layer thickness that is a fraction of a monolayer, to avoid forming a continuous coating 440 thereof. Rather, the monomers 632 (FIG. 6) of such material may tend to be spaced apart in the lateral aspect so as to form discrete nucleation sites for the deposited material 631 and/or seed material.

Co-Deposition with Dielectric Material

Although not shown, in some non-limiting examples, the particle structures 121 of which the EM radiation-absorbing layer 120 may be comprised, may be formed without the use of seeds 122, including without limitation, by co-depositing the deposited material 631 with a dielectric material.

In some non-limiting examples, the deposited material 631 to be deposited over the exposed layer surface 11 of the device 200 may be co-deposited with a co-deposited dielectric material, which in some non-limiting examples, may be the same or different from the supporting dielectric material used to form the supporting dielectric layer 220.

In some non-limiting examples, a ratio of the deposited material to the co-deposited dielectric material may be in a range of at least one of between about: 50:1-5:1, 30:1-5:1, or 20:1-10:1 In some non-limiting examples, the ratio may be at least one of about: 50:1, 45:1, 40:1, 35:1, 30:1, 25:1, 20:1, 19:1, 15:1, 12.5:1, 10:1, 7.5:1, or 5:1.

In some non-limiting examples, the co-deposited dielectric material may have an initial sticking probability, against the deposition of the deposited material 631 with which it may be co-deposited, that may be less than 1.

In some non-limiting examples, a ratio of the deposited material 631 to the co-deposited dielectric material may vary depending upon the initial sticking probability of the co-deposited dielectric material against the deposition of the deposited material 631.

In some non-limiting examples, the co-deposited dielectric material may be an organic material. In some non-limiting examples, the co-deposited dielectric material may be a semiconductor. In some non-limiting examples, the co-deposited dielectric material may be an organic semiconductor.

In some non-limiting examples, co-depositing the deposited material 631 with the co-deposited dielectric material may facilitate formation of particle structures 121 in the EM radiation-absorbing layer 120 in the absence of a templating layer comprising the seeds 122.

In some non-limiting examples, co-depositing the deposited material 631 with the co-deposited dielectric material may facilitate and/or increase absorption, by the EM radiation-absorbing layer 120, of EM radiation generally, or in some non-limiting examples, in a wavelength range of the EM spectrum, including without limitation, the visible spectrum, and/or a sub-range and/or wavelength thereof, including without limitation, corresponding to a specific colour.

### Supporting Dielectric Layer

In some non-limiting examples, the EM radiation-absorbing layer 120 may comprise a supporting dielectric layer 220 that may be disposed on an exposed layer surface 11 of the underlying layer, including without limitation, the first layer 110, and/or an EM radiation-absorbing layer 120 that may have been previously deposited on the device 200, by deposition thereon of a supporting dielectric material.

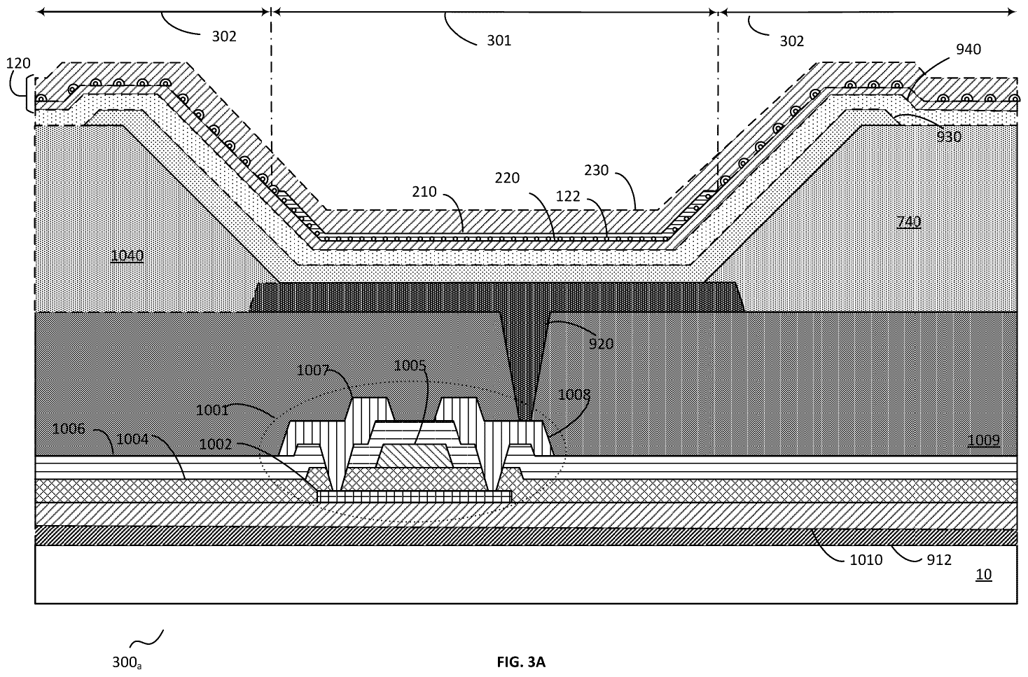

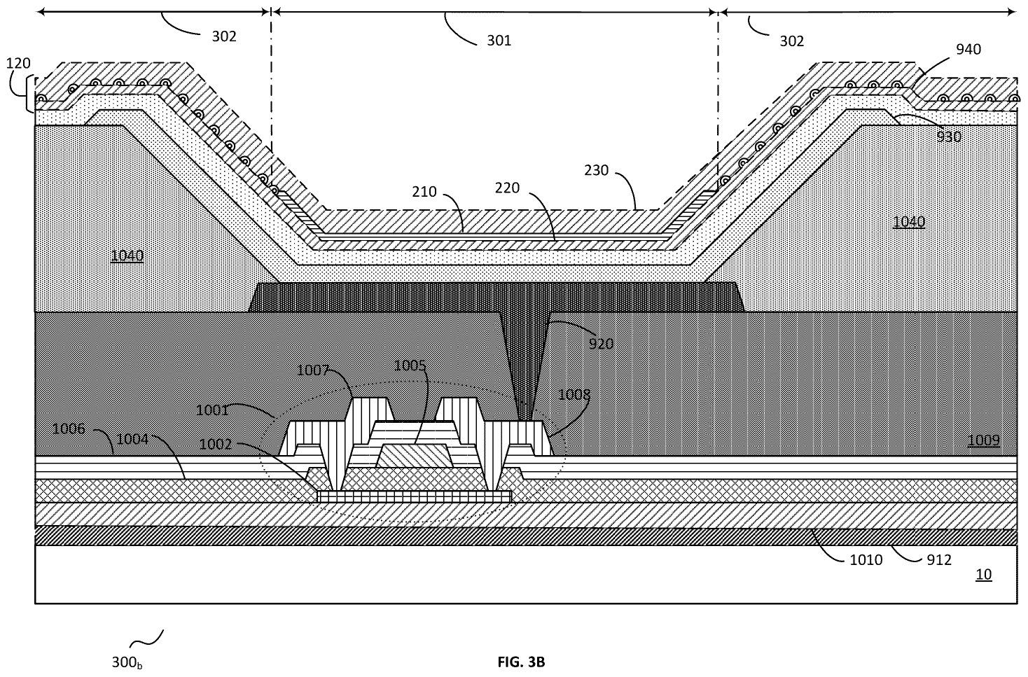

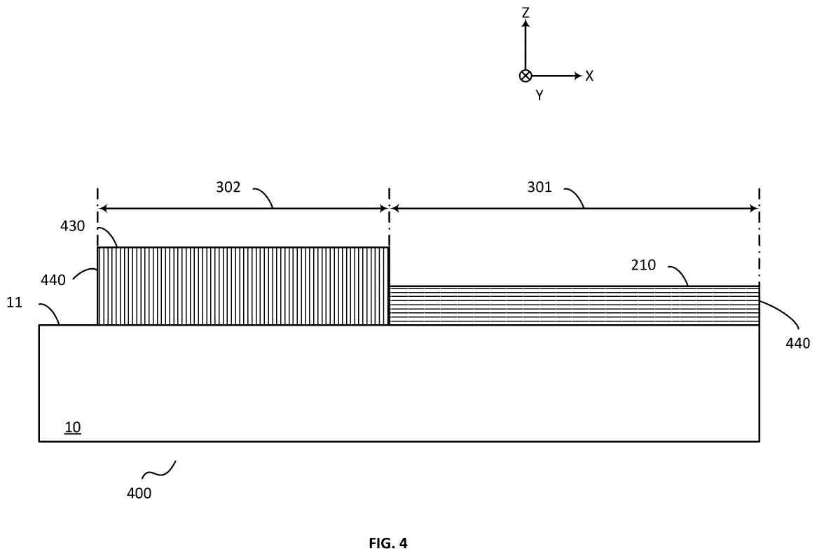

In some non-limiting examples, the supporting dielectric layer 220 may be selectively deposited only onto a part of the exposed layer surface 11, by the interposition, between the supporting dielectric material and the exposed layer surface 11, of a shadow mask 515 (FIG. 5), which in some non-limiting examples, may be an FMM. In some non-limiting examples, the supporting dielectric layer 220 may be disposed across both a first portion 301 (FIG. 3A) and a second portion 302 (FIG. 3A) of a lateral aspect of an exposed layer surface 11 of the device 200. In some non-limiting examples, the second portion 302 may comprise that part of the exposed layer surface 11 of the underlying layer of the device 100 that lies beyond the first portion 301. In some non-limiting examples, the supporting dielectric layer 220 may be limited to only the second portion 302.

In some non-limiting examples, the supporting dielectric layer 220 may comprise a capping layer (CPL) that may have been previously deposited on an exposed layer surface 11 of the device 200.

In some non-limiting examples, the supporting dielectric layer 220 may serve to electrically de-couple, in whole or in part, the particle structures 121 of an underlying EM radiation-absorbing layer 120, that may otherwise form the exposed layer surface 11 of the device 200, on which the particle structures 121 may otherwise be deposited thereon.

In some non-limiting examples, the supporting dielectric layer 220 may serve to facilitate and/or increase absorption, by the EM radiation-absorbing layer 120, of EM radiation generally, or in some non-limiting examples, in a wavelength range of the EM spectrum, including without limitation, the visible spectrum, and/or a sub-range and/or wavelength thereof, including without limitation, corresponding to a specific colour.

In some non-limiting examples, the supporting dielectric layer 220 may act as a patterning coating 210 for purposes of depositing the EM radiation-absorbing layer 120.

### Covering Dielectric Layer

In some non-limiting examples, the EM radiation-absorbing layer 120 may comprise a covering dielectric layer 230 that may be disposed on an exposed layer surface 11 of the device 200, by deposition thereon of a covering dielectric material to cover the particle structures 121. In some non-limiting examples, the covering dielectric material used to form the covering dielectric layer 230 may be the same or different from the supporting dielectric material used to form the supporting dielectric layer 220.

In some non-limiting examples, the covering dielectric layer 230 may be selectively deposited only onto a part of the exposed layer surface 11, by the interposition, between the covering dielectric material and the exposed layer surface 11, of a shadow mask 515, which in some non-limiting examples, may be an FMM. In some non-limiting examples, the covering dielectric layer 230 may thus be limited to only the second portion 302. In some non-limiting examples, the covering dielectric layer 230 may be disposed across both the first portion 301 and the second portion 302.

In some non-limiting examples, the covering dielectric layer 230 may comprise a CPL that may have been previously deposited on an exposed layer surface 11 of the device 200.

In some non-limiting examples, the covering dielectric layer 230 may serve to electrically de-couple, in whole or in part, the particle structures 121, including without limitation, any seeds 122 contained thereon, of an overlying EM radiation-absorbing layer 120, that may otherwise be deposited on the exposed layer surface 11 of the device 200, on which the covering dielectric layer 230 is disposed.

In some non-limiting examples, the covering dielectric layer 230 may serve to facilitate and/or increase absorption, by the EM radiation-absorbing layer 120, of EM radiation generally, or in some non-limiting examples, in a wavelength range of the EM spectrum, including without limitation, the visible spectrum, and/or a sub-range and/or wavelength thereof, including without limitation, corresponding to a specific colour.

In some non-limiting examples, the covering dielectric layer 230 may serve as a supporting dielectric layer 220 of a further EM radiation-absorbing layer 120.

### Absorption Around Emissive Regions

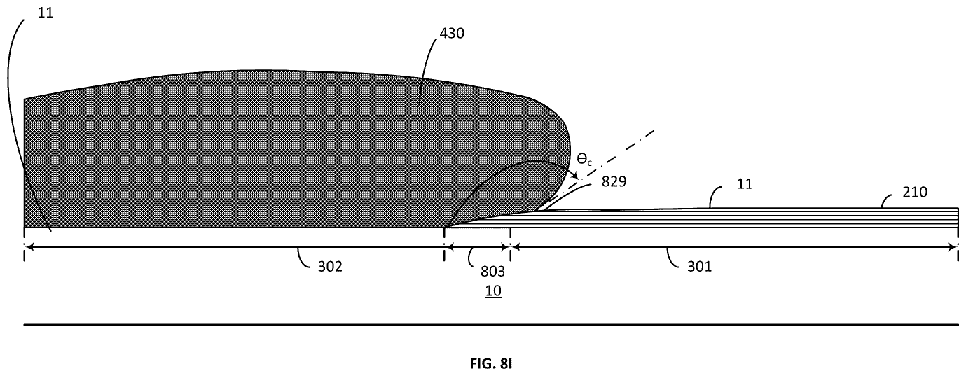

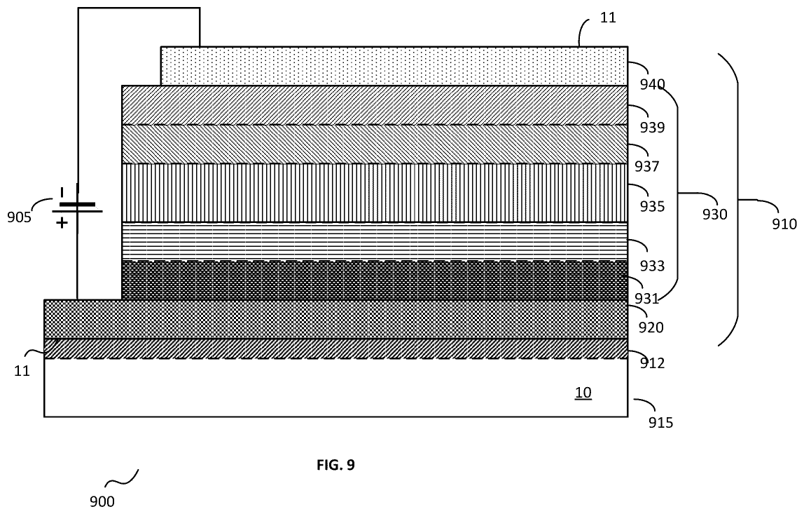

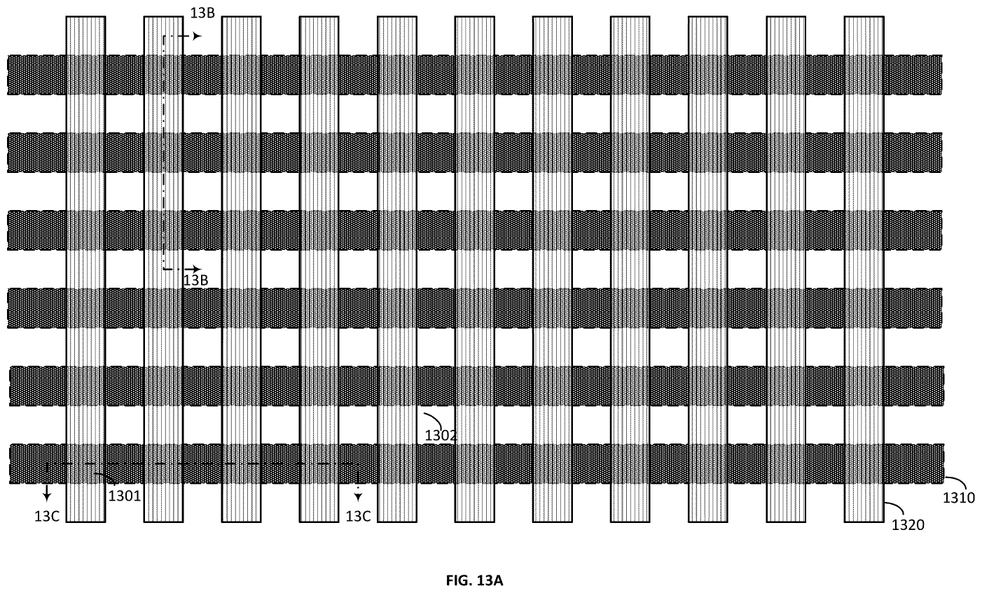

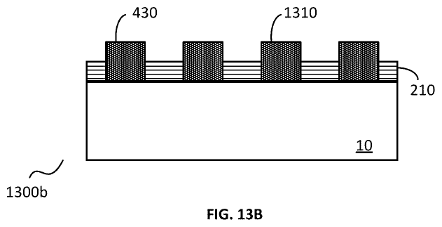

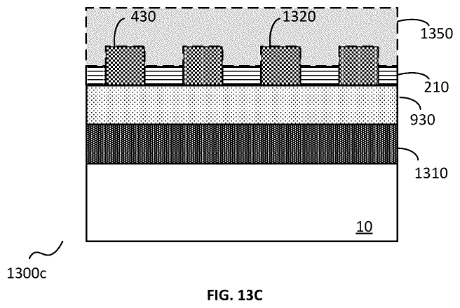

In some non-limiting examples, the layered semiconductor device 100 may be an opto-electronic device 200, such as an organic light-emitting diode (OLED), comprising at least one emissive region 1301 (shown in the context of a PMOLED structure in FIG. 13A). In some non-limiting examples, the emissive region 1301 corresponds to at least one semiconducting layer 930 (FIG. 9) disposed between a first electrode 920 (FIG. 9), which in some non-limiting examples, may be an anode, and a second electrode 940 (FIG. 9), which in some non-limiting examples, may be a cathode. The anode and cathode may be electrically coupled with a power source 905 (FIG. 9) and respectively generate holes and electrons that migrate toward each other through the at least one semiconducting layer 930. When a pair of holes and electrons combine, a photon may be emitted.

In some non-limiting examples, the EM radiation-absorbing layer 120 may be deposited on and/or over the exposed layer surface 11 of the second electrode 940.

In some non-limiting examples, a lateral aspect of an exposed layer surface 11 of the device 100 may comprise a first portion 301 and a second portion 302. In some non-limiting examples, the second portion 302 may comprise that part of the exposed layer surface 11 of the underlying layer of the device 100 that lies beyond the first portion 3301.

In some non-limiting examples, the EM radiation-absorbing layer 120 may be omitted, or may not extend over the first portion 301, but rather only extends over the second portion 302. In some non-limiting examples, as shown by way of non-limiting example in FIG. 3A, the first portion 301 may correspond, to a greater or lesser extent, to a lateral aspect 1020 of at least one non-emissive region 1302 (FIG. 13A) of a version 300ₐ of the device 100, in which the seeds 122 may be deposited before deposition of a patterning coating 210.

Such a non-limiting configuration may be appropriate to enable and/or to maximize transmittance of EM radiation emitted from the at least one emissive region 1301, while reducing reflection of external EM radiation incident on an exposed layer surface 11 of the device 100.

Thus, as shown in FIG. 3A, in such a scenario, the patterning coating 210 is deposited not for purposes of depositing the EM radiation-absorbing layer 120, but for limiting the lateral extent thereof, the patterning material 511 of which such patterning coating 210 may be comprised may not exhibit a relatively low initial sticking probability with respect to the seed material and/or the deposited material 631, such as discussed above.

Those having ordinary skill in the relevant art will appreciate that in some non-limiting examples, the EM radiation-absorbing layer 120 may be omitted from region(s) of the device 100 other than, and/or in addition to, the emissive region(s) 1301 of the device 100, and the second portion 302 may, in such examples, correspond to, and/or comprise such other region(s).

In some non-limiting examples, the absorption may be concentrated in an absorption spectrum that is a range of the EM spectrum, including without limitation, the visible spectrum, and/or a sub-range thereof. In some non-limiting examples, employing an EM radiation-absorbing layer 120 as part of a layered semiconductor device 100 may reduce reliance on a polarizer therein.

Those having ordinary skill in the relevant art will appreciate that in some non-limiting examples, a plurality of EM radiation-absorbing layers 120 may be disposed on one another, whether or not separated by additional layers, with varying lateral aspects and having different absorption spectra. In this fashion, the absorption of certain regions of the device may be tuned according to one or more desired absorption spectra.

While the EM radiation-absorbing layer 120 may absorb EM radiation incident thereon from beyond the layered semiconductor device 100, thus reducing reflection, those having ordinary skill in the relevant art will appreciate that, in some non-limiting examples, the EM radiation-absorbing layer 120 may absorb EM radiation incident thereon that is emitted by the device 100.

In some non-limiting examples, such as shown in FIG. 3A, the patterning coating 210 may be deposited on the exposed layer surface 11, after deposition of the seeds 122 in the templating layer, if any, such that the seeds 122 may be deposited across both the first portion 301 and the second portion 302, and the patterning coating 210 may cover the seeds 122 deposited across the first portion 301.

In some non-limiting examples, the patterning coating 210 may provide a surface with a relatively low initial sticking probability against the deposition, not only of the deposited material 631, but also of the seed material. In such examples, such as is shown in the example version 300_{b} of the device 100 in FIG. 3B, the patterning coating 210 may be deposited before, not after, any deposition of the seed material.

After selective deposition of the patterning coating 210 across the first portion 301, a conductive deposited material 631 (FIG. 6) may be deposited over the device 100, in some non-limiting examples, using an open mask and/or a mask-free deposition process, but may remain substantially only within the second portion 302, which may be substantially devoid of the patterning coating 210, as, and/or to form, particle structures 121 therein, including without limitation, by coalescing around respective seeds 122, if any, that are not covered by the patterning coating 210.

After selective deposition of the patterning coating 210 across the first portion 301, the seed material, if deposited, may be deposited in the templating layer, across the exposed layer surface 11 including without limitation, of the supporting dielectric layer 220, of the device 300, in some non-limiting examples, using an open mask and/or a mask-free deposition process, but the seeds 122 may remain substantially only within the second portion, which may be substantially devoid of the patterning coating 110.

Further, the deposited material 631 may be deposited across the exposed layer surface 11, including without limitation, of the supporting dielectric layer 220, of the device 300, in some non-limiting examples, using an open mask and/or a mask-free deposition process, but the deposited material 631 may remain substantially only within the second portion 302, which may be substantially devoid of the patterning coating 210, as and/or to form particle structures 121 therein, including without limitation, by coalescing around respective seeds 122.

The patterning coating 210 may provide, within the first portion 301, a surface with a relatively low initial sticking probability against the deposition of the deposited material 631 and/or the seed material, if any, that may be substantially less than an initial sticking probability against the deposition of the deposited material 631, and/or the seed material, if any, of the exposed layer surface 11 of the underlying layer of device 300 within the second portion 302.

Thus, the first portion 301 may be substantially devoid of a closed coating 440 of the deposited material 631 that may be deposited within the second portion 302 to form the particle structures 121, including without limitation, by coalescing around the seeds 122, and/or of any seeds 122.

Those having ordinary skill in the relevant art will appreciate that, even if some of the deposited material 631, and/or some of the seed material, remains within the first portion 301, the amount of any such deposited material 631, and/or seeds 122 formed of the seed material, in the first portion 301, may be substantially less than in the second portion 302, and that any such deposited material 631 in the first portion 301 may tend to form a discontinuous layer 130 that may be substantially devoid of particle structures 121. Even if some of such deposited material 631 in the first portion were to form a particle structure 121, including without limitation, about a seed 122 formed of the seed material, the size, height, weight, thickness, shape, profile, and/or spacing of any such particle structures may nevertheless be sufficiently different from that of the particle structures 121 of the EM radiation-absorbing layer 120 of the second portion 302, that absorption of EM radiation in the first portion 301 may be substantially less than in the second portion 302, including without limitation, in a wavelength range of the EM spectrum, including without limitation, the visible spectrum, and/or a sub-range and/or wavelength thereof, including without limitation, corresponding to a specific colour.

In this fashion, the patterning coating 210 may be selectively deposited, including without limitation, using a shadow mask 515, to allow the deposited material 631 to be deposited, including without limitation, using an open mask and/or a mask-free deposition process, so as to form particle structures 121, including without limitation, by coalescing around respective seeds 122.

A series of example samples were fabricated on glass substrates 10 to measure the reflectance or transmittance of the samples. The description of the construction of each sample is set out below:

TABLE 1

| | | Reflectance/ |
|---|---|---|
| | | Transmittance |
| Sample | Description | (%) |
| Sample 1 | Mg (50 nm) | Reflectance 91.5 |
| Sample 2 | Mg (50 nm)/Supporting Dielectric (20 nm)/ | Reflectance 30.0 |
| | Yb (0.1 nm)/Mg (30 nm) | |
| Sample 3 | Mg (50 nm)/Supporting Dielectric (20 nm)/ | Reflectance 4.6 |
| | Yb (0.1 nm)/Mg (30 nm)/Covering | |
| | Dielectric (40 nm) | |
| Sample 4 | Co-deposited Dielectric: Mg (1:19, | Reflectance 88.5 |
| | 100 nm) | |
| Sample 5 | Co-deposited Dielectric: Mg (1:19, 100 | Reflectance 6.1 |
| | nm)/Covering Dielectric (60 nm) | |
| Sample | Supporting Dielectric (40 nm)/Yb (3 nm)/ | Reflectance 31.3 |
| 6A | Co-deposited Dielectric: Mg (1:10, 100 | |
| | nm) | |
| Sample | Supporting Dielectric (40 nm)/Yb (3 nm)/ | Reflectance 2.3 |
| 7A | Co-deposited Dielectric: Mg (1:10, 100 | |
| | nm)/Covering Dielectric (50 nm) | |
| Sample | Supporting Dielectric (40 nm)/Patterning | Transmittance |
| 6B | Coating (15 nm)/Co-deposited Dielectric: | 86.3 |
| | Mg (1:10, 100 nm) | |
| Sample | Supporting Dielectric (40 nm)/Patterning | Transmittance |
| 7B | Coating (15 nm)/Co-deposited Dielectric: | 92.1 |
| | Mg (1:10, 100 nm)/Covering Dielectric | |
| | (50 nm) | |

The reflectance of a sample was measured by directing an external EM radiation source toward the exposed layer surface 11 of the sample (opposite to the glass substrate 10), and by measuring a relative amount of EM radiation reflected therefrom.

The transmittance of a sample was measured by directing an external EM radiation source toward the exposed layer surface 11 of the sample (opposite to the glass substrate 10), and by measuring a relative amount of EM radiation transmitted therethrough.

The reflectance or transmittance of each sample summarized in Table 1 was measured at a wavelength of 550 nm.

Those having ordinary skill in the relevant art will appreciate that structures exhibiting relatively low reflectance may, in some non-limiting examples, be suitable for providing an EM radiation-absorbing layer 120.

Sample 1 is a comparative sample in which a 50 nm thick layer of Mg was deposited onto a glass substrate, resulting in a highly reflective surface.

Sample 2 is an example structure in which an EM radiation-absorbing layer 120, comprising a supporting dielectric layer 220, a templating layer of Yb seeds 122 and particle structures 121 formed from deposited material 631 of Mg coalescing therearound, has been deposited onto the reflective Mg layer surface of Sample 1, resulting in a reduced reflectance of about 30% (a reduction of approximately ⅔ relative to that of Sample 1).

Sample 3 is an example structure in which the EM radiation-absorbing layer 120 of Sample 2 further comprises a covering dielectric layer 230 deposited on the particle structures 121, resulting in a reflectance of about 5% (a further reduction of ⅙ relative to that of Sample 2).

Sample 4 is an example structure in which a deposited material 631 was co-deposited with a co-deposited dielectric material to form an EM radiation-absorbing layer 120 comprising particle structures 121 on a glass substrate 10.

Sample 5 is an example structure in which the EM radiation-absorbing layer 120 of Sample 4 further comprises a covering dielectric layer 22 deposited on the particle structures 121, resulting in a reduced reflectance of over 80%.

Sample 6 is an example structure comprising a supporting dielectric layer 220 deposited on a glass substrate 10. In a first portion 301 (Sample 6B), a patterning coating 210 was deposited thereon. In a second portion 302 (Sample 6A), a templating layer of Yb seeds 122 was deposited thereon, instead of, and in the absence of the patterning coating 210. Thereafter, a deposited material 631 of Mg was co-deposited with a co-deposited dielectric material over both the first portion 301 and the second portion 302 to form particle structures 121 of an EM radiation-absorbing layer 120 in the second portion 302 only.

Sample 7 is an example structure in which both the first portion 301 and the second portion 302 of Sample 6 was further supplemented with a covering dielectric layer 230.

The reflectance values measured for Samples 6A and 7A referenced in Table 1 were measured at a point within the second portion 302. A comparison of these values shows a reduced reflectance of about 30% for Sample 7A relative to Sample 6A.

As may be seen from the foregoing examples, it was somewhat surprisingly found that providing a covering dielectric layer 230, over particle structures 121 in an EM radiation-absorbing layer 120 on a sample, substantially reduced the reflectance of the sample, particularly, when compared with samples in which no such covering dielectric layer 230 was provided.

The transmittance of Samples 6B and 7B was measured across a broad range of the EM spectrum at a point within the first portion 301. The measurement at 550 nm was recorded in Table 1. A comparison of these measurements show an increased transmittance across a broad range of the EM spectrum, including at the 550 nm wavelength, with the addition of the covering dielectric layer 230 of Sample 7A.

### Patterning

Those having ordinary skill in the relevant art will appreciate that further particulars of patterning a deposited material 631 using a patterning coating 210, including without limitation, to form particle structures 121 in an EM radiation-absorbing NP layer 120, will now be described.

In some non-limiting examples, in the first portion 301, a patterning coating 210, which may, in some non-limiting examples, be a nucleation inhibiting coating (NIC), comprising a patterning material 511, which in some non-limiting examples, may be an NIC material, may be selectively deposited as a closed coating 440 on the exposed layer surface 11 of an underlying layer, including without limitation, a substrate 10, of the device 100, only in the first portion 301. However, in the second portion 302, the exposed layer surface 11 of the underlying layer may be substantially devoid of a closed coating 440 of the patterning material 511.

### Patterning Coating

FIG. 4 is a cross-sectional view of a layered semiconductor device 400, of which the device 100 may, in some non-limiting examples, be a version thereof. The patterning coating 210 may comprise a patterning material 511. In some non-limiting examples, the patterning coating 210 may comprise a closed coating 440 of the patterning material 511.

The patterning coating 210 may provide an exposed layer surface 11 with a relatively low initial sticking probability (in some non-limiting examples, under the conditions identified in the dual QCM technique described by Walker et al.) against the deposition of deposited material 631, which, in some non-limiting examples, may be substantially less than the initial sticking probability against the deposition of the deposited material 631 of the exposed layer surface 11 of the underlying layer of the device 400, upon which the patterning coating 210 has been deposited.

Because of the low initial sticking probability of the patterning coating 210, and/or the patterning material 511, in some non-limiting examples, when deposited as a film, and/or coating in a form, and under similar circumstances to the deposition of the patterning coating 210 within the device 400, against the deposition of the deposited material 631, the first portion 301 comprising the patterning coating 210 may be substantially devoid of a closed coating 440 of the deposited material 631.

In some non-limiting examples, the patterning coating 210, and/or the patterning material 511, in some non-limiting examples, when deposited as a film, and/or coating in a form, and under similar circumstances to the deposition of the patterning coating 210 within the device 400, may have an initial sticking probability against the deposition of the deposited material 631, that is no more than at least one of about: 0.9, 0.3, 0.2, 0.15, 0.1, 0.08, 0.05, 0.03, 0.02, 0.01, 0.008, 0.005, 0.003, 0.001, 0.0008, 0.0005, 0.0003, or 0.0001.

In some non-limiting examples, the patterning coating 210, and/or the patterning material 511, in some non-limiting examples, when deposited as a film, and/or coating in a form, and under similar circumstances to the deposition of the patterning coating 210 within the device 400, may have an initial sticking probability against the deposition of silver (Ag), and/or magnesium (Mg) that is no more than at least one of about: 0.9, 0.3, 0.2, 0.15, 0.1, 0.08, 0.05, 0.03, 0.02, 0.01, 0.008, 0.005, 0.003, 0.001, 0.0008, 0.0005, 0.0003, or 0.0001.

In some non-limiting examples, the patterning coating 210, and/or the patterning material 511, in some non-limiting examples, when deposited as a film, and/or coating in a form, and under similar circumstances to the deposition of the patterning coating 210 within the device 400, may have an initial sticking probability against the deposition of a deposited material 631 of at least one of between about: 0.15-0.0001, 0.1-0.0003, 0.08-0.0005, 0.08-0.0008, 0.05-0.001, 0.03-0.0001, 0.03-0.0003, 0.03-0.0005, 0.03-0.0008, 0.03-0.001, 0.03-0.005, 0.03-0.008, 0.03-0.01, 0.02-0.0001, 0.02-0.0003, 0.02-0.0005, 0.02-0.0008, 0.02-0.001, 0.02-0.005, 0.02-0.008, 0.02-0.01, 0.01-0.0001, 0.01-0.0003, 0.01-0.0005, 0.01-0.0008, 0.01-0.001, 0.01-0.005, 0.01-0.008, 0.008-0.0001, 0.008-0.0003, 0.008-0.0005, 0.008-0.0008, 0.008-0.001, 0.008-0.005, 0.005-0.0001, 0.005-0.0003, 0.005-0.0005, 0.005-0.0008, or 0.005-0.001.

In some non-limiting examples, the patterning coating 210, and/or the patterning material 511, in some non-limiting examples, when deposited as a film, and/or coating in a form, and under similar circumstances to the deposition of the patterning coating 210 within the device 400, may have an initial sticking probability against the deposition of a plurality of deposited materials 631 that is no more than a threshold value. In some non-limiting examples, such threshold value may be at least one of about: 0.3, 0.2, 0.18, 0.15, 0.13, 0.1, 0.08, 0.05, 0.03, 0.02, 0.01, 0.008, 0.005, 0.003, or 0.001.

In some non-limiting examples, the patterning coating 210, and/or the patterning material 511, in some non-limiting examples, when deposited as a film, and/or coating in a form, and under similar circumstances to the deposition of the patterning coating 210 within the device 400, may have an initial sticking probability that is less than such threshold value against the deposition of a plurality of deposited materials 631 selected from at least one of: Ag, Mg, Yb, cadmium (Cd), and zinc (Zn). In some further non-limiting examples, the patterning coating 210 may exhibit an initial sticking probability of or below such threshold value against the deposition of a plurality of deposited materials 631 selected from at least one of: Ag, Mg, and Yb.

In some non-limiting examples, the patterning coating 210, and/or the patterning material 511, in some non-limiting examples, when deposited as a film, and/or coating in a form, and under similar circumstances to the deposition of the patterning coating 210 within the device 400, may exhibit an initial sticking probability against the deposition of a first deposited material 631 of, or below, a first threshold value, and an initial sticking probability against the deposition of a second deposited material 631 of, or below, a second threshold value. In some non-limiting examples, the first deposited material 631 may be Ag, and the second deposited material 631 may be Mg. In some other non-limiting examples, the first deposited material 631 may be Ag, and the second deposited material 631 may be Yb. In some other non-limiting examples, the first deposited material 631 may be Yb, and the second deposited material 631 may be Mg. In some non-limiting examples, the first threshold value may exceed the second threshold value.

In some non-limiting examples, the patterning coating 210, and/or the patterning material 511, in some non-limiting examples, when deposited as a film, and/or coating in a form, and under circumstances similar to the deposition of the patterning coating 210 within the device 400 may have a transmittance for EM radiation of at least a threshold transmittance value, after being subjected to a vapor flux 632 (FIG. 6) of the deposited material 631, including without limitation, Ag.

In some non-limiting examples, such transmittance may be measured after exposing the exposed layer surface 11 of the patterning coating 210 and/or the patterning material 511, formed as a thin film, to a vapor flux 632 of the deposited material 631, including without limitation, Ag, under typical conditions that may be used for depositing an electrode of an opto-electronic device, which by way of non-limiting example, may be a cathode of an OLED device.

In some non-limiting examples, the conditions for subjecting the exposed layer surface 11 to the vapor flux 632 of the deposited material 631, including without limitation, Ag, may be as follows: (i) vacuum pressure of about 10-4 Torr or 10⁻⁵ Torr; (ii) the vapor flux 632 of the deposited material 631, including without limitation, Ag being substantially consistent with a reference deposition rate of about 1 angstrom (A)/sec, which by way of non-limiting example, may be monitored and/or measured using a QCM; and (iii) the exposed layer surface 11 being subjected to the vapor flux 632 of the deposited material 631, including without limitation, Ag until a reference average layer thickness of about 15 nm is reached, and upon such reference average layer thickness being attained, the exposed layer surface 11 not being further subjected to the vapor flux 632 of the deposited material 631, including without limitation, Ag.

In some non-limiting examples, the exposed layer surface 11 being subjected to the vapor flux 632 of the deposited material 631, including without limitation, Ag may be substantially at room temperature (e.g. about 25° C.). In some non-limiting examples, the exposed layer surface 11 being subjected to the vapor flux 632 of the deposited material 631, including without limitation, Ag may be positioned about 65 cm away from an evaporation source by which the deposited material 631, including without limitation, Ag, is evaporated.

In some non-limiting examples, the threshold transmittance value may be measured at a wavelength in the visible spectrum. By way of non-limiting example, the threshold transmittance value may be measured at a wavelength of about 460 nm. In some non-limiting examples, the threshold transmittance value may be expressed as a percentage of incident EM power that may be transmitted through a sample. In some non-limiting examples, the threshold transmittance value may be at least one of at least about: 60%, 65%, 70%, 75%, 80%, 85%, or 90%.

In some non-limiting examples, there may be a positive correlation between the initial sticking probability of the patterning coating 210, and/or the patterning material 511, in some non-limiting examples, when deposited as a film, and/or coating in a form, and under circumstances similar to the deposition of the patterning coating 210 within the device 400, against the deposition of the deposited material 631 and an average layer thickness of the deposited material 631 thereon.

It would be appreciated by a person having ordinary skill in the relevant art that high transmittance may generally indicate an absence of a closed coating 440 of the deposited material 631, which by way of non-limiting example, may be Ag. On the other hand, low transmittance may generally indicate presence of a closed coating 440 of the deposited material 631, including without limitation, Ag, Mg, and/or Yb, since metallic thin films, particularly when formed as a closed coating 440, may exhibit a high degree of absorption of EM radiation.

It may be further postulated that exposed layer surfaces 11 exhibiting low initial sticking probability with respect to the deposited material 631, including without limitation, Ag, Mg, and/or Yb, may exhibit high transmittance. On the other hand, exposed layer surfaces 11 exhibiting high sticking probability with respect to the deposited material 631, including without limitation, Ag, Mg, and/or Yb, may exhibit low transmittance.

A series of samples was fabricated to measure the transmittance of an example material, as well as to visually observe whether or not a closed coating 440 of Ag was formed on the exposed layer surface 11 of such example material. Each sample was prepared by depositing, on a glass substrate, an approximately 50 nm thick coating of an example material, then subjecting the exposed layer surface 11 of the coating to a vapor flux of Ag at a rate of about 1 Å/sec until a reference layer thickness of about 15 nm was reached. Each sample was then visually analyzed and the transmittance through each sample was measured.

The molecular structures of the example materials used in the samples herein are set out below:

TABLE 2

| Material | Molecular Structure / Name |
|---|---|
| HT211 | 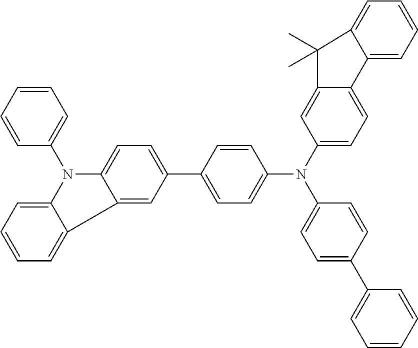 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21] |
| HT01 | 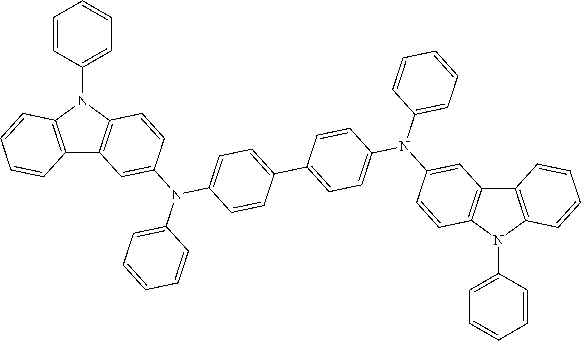 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1] |
| TAZ | 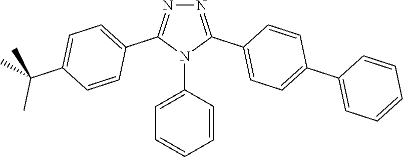 |
| BAlq | 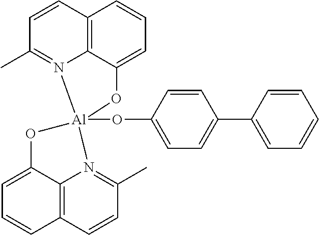 |
| Liq | 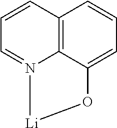 |
| Example Material 1 | 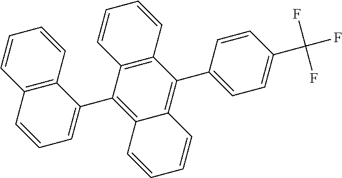 [SMILES: FC(F)(F)c1ccc(-c2c3ccccc3c(-c3cccc4ccccc34)c3ccccc23)cc1] |
| Example Material 2 | 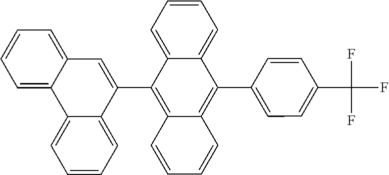 [SMILES: FC(F)(F)c1ccc(-c2c3ccccc3c(-c3cc4ccccc4c4ccccc34)c3ccccc23)cc1] |
| Example Material 3 | 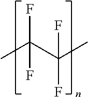 |
| Example Material 4 | 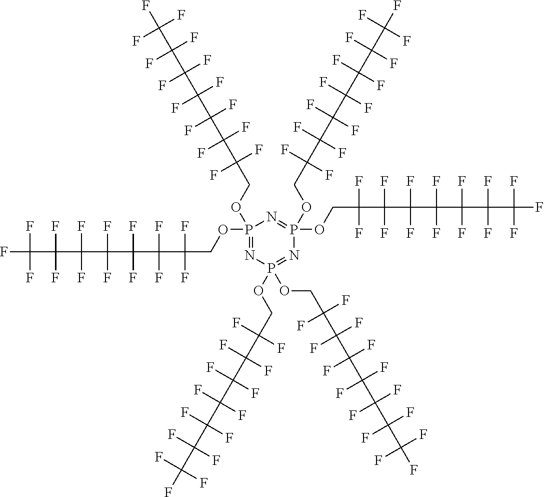 [SMILES: FC(F)(F)C(F)(F)C(F)(F)C(F)(F)C(F)(F)C(F)(F)C(F)(F)COP1(OCC(F)(F)C(F)(F)C(F)(F)C(F)(F)C(F)(F)C(F)(F)C(F)(F)F)=NP(OCC(F)(F)C(F)(F)C(F)(F)C(F)(F)C(F)(F)C(F)(F)C(F)(F)F)(OCC(F)(F)C(F)(F)C(F)(F)C(F)(F)C(F)(F)C(F)(F)C(F)(F)F)=NP(OCC(F)(F)C(F)(F)C(F)(F)C(F)(F)C(F)(F)C(F)(F)C(F)(F)F)(OCC(F)(F)C(F)(F)C(F)(F)C(F)(F)C(F)(F)C(F)(F)C(F)(F)F)=N1] |
| Example Material 5 | 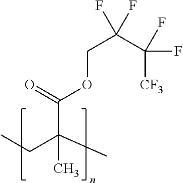 |
| Example Material 6 | 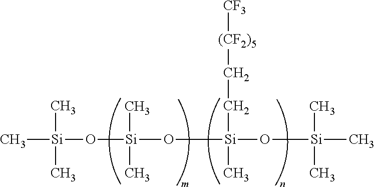 |
| Example Material 7 | 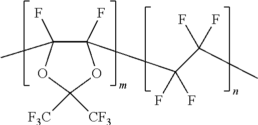 |
| Example Material 8 | 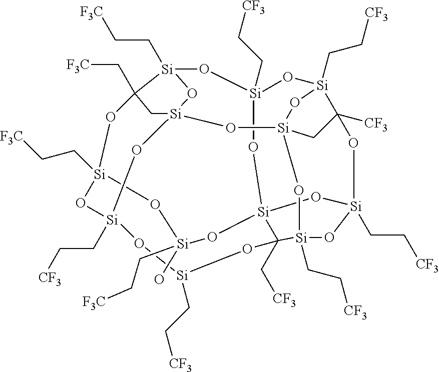 |
| Example Material 9 | 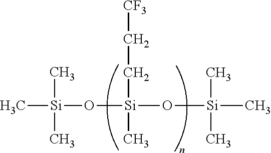 |

The samples in which a substantially closed coating 440 of Ag had formed were visually identified, and the presence of such coating in these samples was further confirmed by measurement of transmittance therethrough, which showed transmittance of no more than about 50% at a wavelength of about 460 nm.

The samples in which no closed coating 440 of Ag had formed were also identified, and the absence of such coating in these samples was further confirmed by measurement of transmittance therethrough, which showed transmittance in excess of about 70% at a wavelength of about 460 nm.

The results are summarized below:

TABLE 3

| Material | Closed Coating of Ag? |
|---|---|
| HT211 | Present |
| HT01 | Present |
| TAZ | Present |
| Balq | Present |
| Liq | Present |
| Example Material | Present |
| 1 | |
| Example Material | Present |
| 2 | |
| Example Material | Not Present |
| 3 | |
| Example Material | Not Present |
| 4 | |
| Example Material | Not Present |
| 5 | |
| Example Material | Not Present |
| 6 | |
| Example Material | Not Present |
| 7 | |
| Example Material | Not Present |
| 8 | |
| Example Material | Not Present |
| 9 | |

Based on the foregoing, it was found that the materials used in the first 7 samples in Tables 2 and 3 (HT211 to Example Material 2) may be less suitable for inhibiting the deposition of the deposited material 631 thereon, including without limitation, Ag, and/or Ag-containing materials.

On the other hand, it was found that Example Material 3 to Example Material 9 may be suitable, at least in some non-limiting applications, to act as a patterning coating 210 for inhibiting the deposition of the deposited material 631 thereon, including without limitation, Ag, and/or Ag-containing materials.

In some non-limiting examples, the patterning coating 210, and/or the patterning material 511, in some non-limiting examples, when deposited as a film, and/or coating in a form, and under circumstances similar to the deposition of the patterning coating within the device 400, may have a surface energy of no more than at least one of about: 24 dynes/cm, 22 dynes/cm, 20 dynes/cm, 18 dynes/cm, 16 dynes/cm, 15 dynes/cm, 13 dynes/cm, 12 dynes/cm, or 11 dynes/cm.

In some non-limiting examples, the surface energy may be at least one of at least about: 6 dynes/cm, 7 dynes/cm, or 8 dynes/cm.

In some non-limiting examples, the surface energy may be at least one of between about: 10-20 dynes/cm, or 13-19 dynes/cm.

In some non-limiting examples, the critical surface tension of a surface may be determined according to the Zisman method, as further detailed in W. A. Zisman, Advances in Chemistry 43 (1964), pp. 1-51.

By way of non-limiting example, a series of samples was fabricated to measure the critical surface tension of the surfaces formed by the various materials. The results of the measurement are summarized below:

TABLE 4

| Material | Critical Surface Tension (dynes/cm) |
|---|---|
| HT211 | 25.6 |
| HT01 | >24 |
| TAZ | 22.4 |
| BAlq | 25.9 |
| Liq | 24 |
| Example Material | 26.3 |
| 1 | |
| Example Material | 24.8 |
| 2 | |
| Example Material | 19 |
| 3 | |
| Example Material | 7.6 |
| 4 | |
| Example Material | 15.9 |
| 5 | |
| Example Material | <20 |
| 6 | |
| Example Material | 13.1 |
| 7 | |
| Example Material | 20 |
| 8 | |
| Example Material | 18.9 |
| 9 | |

Based on the foregoing measurement of the critical surface tension in Table 4 and the previous observation regarding the presence or absence of a substantially closed coating 440 of Ag, it was found that materials that form low surface energy surfaces when deposited as a coating, which by way of non-limiting example, may be those having a critical surface tension of at least one of between about: 13-20 dynes/cm, or 13-19 dynes/cm, may be suitable for forming the patterning coating 210 to inhibit deposition of a deposited material 631 thereon, including without limitation, Ag, and/or Ag-containing materials.

Without wishing to be bound by any particular theory, it may be postulated that materials that form a surface having a surface energy lower than, by way of non-limiting example, about 13 dynes/cm, may be less suitable as a patterning material 511 in certain applications, as such materials may exhibit relatively poor adhesion to layer(s) surrounding such materials, exhibit a low melting point, and/or exhibit a low sublimation temperature.

In some non-limiting examples, the patterning coating 210, and/or the patterning material 511, in some non-limiting examples, when deposited as a film, and/or coating in a form, and under circumstances similar to the deposition of the patterning coating 210 within the device 400, may have a low refractive index.

In some non-limiting examples, the patterning coating 210, and/or the patterning material 511, in some non-limiting examples, when deposited as a film, and/or coating in a form, and under circumstances similar to the deposition of the patterning coating 210 within the device 400, may have a refractive index for EM radiation at a wavelength of 550 nm that may be no more than at least one of about: 1.55, 1.5, 1.45, 1.43, 1.4, 1.39, 1.37, 1.35, 1.32, or 1.3.

Without wishing to be bound by any particular theory, it has been observed that providing the patterning coating 210 having a low refractive index may, at least in some devices 400, enhance transmission of external EM radiation through the second portion 302 thereof. By way of non-limiting example, devices 100 including an air gap therein, which may be arranged near or adjacent to the patterning coating 210, may exhibit a higher transmittance when the patterning coating 210 has a low refractive index relative to a similarly configured device in which such low-index patterning coating 210 was not provided.

By way of non-limiting example, a series of samples was fabricated to measure the refractive index at a wavelength of 550 nm for the coatings formed by some of the various example materials. The results of the measurement are summarized below:

TABLE 5

| Material | Refractive Index |
|---|---|
| HT211 | 1.76 |
| HT01 | 1.80 |
| TAZ | 1.69 |
| BAlq | 1.69 |
| Liq | 1.64 |
| Example Material | 1.72 |
| 2 | |
| Example Material | 1.37 |
| 3 | |
| Example Material | 1.38 |
| 5 | |
| Example Material | 1.3 |
| 7 | |

Based on the foregoing measurement of refractive index in Table 5, and the previous observation regarding the presence or absence of a substantially closed coating 440 of Ag in Table 3, it was found that materials that form a low refractive index coating, which by way of non-limiting example, may be those having a refractive index of no more than at least one of about: 1.4 or 1.38, may be suitable for forming the patterning coating 210 to inhibit deposition of a deposited material 631 thereon, including without limitation, Ag, and/or an Ag-containing materials.

In some non-limiting examples, the patterning coating 210, and/or the patterning material 511, in some non-limiting examples, when deposited as a film, and/or coating in a form, and under similar circumstances to the deposition of the patterning coating 210 within the device 400, may have an extinction coefficient that may be no more than about 0.01 for photons at a wavelength that is at least one of at least about: 600 nm, 500 nm, 460 nm, 420 nm, or 410 nm.

In some non-limiting examples, the patterning coating 210, and/or the patterning material 511, in some non-limiting examples, when deposited as a film, and/or coating in a form, and under circumstances similar to the deposition of the patterning coating 210 within the device 400, may not substantially attenuate EM radiation passing therethrough, in at least the visible spectrum.

In some non-limiting examples, the patterning coating 210, and/or the patterning material 511, when deposited as a film, and/or coating in a form, and under circumstances similar to the deposition of the patterning coating 210 within the device 400, may not substantially attenuate EM radiation passing therethrough, in at least the IR spectrum and/or the NIR spectrum.

In some non-limiting examples, the patterning coating 210, and/or the patterning material 511, in some non-limiting examples, when deposited as a film, and/or coating in a form, and under circumstances similar to the deposition of the patterning coating 210 within the device 400, may have an extinction coefficient that may be at least one of at least about: 0.05, 0.1, 0.2, or 0.5 for EM radiation at a wavelength shorter than at least one of at least about: 400 nm, 390 nm, 380 nm, or 370 nm. In this way, the patterning coating 210, and/or the patterning material 511, when deposited as a film, and/or coating in a form, and under circumstances similar to the deposition of the patterning coating 210 within the device 400, may absorb EM radiation in the UVA spectrum incident upon the device 400, thereby reducing a likelihood that EM radiation in the UVA spectrum may impart undesirable effects in terms of device performance, device stability, device reliability, and/or device lifetime.

In some non-limiting examples, the patterning coating 210, and/or the patterning material 511, in some non-limiting examples, when deposited as a film, and/or coating in a form, and under circumstances similar to the deposition of the patterning coating 210 within the device 400, may have a glass transition temperature that is no more than at least one of about: 300° C., 150° C., 130° C., 30° C., 0° C., −30° C., or −50° C.

In some non-limiting examples, the patterning material may have a sublimation temperature of at least one of between about: 100-320° C., 120-300° C., 140-280° C., or 150-250° C. In some non-limiting examples, such sublimation temperature may allow the patterning material 511 to be readily deposited as a coating using PVD.

The sublimation temperature of a material may be determined using various methods apparent to those having ordinary skill in the relevant art, including without limitation, by heating the material under high vacuum in a crucible and by determining a temperature that may be attained to:
observe commencement of the deposition of the material onto a surface on a QCM mounted a fixed distance from the crucible;
observe a specific deposition rate, by way of non-limiting example, 0.1 Å/sec, onto a surface on a QCM mounted a fixed distance from the crucible; and/or
reach a threshold vapor pressure of the material, by way of non-limiting example, about 10⁻⁴ or 10⁻⁵ Torr.

In some non-limiting examples, the sublimation temperature of a material may be determined by heating the material in an evaporation source under a high vacuum environment, by way of non-limiting example, about 10⁻⁴ Torr, and by determining a temperature that may be attained to cause the material to evaporate, thus generating a vapor flux sufficient to cause deposition of the material, by way of non-limiting example, at a deposition rate of about 0.1 Å/sec onto a surface on a QCM mounted a fixed distance from the source.

In some non-limiting examples, the QCM may be mounted about 65 cm away from the crucible for the purpose of determining the sublimation temperature.

In some non-limiting examples, the patterning coating 210, and/or the patterning material 511, may comprise a fluorine (F) atom and/or a silicon (Si) atom. By way of non-limiting example, the patterning material 511 for forming the patterning coating 210 may be a compound that includes F and/or Si.

In some non-limiting examples, the patterning material 511 may comprise a compound that comprises F. In some non-limiting examples, the patterning material 511 may comprise a compound that comprises F and a carbon (C) atom. In some non-limiting examples, the patterning material 511 may comprise a compound that comprises F and C in an atomic ratio corresponding to a quotient of F/C of at least one of at least about: 1, 1.5, or 2. In some non-limiting examples, an atomic ratio of F to C may be determined by counting all of the F atoms present in the compound structure, and for C atoms, counting solely the sp³ hybridized C atoms present in the compound structure. In some non-limiting examples, the patterning material 511 may comprise a compound that comprises, as part of its molecular sub-structure, a moiety comprising F and C in an atomic ratio corresponding to a quotient of F/C of at least about: 1, 1.5, or 2.

In some non-limiting examples, the compound of the patterning material 511 may comprise an organic-inorganic hybrid material.

In some non-limiting examples, the patterning material 511 may be, or comprise, an oligomer.

In some non-limiting examples, the patterning material 511 may be, or comprise, a compound having a molecular structure containing a backbone and at least one functional group bonded to the backbone. In some non-limiting examples, the backbone may be an inorganic moiety, and the at least one functional group may be an organic moiety.

In some non-limiting examples, such compound may have a molecular structure comprising a siloxane group. In some non-limiting examples, the siloxane group may be a linear, branched, or cyclic siloxane group. In some non-limiting examples, the backbone may be, or comprise, a siloxane group. In some non-limiting examples, the backbone may be, or comprise, a siloxane group and at least one functional group containing F. In some non-limiting examples, the at least one functional group comprising F may be a fluoroalkyl group. Non-limiting examples of such compound include fluoro-siloxanes. Non-limiting examples of such compound are Example Material 6 and Example Material 9.

In some non-limiting examples, the compound may have a molecular structure comprising a silsesquioxane group. In some non-limiting examples, the silsesquioxane group may be a POSS. In some non-limiting examples, the backbone may be, or comprise, a silsesquioxane group. In some non-limiting examples, the backbone may be, or comprise, a silsesquioxane group and at least one functional group comprising F. In some non-limiting examples, the at least one functional group comprising F may be a fluoroalkyl group. Non-limiting examples of such compound include fluoro-silsesquioxane and/or fluoro-POSS. A non-limiting example of such compound is Example Material 8.

In some non-limiting examples, the compound may have a molecular structure comprising a substituted or unsubstituted aryl group, and/or a substituted or unsubstituted heteroaryl group. In some non-limiting examples, the aryl group may be phenyl, or naphthyl. In some non-limiting examples, at least one C atom of an aryl group may be substituted by a heteroatom, which by way of non-limiting example may be O, N, and/or S, to derive a heteroaryl group. In some non-limiting examples, the backbone may be, or comprise, a substituted or unsubstituted aryl group, and/or a substituted or unsubstituted heteroaryl group. In some non-limiting examples, the backbone may be, or comprise, a substituted or unsubstituted aryl group, and/or a substituted or unsubstituted heteroaryl group and at least one functional group comprising F. In some non-limiting examples, the at least one functional group comprising F may be a fluoroalkyl group.

In some non-limiting examples, the compound may have a molecular structure comprising a substituted or unsubstituted, linear, branched, or cyclic hydrocarbon group. In some non-limiting examples, one or more C atoms of the hydrocarbon group may be substituted by a heteroatom, which by way of non-limiting example may be O, N, and/or S.

In some non-limiting examples, the compound may have a molecular structure comprising a phosphazene group. In some non-limiting examples, the phosphazene group may be a linear, branched, or cyclic phosphazene group. In some non-limiting examples, the backbone may be, or comprise, a phosphazene group. In some non-limiting examples, the backbone may be, or comprise, a phosphazene group and at least one functional group comprising F. In some non-limiting examples, the at least one functional group comprising F may be a fluoroalkyl group. Non-limiting examples of such compound include fluoro-phosphazenes. A non-limiting example of such compound is Example Material 4.

In some non-limiting examples, the compound may be a fluoropolymer. In some non-limiting examples, the compound may be a block copolymer comprising F. In some non-limiting examples, the compound may be an oligomer. In some non-limiting examples, the oligomer may be a fluorooligomer. In some non-limiting examples, the compound may be a block oligomer comprising F. Non-limiting examples, of fluoropolymers and/or fluorooligomers are those having the molecular structure of Example Material 3, Example Material 5, and/or Example Material 7.

In some non-limiting examples, the compound may be a metal complex. In some non-limiting examples, the metal complex may be an organo-metal complex. In some non-limiting examples, the organo-metal complex may comprise F. In some non-limiting examples, the organo-metal complex may comprise at least one ligand comprising F. In some non-limiting examples, the at least one ligand comprising F may be, or comprise, a fluoroalkyl group.

In some non-limiting examples, the patterning material 511 may be, or comprise, an organic-inorganic hybrid material.

In some non-limiting examples, the patterning material 511 may comprise a plurality of different materials.

In some non-limiting examples, a molecular weight of the compound of the patterning material 511 may be no more than at least one of about: 5,000 g/mol, 4,500 g/mol, 4,000 g/mol, 3,800 g/mol, or 3,500 g/mol.

In some non-limiting examples, the molecular weight of the compound of the patterning material 511 may be at least one of at least about: 1,500 g/mol, 1,700 g/mol, 2,000 g/mol, 2,200 g/mol, or 2,500 g/mol.

Without wishing to be bound by any particular theory, it may be postulated that, for compounds that are adapted to form surfaces with relatively low surface energy, there may be an aim, in at least some applications, for the molecular weight of such compounds to be at least one of between about: 1,500-5,000 g/mol, 1,500-4,500 g/mol, 1,700-4,500 g/mol, 2,000-4,000 g/mol, 2,200-4,000 g/mol, or 2,500-3,800 g/mol.

Without wishing to be bound by any particular theory, it may be postulated that such compounds may exhibit at least one property that may be suitable for forming a coating, and/or layer having: (i) a relatively high melting point, by way of non-limiting example, of at least 100° C., (ii) a relatively low surface energy, and/or (iii) a substantially amorphous structure, when deposited, by way of non-limiting example, using vacuum-based thermal evaporation processes.

In some non-limiting examples, a percentage of the molar weight of such compound that may be attributable to the presence of F atoms, may be at least one of between about: 40-90%, 45-85%, 50-80%, 55-75%, or 60-75%. In some non-limiting examples, F atoms may constitute a majority of the molar weight of such compound.

In some non-limiting examples, the patterning coating 210 may be disposed in a pattern that may be defined by at least one region therein that may be substantially devoid of a closed coating 440 of the patterning coating 210. In some non-limiting examples, the at least one region may separate the patterning coating 210 into a plurality of discrete fragments thereof. In some non-limiting examples, the plurality of discrete fragments of the patterning coating 210 may be physically spaced apart from one another in the lateral aspect thereof. In some non-limiting examples, the plurality of the discrete fragments of the patterning coating 210 may be arranged in a regular structure, including without limitation, an array or matrix, such that in some non-limiting examples, the discrete fragments of the patterning coating 210 may be configured in a repeating pattern.

In some non-limiting examples, at least one of the plurality of the discrete fragments of the patterning coating 210 may each correspond to an emissive region 1301.

In some non-limiting examples, an aperture ratio of the emissive regions 1301 may be no more than at least one of about: 50%, 40%, 30%, or 20%.

In some non-limiting examples, the patterning coating 210 may be formed as a single monolithic coating.

In some non-limiting examples, the patterning coating 210 may have and/or provide, including without limitation, because of the patterning material 511 used and/or the deposition environment, at least one nucleation site for the deposited material 631.

In some non-limiting examples, the patterning coating 210 may be doped, covered, and/or supplemented with another material that may act as a seed or heterogeneity, to act as such a nucleation site for the deposited material 631. In some non-limiting examples, such other material may comprise an NPC. In some non-limiting examples, such other material may comprise an organic material, such as by way of non-limiting example, a polycyclic aromatic compound, and/or a material comprising a non-metallic element such as, without limitation, at least one of: O, S, N, or C, whose presence might otherwise be a contaminant in the source material, equipment used for deposition, and/or the vacuum chamber environment. In some non-limiting examples, such other material may be deposited in a layer thickness that is a fraction of a monolayer, to avoid forming a closed coating 440 thereof. Rather, the monomers of such other material may tend to be spaced apart in the lateral aspect so as form discrete nucleation sites for the deposited material.

In some non-limiting examples, a material suitable for use as the patterning coating 210 may generally have a low surface energy when deposited as a thin film or coating on a surface. In some non-limiting examples, a material with a low surface energy may exhibit low intermolecular forces. In some non-limiting examples, a material with low intermolecular forces may readily crystallize or undergo other phase transformation at a temperature that is low relative to a temperature at which a material with high intermolecular forces may readily crystallize or undergo other phase transformation. In some non-limiting examples, in at least some applications, a material that readily crystallizes or undergoes other phase transformations at a relatively low temperature may impact the long-term stability and/or reliability of a device containing such a material.

Without wishing to be bound by any particular theory, it has now been found that a patterning coating 210 containing a plurality of different materials may provide at least one advantage relative to a patterning coating 210 formed substantially of a single material, including without limitation: a lower initial sticking probability against the deposition of a deposited material 430 on an exposed layer surface 11 thereof under a given set of conditions, and/or improved long-term stability and/or reliability of a device containing such a material.

In some non-limiting examples, the patterning coating 210 may act as an optical coating. In some non-limiting examples, the patterning coating 210 may modify at least one property, and/or characteristic of EM radiation (including without limitation, in the form of photons) emitted by the device 400. In some non-limiting examples, the patterning coating 210 may exhibit a degree of haze, causing emitted EM radiation to be scattered. In some non-limiting examples, the patterning coating 210 may comprise a crystalline material for causing EM radiation transmitted therethrough to be scattered. Such scattering of EM radiation may facilitate enhancement of the outcoupling of EM radiation from the device in some non-limiting examples. In some non-limiting examples, the patterning coating 210 may initially be deposited as a substantially non-crystalline, including without limitation, substantially amorphous, coating, whereupon, after deposition thereof, the patterning coating 210 may become crystallized and thereafter serve as an optical coupling.

### Deposited Layer

In some non-limiting examples, in the second portion 302 of the lateral aspect of the device 400, a deposited layer 430 comprising a deposited material 631 may be disposed as a closed coating 440 on an exposed layer surface 11 of an underlying layer, including without limitation, the substrate 10.

In some non-limiting examples, the deposited layer 430 may comprise a deposited material 631.

In some non-limiting examples, the deposited material 631 may comprise an element selected from at least one of: potassium (K), sodium (Na), lithium (Li), barium (Ba), cesium (Cs), Yb, Ag, gold (Au), copper (Cu), aluminum (AI), Mg, Zn, Cd, tin (Sn), or yttrium (Y). In some non-limiting examples, the element may comprise at least one of: K, Na, Li, Ba, Cs, Yb, Ag, Au, Cu, Al, and/or Mg. In some non-limiting examples, the element may comprise at least one of: Cu, Ag, and/or Au. In some non-limiting examples, the element may be Cu. In some non-limiting examples, the element may be Al. In some non-limiting examples, the element may comprise at least one of: Mg, Zn, Cd, or Yb. In some non-limiting examples, the element may comprise at least one of: Mg, Ag, Al, Yb, or Li. In some non-limiting examples, the element may comprise at least one of: Mg, Ag, or Yb. In some non-limiting examples, the element may comprise at least one of: Mg, or Ag. In some non-limiting examples, the element may be Ag.

In some non-limiting examples, the deposited material 631 may be and/or comprise a pure metal. In some non-limiting examples, the deposited material 631 may be at least one of: pure Ag or substantially pure Ag. In some non-limiting examples, the substantially pure Ag may have a purity of at least one of at least about: 95%, 99%, 99.9%, 99.99%, 99.999%, or 99.9995%. In some non-limiting examples, the deposited material 631 may be at least one of: pure Mg or substantially pure Mg. In some non-limiting examples, the substantially pure Mg may have a purity of at least one of at least about: 95%, 99%, 99.9%, 99.99%, 99.999%, or 99.9995%.

In some non-limiting examples, the deposited material 631 may comprise an alloy. In some non-limiting examples, the alloy may be at least one of: an Ag-containing alloy, an Mg-containing alloy, or an AgMg-containing alloy. In some non-limiting examples, the AgMg-containing alloy may have an alloy composition that may range from about 1:10 (Ag:Mg) to about 10:1 by volume.

In some non-limiting examples, the deposited material 631 may comprise other metals in place of, and/or in combination with, Ag. In some non-limiting examples, the deposited material 631 may comprise an alloy of Ag with at least one other metal. In some non-limiting examples, the deposited material 631 may comprise an alloy of Ag with at least one of: Mg, or Yb. In some non-limiting examples, such alloy may be a binary alloy having a composition between about 5-95 vol. % Ag, with the remainder being the other metal. In some non-limiting examples, the deposited material 631 may comprise Ag and Mg. In some non-limiting examples, the deposited material 631 may comprise an Ag:Mg alloy having a composition between about 1:10-10:1 by volume. In some non-limiting examples, the deposited material 631 may comprise Ag and Yb. In some non-limiting examples, the deposited material 631 may comprise a Yb:Ag alloy having a composition between about 1:20-10:1 by volume. In some non-limiting examples, the deposited material 631 may comprise Mg and Yb. In some non-limiting examples, the deposited material 631 may comprise an Mg:Yb alloy. In some non-limiting examples, the deposited material 631 may comprise Ag, Mg, and Yb. In some non-limiting examples, the deposited layer 430 may comprise an Ag:Mg:Yb alloy.

In some non-limiting examples, the deposited layer 430 may comprise at least one additional element. In some non-limiting examples, such additional element may be a non-metallic element. In some non-limiting examples, the non-metallic element may be at least one of: O, S, N, or C. It will be appreciated by those having ordinary skill in the relevant art that, in some non-limiting examples, such additional element(s) may be incorporated into the deposited layer 430 as a contaminant, due to the presence of such additional element(s) in the source material, equipment used for deposition, and/or the vacuum chamber environment. In some non-limiting examples, the concentration of such additional element(s) may be limited to be below a threshold concentration. In some non-limiting examples, such additional element(s) may form a compound together with other element(s) of the deposited layer 430. In some non-limiting examples, a concentration of the non-metallic element in the deposited material 631 may be no more than at least one of about: 1%, 0.1%, 0.01%, 0.001%, 0.0001%, 0.00001%, 0.000001%, or 0.0000001%. In some non-limiting examples, the deposited layer 430 may have a composition in which a combined amount of O and C therein may be no more than at least one of about: 10%, 5%, 1%, 0.1%, 0.01%, 0.001%, 0.0001%, 0.00001%, 0.000001%, or 0.0000001%.

It has now been found, somewhat surprisingly, that reducing a concentration of certain non-metallic elements in the deposited layer 430, particularly in cases wherein the deposited layer 430 may be substantially comprised of metal(s), and/or metal alloy(s), may facilitate selective deposition of the deposited layer 430. Without wishing to be bound by any particular theory, it may be postulated that certain non-metallic elements, such as, by way of non-limiting example, O, or C, when present in the vapor flux 632 of the deposited layer 430, and/or in the deposition chamber, and/or environment, may be deposited onto the surface of the patterning coating 210 to act as nucleation sites for the metallic element(s) of the deposited layer 430. It may be postulated that reducing a concentration of such non-metallic elements that could act as nucleation sites may facilitate reducing an amount of deposited material 631 deposited on the exposed layer surface 11 of the patterning coating 210.

In some non-limiting examples, the deposited material 631 in the second portion 302 and the underlying layer thereunder may comprise a common metal.

In some non-limiting examples, the deposited layer 430 may comprise a plurality of layers of the deposited material 631. In some non-limiting examples, the deposited material 631 of a first one of the plurality of layers may be different from the deposited material 631 of a second one of the plurality of layers. In some non-limiting examples, the deposited layer 430 may comprise a multilayer coating. In some non-limiting examples, such multilayer coating may be at least one of: Yb/Ag, Yb/Mg, Yb/Mg:Ag, Yb/Yb:Ag, Yb/Ag/Mg, or Yb/Mg/Ag.

In some non-limiting examples, the deposited material 631 may comprise a metal having a bond dissociation energy, of no more than at least one of about: 300 kJ/mol, 200 kJ/mol, 165 kJ/mol, 150 kJ/mol, 100 kJ/mol, 50 kJ/mol, or 20 kJ/mol.

In some non-limiting examples, the deposited material 631 may comprise a metal having an electronegativity that is no more than at least one of about: 1.4, 1.3, or 1.2.

In some non-limiting examples, a sheet resistance of the deposited layer 430 may generally correspond to a sheet resistance of the deposited layer 430, measured or determined in isolation from other components, layers, and/or parts of the device 400. In some non-limiting examples, the deposited layer 430 may be formed as a thin film. Accordingly, in some non-limiting examples, the characteristic sheet resistance for the deposited layer 430 may be determined, and/or calculated based on the composition, thickness, and/or morphology of such thin film. In some non-limiting examples, the sheet resistance may be no more than at least one of about: 10Ω/□, 5Ω/□, 1Ω/□, 0.5Ω/□, 0.2Ω/□, or 0.1Ω/□.

In some non-limiting examples, the deposited layer 430 may be disposed in a pattern that may be defined by at least one region therein that is substantially devoid of a closed coating 440 of the deposited layer 430. In some non-limiting examples, the at least one region may separate the deposited layer 430 into a plurality of discrete fragments thereof. In some non-limiting examples, each discrete fragment of the deposited layer 430 may be a distinct second portion 302. In some non-limiting examples, the plurality of discrete fragments of the deposited layer 430 may be physically spaced apart from one another in the lateral aspect thereof. In some non-limiting examples, at least two of such plurality of discrete fragments of the deposited layer 430 may be electrically coupled. In some non-limiting examples, at least two of such plurality of discrete fragments of the deposited layer 430 may be each electrically coupled with a common conductive layer or coating, including without limitation, the underlying surface, to allow the flow of electrical current between them. In some non-limiting examples, at least two of such plurality of discrete fragments of the deposited layer 430 may be electrically insulated from one another.

### Selective Deposition Using Patterning Coatings

FIG. 5 is an example schematic diagram illustrating a non-limiting example of an evaporative deposition process, shown generally at 500, in a chamber 50, for selectively depositing a patterning coating 210 onto a first portion 301 of an exposed layer surface 11 of the underlying layer.

In the process 500, a quantity of a patterning material 511 is heated under vacuum, to evaporate, and/or sublime the patterning material 511. In some non-limiting examples, the patterning material 511 may comprise entirely, and/or substantially, a material used to form the patterning coating 210. In some non-limiting examples, such material may comprise an organic material.

An evaporated flux 512 of the patterning material 511 may flow through the chamber 50, including in a direction indicated by arrow 51, toward the exposed layer surface 11. When the evaporated flux 512 is incident on the exposed layer surface 11, the patterning coating 210 may be formed thereon.

In some non-limiting examples, as shown in the figure for the process 500, the patterning coating 210 may be selectively deposited only onto a portion, in the example illustrated, the first portion 301, of the exposed layer surface 11, by the interposition, between the evaporated flux 512 and the exposed layer surface 11, of a shadow mask 515, which in some non-limiting examples, may be an FMM. In some non-limiting examples, such a shadow mask 515 may, in some non-limiting examples, be used to form relatively small features, with a feature size on the order of tens of microns or smaller.

The shadow mask 515 may have at least one aperture 516 extending therethrough such that a part of the evaporated flux 512 passes through the aperture 516 and may be incident on the exposed layer surface 11 to form the patterning coating 210. Where the evaporated flux 512 does not pass through the aperture 516 but is incident on the surface 517 of the shadow mask 515, it is precluded from being disposed on the exposed layer surface 11 to form the patterning coating 210. In some non-limiting examples, the shadow mask 515 may be configured such that the evaporated flux 512 that passes through the aperture 516 may be incident on the first portion 301 but not the second portion 302. The second portion 302 of the exposed layer surface 11 may thus be substantially devoid of the patterning coating 210. In some non-limiting examples (not shown), the patterning material 511 that is incident on the shadow mask 515 may be deposited on the surface 517 thereof.

Accordingly, a patterned surface may be produced upon completion of the deposition of the patterning coating 210.

FIG. 6 is an example schematic diagram illustrating a non-limiting example of a result of an evaporative process, shown generally at 600ₐ, in a chamber 50, for selectively depositing a closed coating 440 of a deposited layer 430 onto the second portion 302 of an exposed layer surface 11 of the underlying layer that is substantially devoid of the patterning coating 210 that was selectively deposited onto the first portion 301, including without limitation, by the evaporative process 500 of FIG. 5.

In some non-limiting examples, the deposited layer 430 may be comprised of a deposited material 631, in some non-limiting examples, comprising at least one metal. It will be appreciated by those having ordinary skill in the relevant art that typically, the vaporization temperature of an organic material is low relative to the vaporization temperature of metals, such as may be employed as a deposited material 631.

Thus, in some non-limiting examples, there may be fewer constraints in employing a shadow mask 515 to selectively deposit a patterning coating 210 in a pattern, relative to directly patterning the deposited layer 430 using such shadow mask 515.

Once the patterning coating 210 has been deposited on the first portion 301 of the exposed layer surface 11 of the underlying layer, a closed coating 440 of the deposited material 631 may be deposited, on the second portion 302 of the exposed layer surface 11 that is substantially devoid of the patterning coating 210, as the deposited layer 430.

In the process 600ₐ, a quantity of the deposited material 631 may be heated under vacuum, to evaporate, and/or sublime the deposited material 631. In some non-limiting examples, the deposited material 631 may comprise entirely, and/or substantially, a material used to form the deposited layer 430.

An evaporated flux 632 of the deposited material 631 may be directed inside the chamber 50, including in a direction indicated by arrow 61, toward the exposed layer surface 11 of the first portion 301 and of the second portion 302. When the evaporated flux 632 is incident on the second portion 302 of the exposed layer surface 11, a closed coating 440 of the deposited material 631 may be formed thereon as the deposited layer 430.

In some non-limiting examples, deposition of the deposited material 631 may be performed using an open mask and/or a mask-free deposition process.

It will be appreciated by those having ordinary skill in the relevant art that, contrary to that of a shadow mask 515, the feature size of an open mask may be generally comparable to the size of a device 400 being manufactured.

It will be appreciated by those having ordinary skill in the relevant art that, in some non-limiting examples, the use of an open mask may be omitted. In some non-limiting examples, an open mask deposition process described herein may alternatively be conducted without the use of an open mask, such that an entire target exposed layer surface 11 may be exposed.

Indeed, as shown in FIG. 6, the evaporated flux 632 may be incident both on an exposed layer surface 11 of the patterning coating 210 across the first portion 301 as well as the exposed layer surface 11 of the underlying layer across the second portion 302 that is substantially devoid of the patterning coating 210.

Since the exposed layer surface 11 of the patterning coating 210 in the first portion 301 may exhibit a relatively low initial sticking probability against the deposition of the deposited material 631 relative to the exposed layer surface 11 of the underlying layer in the second portion 302, the deposited layer 430 may be selectively deposited substantially only on the exposed layer surface 11, of the underlying layer in the second portion 302, that is substantially devoid of the patterning coating 210. By contrast, the evaporated flux 632 incident on the exposed layer surface 11 of the patterning coating 210 across the first portion 301 may tend to not be deposited (as shown 533), and the exposed layer surface 11 of the patterning coating 210 across the first portion 301 may be substantially devoid of a closed coating 440 of the deposited layer 430.

In some non-limiting examples, an initial deposition rate, of the evaporated flux 632 on the exposed layer surface 11 of the underlying layer in the second portion 302, may exceed at least one of about: 200 times, 550 times, 900 times, 1,000 times, 1,500 times, 1,900 times, or 2,000 times an initial deposition rate of the evaporated flux 632 on the exposed layer surface 11 of the patterning coating 210 in the first portion 301.

Thus, the combination of the selective deposition of a patterning coating 210 in FIG. 5 using a shadow mask 515 and the open mask and/or a mask-free deposition of the deposited material 631 may result in a version 600ₐ of the device 400 shown in FIG. 4.

After selective deposition of the patterning coating 210 across the first portion 301, a closed coating 440 of the deposited material 631 may be deposited over the device 600ₐ as the deposited layer 430, in some non-limiting examples, using an open mask and/or a mask-free deposition process, but may remain substantially only within the second portion 302, which is substantially devoid of the patterning coating 210.

The patterning coating 210 may provide, within the first portion 301, an exposed layer surface 11 with a relatively low initial sticking probability, against the deposition of the deposited material 631, and that is substantially less than the initial sticking probability, against the deposition of the deposited material 631, of the exposed layer surface 11 of the underlying material of the device 600ₐ within the second portion 302.

Thus, the first portion 301 may be substantially devoid of a closed coating 440 of the deposited material 631.

While the present disclosure contemplates the patterned deposition of the patterning coating 210 by an evaporative deposition process, involving a shadow mask 515, those having ordinary skill in the relevant art will appreciate that, in some non-limiting examples, this may be achieved by any suitable deposition process, including without limitation, a micro-contact printing process.

While the present disclosure contemplates the patterning coating 210 being an NIC, those having ordinary skill in the relevant art will appreciate that, in some non-limiting examples, the patterning coating 210 may be an NPC 820. In such examples, the portion (such as, without limitation, the first portion 301) in which the NPC 820 has been deposited may, in some non-limiting examples, have a closed coating 440 of the deposited material 631, while the other portion (such as, without limitation, the second portion 302) may be substantially devoid of a closed coating 440 of the deposited material 631.

In some non-limiting examples, an average layer thickness of the patterning coating 210 and of the deposited layer 430 deposited thereafter may be varied according to a variety of parameters, including without limitation, a given application and given performance characteristics. In some non-limiting examples, the average layer thickness of the patterning coating 210 may be comparable to, and/or substantially no more than an average layer thickness of the deposited layer 430 deposited thereafter. Use of a relatively thin patterning coating 210 to achieve selective patterning of a deposited layer 430 may be suitable to provide flexible devices 100. In some non-limiting examples, a relatively thin patterning coating 210 may provide a relatively planar surface on which a barrier coating or other thin film encapsulation (TFE) layer 1650, may be deposited. In some non-limiting examples, providing such a relatively planar surface for application of such barrier coating 1350 may increase adhesion thereof to such surface.

### Edge Effects

Patterning Coating Transition Region

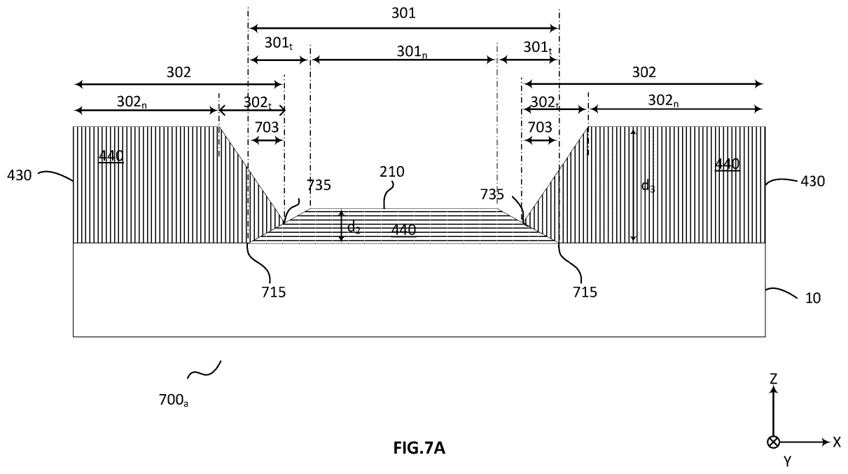

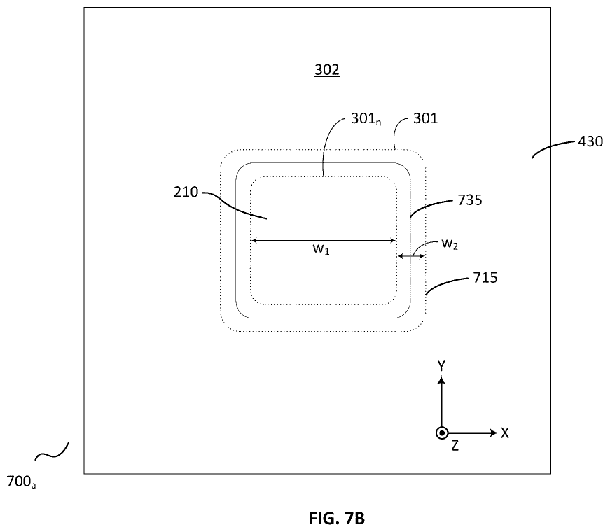

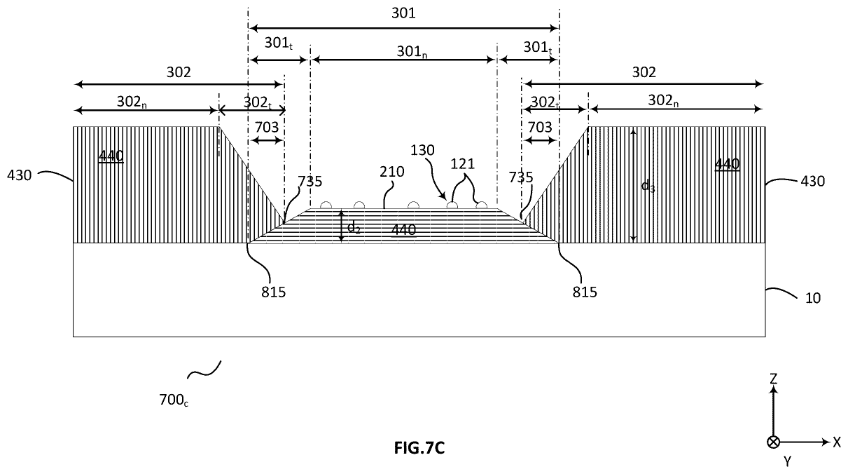

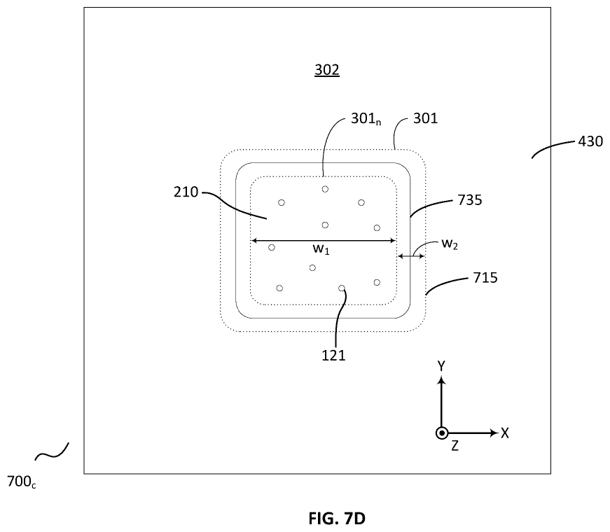

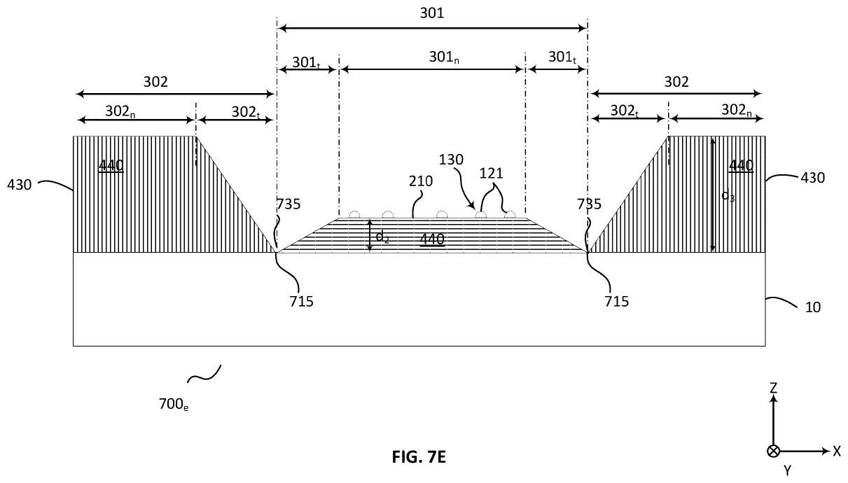

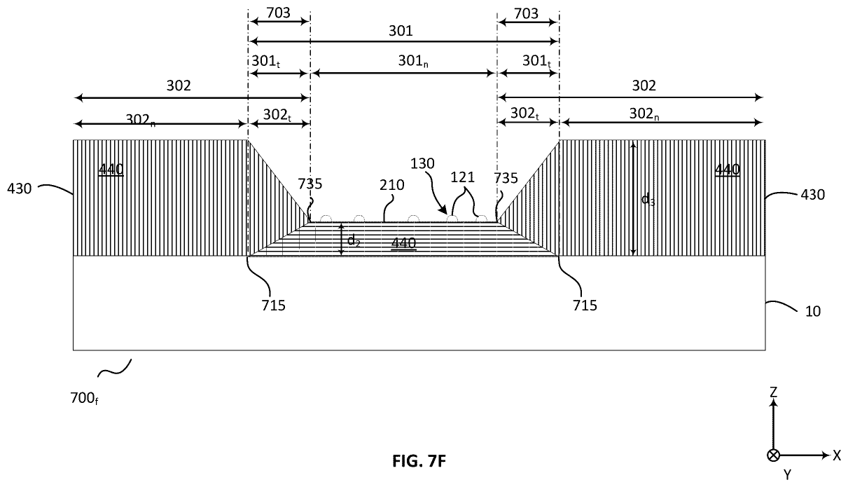

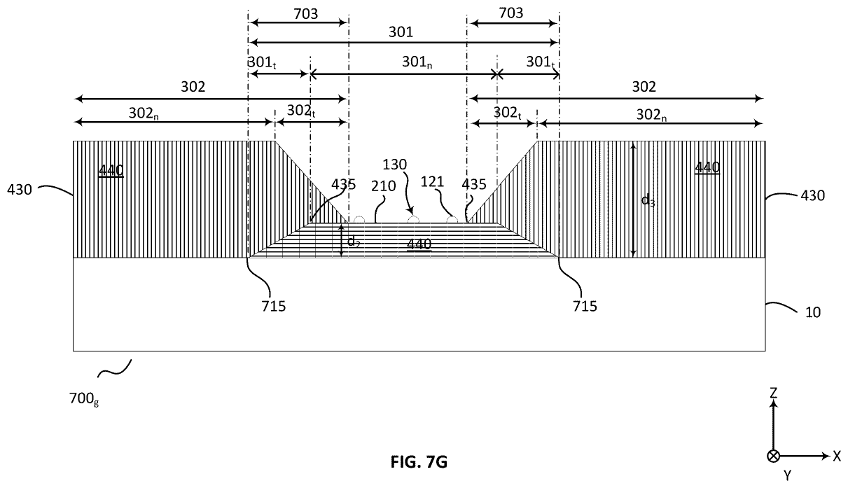

Turning to FIG. 7A, there may be shown a version 700ₐ of the device 400 of FIG. 4 that may show in exaggerated form, an interface between the patterning coating 210 in the first portion 301 and the deposited layer 430 in the second portion 302. FIG. 7B may show the device 700ₐ in plan.

As may be better seen in FIG. 7B, in some non-limiting examples, the patterning coating 210 in the first portion 301 may be surrounded on all sides by the deposited layer 430 in the second portion 302, such that the first portion 301 may have a boundary that is defined by the further extent or edge 715 of the patterning coating 210 in the lateral aspect along each lateral axis. In some non-limiting examples, the patterning coating edge 715 in the lateral aspect may be defined by a perimeter of the first portion 301 in such aspect.

In some non-limiting examples, the first portion 301 may comprise at least one patterning coating transition region 301ₜ, in the lateral aspect, in which a thickness of the patterning coating 210 may transition from a maximum thickness to a reduced thickness. The extent of the first portion 301 that does not exhibit such a transition may be identified as a patterning coating non-transition part 301ₙ of the first portion 301. In some non-limiting examples, the patterning coating 210 may form a substantially closed coating 440 in the patterning coating non-transition part 301ₙ of the first portion 301.

In some non-limiting examples, the patterning coating transition region 301ₜ may extend, in the lateral aspect, between the patterning coating non-transition part 301ₙ of the first portion 301 and the patterning coating edge 715.

In some non-limiting examples, in plan, the patterning coating transition region 301ₜ may surround, and/or extend along a perimeter of, the patterning coating non-transition part 301ₙ of the first portion 301.

In some non-limiting examples, along at least one lateral axis, the patterning coating non-transition part 301ₙ may occupy the entirety of the first portion 301, such that there is no patterning coating transition region 301ₜ between it and a second portion 302.

As illustrated in FIG. 7A, in some non-limiting examples, the patterning coating 210 may have an average film thickness d₂ in the patterning coating non-transition part 301ₙ of the first portion 301 that may be in a range of at least one of between about: 1-100 nm, 2-50 nm, 3-30 nm, 4-20 nm, 5-15 nm, 5-10 nm, or 1-10 nm. In some non-limiting examples, the average film thickness d₂ of the patterning coating 210 in the patterning coating non-transition part 301ₙ of the first portion 301 may be substantially the same, or constant, thereacross. In some non-limiting examples, an average layer thickness d₂ of the patterning coating 210 may remain, within the patterning coating non-transition part 301ₙ, within at least one of about: 95%, or 90% of the average film thickness d₂ of the patterning coating 210.

In some non-limiting examples, the average film thickness d₂ may be between about 1-100 nm. In some non-limiting examples, the average film thickness d₂ may be no more than at least one of about: 80 nm, 60 nm, 50 nm, 40 nm, 30 nm, 20 nm, 15 nm, or 10 nm. In some non-limiting examples, the average film thickness d₂ of the patterning coating 210 may exceed at least one of about: 3 nm, 5 nm, or 8 nm.

In some non-limiting examples, the average film thickness d₂ of the patterning coating 210 in the patterning coating non-transition part 301ₙ of the first portion 301 may be no more than about 10 nm. Without wishing to be bound by any particular theory, it has been found, somewhat surprisingly, that an average film thickness d₂ of the patterning coating 210 that exceeds zero and is no more than about 10 nm may, at least in some non-limiting examples, provide certain advantages for achieving, by way of non-limiting example, enhanced patterning contrast of the deposited layer 430, relative to a patterning coating 210 having an average film thickness d₂ in the patterning coating non-transition part 301ₙ of the first portion 301 in excess of 10 nm.

In some non-limiting examples, the patterning coating 210 may have a patterning coating thickness that decreases from a maximum to a minimum within the patterning coating transition region 301ₜ. In some non-limiting examples, the maximum may be at, and/or proximate to, a boundary between the patterning coating transition region 301ₜ and the patterning coating non-transition part 301ₙ of the first portion 301. In some non-limiting examples, the minimum may be at, and/or proximate to, the patterning coating edge 715. In some non-limiting examples, the maximum may be the average film thickness d₂ in the patterning coating non-transition part 301ₙ of the first portion 301. In some non-limiting examples, the maximum may be no more than at least one of about: 95% or 90% of the average film thickness d₂ in the patterning coating non-transition part 301ₙ of the first portion 301. In some non-limiting examples, the minimum may be in a range of between about 0-0.1 nm.

In some non-limiting examples, a profile of the patterning coating thickness in the patterning coating transition region 301ₜ may be sloped, and/or follow a gradient. In some non-limiting examples, such profile may be tapered. In some non-limiting examples, the taper may follow a linear, non-linear, parabolic, and/or exponential decaying profile.

In some non-limiting examples, the patterning coating 210 may completely cover the underlying surface in the patterning coating transition region 301ₜ. In some non-limiting examples, at least a part of the underlying layer may be left uncovered by the patterning coating 210 in the patterning coating transition region 301ₜ. In some non-limiting examples, the patterning coating 210 may comprise a substantially closed coating 440 in at least a part of the patterning coating transition region 301ₜ and/or at least a part of the patterning coating non-transition part 301ₙ.

In some non-limiting examples, the patterning coating 210 may comprise a discontinuous layer 130 in at least a part of the patterning coating transition region 301ₜ and/or at least a part of the patterning coating non-transition part 301ₙ.

In some non-limiting examples, at least a part of the patterning coating 210 in the first portion 301 may be substantially devoid of a closed coating 440 of the deposited layer 430. In some non-limiting examples, at least a part of the exposed layer surface 11 of the first portion 301 may be substantially devoid of a closed coating of the deposited layer 430 or of the deposited material 631.

In some non-limiting examples, along at least one lateral axis, including without limitation, the X-axis, the patterning coating non-transition part 301ₙ may have a width of w₁, and the patterning coating transition region 301ₜ may have a width of w₂. In some non-limiting examples, the patterning coating non-transition part 301ₙ may have a cross-sectional area that, in some non-limiting examples, may be approximated by multiplying the average film thickness d₂ by the width w₁. In some non-limiting examples, the patterning coating transition region 301ₜ may have a cross-sectional area that, in some non-limiting examples, may be approximated by multiplying an average film thickness across the patterning coating transition region 301ₜ by the width w₁.

In some non-limiting examples, w₁ may exceed w₂. In some non-limiting examples, a quotient of w₁/w₂ may be at least one of at least about: 5, 10, 20, 50, 100, 500, 1,000, 1,500, 5,000, 10,000, 50,000, or 100,000.

In some non-limiting examples, at least one of w₁ and w₂ may exceed the average film thickness d₁ of the underlying layer.

In some non-limiting examples, at least one of w₁ and w₂ may exceed d₂. In some non-limiting examples, both w₁ and w₂ may exceed d₂. In some non-limiting examples, w₁ and w₂ both may exceed d₁, and d₁ may exceed d₂.

Deposited Layer Transition Region

As may be better seen in FIG. 7B, in some non-limiting examples, the patterning coating 210 in the first portion 301 may be surrounded by the deposited layer 430 in the second portion 302 such that the second portion 302 has a boundary that is defined by the further extent or edge 735 of the deposited layer 430 in the lateral aspect along each lateral axis. In some non-limiting examples, the deposited layer edge 735 in the lateral aspect may be defined by a perimeter of the second portion 302 in such aspect.

In some non-limiting examples, the second portion 302 may comprise at least one deposited layer transition region 302ₜ, in the lateral aspect, in which a thickness of the deposited layer 430 may transition from a maximum thickness to a reduced thickness. The extent of the second portion 302 that does not exhibit such a transition may be identified as a deposited layer non-transition part 302ₙ of the second portion 302. In some non-limiting examples, the deposited layer 430 may form a substantially closed coating 440 in the deposited layer non-transition part 302ₙ of the second portion 302.

In some non-limiting examples, in plan, the deposited layer transition region 302ₜ may extend, in the lateral aspect, between the deposited layer non-transition part 302ₙ of the second portion 302 and the deposited layer edge 735.

In some non-limiting examples, in plan, the deposited layer transition region 302ₜ may surround, and/or extend along a perimeter of, the deposited layer non-transition part 302ₙ of the second portion 302.

In some non-limiting examples, along at least one lateral axis, the deposited layer non-transition part 302ₙ of the second portion 302 may occupy the entirety of the second portion 302, such that there is no deposited layer transition region 302ₜ between it and the first portion 301.

As illustrated in FIG. 7A, in some non-limiting examples, the deposited layer 430 may have an average film thickness d₃ in the deposited layer non-transition part 302ₙ of the second portion 302 that may be in a range of at least one of between about: 1-500 nm, 5-200 nm, 5-40 nm, 10-30 nm, or 10-100 nm. In some non-limiting examples, d₃ may exceed at least one of about: 10 nm, 50 nm, or 100 nm. In some non-limiting examples, the average film thickness d₃ of the deposited layer 430 in the deposited layer non-transition part 302ₜ of the second portion 302 may be substantially the same, or constant, thereacross.

In some non-limiting examples, d₃ may exceed the average film thickness d₁ of the underlying layer.

In some non-limiting examples, a quotient d₃/d₁ may be at least one of at least about: 1.5, 2, 5, 10, 20, 50, or 100. In some non-limiting examples, the quotient d₃/d₁ may be in a range of at least one of between about: 0.1-10, or 0.2-40.

In some non-limiting examples, d₃ may exceed an average film thickness d₂ of the patterning coating 210.

In some non-limiting examples, a quotient d₃/d₂ may be at least one of at least about: 1.5, 2, 5, 10, 20, 50, or 100. In some non-limiting examples, the quotient d₃/d₂ may be in a range of at least one of between about: 0.2-10, or 0.5-40.

In some non-limiting examples, d₃ may exceed d₂ and d₂ may exceed d₁. In some other non-limiting examples, d₃ may exceed d₁ and d₁ may exceed d₂.

In some non-limiting examples, a quotient d₂/d₁ may be between at least one of about: 0.2-3, or 0.1-5.

In some non-limiting examples, along at least one lateral axis, including without limitation, the X-axis, the deposited layer non-transition part 302ₙ of the second portion 302 may have a width of w₃. In some non-limiting examples, the deposited layer non-transition part 302ₙ of the second portion 302 may have a cross-sectional area a₃ that, in some non-limiting examples, may be approximated by multiplying the average film thickness d₃ by the width w₃.

In some non-limiting examples, w₃ may exceed the width w₁ of the patterning coating non-transition part 301ₙ. In some non-limiting examples, w₁ may exceed w₃.

In some non-limiting examples, a quotient w₁/w₃ may be in a range of at least one of between about: 0.1-10, 0.2-5, 0.3-3, or 0.4-2. In some non-limiting examples, a quotient w₃/w₁ may be at least one of at least about: 1, 2, 3, or 4.

In some non-limiting examples, w₃ may exceed the average film thickness d₃ of the deposited layer 430.

In some non-limiting examples, a quotient w₃/d₃ may be at least one of at least about: 10, 50, 100, or 500. In some non-limiting examples, the quotient w₃/d₃ may be no more than about 100,000.

In some non-limiting examples, the deposited layer 430 may have a thickness that decreases from a maximum to a minimum within the deposited layer transition region 302ₜ. In some non-limiting examples, the maximum may be at, and/or proximate to, the boundary between the deposited layer transition region 302ₜ and the deposited layer non-transition part 302ₙ of the second portion 302. In some non-limiting examples, the minimum may be at, and/or proximate to, the deposited layer edge 735. In some non-limiting examples, the maximum may be the average film thickness d₃ in the deposited layer non-transition part 302ₙ of the second portion 302. In some non-limiting examples, the minimum may be in a range of between about 0-0.1 nm. In some non-limiting examples, the minimum may be the average film thickness d₃ in the deposited layer non-transition part 302ₙ of the second portion 302.

In some non-limiting examples, a profile of the thickness in the deposited layer transition region 302ₜ may be sloped, and/or follow a gradient. In some non-limiting examples, such profile may be tapered. In some non-limiting examples, the taper may follow a linear, non-linear, parabolic, and/or exponential decaying profile.

In some non-limiting examples, as shown by way of non-limiting example in the example version 700ₑ in FIG. 7E of the device 400, the deposited layer 430 may completely cover the underlying surface in the deposited layer transition region 302ₜ. In some non-limiting examples, the deposited layer 430 may comprise a substantially closed coating 440 in at least a part of the deposited layer transition region 302ₜ. In some non-limiting examples, at least a part of the underlying surface may be uncovered by the deposited layer 430 in the deposited layer transition region 302ₜ.

In some non-limiting examples, the deposited layer 430 may comprise a discontinuous layer 130 in at least a part of the deposited layer transition region 302ₜ.

Those having ordinary skill in the relevant art will appreciate that, while not explicitly illustrated, the patterning material 511 may also be present to some extent at an interface between the deposited layer 430 and an underlying layer. Such material may be deposited as a result of a shadowing effect, in which a deposited pattern is not identical to a pattern of a mask and may, in some non-limiting examples, result in some evaporated patterning material 511 being deposited on a masked part of a target exposed layer surface 11. By way of non-limiting example, such material may form as particle structures 121 and/or as a thin film having a thickness that may be substantially no more than an average thickness of the patterning coating 210.

Overlap

In some non-limiting examples, the deposited layer edge 735 may be spaced apart, in the lateral aspect from the patterning coating transition region 301ₜ of the first portion 301, such that there is no overlap between the first portion 301 and the second portion 302 in the lateral aspect.

In some non-limiting examples, at least a part of the first portion 301 and at least a part of the second portion 302 may overlap in the lateral aspect. Such overlap may be identified by an overlap portion 703, such as may be shown by way of non-limiting example in FIG. 7A, in which at least a part of the second portion 302 overlaps at least a part of the first portion 301.

In some non-limiting examples, as shown by way of non-limiting example in FIG. 7F, at least a part of the deposited layer transition region 302ₜ may be disposed over at least a part of the patterning coating transition region 301ₜ. In some non-limiting examples, at least a part of the patterning coating transition region 301ₜ may be substantially devoid of the deposited layer 430, and/or the deposited material 631. In some non-limiting examples, the deposited material 631 may form a discontinuous layer 130 on an exposed layer surface 11 of at least a part of the patterning coating transition region 301ₜ.

In some non-limiting examples, as shown by way of non-limiting example in FIG. 7G, at least a part of the deposited layer transition region 302ₜ may be disposed over at least a part of the patterning coating non-transition part 301ₙ of the first portion 301.

Although not shown, those having ordinary skill in the relevant art will appreciate that, in some non-limiting examples, the overlap portion 703 may reflect a scenario in which at least a part of the first portion 301 overlaps at least a part of the second portion 302.

Thus, in some non-limiting examples, at least a part of the patterning coating transition region 301ₜ may be disposed over at least a part of the deposited layer transition region 302ₜ. In some non-limiting examples, at least a part of the deposited layer transition region 302ₜ may be substantially devoid of the patterning coating 210, and/or the patterning material 511. In some non-limiting examples, the patterning material 511 may form a discontinuous layer 130 on an exposed layer surface of at least a part of the deposited layer transition region 302ₜ.

In some non-limiting examples, at least a part of the patterning coating transition region 301ₜ may be disposed over at least a part of the deposited layer non-transition part 302ₙ of the second portion 302.

In some non-limiting examples, the patterning coating edge 715 may be spaced apart, in the lateral aspect, from the deposited layer non-transition part 302ₙ of the second portion 302.

In some non-limiting examples, the deposited layer 430 may be formed as a single monolithic coating across both the deposited layer non-transition part 302ₙ and the deposited layer transition region 302ₜ of the second portion 302.

Edge Effects of Patterning Coatings and Deposited Layers

FIGS. 8A-81 describe various potential behaviours of patterning coatings 210 at a deposition interface with deposited layers 430.

Turning to FIG. 8A, there may be shown a first example of a part of an example version 800 of the device 400 at a patterning coating deposition boundary. The device 800 may comprise a substrate 10 having an exposed layer surface 11. A patterning coating 210 may be deposited over a first portion 301 of the exposed layer surface 11. A deposited layer 430 may be deposited over a second portion 302 of the exposed layer surface 11. As shown, by way of non-limiting example, the first portion 301 and the second portion 302 may be distinct and non-overlapping parts of the exposed layer surface 11.

The deposited layer 430 may comprise a first part 430₁ and a second part 430₂. As shown, by way of non-limiting example, the first part 430₁ of the deposited layer 430 may substantially cover the second portion 302 and the second part 430₂ of the deposited layer 430 may partially project over, and/or overlap a first part of the patterning coating 210.

In some non-limiting examples, since the patterning coating 210 may be formed such that its exposed layer surface 11 exhibits a relatively low initial sticking probability against deposition of the deposited material 631, there may be a gap 829 formed between the projecting, and/or overlapping second part 430₂ of the deposited layer 430 and the exposed layer surface 11 of the patterning coating 210. As a result, the second part 430₂ may not be in physical contact with the patterning coating 210 but may be spaced-apart therefrom by the gap 829 in a cross-sectional aspect. In some non-limiting examples, the first part 430₁ of the deposited layer 430 may be in physical contact with the patterning coating 210 at an interface, and/or boundary between the first portion 301 and the second portion 302.

In some non-limiting examples, the projecting, and/or overlapping second part 430₂ of the deposited layer 430 may extend laterally over the patterning coating 210 by a comparable extent as an average layer thickness dₐ of the first part 430₁ of the deposited layer 430. By way of non-limiting example, as shown, a width w_{b} of the second part 430₂ may be comparable to the average layer thickness dₐ of the first part 430₁. In some non-limiting examples, a ratio of a width w_{b} of the second part 430₂ by an average layer thickness dₐ of the first part 430₁ may be in a range of at least one of between about: 1:1-1:3, 1:1-1:1.5, or 1:1-1:2. While the average layer thickness dₐ may in some non-limiting examples be relatively uniform across the first part 430₁, in some non-limiting examples, the extent to which the second part 430₂ may project, and/or overlap with the patterning coating 210 (namely w_{b}) may vary to some extent across different parts of the exposed layer surface 11.

Turning now to FIG. 8B, the deposited layer 430 may be shown to include a third part 4303 disposed between the second part 430₂ and the patterning coating 210. As shown, the second part 430₂ of the deposited layer 430 may extend laterally over and is longitudinally spaced apart from the third part 4303 of the deposited layer 430 and the third part 4303 may be in physical contact with the exposed layer surface 11 of the patterning coating 210. An average layer thickness de of the third part 4303 of the deposited layer 430 may be no more, and in some non-limiting examples, substantially so, than the average layer thickness dₐ of the first part 430₁ thereof. In some non-limiting examples, a width we of the third part 4303 may exceed the width w_{b} of the second part 430₂. In some non-limiting examples, the third part 4303 may extend laterally to overlap the patterning coating 210 to a greater extent than the second part 430₂. In some non-limiting examples, a ratio of a width we of the third part 4303 by an average layer thickness dₐ of the first part 430₁ may be in a range of at least one of between about: 1:2-3:1, or 1:1.2-2.5:1. While the average layer thickness dₐ may in some non-limiting examples be relatively uniform across the first part 430₁, in some non-limiting examples, the extent to which the third part 4303 may project, and/or overlap with the patterning coating 210 (namely we) may vary to some extent across different parts of the exposed layer surface 11.

In some non-limiting examples, the average layer thickness de of the third part 4303 may not exceed about 5% of the average layer thickness dₐ of the first part 430₁. By way of non-limiting example, de may be no more than at least one of about: 4%, 3%, 2%, 1%, or 0.5% of dₐ. Instead of, and/or in addition to, the third part 4303 being formed as a thin film, as shown, the material of the deposited layer 430 may form as particle structures 121 on a part of the patterning coating 210. By way of non-limiting example, such particle structures 121 may comprise features that are physically separated from one another, such that they do not form a continuous layer.

Turning now to FIG. 8C, an NPC 820 may be disposed between the substrate 10 and the deposited layer 430. The NPC 820 may be disposed between the first part 430₁ of the deposited layer 430 and the second portion 302 of the substrate 10. The NPC 820 is illustrated as being disposed on the second portion 302 and not on the first portion 301, where the patterning coating 210 has been deposited. The NPC 820 may be formed such that, at an interface, and/or boundary between the NPC 820 and the deposited layer 430, a surface of the NPC 820 may exhibit a relatively high initial sticking probability against deposition of the deposited material 631. As such, the presence of the NPC 820 may promote the formation, and/or growth of the deposited layer 430 during deposition.

Turning now to FIG. 8D, the NPC 820 may be disposed on both the first portion 301 and the second portion 302 of the substrate 10 and the patterning coating 210 may cover a part of the NPC 820 disposed on the first portion 301. Another part of the NPC 820 may be substantially devoid of the patterning coating 210 and the deposited layer 430 may cover such part of the NPC 820.

Turning now to FIG. 8E, the deposited layer 430 may be shown to partially overlap a part of the patterning coating 210 in a third portion 803 of the substrate 10. In some non-limiting examples, in addition to the first part 430₁ and the second part 430₂, the deposited layer 430 may further include a fourth part 4304. As shown, the fourth part 4304 of the deposited layer 430 may be disposed between the first part 430₁ and the second part 430₂ of the deposited layer 430 and the fourth part 4304 may be in physical contact with the exposed layer surface 11 of the patterning coating 210. In some non-limiting examples, the overlap in the third portion 803 may be formed as a result of lateral growth of the deposited layer 430 during an open mask and/or a mask-free deposition process. In some non-limiting examples, while the exposed layer surface 11 of the patterning coating 210 may exhibit a relatively low initial sticking probability against deposition of the deposited material 631, and thus a probability of the material nucleating on the exposed layer surface 11 may be low, as the deposited layer 430 grows in thickness, the deposited layer 430 may also grow laterally and may cover a subset of the patterning coating 210 as shown.

Turning now to FIG. 8F the first portion 301 of the substrate 10 may be coated with the patterning coating 210 and the second portion 302 adjacent thereto may be coated with the deposited layer 430. In some non-limiting examples, it has been observed that conducting an open mask and/or a mask-free deposition of the deposited layer 430 may result in the deposited layer 430 exhibiting a tapered cross-sectional profile at, and/or near an interface between the deposited layer 430 and the patterning coating 210.

In some non-limiting examples, an average layer thickness of the deposited layer 430 at, and/or near the interface may be less than an average layer thickness d₃ of the deposited layer 430. While such tapered profile may be shown as being curved, and/or arched, in some non-limiting examples, the profile may, in some non-limiting examples be substantially linear, and/or non-linear. By way of non-limiting example, an average layer thickness d₃ of the deposited layer 430 may decrease, without limitation, in a substantially linear, exponential, and/or quadratic fashion in a region proximal to the interface.

It has been observed that a contact angle θ_{c} of the deposited layer 430 at, and/or near the interface between the deposited layer 430 and the patterning coating 210 may vary, depending on properties of the patterning coating 210, such as a relative initial sticking probability. It may be further postulated that the contact angle θ_{c} of the nuclei may, in some non-limiting examples, dictate the thin film contact angle of the deposited layer 430 formed by deposition. Referring to FIG. 8F by way of non-limiting example, the contact angle θ_{c} may be determined by measuring a slope of a tangent of the deposited layer 430 at and/or near the interface between the deposited layer 430 and the patterning coating 210. In some non-limiting examples, where the cross-sectional taper profile of the deposited layer 430 may be substantially linear, the contact angle θ_{c} may be determined by measuring the slope of the deposited layer 430 at, and/or near the interface. As will be appreciated by those having ordinary skill in the relevant art, the contact angle θ_{c} may be generally measured relative to an angle of the underlying layer. In the present disclosure, for purposes of simplicity of illustration, the patterning coating 210 and the deposited layer 430 may be shown deposited on a planar surface. However, those having ordinary skill in the relevant art will appreciate that the patterning coating 210 and the deposited layer 430 may be deposited on non-planar surfaces.

In some non-limiting examples, the contact angle θ_{c} of the deposited layer 430 may exceed about 90°. Referring now to FIG. 8G, by way of non-limiting example, the deposited layer 430 may be shown as including a part extending past the interface between the patterning coating 210 and the deposited layer 430 and may be spaced apart from the patterning coating 210 by a gap 829. In such non-limiting scenario, the contact angle θ_{c} may, in some non-limiting examples, exceed 900.

In some non-limiting examples, it may be advantageous to form a deposited layer 430 exhibiting a relatively high contact angle θ_{c}. By way of non-limiting example, the contact angle θ_{c} may exceed at least one of about: 10°, 15°, 20°, 25°, 30°, 35°, 40°, 50°, 70°, 75°, or 80°. By way of non-limiting example, a deposited layer 430 having a relatively high contact angle θ_{c} may allow for creation of finely patterned features while maintaining a relatively high aspect ratio. By way of non-limiting example, there may be an aim to form a deposited layer 430 exhibiting a contact angle θ_{c} greater than about 90°. By way of non-limiting example, the contact angle θ_{c} may exceed at least one of about: 90°, 95°, 100°, 105°, 110° 120°, 130°, 135°, 140°, 145°, 150°, or 170°.

Turning now to FIGS. 8H-81, the deposited layer 430 may partially overlap a part of the patterning coating 210 in the third portion 803 of the substrate 10, which may be disposed between the first portion 301 and the second portion 302 thereof. As shown, the subset of the deposited layer 430 partially overlapping a subset of the patterning coating 210 may be in physical contact with the exposed layer surface 11 thereof. In some non-limiting examples, the overlap in the third portion 803 may be formed because of lateral growth of the deposited layer 430 during an open mask and/or a mask-free deposition process. In some non-limiting examples, while the exposed layer surface 11 of the patterning coating 210 may exhibit a relatively low initial sticking probability against deposition of the deposited material 631 and thus the probability of the material nucleating on the exposed layer surface 11 is low, as the deposited layer 430 grows in thickness, the deposited layer 430 may also grow laterally and may cover a subset of the patterning coating 210.

In the case of FIGS. 8H-81, the contact angle θ_{c} of the deposited layer 430 may be measured at an edge thereof near the interface between it and the patterning coating 210, as shown. In FIG. 81, the contact angle θ_{c} may exceed about 90°, which may in some non-limiting examples result in a subset of the deposited layer 430 being spaced apart from the patterning coating 210 by the gap 829.

### Particle

In some non-limiting examples, such as may be shown in FIG. 7C, there may be at least one particle, including without limitation, a nanoparticle (NP), a (plasmonic) island, a plate, a disconnected cluster, and/or a network (collectively particle structure 121) disposed on an exposed layer surface 11 of an underlying layer. In some non-limiting examples, the underlying layer may be the patterning coating 210 in the first portion 301. In some non-limiting examples, the at least one particle structure 121 may be disposed on an exposed layer surface 11 of the patterning coating 210. In some non-limiting examples, there may be a plurality of such particle structures 121.

In some non-limiting examples, the at least one particle structure 121 may comprise a particle structure material. In some non-limiting examples, the particle structure material may be the same as the deposited material 631 in the deposited layer.

In some non-limiting examples, the particle structure material in the discontinuous layer 130 in the first portion 301, the deposited material 631 in the deposited layer 430, and/or a material of which the underlying layer thereunder may be comprised, may comprise a common metal.

In some non-limiting examples, the particle structure material may comprise an element selected from at least one of: K, Na, Li, Ba, Cs, Yb, Ag, Au, Cu, Al, Mg, Zn, Cd, Sn, or Y. In some non-limiting examples, the element may comprise at least one of: K, Na, Li, Ba, Cs, Yb, Ag, Au, Cu, Al, or Mg. In some non-limiting examples, the element may comprise at least one of: Cu, Ag, or Au. In some non-limiting examples, the element may be Cu. In some non-limiting examples, the element may be Al. In some non-limiting examples, the element may comprise at least one of: Mg, Zn, Cd, or Yb. In some non-limiting examples, the element may comprise at least one of: Mg, Ag, Al, Yb, or Li. In some non-limiting examples, the element may comprise at least one of: Mg, Ag, or Yb. In some non-limiting examples, the element may comprise at least one of: Mg, or Ag. In some non-limiting examples, the element may be Ag.

In some non-limiting examples, the particle structure material may comprise a pure metal. In some non-limiting examples, the at least one particle structure 121 may be a pure metal. In some non-limiting examples, the at least one particle structure 121 may be at least one of: pure Ag or substantially pure Ag. In some non-limiting examples, the substantially pure Ag may have a purity of at least one of at least about: 95%, 99%, 99.9%, 99.99%, 99.999%, or 99.9995%. In some non-limiting examples, the at least one particle structure 121 may be at least one of: pure Mg or substantially pure Mg. In some non-limiting examples, the substantially pure Mg may have a purity of at least one of at least about: 95%, 99%, 99.9%, 99.99%, 99.999%, or 99.9995%.

In some non-limiting examples, the at least one particle structure 121 may comprise an alloy. In some non-limiting examples, the alloy may be at least one of: an Ag-containing alloy, an Mg-containing alloy, or an AgMg-containing alloy. In some non-limiting examples, the AgMg-containing alloy may have an alloy composition that may range from about 1:10 (Ag:Mg) to about 10:1 by volume.

In some non-limiting examples, the particle structure material may comprise other metals in place of, or in combination with Ag. In some non-limiting examples, the particle structure material may comprise an alloy of Ag with at least one other metal. In some non-limiting examples, the particle structure material may comprise an alloy of Ag with at least one of: Mg, or Yb. In some non-limiting examples, such alloy may be a binary alloy having a composition of between about: 5-95 vol. % Ag, with the remainder being the other metal. In some non-limiting examples, the particle structure material may comprise Ag and Mg. In some non-limiting examples, the particle structure material may comprise an Ag:Mg alloy having a composition of between about 1:10-10:1 by volume. In some non-limiting examples, the particle structure material may comprise Ag and Yb. In some non-limiting examples, the particle structure material may comprise a Yb:Ag alloy having a composition of between about 1:20-10:1 by volume. In some non-limiting examples, the particle structure material may comprise Mg and Yb. In some non-limiting examples, the particle structure material may comprise an Mg:Yb alloy. In some non-limiting examples, the particle structure material may comprise an Ag:Mg:Yb alloy.

In some non-limiting examples, the at least one particle structure 121 may comprise at least one additional element. In some non-limiting examples, such additional element may be a non-metallic element. In some non-limiting examples, the non-metallic material may be at least one of: O, S, N, or C. It will be appreciated by those having ordinary skill in the relevant art that, in some non-limiting examples, such additional element(s) may be incorporated into the at least one particle structure 121 as a contaminant, due to the presence of such additional element(s) in the source material, equipment used for deposition, and/or the vacuum chamber environment. In some non-limiting examples, such additional element(s) may form a compound together with other element(s) of the at least one particle structure 121. In some non-limiting examples, a concentration of the non-metallic element in the deposited material 631 may be no more than at least one of about: 1%, 0.1%, 0.01%, 0.001%, 0.0001%, 0.00001%, 0.000001%, or 0.0000001%. In some non-limiting examples, the at least one particle structure 121 may have a composition in which a combined amount of O and C therein is no more than at least one of about: 10%, 5%, 1%, 0.1%, 0.01%, 0.001%, 0.0001%, 0.00001%, 0.000001%, or 0.0000001%.

In some non-limiting examples, the presence of the at least one particle structure 121, including without limitation, NPs, including without limitation, in a discontinuous layer 130, on an exposed layer surface 11 of the patterning coating 210 may affect some optical properties of the device 400.

In some non-limiting examples, such plurality of particle structures 121 may form a discontinuous layer 130.

Without wishing to be limited to any particular theory, it may be postulated that, while the formation of a closed coating 440 of the deposited material 631 may be substantially inhibited by and/or on the patterning coating 210, in some non-limiting examples, when the patterning coating 210 is exposed to deposition of the deposited material 631 thereon, some vapor monomers 632 of the deposited material 631 may ultimately form at least one particle structure 121 of the deposited material 631 thereon.

In some non-limiting examples, at least some of the particle structures 121 may be disconnected from one another. In other words, in some non-limiting examples, the discontinuous layer 130 may comprise features, including particle structures 121, that may be physically separated from one another, such that the particle structures 121 do not form a closed coating 440. Accordingly, such discontinuous layer 130 may, in some non-limiting examples, thus comprise a thin disperse layer of deposited material 631 formed as particle structures 121, inserted at, and/or substantially across the lateral extent of, an interface between the patterning coating 210 and at least one covering layer in the device 100.

In some non-limiting examples, at least one of the particle structures 121 of deposited material 631 may be in physical contact with an exposed layer surface 11 of the patterning coating 210. In some non-limiting examples, substantially all of the particle structures 121 of deposited material 631 may be in physical contact with the exposed layer surface 11 of the patterning coating 210.

Without wishing to be bound by any particular theory, it has been found, somewhat surprisingly, that the presence of such a thin, disperse discontinuous layer 130 of deposited material 631, including without limitation, at least one particle structure 121, including without limitation, metal particle structures 121, on an exposed layer surface 11 of the patterning coating 210, may exhibit at least one varied characteristic and concomitantly, varied behaviour, including without limitation, optical effects and properties of the device 400, as discussed herein. In some non-limiting examples, such effects and properties may be controlled to some extent by judicious selection of at least one of: the characteristic size, size distribution, shape, surface coverage, configuration, deposited density, and/or dispersity of the particle structures 121 on the patterning coating 210.

In some non-limiting examples, the formation of at least one of: the characteristic size, size distribution, shape, surface coverage, configuration, deposited density, and/or dispersity of such discontinuous layer 130 may be controlled, in some non-limiting examples, by judicious selection of at least one of: at least one characteristic of the patterning material 511, an average film thickness d₂ of the patterning coating 210, the introduction of heterogeneities in the patterning coating 210, and/or a deposition environment, including without limitation, a temperature, pressure, duration, deposition rate, and/or deposition process for the patterning coating 210.

In some non-limiting examples, the formation of at least one of the characteristic size, size distribution, shape, surface coverage, configuration, deposited density, and/or dispersity of such discontinuous layer 130 may be controlled, in some non-limiting examples, by judicious selection of at least one of: at least one characteristic of the particle structure material (which may be the deposited material 631), an extent to which the patterning coating 210 may be exposed to deposition of the particle structure material (which, in some non-limiting examples may be specified in terms of a thickness of the corresponding discontinuous layer 130), and/or a deposition environment, including without limitation, a temperature, pressure, duration, deposition rate, and/or method of deposition for the particle structure material.

In some non-limiting examples, the discontinuous layer 130 may be deposited in a pattern across the lateral extent of the patterning coating 210.

In some non-limiting examples, the discontinuous layer 130 may be disposed in a pattern that may be defined by at least one region therein that is substantially devoid of the at least one particle structure 121.

In some non-limiting examples, the characteristics of such discontinuous layer 130 may be assessed, in some non-limiting examples, somewhat arbitrarily, according to at least one of several criteria, including without limitation, a characteristic size, size distribution, shape, configuration, surface coverage, deposited distribution, dispersity, and/or a presence, and/or extent of aggregation instances of the particle structure material, formed on a part of the exposed layer surface 11 of the underlying layer.

In some non-limiting examples, an assessment of the discontinuous layer 130 according to such at least one criterion, may be performed on, including without limitation, by measuring, and/or calculating, at least one attribute of the discontinuous layer 130, using a variety of imaging techniques, including without limitation, at least one of: transmission electron microscopy (TEM), atomic force microscopy (AFM), and/or scanning electron microscopy (SEM).

Those having ordinary skill in the relevant art will appreciate that such an assessment of the discontinuous layer 130 may depend, to a greater, and/or lesser extent, by the extent, of the exposed layer surface 11 under consideration, which in some non-limiting examples may comprise an area, and/or region thereof. In some non-limiting examples, the discontinuous layer 130 may be assessed across the entire extent, in a first lateral aspect, and/or a second lateral aspect that is substantially transverse thereto, of the exposed layer surface 11. In some non-limiting examples, the discontinuous layer 130 may be assessed across an extent that comprises at least one observation window applied against (a part of) the discontinuous layer 130.

In some non-limiting examples, the at least one observation window may be located at at least one of: a perimeter, interior location, and/or grid coordinate of the lateral aspect of the exposed layer surface 11. In some non-limiting examples, a plurality of the at least one observation windows may be used in assessing the discontinuous layer 130.

In some non-limiting examples, the observation window may correspond to a field of view of an imaging technique applied to assess the discontinuous layer 130, including without limitation, at least one of: TEM, AFM, and/or SEM. In some non-limiting examples, the observation window may correspond to a given level of magnification, including without limitation, at least one of: 2.00 μm, 1.00 μm, 500 nm, or 200 nm.

In some non-limiting examples, the assessment of the discontinuous layer 130, including without limitation, at least one observation window used, of the exposed layer surface 11 thereof, may involve calculating, and/or measuring, by any number of mechanisms, including without limitation, manual counting, and/or known estimation techniques, which may, in some non-limiting examples, may comprise curve, polygon, and/or shape fitting techniques.

In some non-limiting examples, the assessment of the discontinuous layer 130, including without limitation, at least one observation window used, of the exposed layer surface 11 thereof, may involve calculating, and/or measuring an average, median, mode, maximum, minimum, and/or other probabilistic, statistical, and/or data manipulation of a value of the calculation, and/or measurement.

In some non-limiting examples, one of the at least one criterion by which such discontinuous layer 130 may be assessed, may be a surface coverage of the deposited material 631 on such (part of the) discontinuous layer 130. In some non-limiting examples, the surface coverage may be represented by a (non-zero) percentage coverage by such deposited material 631 of such (part of the) discontinuous layer 130. In some non-limiting examples, the percentage coverage may be compared to a maximum threshold percentage coverage.

In some non-limiting examples, a (part of a) discontinuous layer 130 having a surface coverage that may be substantially no more than the maximum threshold percentage coverage, may result in a manifestation of different optical characteristics that may be imparted by such part of the discontinuous layer 130, to EM radiation passing therethrough, whether transmitted entirely through the device 400, and/or emitted thereby, relative to EM radiation passing through a part of the discontinuous layer 130 having a surface coverage that substantially exceeds the maximum threshold percentage coverage.

In some non-limiting examples, one measure of a surface coverage of an amount of an electrically conductive material on a surface may be a (EM radiation) transmittance, since in some non-limiting examples, electrically conductive materials, including without limitation, metals, including without limitation: Ag, Mg, or Yb, attenuate, and/or absorb EM radiation.

Those having ordinary skill in the relevant art will appreciate that in some non-limiting examples, surface coverage may be understood to encompass one or both of particle size, and deposited density. Thus, in some non-limiting examples, a plurality of these three criteria may be positively correlated. Indeed, in some non-limiting examples, a criterion of low surface coverage may comprise some combination of a criterion of low deposited density with a criterion of low particle size.

In some non-limiting examples, one of the at least one criterion by which such discontinuous layer 130 may be assessed, may be a characteristic size of the constituent particle structures 121.

In some non-limiting examples, the at least one particle structure 121 of the discontinuous layer 130, may have a characteristic size that is no more than a maximum threshold size. Non-limiting examples of the characteristic size may include at least one of: height, width, length, and/or diameter.

In some non-limiting examples, substantially all of the particle structures 121, of the discontinuous layer 130 may have a characteristic size that lies within a specified range.

In some non-limiting examples, such characteristic size may be characterized by a characteristic length, which in some non-limiting examples, may be considered a maximum value of the characteristic size. In some non-limiting examples, such maximum value may extend along a major axis of the particle structure 121. In some non-limiting examples, the major axis may be understood to be a first dimension extending in a plane defined by the plurality of lateral axes. In some non-limiting examples, a characteristic width may be identified as a value of the characteristic size of the particle structure 121 that may extend along a minor axis of the particle structure 121. In some non-limiting examples, the minor axis may be understood to be a second dimension extending in the same plane but substantially transverse to the major axis.

In some non-limiting examples, the characteristic length of the at least one particle structure 121, along the first dimension, may be no more than the maximum threshold size.

In some non-limiting examples, the characteristic width of the at least one particle structure 121, along the second dimension, may be no more than the maximum threshold size.

In some non-limiting examples, a size of the constituent particle structures 121, in the (part of the) discontinuous layer 130, may be assessed by calculating, and/or measuring a characteristic size of such at least one particle structure 121, including without limitation, a mass, volume, length of a diameter, perimeter, major, and/or minor axis thereof.

In some non-limiting examples, one of the at least one criterion by which such discontinuous layer 130 may be assessed, may be a deposited density thereof.

In some non-limiting examples, the characteristic size of the particle structure 121 may be compared to a maximum threshold size.

In some non-limiting examples, the deposited density of the particle structures 121 may be compared to a maximum threshold deposited density.

In some non-limiting examples, at least one of such criteria may be quantified by a numerical metric. In some non-limiting examples, such a metric may be a calculation of a dispersity D that describes the distribution of particle (area) sizes in a deposited layer 430 of particle structures 121, in which:

$$D = \frac{\overline{{S}_{s}}}{\overline{{S}_{n}}} where : \qquad ( 1 )$$

$$\overline{{S}_{s}} = \frac{{\sum }_{i = 1}^{n} {S}_{i}^{2}}{{\sum }_{i = 1}^{n} {S}_{i}} , \overline{{S}_{n}} = \frac{{\sum }_{i = 1}^{n} {S}_{i}}{n} , \qquad ( 2 )$$

n is the number of particle structures 121 in a sample area,
Sᵢ is the (area) size of the i^{th} particle structure 121,
S̅ₙ is the number average of the particle (area) sizes and
S̅ₛ is the (area) size average of the particle (area) sizes.

Those having ordinary skill in the relevant art will appreciate that the dispersity is roughly analogous to a polydispersity index (PDI) and that these averages are roughly analogous to the concepts of number average molecular weight and weight average molecular weight familiar in organic chemistry, but applied to an (area) size, as opposed to a molecular weight of a sample particle structure 121.

Those having ordinary skill in the relevant will also appreciate that while the concept of dispersity may, in some non-limiting examples, be considered a three-dimensional volumetric concept, in some non-limiting examples, the dispersity may be considered to be a two-dimensional concept. As such, the concept of dispersity may be used in connection with viewing and analyzing two-dimensional images of the deposited layer 430, such as may be obtained by using a variety of imaging techniques, including without limitation, at least one of: TEM, AFM and/or SEM. It is in such a two-dimensional context, that the equations set out above are defined.

In some non-limiting examples, the dispersity and/or the number average of the particle (area) size and the (area) size average of the particle (area) size may involve a calculation of at least one of: the number average of the particle diameters and the (area) size average of the particle diameters:

$$\overline{{d}_{n}} = 2 \sqrt{\frac{\overline{{S}_{n}}}{π}} , \overline{{d}_{s}} = 2 \sqrt{\frac{\overline{{S}_{s}}}{π}} \qquad ( 3 )$$

In some non-limiting examples, the deposited material, including without limitation as particle structures 121, of the at least one deposited layer 430, may be deposited by a mask-free and/or open mask deposition process.

In some non-limiting examples, the particle structures 121 may have a substantially round shape. In some non-limiting examples, the particle structures 121 may have a substantially spherical shape.

For purposes of simplification, in some non-limiting examples, it may be assumed that a longitudinal extent of each particle structure 121 may be substantially the same (and, in any event, may not be directly measured from a plan view SEM image) so that the (area) size of the particle structure 121 may be represented as a two-dimensional area coverage along the pair of lateral axes. In the present disclosure, a reference to an (area) size may be understood to refer to such two-dimensional concept, and to be differentiated from a size (without the prefix “area”) that may be understood to refer to a one-dimensional concept, such as a linear dimension.

Indeed, in some early investigations, it appears that, in some non-limiting examples, the longitudinal extent, along the longitudinal axis, of such particle structures 121, may tend to be small relative to the lateral extent (along at least one of the lateral axes), such that the volumetric contribution of the longitudinal extent thereof may be much less than that of such lateral extent. In some non-limiting examples, this may be expressed by an aspect ratio (a ratio of a longitudinal extent to a lateral extent) that may be no more than 1. In some non-limiting examples, such aspect ratio may be at least one of about: 1:10, 1:20, 1:50, 1:75, or 1:300.

In this regard, the assumption set out above (that the longitudinal extent is substantially the same and can be ignored) to represent the particle structure 121 as a two-dimensional area coverage may be appropriate.

Those having ordinary skill in the relevant art will appreciate, having regard to the non-determinative nature of the deposition process, especially in the presence of defects, and/or anomalies on the exposed layer surface 11 of the underlying material, including without limitation, heterogeneities, including without limitation, at least one of: a step edge, a chemical impurity, a bonding site, a kink, and/or a contaminant thereon, and consequently the formation of particle structures 121 thereon, the non-uniform nature of coalescence thereof as the deposition process continues, and in view of the uncertainty in the size, and/or position of observation windows, as well as the intricacies and variability inherent in the calculation, and/or measurement of their characteristic size, spacing, deposited density, degree of aggregation, and the like, there may be considerable variability in terms of the features, and/or topology within observation windows.

In the present disclosure, for purposes of simplicity of illustration, certain details of deposited materials 631, including without limitation, thickness profiles, and/or edge profiles of layer(s) have been omitted.

Those having ordinary skill in the relevant art will appreciate that certain metal NPs, whether or not as part of a discontinuous layer 130 of deposited material 631, including without limitation, at least one particle structure 121, may exhibit surface plasmon (SP) excitations, and/or coherent oscillations of free electrons, with the result that such NPs may absorb, and/or scatter light in a range of the EM spectrum, including without limitation, the visible spectrum, and/or a sub-range thereof. The optical response, including without limitation, the (sub-)range of the EM spectrum over which absorption may be concentrated (absorption spectrum), refractive index, and/or extinction coefficient, of such localized SP (LSP) excitations, and/or coherent oscillations, may be tailored by varying properties of such NPs, including without limitation, at least one of: a characteristic size, size distribution, shape, surface coverage, configuration, deposition density, dispersity, and/or property, including without limitation, material, and/or degree of aggregation, of the nanostructures, and/or a medium proximate thereto.

Such optical response, in respect of photon-absorbing coatings, may include absorption of photons incident thereon, thereby reducing reflection. In some non-limiting examples, the absorption may be concentrated in a range of the EM spectrum, including without limitation, the visible spectrum, and/or a sub-range thereof. In some non-limiting examples, employing a photon-absorbing layer as part of an opto-electronic device may reduce reliance on a polarizer therein.

It has been reported in Fusella et al., “Plasmonic enhancement of stability and brightness in organic light-emitting devices”, Nature 2020, 585, at 379-382 (“Fusella et al.”), that the stability of an OLED device may be enhanced by incorporating an NP-based outcoupling layer above the cathode layer to extract energy from the plasmon modes. The NP-based outcoupling layer was fabricated by spin-casting cubic Ag NPs on top of an organic layer on top of a cathode. However, since most commercial OLED devices are fabricated using vacuum-based processing, spin-casting from solution may not constitute an appropriate mechanism for forming such an NP-based outcoupling layer above the cathode.

It has been discovered that such an NP-based outcoupling layer above the cathode may be fabricated in vacuum (and thus, may be suitable for use in a commercial OLED fabrication process), by depositing a metal deposited material 631 in a discontinuous layer 130 onto a patterning coating 210, which in some non-limiting examples, may be, and/or be deposited on, the cathode. Such process may avoid the use of solvents or other wet chemicals that may cause damage to the OLED device, and/or may adversely impact device reliability.

In some non-limiting examples, the presence of such a discontinuous layer 130 of deposited material 631, including without limitation, at least one particle structure 121, may contribute to enhanced extraction of EM radiation, performance, stability, reliability, and/or lifetime of the device.

In some non-limiting examples, the existence, in a layered device 400, of at least one discontinuous layer 130, on, and/or proximate to the exposed layer surface 11 of a patterning coating 210, and/or, in some non-limiting examples, and/or proximate to the interface of such patterning 110 with at least one covering layer, may impart optical effects to EM signals, including without limitation, photons, emitted by the device, and/or transmitted therethrough.

Those having ordinary skill in the relevant art will appreciate that, while a simplified model of the optical effects is presented herein, other models, and/or explanations may be applicable.

In some non-limiting examples, the presence of such a discontinuous layer 130 of the deposited material 631, including without limitation, at least one particle structure 121, may reduce, and/or mitigate crystallization of thin film layers, and/or coatings disposed adjacent in the longitudinal aspect, including without limitation, the patterning coating 210, and/or at least one covering layer, thereby stabilizing the property of the thin film(s) disposed adjacent thereto, and, in some non-limiting examples, reducing scattering. In some non-limiting examples, such thin film may be, and/or comprise at least one layer of an outcoupling, and/or encapsulating coating 1350 of the device, including without limitation, a CPL.

In some non-limiting examples, the presence of such a discontinuous layer 130 of deposited material 631, including without limitation, at least one particle structure 121, may provide an enhanced absorption in at least a part of the UV spectrum. In some non-limiting examples, controlling the characteristics of such particle structures 121, including without limitation, at least one of: characteristic size, size distribution, shape, surface coverage, configuration, deposited density, dispersity, deposited material 631, and refractive index, of the particle structures 121, may facilitate controlling the degree of absorption, wavelength range and peak wavelength of the absorption spectrum, including in the UV spectrum. Enhanced absorption of EM radiation in at least a part of the UV spectrum may be advantageous, for example, for improving device performance, stability, reliability, and/or lifetime.

In some non-limiting examples, the optical effects may be described in terms of its impact on the transmission, and/or absorption wavelength spectrum, including a wavelength range, and/or peak intensity thereof.

Additionally, while the model presented may suggest certain effects imparted on the transmission, and/or absorption of photons passing through such discontinuous layer 130, in some non-limiting examples, such effects may reflect local effects that may not be reflected on a broad, observable basis.

### Opto-Electronic Device

FIG. 9 is a simplified block diagram from a cross-sectional aspect, of an example electro-luminescent device 900 according to the present disclosure. In some non-limiting examples, the device 900 is an OLED.

The device 900 may comprise a substrate 10, upon which a frontplane 910, comprising a plurality of layers, respectively, a first electrode 920, at least one semiconducting layer 930, and a second electrode 940, are disposed. In some non-limiting examples, the frontplane 910 may provide mechanisms for photon emission, and/or manipulation of emitted photons.

In some non-limiting examples, the deposited layer 430 and the underlying layer may together form at least a part of at least one of the first electrode 920 and the second electrode 940 of the device 900. In some non-limiting examples, the deposited layer 430 and the underlying layer thereunder may together form at least a part of a cathode of the device 900.

In some non-limiting examples, the device 900 may be electrically coupled with a power source 905. When so coupled, the device 900 may emit photons as described herein.

Substrate

In some examples, the substrate 10 may comprise a base substrate 912. In some examples, the base substrate 912 may be formed of material suitable for use thereof, including without limitation, an inorganic material, including without limitation, Si, glass, metal (including without limitation, a metal foil), sapphire, and/or other inorganic material, and/or an organic material, including without limitation, a polymer, including without limitation, a polyimide, and/or an Si-based polymer. In some examples, the base substrate 912 may be rigid or flexible. In some examples, the substrate 10 may be defined by at least one planar surface. In some non-limiting examples, the substrate 10 may have at least one surface that supports the remaining frontplane 910 components of the device 900, including without limitation, the first electrode 920, the at least one semiconducting layer 930, and/or the second electrode 940.

In some non-limiting examples, such surface may be an organic surface, and/or an inorganic surface.

In some examples, the substrate 10 may comprise, in addition to the base substrate 912, at least one additional organic, and/or inorganic layer (not shown nor specifically described herein) supported on an exposed layer surface 11 of the base substrate 912.

In some non-limiting examples, such additional layers may comprise, and/or form at least one organic layer, which may comprise, replace, and/or supplement at least one of the at least one semiconducting layers 930.

In some non-limiting examples, such additional layers may comprise at least one inorganic layer, which may comprise, and/or form at least one electrode, which in some non-limiting examples, may comprise, replace, and/or supplement the first electrode 920, and/or the second electrode 940.

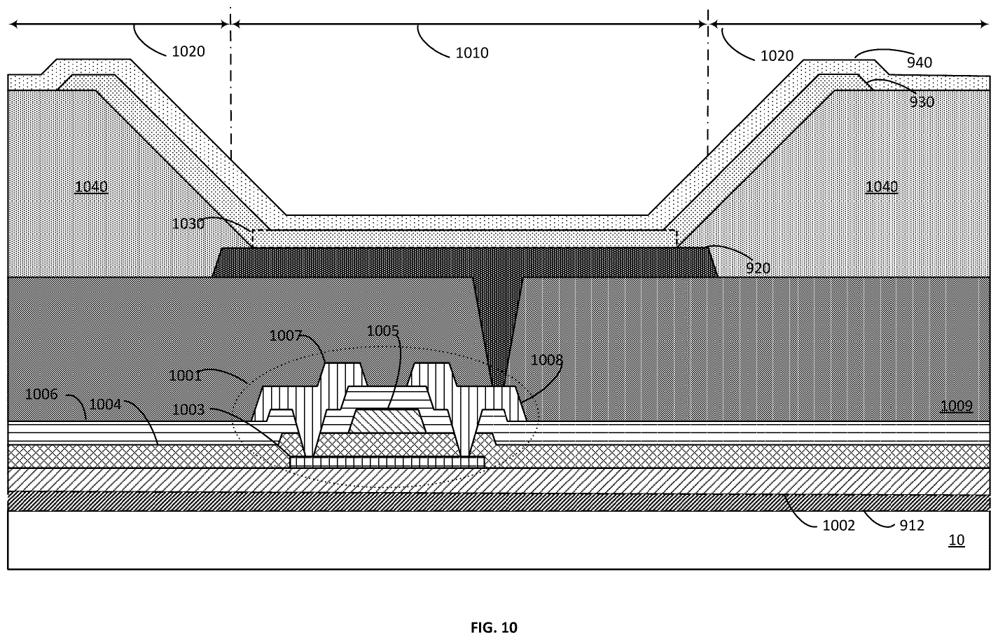

In some non-limiting examples, such additional layers may comprise, and/or be formed of, and/or as a backplane 915. In some non-limiting examples, the backplane 915 may contain power circuitry, and/or switching elements for driving the device 900, including without limitation, electronic TFT structure(s) 1001 (FIG. 10), and/or component(s) thereof, that may be formed by a photolithography process, which may not be provided under, and/or may precede the introduction of a low pressure (including without limitation, a vacuum) environment.

Backplane and TFT Structure(s) Embodied Therein

In some non-limiting examples, the backplane 915 of the substrate 10 may comprise at least one electronic, and/or opto-electronic component, including without limitation, transistors, resistors, and/or capacitors, such as which may support the device 900 acting as an active-matrix, and/or a passive matrix device. In some non-limiting examples, such structures may be a thin-film transistor (TFT) structure 1001.

Non-limiting examples of TFT structures 1001 include top-gate, bottom-gate, n-type and/or p-type TFT structures 1001. In some non-limiting examples, the TFT structure 1001 may incorporate any at least one of amorphous Si (a-Si), indium gallium zinc oxide (IGZO), and/or low-temperature polycrystalline Si (LTPS).

First Electrode

The first electrode 920 may be deposited over the substrate 10. In some non-limiting examples, the first electrode 920 may be electrically coupled with a terminal of the power source 905, and/or to ground. In some non-limiting examples, the first electrode 920 may be so coupled through at least one driving circuit which in some non-limiting examples, may incorporate at least one TFT structure 1001 in the backplane 915 of the substrate 10.

In some non-limiting examples, the first electrode 920 may comprise an anode, and/or a cathode. In some non-limiting examples, the first electrode 920 may be an anode.

In some non-limiting examples, the first electrode 920 may be formed by depositing at least one thin conductive film, over (a part of) the substrate 10. In some non-limiting examples, there may be a plurality of first electrodes 920, disposed in a spatial arrangement over a lateral aspect of the substrate 10. In some non-limiting examples, at least one of such at least one first electrode 920 may be deposited over (a part of) a TFT insulating layer 1009 (FIG. 10) disposed in a lateral aspect in a spatial arrangement. If so, in some non-limiting examples, at least one of such at least one first electrode 920 may extend through an opening of the corresponding TFT insulating layer 1009 to be electrically coupled with an electrode of the TFT structures 1001 in the backplane 915.

In some non-limiting examples, the at least one first electrode 920, and/or at least one thin film thereof, may comprise various materials, including without limitation, at least one metallic material, including without limitation, Mg, Al, calcium (Ca), Zn, Ag, Cd, Ba, or Yb, or combinations of any plurality thereof, including without limitation, alloys containing any of such materials, at least one metal oxide, including without limitation, a transparent conducting oxide (TCO), including without limitation, ternary compositions such as, without limitation, fluorine tin oxide (FTO), indium zinc oxide (IZO), or indium tin oxide (ITO), or combinations of any plurality thereof, or in varying proportions, or combinations of any plurality thereof in at least one layer, any at least one of which may be, without limitation, a thin film.

Second Electrode

The second electrode 940 may be deposited over the at least one semiconducting layer 930. In some non-limiting examples, the second electrode 940 may be electrically coupled with a terminal of the power source 905, and/or with ground. In some non-limiting examples, the second electrode 940 may be so coupled through at least one driving circuit, which in some non-limiting examples, may incorporate at least one TFT structure 1001 in the backplane 915 of the substrate 10.

In some non-limiting examples, the second electrode 940 may comprise an anode, and/or a cathode. In some non-limiting examples, the second electrode 940 may be a cathode.

In some non-limiting examples, the second electrode 940 may be formed by depositing a deposited layer 430, in some non-limiting examples, as at least one thin film, over (a part of) the at least one semiconducting layer 930. In some non-limiting examples, there may be a plurality of second electrodes 940, disposed in a spatial arrangement over a lateral aspect of the at least one semiconducting layer 930.

In some non-limiting examples, the at least one second electrode 940 may comprise various materials, including without limitation, at least one metallic materials, including without limitation, Mg, Al, Ca, Zn, Ag, Cd, Ba, or Yb, or combinations of any plurality thereof, including without limitation, alloys containing any of such materials, at least one metal oxides, including without limitation, a TCO, including without limitation, ternary compositions such as, without limitation, FTO, IZO, or ITO, or combinations of any plurality thereof, or in varying proportions, or zinc oxide (ZnO), or other oxides containing indium (In), or Zn, or combinations of any plurality thereof in at least one layer, and/or at least one non-metallic materials, any at least one of which may be, without limitation, a thin conductive film. In some non-limiting examples, for a Mg:Ag alloy, such alloy composition may range between about 1:9-9:1 by volume.

In some non-limiting examples, the deposition of the second electrode 940 may be performed using an open mask and/or a mask-free deposition process.

In some non-limiting examples, the second electrode 940 may comprise a plurality of such layers, and/or coatings. In some non-limiting examples, such layers, and/or coatings may be distinct layers, and/or coatings disposed on top of one another.

In some non-limiting examples, the second electrode 940 may comprise a Yb/Ag bi-layer coating. By way of non-limiting example, such bi-layer coating may be formed by depositing a Yb coating, followed by an Ag coating. In some non-limiting examples, a thickness of such Ag coating may exceed a thickness of the Yb coating.

In some non-limiting examples, the second electrode 940 may be a multi-layer electrode 940 comprising at least one metallic layer, and/or at least one oxide layer.

In some non-limiting examples, the second electrode 940 may comprise a fullerene and Mg.

By way of non-limiting example, such coating may be formed by depositing a fullerene coating followed by an Mg coating. In some non-limiting examples, a fullerene may be dispersed within the Mg coating to form a fullerene-containing Mg alloy coating. Non-limiting examples of such coatings are described in United States Patent Application Publication No. 2015/0287846 published 8 Oct. 2015, and/or in PCT International Application No. PCT/IB2017/054970 filed 15 Aug. 2017 and published as WO2018/033860 on 22 Feb. 2018.

Semiconducting Layer

In some non-limiting examples, the at least one semiconducting layer 930 may comprise a plurality of layers 931, 933, 935, 937, 939, any of which may be disposed, in some non-limiting examples, in a thin film, in a stacked configuration, which may include, without limitation, at least one of a hole injection layer (HIL) 931, a hole transport layer (HTL) 933, an emissive layer (EML) 935, an electron transport layer (ETL) 937, and/or an electron injection layer (EIL) 939.

In some non-limiting examples, the at least one semiconducting layer 930 may form a “tandem” structure comprising a plurality of EMLs 935. In some non-limiting examples, such tandem structure may also comprise at least one charge generation layer (CGL).

Those having ordinary skill in the relevant art will readily appreciate that the structure of the device 900 may be varied by omitting, and/or combining at least one of the semiconductor layers 931, 933, 935, 937, 939.

Further, any of the layers 931, 933, 935, 937, 939 of the at least one semiconducting layer 930 may comprise any number of sub-layers. Still further, any of such layers 931, 933, 935, 937, 939, and/or sub-layer(s) thereof may comprise various mixture(s), and/or composition gradient(s). In addition, those having ordinary skill in the relevant art will appreciate that the device 900 may comprise at least one layer comprising inorganic, and/or organometallic materials and may not be necessarily limited to devices comprised solely of organic materials. By way of non-limiting example, the device 900 may comprise at least one QD.

In some non-limiting examples, the HIL 931 may be formed using a hole injection material, which may facilitate injection of holes by the anode.

In some non-limiting examples, the HTL 933 may be formed using a hole transport material, which may, in some non-limiting examples, exhibit high hole mobility.

In some non-limiting examples, the ETL 937 may be formed using an electron transport material, which may, in some non-limiting examples, exhibit high electron mobility.

In some non-limiting examples, the EIL 939 may be formed using an electron injection material, which may facilitate injection of electrons by the cathode.

In some non-limiting examples, the EML 935 may be formed, by way of non-limiting example, by doping a host material with at least one emitter material. In some non-limiting examples, the emitter material may be a fluorescent emitter, a phosphorescent emitter, a thermally activated delayed fluorescence (TADF) emitter, and/or a plurality of any combination of these.

In some non-limiting examples, the device 900 may be an OLED in which the at least one semiconducting layer 930 comprises at least an EML 935 interposed between conductive thin film electrodes 920, 940, whereby, when a potential difference is applied across them, holes may be injected into the at least one semiconducting layer 930 through the anode and electrons may be injected into the at least one semiconducting layer 930 through the cathode, migrate toward the EML 935 and combine to emit EM radiation in the form of photons.

In some non-limiting examples, the device 900 may be an electro-luminescent QD device in which the at least one semiconducting layer 930 may comprise an active layer comprising at least one QD. When current may be provided by the power source 905 to the first electrode 920 and second electrode 940, photons may be emitted from the active layer comprising the at least one semiconducting layer 930 between them.

Those having ordinary skill in the relevant art will readily appreciate that the structure of the device 900 may be varied by the introduction of at least one additional layer (not shown) at appropriate position(s) within the at least one semiconducting layer 930 stack, including without limitation, a hole blocking layer (HBL) (not shown), an electron blocking layer (EBL) (not shown), an additional charge transport layer (CTL) (not shown), and/or an additional charge injection layer (CIL) (not shown).

In some non-limiting examples, including where the OLED device 900 comprises a lighting panel, an entire lateral aspect of the device 900 may correspond to a single emissive element. As such, the substantially planar cross-sectional profile shown in FIG. 9 may extend substantially along the entire lateral aspect of the device 900, such that EM radiation is emitted from the device 900 substantially along the entirety of the lateral extent thereof. In some non-limiting examples, such single emissive element may be driven by a single driving circuit of the device 900.

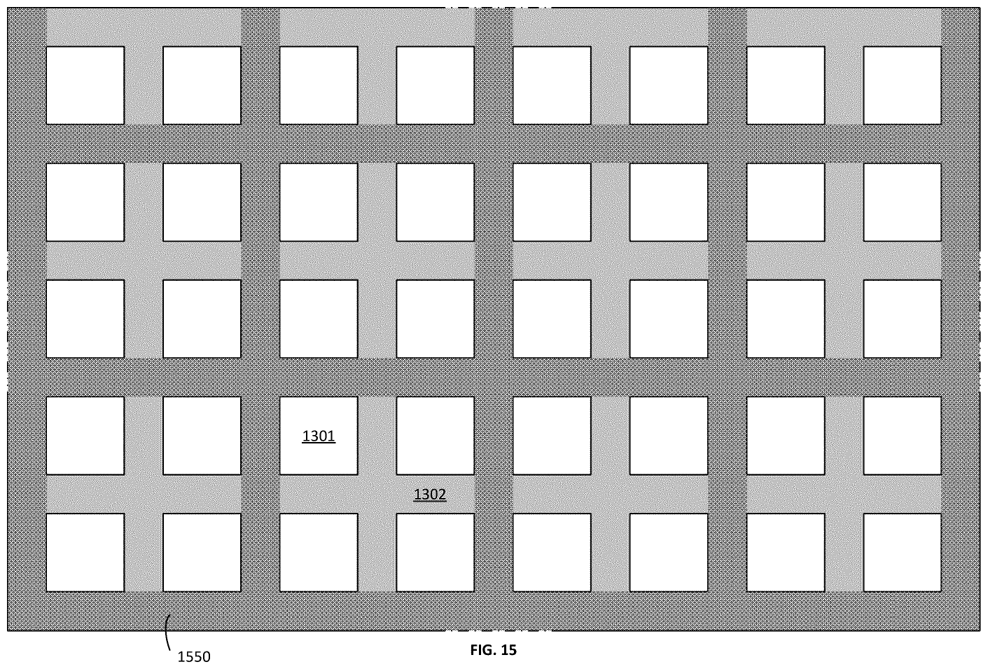

In some non-limiting examples, including where the OLED device 900 comprises a display module, the lateral aspect of the device 900 may be sub-divided into a plurality of emissive regions 1301 of the device 900, in which the cross-sectional aspect of the device structure 900, within each of the emissive region(s) 1301 shown, without limitation, in FIG. 15 may cause EM radiation to be emitted therefrom when energized.

### Emissive Regions

In some non-limiting examples, such as may be shown by way of non-limiting example in FIG. 10, an active region 1030 of an emissive region 1301 may be defined to be bounded, in the transverse aspect, by the first electrode 920 and the second electrode 940, and to be confined, in the lateral aspect, to an emissive region 1301 defined by the first electrode 920 and the second electrode 940. Those having ordinary skill in the relevant art will appreciate that the lateral extent of the emissive region 1301, and thus the lateral boundaries of the active region 1030, may not correspond to the entire lateral aspect of either, or both, of the first electrode 920 and the second electrode 940. Rather, the lateral extent of the emissive region 1301 may be substantially no more than the lateral extent of either of the first electrode 920 and the second electrode 940. By way of non-limiting example, parts of the first electrode 920 may be covered by the pixel definition layer(s) (PDL) 1040 (FIG. 10) and/or parts of the second electrode 940 may not be disposed on the at least one semiconducting layer 930, with the result, in either, or both, scenarios, that the emissive region 1301 may be laterally constrained.

In some non-limiting examples, individual emissive regions 1301 of the device 900 may be laid out in a lateral pattern. In some non-limiting examples, the pattern may extend along a first lateral direction. In some non-limiting examples, the pattern may also extend along a second lateral direction, which in some non-limiting examples, may be substantially normal to the first lateral direction. In some non-limiting examples, the pattern may have a number of elements in such pattern, each element being characterized by at least one feature thereof, including without limitation, a wavelength of EM radiation emitted by the emissive region 1301 thereof, a shape of such emissive region 1301, a dimension (along either, or both of, the first, and/or second lateral direction(s)), an orientation (relative to either, and/or both of the first, and/or second lateral direction(s)), and/or a spacing (relative to either, or both of, the first, and/or second lateral direction(s)) from a previous element in the pattern. In some non-limiting examples, the pattern may repeat in either, or both of, the first and/or second lateral direction(s).

In some non-limiting examples, each individual emissive region 1301 of the device 900 may be associated with, and driven by, a corresponding driving circuit within the backplane 915 of the device 900, for driving an OLED structure for the associated emissive region 1301. In some non-limiting examples, including without limitation, where the emissive regions 1301 may be laid out in a regular pattern extending in both the first (row) lateral direction and the second (column) lateral direction, there may be a signal line in the backplane 915, corresponding to each row of emissive regions 1301 extending in the first lateral direction and a signal line, corresponding to each column of emissive regions 1301 extending in the second lateral direction. In such a non-limiting configuration, a signal on a row selection line may energize the respective gates of the switching TFT(s) 1001 electrically coupled therewith and a signal on a data line may energize the respective sources of the switching TFT(s) 1001 electrically coupled therewith, such that a signal on a row selection line/data line pair may electrically couple and energise, by the positive terminal of the power source 905, the anode of the OLED structure of the emissive region 1301 associated with such pair, causing the emission of a photon therefrom, the cathode thereof being electrically coupled with the negative terminal of the power source 905.

In some non-limiting examples, each emissive region 1301 of the device 900 may correspond to a single display pixel 2110 (FIG. 21A). In some non-limiting examples, each pixel 2110 may emit light at a given wavelength spectrum. In some non-limiting examples, the wavelength spectrum may correspond to a colour in, without limitation, the visible spectrum.

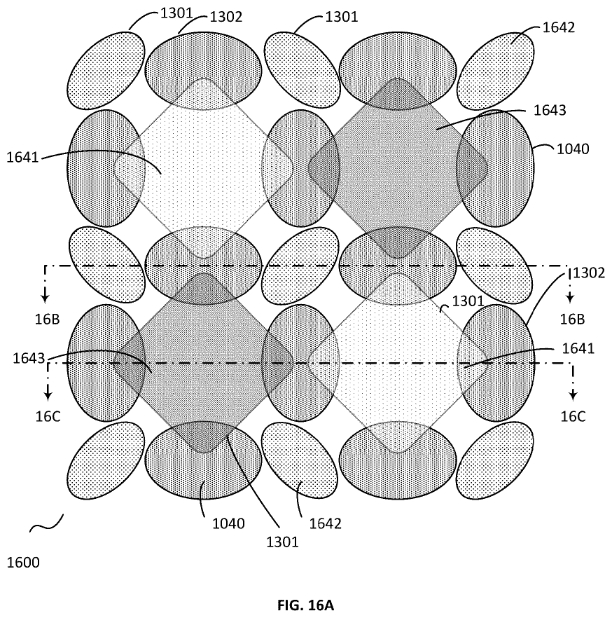

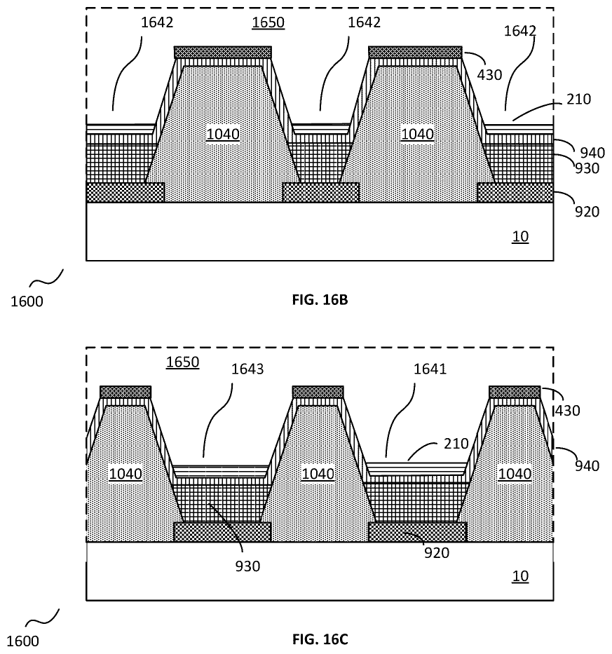

In some non-limiting examples, each emissive region 1301 of the device 900 may correspond to a sub-pixel 164x (FIG. 16A) of a display pixel 2110. In some non-limiting examples, a plurality of sub-pixels 164x may combine to form, or to represent, a single display pixel 2110.

In some non-limiting examples, a single display pixel 2110 may be represented by three sub-pixels 164x. In some non-limiting examples, the three sub-pixels 164x may be denoted as, respectively, R(ed) sub-pixels 1641, G(reen) sub-pixels 1642, and/or B(lue) sub-pixels 1643. In some non-limiting examples, a single display pixel 2110 may be represented by four sub-pixels 164x, in which three of such sub-pixels 164x may be denoted as R(ed), G(reen) and B(lue) sub-pixels 164x and the fourth sub-pixel 164x may be denoted as a W(hite) sub-pixel 164x. In some non-limiting examples, the emission spectrum of the EM radiation emitted by a given sub-pixel 164x may correspond to the colour by which the sub-pixel 164x is denoted. In some non-limiting examples, the wavelength of the EM radiation may not correspond to such colour, but further processing may be performed, in a manner apparent to those having ordinary skill in the relevant art, to transform the wavelength to one that does so correspond.

Since the wavelength of sub-pixels 164x of different colours may be different, the optical characteristics of such sub-pixels 164x may differ, especially if a common electrode 920, 940 having a substantially uniform thickness profile may be employed for sub-pixels 164x of different colours.

When a common electrode 920, 940 having a substantially uniform thickness may be provided as the second electrode 940 in a device 900, the optical performance of the device 900 may not be readily be fine-tuned according to an emission spectrum associated with each (sub-)pixel 2110/164x. The second electrode 940 used in such OLED devices 600 may in some non-limiting examples, be a common electrode 920, 940 coating a plurality of (sub-)pixels 2110/164x. By way of non-limiting example, such common electrode 920, 940 may be a relatively thin conductive film having a substantially uniform thickness across the device 900. While efforts have been made in some non-limiting examples, to tune the optical microcavity effects associated with each (sub-)pixel 2110/164x color by varying a thickness of organic layers disposed within different (sub-) pixel(s) 2110/164x, such approach may, in some non-limiting examples, provide a significant degree of tuning of the optical microcavity effects in at least some cases. In addition, in some non-limiting examples, such approach may be difficult to implement in an OLED display production environment.

As a result, the presence of optical interfaces created by numerous thin-film layers and coatings with different refractive indices, such as may in some non-limiting examples be used to construct opto-electronic devices including without limitation OLED devices 900, may create different optical microcavity effects for sub-pixels 164x of different colours.

Some factors that may impact an observed microcavity effect in a device 900 include, without limitation, a total path length (which in some non-limiting examples may correspond to a total thickness (in the longitudinal aspect) of the device 900 through which EM radiation emitted therefrom will travel before being outcoupled) and the refractive indices of various layers and coatings.

In some non-limiting examples, modulating a thickness of an electrode 920, 940 in and across a lateral aspect of emissive region(s) 1301 of a (sub-) pixel 2110/164x may impact the microcavity effect observable. In some non-limiting examples, such impact may be attributable to a change in the total optical path length.

In some non-limiting examples, a change in a thickness of the electrode 920, 940 may also change the refractive index of EM radiation passing therethrough, in some non-limiting examples, in addition to a change in the total optical path length. In some non-limiting examples, this may be particularly the case where the electrode 920, 940 may be formed of at least one deposited layer 430.

In some non-limiting examples, the optical properties of the device 900, and/or in some non-limiting examples, across the lateral aspect of emissive region(s) 1301 of a (sub-) pixel 2110/164x that may be varied by modulating at least one optical microcavity effect, may include, without limitation, the emission spectrum, the intensity (including without limitation, luminous intensity), and/or angular distribution of emitted EM radiation, including without limitation, an angular dependence of a brightness, and/or color shift of the emitted EM radiation.

In some non-limiting examples, a sub-pixel 164x may be associated with a first set of other sub-pixels 164x to represent a first display pixel 2110 and also with a second set of other sub-pixels 164x to represent a second display pixel 2110, so that the first and second display pixels 2110 may have associated therewith, the same sub-pixel(s) 164x.

The pattern, and/or organization of sub-pixels 164x into display pixels 2110 continues to develop. All present and future patterns, and/or organizations are considered to fall within the scope of the present disclosure.

### Non-Emissive Regions

In some non-limiting examples, the various emissive regions 1301 of the device 900 may be substantially surrounded and separated by, in at least one lateral direction, at least one non-emissive region 1302, in which the structure, and/or configuration along the cross-sectional aspect, of the device structure 900 shown, without limitation, in FIG. 9, may be varied, to substantially inhibit EM radiation to be emitted therefrom. In some non-limiting examples, the non-emissive regions 1302 may comprise those regions in the lateral aspect, that are substantially devoid of an emissive region 1301.

Thus, as shown in the cross-sectional view of FIG. 10, the lateral topology of the various layers of the at least one semiconducting layer 930 may be varied to define at least one emissive region 1301, surrounded (at least in one lateral direction) by at least one non-emissive region 1302.

In some non-limiting examples, the emissive region 1301 corresponding to a single display (sub-) pixel 2110/164x may be understood to have a lateral aspect 1010, surrounded in at least one lateral direction by at least one non-emissive region 1302 having a lateral aspect 1020.

A non-limiting example of an implementation of the cross-sectional aspect of the device 900 as applied to an emissive region 1301 corresponding to a single display (sub-) pixel 2110/164x of an OLED display 900 will now be described. While features of such implementation are shown to be specific to the emissive region 1301, those having ordinary skill in the relevant art will appreciate that in some non-limiting examples, more than one emissive region 1301 may encompass common features.

In some non-limiting examples, the first electrode 920 may be disposed over an exposed layer surface 11 of the device 900, in some non-limiting examples, within at least a part of the lateral aspect 1010 of the emissive region 1301. In some non-limiting examples, at least within the lateral aspect 1010 of the emissive region 1301 of the (sub-) pixel(s) 2110/164x, the exposed layer surface 11, may, at the time of deposition of the first electrode 920, comprise the TFT insulating layer 1009 of the various TFT structures 1001 that make up the driving circuit for the emissive region 1301 corresponding to a single display (sub-) pixel 2110/164x.

In some non-limiting examples, the TFT insulating layer 1009 may be formed with an opening extending therethrough to permit the first electrode 920 to be electrically coupled with one of the TFT electrodes 1005, 1007, 1008, including, without limitation, as shown in FIG. 10, the TFT drain electrode 1008.

Those having ordinary skill in the relevant art will appreciate that the driving circuit comprises a plurality of TFT structures 1001. In FIG. 10, for purposes of simplicity of illustration, only one TFT structure 1001 may be shown, but it will be appreciated by those having ordinary skill in the relevant art, that such TFT structure 1001 may be representative of such plurality thereof that comprise the driving circuit.

In a cross-sectional aspect, the configuration of each emissive region 1301 may, in some non-limiting examples, be defined by the introduction of at least one PDL 1040 substantially throughout the lateral aspects 1020 of the surrounding non-emissive region(s) 1302. In some non-limiting examples, the PDLs 1040 may comprise an insulating organic, and/or inorganic material.

In some non-limiting examples, the PDLs 1040 may be deposited substantially over the TFT insulating layer 1009, although, as shown, in some non-limiting examples, the PDLs 1040 may also extend over at least a part of the deposited first electrode 920, and/or its outer edges.

In some non-limiting examples, as shown in FIG. 10, the cross-sectional thickness, and/or profile of the PDLs 1040 may impart a substantially valley-shaped configuration to the emissive region 1301 of each (sub-) pixel 2110/164x by a region of increased thickness along a boundary of the lateral aspect 1020 of the surrounding non-emissive region 1302 with the lateral aspect of the surrounded emissive region 1301, corresponding to a (sub-) pixel 2110/164x.

In some non-limiting examples, the profile of the PDLs 1040 may have a reduced thickness beyond such valley-shaped configuration, including without limitation, away from the boundary between the lateral aspect 1020 of the surrounding non-emissive region 1302 and the lateral aspect 1010 of the surrounded emissive region 1301, in some non-limiting examples, substantially well within the lateral aspect 1020 of such non-emissive region 1302.

While the PDL(s) 1040 have been generally illustrated as having a linearly sloped surface to form a valley-shaped configuration that define the emissive region(s) 1301 surrounded thereby, those having ordinary skill in the relevant art will appreciate that in some non-limiting examples, at least one of the shape, aspect ratio, thickness, width, and/or configuration of such PDL(s) 1040 may be varied. By way of non-limiting example, a PDL 1040 may be formed with a more steep or more gradually sloped part. In some non-limiting examples, such PDL(s) 1040 may be configured to extend substantially normally away from a surface on which it is deposited, that may cover at least one edges of the first electrode 920. In some non-limiting examples, such PDL(s) 1040 may be configured to have deposited thereon at least one semiconducting layer 930 by a solution-processing technology, including without limitation, by printing, including without limitation, ink-jet printing.

In some non-limiting examples, the at least one semiconducting layer 930 may be deposited over the exposed layer surface 11 of the device 900, including at least a part of the lateral aspect 1010 of such emissive region 1301 of the (sub-) pixel(s) 2110/164x. In some non-limiting examples, at least within the lateral aspect 1010 of the emissive region 1301 of the (sub-) pixel(s) 2110/164x, such exposed layer surface 11, may, at the time of deposition of the at least one semiconducting layer 930 (and/or layers 931, 933, 935, 937, 939 thereof), comprise the first electrode 920.

In some non-limiting examples, the at least one semiconducting layer 930 may also extend beyond the lateral aspect 1010 of the emissive region 1301 of the (sub-) pixel(s) 2110/164x and at least partially within the lateral aspects 1020 of the surrounding non-emissive region(s) 1302. In some non-limiting examples, such exposed layer surface 11 of such surrounding non-emissive region(s) 1302 may, at the time of deposition of the at least one semiconducting layer 930, comprise the PDL(s) 1040.

In some non-limiting examples, the second electrode 940 may be disposed over an exposed layer surface 11 of the device 900, including at least a part of the lateral aspect 1010 of the emissive region 1301 of the (sub-) pixel(s) 2110/164x. In some non-limiting examples, at least within the lateral aspect of the emissive region 1301 of the (sub-) pixel(s) 2110/164x, such exposed layer surface 11, may, at the time of deposition of the second electrode 920, comprise the at least one semiconducting layer 930.

In some non-limiting examples, the second electrode 940 may also extend beyond the lateral aspect 1010 of the emissive region 1301 of the (sub-) pixel(s) 2110/164x and at least partially within the lateral aspects 1020 of the surrounding non-emissive region(s) 1302. In some non-limiting examples, such exposed layer surface 11 of such surrounding non-emissive region(s) 1302 may, at the time of deposition of the second electrode 940, comprise the PDL(s) 1040.

In some non-limiting examples, the second electrode 940 may extend throughout substantially all or a substantial part of the lateral aspects 1020 of the surrounding non-emissive region(s) 1302.

### Selective Deposition of Patterned Electrode

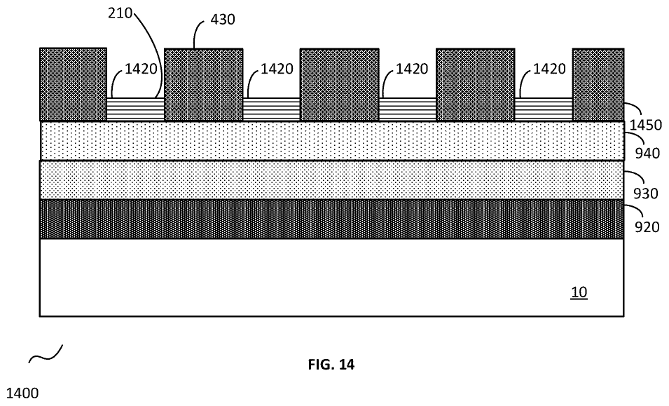

In some non-limiting examples, the ability to achieve selective deposition of the deposited material 631 in an open mask and/or a mask-free deposition process by the prior selective deposition of a patterning coating 210, may be employed to achieve the selective deposition of a patterned electrode 920, 940, 1450 (FIG. 14), and/or at least one layer thereof, of an opto-electronic device, including without limitation, an OLED device 900, and/or a conductive element electrically coupled therewith.

In this fashion, the selective deposition of a patterning coating 210 in FIG. 5 using a shadow mask 515, and the open mask and/or a mask-free deposition of the deposited material 631, may be combined to effect the selective deposition of at least one deposited layer 430 to form a device feature, including without limitation, a patterned electrode 920, 940, 1450, and/or at least one layer thereof, and/or a conductive element electrically coupled therewith, in the device 400 shown in FIG. 4, without employing a shadow mask 515 within the deposition process for forming the deposited layer 430. In some non-limiting examples, such patterning may permit, and/or enhance the transmissivity of the device 400.

A number of non-limiting examples of such patterned electrodes 920, 940, 1450, and/or at least one layer thereof, and/or a conductive element electrically coupled therewith, to impart various structural and/or performance capabilities to such devices 900 will now be described.

As a result of the foregoing, there may be an aim to selectively deposit, across the lateral aspect 1010 of the emissive region 1301 of a (sub-) pixel 2110/164x, and/or the lateral aspect 1020 of the non-emissive region(s) 1302 surrounding the emissive region 1301, a device feature, including without limitation, at least one of the first electrode 920, the second electrode 940, the auxiliary electrode 1450, and/or a conductive element electrically coupled therewith, in a pattern, on an exposed layer surface 11 of a frontplane 910 of the device 900. In some non-limiting examples, the first electrode 920, the second electrode 940, and/or the auxiliary electrode 1450, may be deposited in at least one of a plurality of deposited layers 430.

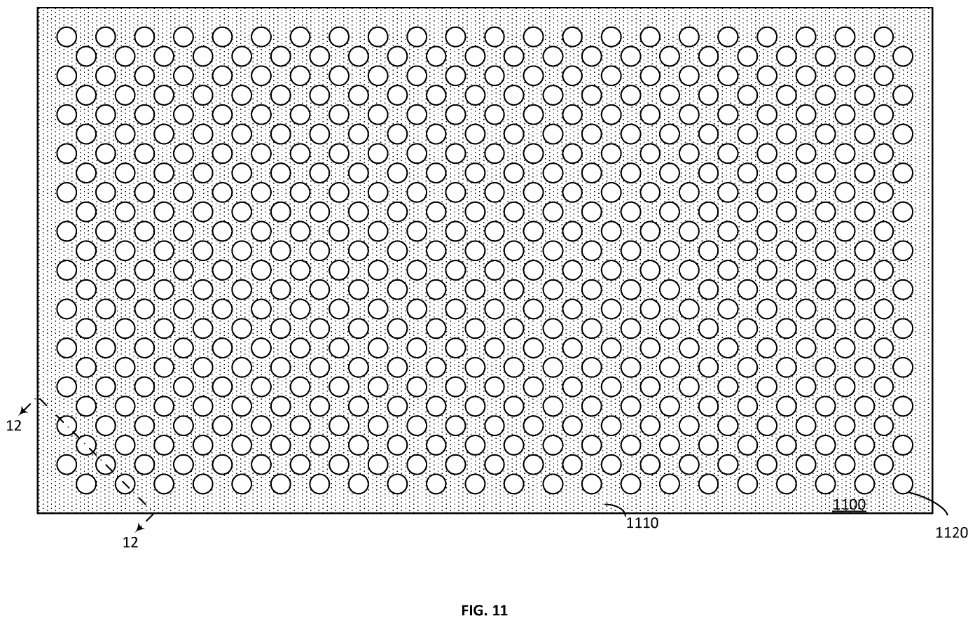

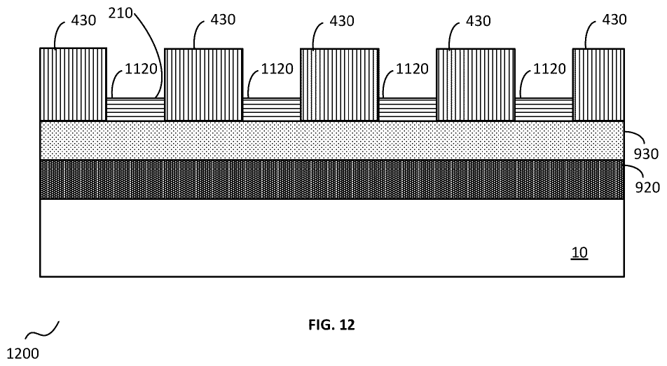

FIG. 11 may show an example patterned electrode 1100 in plan, in the figure, the second electrode 940 suitable for use in an example version 1200 (FIG. 12) of the device 900. The electrode 1100 may be formed in a pattern 1110 that comprises a single continuous structure, having or defining a patterned plurality of apertures 1120 therewithin, in which the apertures 1120 may correspond to regions of the device 1200 where there is no cathode.

In the figure, by way of non-limiting example, the pattern 1110 may be disposed across the entire lateral extent of the device 1200, without differentiation between the lateral aspect(s) 1010 of emissive region(s) 1301 corresponding to (sub-) pixel(s) 2110/164x and the lateral aspect(s) 1020 of non-emissive region(s) 1302 surrounding such emissive region(s) 1301. Thus, the example illustrated may correspond to a device 1200 that may be substantially transmissive relative to EM radiation incident on an external surface thereof, such that a substantial part of such externally-incident EM radiation may be transmitted through the device 1200, in addition to the emission (in a top-emission, bottom-emission, and/or double-sided emission) of EM radiation generated internally within the device 1200 as disclosed herein.

The transmittivity of the device 1200 may be adjusted, and/or modified by altering the pattern 1110 employed, including without limitation, an average size of the apertures 1120, and/or a spacing, and/or density of the apertures 1120.

Turning now to FIG. 12, there may be shown a cross-sectional view of the device 1200, taken along line 12-12 in FIG. 11. In the figure, the device 1200 may be shown as comprising the substrate 10, the first electrode 920 and the at least one semiconducting layer 930.

A patterning coating 210 may be selectively disposed in a pattern substantially corresponding to the pattern 1110 on the exposed layer surface 11 of the underlying layer.

A deposited layer 430 suitable for forming the patterned electrode 1100, which in the figure is the second electrode 940, may be disposed on substantially all of the exposed layer surface 11 of the underlying layer, using an open mask and/or a mask-free deposition process. The underlying layer may comprise both regions of the patterning coating 210, disposed in the pattern 1110, and regions of the at least one semiconducting layer 930, in the pattern 1110 where the patterning coating 210 has not been deposited. In some non-limiting examples, the regions of the patterning coating 210 may correspond substantially to a first portion 301 comprising the apertures 1120 shown in the pattern 1110.

Because of the nucleation-inhibiting properties of those regions of the pattern 1110 where the patterning coating 210 was disposed (corresponding to the apertures 1120), the deposited material 631 disposed on such regions may tend to not remain, resulting in a pattern of selective deposition of the deposited layer 430, that may correspond substantially to the remainder of the pattern 1110, leaving those regions of the first portion 301 of the pattern 1110 corresponding to the apertures 1120 substantially devoid of a closed coating 440 of the deposited layer 430.

In other words, the deposited layer 430 that will form the cathode may be selectively deposited substantially only on a second portion 302 comprising those regions of the at least one semiconducting layer 930 that surround but do not occupy the apertures 1120 in the pattern 1110.

FIG. 13A may show, in plan view, a schematic diagram showing a plurality of patterns 1310, 1320 of electrodes 920, 940, 1450.

In some non-limiting examples, the first pattern 1310 may comprise a plurality of elongated, spaced-apart regions that extend in a first lateral direction. In some non-limiting examples, the first pattern 1310 may comprise a plurality of first electrodes 920. In some non-limiting examples, a plurality of the regions that comprise the first pattern 1310 may be electrically coupled.

In some non-limiting examples, the second pattern 1320 may comprise a plurality of elongated, spaced-apart regions that extend in a second lateral direction. In some non-limiting examples, the second lateral direction may be substantially normal to the first lateral direction. In some non-limiting examples, the second pattern 1320 may comprise a plurality of second electrodes 940. In some non-limiting examples, a plurality of the regions that comprise the second pattern 1320 may be electrically coupled.

In some non-limiting examples, the first pattern 1310 and the second pattern 1320 may form part of an example version, shown generally at 1300, of the device 900.

In some non-limiting examples, the lateral aspect(s) 1010 of emissive region(s) 1301 corresponding to (sub-) pixel(s) 2110/164x may be formed where the first pattern 1310 overlaps the second pattern 1320. In some non-limiting examples, the lateral aspect(s) 1020 of non-emissive region(s) 1302 may correspond to any lateral aspect other than the lateral aspect(s) 1010.

In some non-limiting examples, a first terminal, which, in some non-limiting examples, may be a positive terminal, of the power source 905, may be electrically coupled with at least one electrode 920, 940, 1450 of the first pattern 1310. In some non-limiting examples, the first terminal may be coupled with the at least one electrode 920, 940, 1450 of the first pattern 1310 through at least one driving circuit. In some non-limiting examples, a second terminal, which, in some non-limiting examples, may be a negative terminal, of the power source 905, may be electrically coupled with at least one electrode 920, 940, 1450 of the second pattern 1320. In some non-limiting examples, the second terminal may be coupled with the at least one electrode 920, 940, 1450 of the second pattern 1320 through the at least one driving circuit.

Turning now to FIG. 13B, there may be shown a cross-sectional view of the device 1300, at a deposition stage 1300b, taken along line 13B-13B in FIG. 13A. In the figure, the device 1300 at the stage 1300b may be shown as comprising the substrate 10.

A patterning coating 210 may be selectively disposed in a pattern substantially corresponding to the inverse of the first pattern 1310 on the exposed layer surface 11 of the underlying layer, which, as shown in the figure, may be the substrate 10.

A deposited layer 430 suitable for forming the first pattern 1310 of electrodes 920, 940, 1450, which in the figure is the first electrode 920, may be disposed on substantially all of the exposed layer surface 11 of the underlying layer, using an open mask and/or a mask-free deposition process. The underlying layer may comprise both regions of the patterning coating 210, disposed in the inverse of the first pattern 1310, and regions of the substrate 10, disposed in the first pattern 1310 where the patterning coating 210 has not been deposited. In some non-limiting examples, the regions of the substrate 10 may correspond substantially to the elongated spaced-apart regions of the first pattern 1310, while the regions of the patterning coating 210 may correspond substantially to a first portion 301 comprising the gaps therebetween.

Because of the nucleation-inhibiting properties of those regions of the first pattern 1310 where the patterning coating 210 was disposed (corresponding to the gaps therebetween), the deposited layer 430 disposed on such regions may tend to not remain, resulting in a pattern of selective deposition of the deposited layer 430, that may correspond substantially to elongated spaced-apart regions of the first pattern 1310, leaving a first portion 301 comprising the gaps therebetween substantially devoid of a closed coating 440 of the deposited layer 430.

In other words, the deposited layer 430 that may form the first pattern 1310 of electrodes 920, 940, 1450 may be selectively deposited substantially only on a second portion 302 comprising those regions of the substrate 10 that define the elongated spaced-apart regions of the first pattern 1310.

Turning now to FIG. 13C, there may be shown a cross-sectional view 1300c of the device 1300, taken along line 13C-13C in FIG. 13A. In the figure, the device 1300 may be shown as comprising the substrate 10; the first pattern 1310 of electrodes 920 deposited as shown in FIG. 13B, and the at least one semiconducting layer(s) 930.

In some non-limiting examples, the at least one semiconducting layer(s) 930 may be provided as a common layer across substantially all of the lateral aspect(s) of the device 1300.

A patterning coating 210 may be selectively disposed in a pattern substantially corresponding to the second pattern 1320 on the exposed layer surface 11 of the underlying layer, which, as shown in the figure, is the at least one semiconducting layer 930.

A deposited layer 430 suitable for forming the second pattern 1320 of electrodes 920, 940, 1450, which in the figure is the second electrode 940, may be disposed on substantially all of the exposed layer surface 11 of the underlying layer, using an open mask and/or a mask-free deposition process. The underlying layer may comprise both regions of the patterning coating 210, disposed in the inverse of the second pattern 1320, and regions of the at least one semiconducting layer(s) 930, in the second pattern 1320 where the patterning coating 210 has not been deposited. In some non-limiting examples, the regions of the at least one semiconducting layer(s) 930 may correspond substantially to a first portion 301 comprising the elongated spaced-apart regions of the second pattern 1320, while the regions of the patterning coating 210 may correspond substantially to the gaps therebetween.

Because of the nucleation-inhibiting properties of those regions of the second pattern 1320 where the patterning coating 210 was disposed (corresponding to the gaps therebetween), the deposited layer 430 disposed on such regions may tend not to remain, resulting in a pattern of selective deposition of the deposited layer 430, that may correspond substantially to elongated spaced-apart regions of the second pattern 1320, leaving the first portion 301 comprising the gaps therebetween substantially devoid of a closed coating 440 of the deposited layer 430.

In other words, the deposited layer 430 that may form the second pattern 1320 of electrodes 920, 940, 1450 may be selectively deposited substantially only on a second portion 302 comprising those regions of the at least one semiconducting layer 930 that define the elongated spaced-apart regions of the second pattern 1320.

In some non-limiting examples, an average layer thickness of the patterning coating 210 and of the deposited layer 430 deposited thereafter for forming either, or both, of the first pattern 1310, and/or the second pattern 1320 of electrodes 920, 940, 1450 may be varied according to a variety of parameters, including without limitation, a given application and given performance characteristics. In some non-limiting examples, the average layer thickness of the patterning coating 210 may be comparable to, and/or substantially less than an average layer thickness of the deposited layer 430 deposited thereafter. Use of a relatively thin patterning coating 210 to achieve selective patterning of a deposited layer 430 deposited thereafter may be suitable to provide flexible devices 900. In some non-limiting examples, a relatively thin patterning coating 210 may provide a relatively planar surface on which a barrier coating 1350 may be deposited. In some non-limiting examples, providing such a relatively planar surface for application of the barrier coating 1350 may increase adhesion of the barrier coating 1350 to such surface.

At least one of the first pattern 1310 of electrodes 920, 940, 1450 and at least one of the second pattern 1320 of electrodes 920, 940, 1450 may be electrically coupled with the power source 905, whether directly, and/or, in some non-limiting examples, through their respective driving circuit(s) to control EM radiation emission from the lateral aspect(s) 1010 of the emissive region(s) 1301 corresponding to (sub-) pixel(s) 2110/164x.

### Auxiliary Electrode

Those having ordinary skill in the relevant art will appreciate that the process of forming the second electrode 940 in the second pattern 1320 shown in FIGS. 13A-13C may, in some non-limiting examples, be used in similar fashion to form an auxiliary electrode 1450 for the device 1300. In some non-limiting examples, the second electrode 940 thereof may comprise a common electrode, and the auxiliary electrode 1450 may be deposited in the second pattern 1320, in some non-limiting examples, above or in some non-limiting examples below, the second electrode 940 and electrically coupled therewith. In some non-limiting examples, the second pattern 1320 for such auxiliary electrode 1450 may be such that the elongated spaced-apart regions of the second pattern 1320 lie substantially within the lateral aspect(s) 1020 of non-emissive region(s) 1302 surrounding the lateral aspect(s) 1010 of emissive region(s) 1301 corresponding to (sub-) pixel(s) 2110/164x. In some non-limiting examples, the second pattern 1320 for such auxiliary electrodes 1450 may be such that the elongated spaced-apart regions of the second pattern 1320 lie substantially within the lateral aspect(s) 1010 of emissive region(s) 1301 corresponding to (sub-) pixel(s) 2110/164x, and/or the lateral aspect(s) 1020 of non-emissive region(s) 1302 surrounding them.

FIG. 14 may show an example cross-sectional view of an example version 1400 of the device 900 that is substantially similar thereto, but further may comprise at least one auxiliary electrode 1450 disposed in a pattern above and electrically coupled (not shown) with the second electrode 940.

The auxiliary electrode 1450 may be electrically conductive. In some non-limiting examples, the auxiliary electrode 1450 may be formed by at least one metal, and/or metal oxide. Non-limiting examples of such metals include Cu, Al, molybdenum (Mo), or Ag. By way of non-limiting example, the auxiliary electrode 1450 may comprise a multi-layer metallic structure, including without limitation, one formed by Mo/AI/Mo. Non-limiting examples of such metal oxides include ITO, ZnO, IZO, or other oxides containing In, or Zn. In some non-limiting examples, the auxiliary electrode 1450 may comprise a multi-layer structure formed by a combination of at least one metal and at least one metal oxide, including without limitation, Ag/ITO, Mo/ITO, ITO/Ag/ITO, or ITO/Mo/ITO. In some non-limiting examples, the auxiliary electrode 1450 comprises a plurality of such electrically conductive materials.

The device 1400 may be shown as comprising the substrate 10, the first electrode 920 and the at least one semiconducting layer 930.

The second electrode 940 may be disposed on substantially all of the exposed layer surface 11 of the at least one semiconducting layer 930.

In some non-limiting examples, particularly in a top-emission device 1400, the second electrode 940 may be formed by depositing a relatively thin conductive film layer (not shown) in order, by way of non-limiting example, to reduce optical interference (including, without limitation, attenuation, reflections, and/or diffusion) related to the presence of the second electrode 940. In some non-limiting examples, as discussed elsewhere, a reduced thickness of the second electrode 940, may generally increase a sheet resistance of the second electrode 940, which may, in some non-limiting examples, reduce the performance, and/or efficiency of the device 1400. By providing the auxiliary electrode 1450 that may be electrically coupled with the second electrode 940, the sheet resistance and thus, the IR drop associated with the second electrode 940, may, in some non-limiting examples, be decreased.

In some non-limiting examples, the device 1400 may be a bottom-emission, and/or double-sided emission device 1400. In such examples, the second electrode 940 may be formed as a relatively thick conductive layer without substantially affecting optical characteristics of such a device 1400. Nevertheless, even in such scenarios, the second electrode 940 may nevertheless be formed as a relatively thin conductive film layer (not shown), by way of non-limiting example, so that the device 1400 may be substantially transmissive relative to EM radiation incident on an external surface thereof, such that a substantial part of such externally-incident EM radiation may be transmitted through the device 1400, in addition to the emission of EM radiation generated internally within the device 1400 as disclosed herein.

A patterning coating 210 may be selectively disposed in a pattern on the exposed layer surface 11 of the underlying layer, which, as shown in the figure, may be the at least one semiconducting layer 930. In some non-limiting examples, as shown in the figure, the patterning coating 210 may be disposed, in a first portion 301 of the pattern, as a series of parallel rows 1420.

A deposited layer 430 suitable for forming the patterned auxiliary electrode 1450, may be disposed on substantially all of the exposed layer surface 11 of the underlying layer, using an open mask and/or a mask-free deposition process. The underlying layer may comprise both regions of the patterning coating 210, disposed in the pattern of rows 1420, and regions of the at least one semiconducting layer 930 where the patterning coating 210 has not been deposited.

Because of the nucleation-inhibiting properties of those rows 1420 where the patterning coating 210 was disposed, the deposited layer 430 disposed on such rows 1420 may tend to not remain, resulting in a pattern of selective deposition of the deposited layer 430, that may correspond substantially to at least one second portion 302 of the pattern, leaving the first portion 301 comprising the rows 1420 substantially devoid of a closed coating 440 of the deposited layer 430.

In other words, the deposited layer 430 that may form the auxiliary electrode 1450 may be selectively deposited substantially only on a second portion 302 comprising those regions of the at least one semiconducting layer 930, that surround but do not occupy the rows 1420.

In some non-limiting examples, selectively depositing the auxiliary electrode 1450 to cover only certain rows 1420 of the lateral aspect of the device 1400, while other regions thereof remain uncovered, may control, and/or reduce optical interference related to the presence of the auxiliary electrode 1450.

In some non-limiting examples, the auxiliary electrode 1450 may be selectively deposited in a pattern that may not be readily detected by the naked eye from a typical viewing distance.

In some non-limiting examples, the auxiliary electrode 1450 may be formed in devices other than OLED devices, including for decreasing an effective resistance of the electrodes of such devices.

The ability to pattern electrodes 920, 940, 1450, including without limitation, the second electrode 940, and/or the auxiliary electrode 1450 without employing a shadow mask 515 during the high-temperature deposited layer 430 deposition process by employing a patterning coating 210, including without limitation, the process depicted in FIG. 6, may allow numerous configurations of auxiliary electrodes 1450 to be deployed.

In some non-limiting examples, the auxiliary electrode 1450 may be disposed between neighbouring emissive regions 1301 and electrically coupled with the second electrode 940. In non-limiting examples, a width of the auxiliary electrode 1450 may be less than a separation distance between the neighbouring emissive regions 1301. As a result, there may exist a gap within the at least one non-emissive region 1302 on each side of the auxiliary electrode 1450. In some non-limiting examples, such an arrangement may reduce a likelihood that the auxiliary electrode 1450 would interfere with an optical output of the device 1400, in some non-limiting examples, from at least one of the emissive regions 1301. In some non-limiting examples, such an arrangement may be appropriate where the auxiliary electrode 1450 is relatively thick (in some non-limiting examples, greater than several hundred nm, and/or on the order of a few microns in thickness). In some non-limiting examples, an aspect ratio of the auxiliary electrode 1450 may exceed about 0.05, such as at least one of at least about: 0.1, 0.2, 0.5, 0.8, 1, or 2. By way of non-limiting example, a height (thickness) of the auxiliary electrode 1450 may exceed about 50 nm, such as at least one of at least about: 80 nm, 100 nm, 200 nm, 500 nm, 700 nm, 1,000 nm, 1,500 nm, 1,700 nm, or 2,000 nm.

FIG. 15 may show, in plan view, a schematic diagram showing an example of a pattern 1550 of the auxiliary electrode 1450 formed as a grid that may be overlaid over both the lateral aspects 1010 of emissive regions 1301, which may correspond to (sub-) pixel(s) 2110/164x of an example version 1500 of device 900, and the lateral aspects 1020 of non-emissive regions 1302 surrounding the emissive regions 1301.

In some non-limiting examples, the auxiliary electrode pattern 1550 may extend substantially only over some but not all of the lateral aspects 1020 of non-emissive regions 1302, to not substantially cover any of the lateral aspects 1010 of the emissive regions 1301.

Those having ordinary skill in the relevant art will appreciate that while, in the figure, the pattern 1550 of the auxiliary electrode 1450 may be shown as being formed as a continuous structure such that all elements thereof are both physically connected to and electrically coupled with one another and electrically coupled with at least one electrode 920, 940, 1450, which in some non-limiting examples may be the first electrode 920, and/or the second electrode 940, in some non-limiting examples, the pattern 1550 of the auxiliary electrode 1450 may be provided as a plurality of discrete elements of the pattern 1550 of the auxiliary electrode 1450 that, while remaining electrically coupled with one another, may not be physically connected to one another. Even so, such discrete elements of the pattern 1550 of the auxiliary electrode 1450 may still substantially lower a sheet resistance of the at least one electrode 920, 940, 1450 with which they are electrically coupled, and consequently of the device 1500, to increase an efficiency of the device 1500 without substantially interfering with its optical characteristics.

In some non-limiting examples, auxiliary electrodes 1450 may be employed in devices 1500 with a variety of arrangements of (sub-) pixel(s) 2110/164x. In some non-limiting examples, the (sub-) pixel 2110/164x arrangement may be substantially diamond-shaped.

By way of non-limiting example, FIG. 16A may show, in plan view, in an example version 1600 of device 900, a plurality of groups 1641-1643 of emissive regions 1301 each corresponding to a sub-pixel 164x, surrounded by the lateral aspects of a plurality of non-emissive regions 1302 comprising PDLs 1040 in a diamond configuration. In some non-limiting examples, the configuration may be defined by patterns 1641-1643 of emissive regions 1301 and PDLs 1040 in an alternating pattern of first and second rows.

In some non-limiting examples, the lateral aspects 1020 of the non-emissive regions 1302 comprising PDLs 1040 may be substantially elliptically shaped. In some non-limiting examples, the major axes of the lateral aspects 1020 of the non-emissive regions 1302 in the first row may be aligned and substantially normal to the major axes of the lateral aspects 1020 of the non-emissive regions 1302 in the second row. In some non-limiting examples, the major axes of the lateral aspects 1020 of the non-emissive regions 1302 in the first row may be substantially parallel to an axis of the first row.

In some non-limiting examples, a first group 1641 of emissive regions 1301 may correspond to sub-pixels 164x that emit EM radiation at a first wavelength, in some non-limiting examples the sub-pixels 164x of the first group 1641 may correspond to R(ed) sub-pixels 1641. In some non-limiting examples, the lateral aspects 1010 of the emissive regions 1301 of the first group 1641 may have a substantially diamond-shaped configuration. In some non-limiting examples, the emissive regions 1301 of the first group 1641 may lie in the pattern of the first row, preceded and followed by PDLs 1040. In some non-limiting examples, the lateral aspects 1010 of the emissive regions 1301 of the first group 1641 may slightly overlap the lateral aspects 1020 of the preceding and following non-emissive regions 1302 comprising PDLs 1040 in the same row, as well as of the lateral aspects 1020 of adjacent non-emissive regions 1302 comprising PDLs 1040 in a preceding and following pattern of the second row.

In some non-limiting examples, a second group 1642 of emissive regions 1301 may correspond to sub-pixels 164x that emit EM radiation at a second wavelength, in some non-limiting examples the sub-pixels 164x of the second group 1642 may correspond to G(reen) sub-pixels 1642. In some non-limiting examples, the lateral aspects 1010 of the emissive regions 1301 of the second group 1641 may have a substantially elliptical configuration. In some non-limiting examples, the emissive regions 1301 of the second group 1641 may lie in the pattern of the second row, preceded and followed by PDLs 1040. In some non-limiting examples, a major axis of some of the lateral aspects 1010 of the emissive regions 1301 of the second group 1641 may be at a first angle, which in some non-limiting examples, may be 45° relative to an axis of the second row. In some non-limiting examples, a major axis of others of the lateral aspects 1010 of the emissive regions 1301 of the second group 1641 may be at a second angle, which in some non-limiting examples may be substantially normal to the first angle. In some non-limiting examples, the emissive regions 1301 of the second group 1642, whose lateral aspects 1010 may have a major axis at the first angle, may alternate with the emissive regions 1301 of the second group 1642, whose lateral aspects 1010 may have a major axis at the second angle.

In some non-limiting examples, a third group 1643 of emissive regions 1301 may correspond to sub-pixels 164x that emit EM radiation at a third wavelength, in some non-limiting examples the sub-pixels 164x of the third group 1643 may correspond to B(lue) sub-pixels 1643. In some non-limiting examples, the lateral aspects 1010 of the emissive regions 1301 of the third group 1643 may have a substantially diamond-shaped configuration. In some non-limiting examples, the emissive regions 1301 of the third group 1643 may lie in the pattern of the first row, preceded and followed by PDLs 1040. In some non-limiting examples, the lateral aspects 1010 of the emissive regions 1301 of the third group 1643 may slightly overlap the lateral aspects 1020 of the preceding and following non-emissive regions 1302 comprising PDLs 1040 in the same row, as well as of the lateral aspects 1020 of adjacent non-emissive regions 1302 comprising PDLs 1040 in a preceding and following pattern of the second row. In some non-limiting examples, the pattern of the second row may comprise emissive regions 1301 of the first group 1641 alternating emissive regions 1301 of the third group 1643, each preceded and followed by PDLs 1040.

Turning now to FIG. 16B, there may be shown an example cross-sectional view of the device 1600, taken along line 16B-16B in FIG. 16A. In the figure, the device 1600 may be shown as comprising a substrate 10 and a plurality of elements of a first electrode 920, formed on an exposed layer surface 11 thereof. The substrate 10 may comprise the base substrate 912 (not shown for purposes of simplicity of illustration), and/or at least one TFT structure 1001 (not shown for purposes of simplicity of illustration), corresponding to and for driving each sub-pixel 164x. PDLs 1040 may be formed over the substrate 10 between elements of the first electrode 920, to define emissive region(s) 1301 over each element of the first electrode 920, separated by non-emissive region(s) 1302 comprising the PDL(s) 1040. In the figure, the emissive region(s) 1301 may all correspond to the second group 1642.

In some non-limiting examples, at least one semiconducting layer 930 may be deposited on each element of the first electrode 920, between the surrounding PDLs 1040.

In some non-limiting examples, a second electrode 940, which in some non-limiting examples, may be a common cathode, may be deposited over the emissive region(s) 1301 of the second group 1642 to form the G(reen) sub-pixel(s) 1642 thereof and over the surrounding PDLs 1040.

In some non-limiting examples, a patterning coating 210 may be selectively deposited over the second electrode 940 across the lateral aspects 1010 of the emissive region(s) 1301 of the second group 1642 of G(reen) sub-pixels 1642 to allow selective deposition of a deposited layer 430 over parts of the second electrode 940 that may be substantially devoid of the patterning coating 210, namely across the lateral aspects 1020 of the non-emissive region(s) 1302 comprising the PDLs 1040. In some non-limiting examples, the deposited layer 430 may tend to accumulate along the substantially planar parts of the PDLs 1040, as the deposited layer 430 may tend to not remain on the inclined parts of the PDLs 1040 but may tend to descend to a base of such inclined parts, which may be coated with the patterning coating 210. In some non-limiting examples, the deposited layer 430 on the substantially planar parts of the PDLs 1040 may form at least one auxiliary electrode 1450 that may be electrically coupled with the second electrode 940.

In some non-limiting examples, the device 1600 may comprise a CPL, and/or an outcoupling layer. By way of non-limiting example, such CPL, and/or outcoupling layer may be provided directly on a surface of the second electrode 940, and/or a surface of the patterning coating 210. In some non-limiting examples, such CPL, and/or outcoupling layer may be provided across the lateral aspect of at least one emissive region 1301 corresponding to a (sub-) pixel 2110/164x.

In some non-limiting examples, the patterning coating 210 may also act as an index-matching coating. In some non-limiting examples, the patterning coating 210 may also act as an outcoupling layer.

In some non-limiting examples, the device 1600 may comprise an encapsulation layer 1650. Non-limiting examples of such encapsulation layer 1650 include a glass cap, a barrier film, a barrier adhesive, a barrier coating 1350, and/or a TFE layer such as shown in dashed outline in the figure, provided to encapsulate the device 1600. In some non-limiting examples, the TFE layer 1650 may be considered a type of barrier coating 1350.

In some non-limiting examples, the encapsulation layer 1650 may be arranged above at least one of the second electrode 940, and/or the patterning coating 210. In some non-limiting examples, the device 1600 may comprise additional optical, and/or structural layers, coatings, and components, including without limitation, a polarizer, a color filter, an anti-reflection coating, an anti-glare coating, cover glass, and/or an optically clear adhesive (OCA).

Turning now to FIG. 16C, there may be shown an example cross-sectional view of the device 1600, taken along line 16C-16C in FIG. 16A. In the figure, the device 1600 may be shown as comprising a substrate 10 and a plurality of elements of a first electrode 920, formed on an exposed layer surface 11 thereof. PDLs 1040 may be formed over the substrate 10 between elements of the first electrode 920, to define emissive region(s) 1301 over each element of the first electrode 920, separated by non-emissive region(s) 1302 comprising the PDL(s) 1040. In the figure, the emissive region(s) 1301 may correspond to the first group 1641 and to the third group 1643 in alternating fashion.

In some non-limiting examples, at least one semiconducting layer 930 may be deposited on each element of the first electrode 920, between the surrounding PDLs 1040.

In some non-limiting examples, a second electrode 940, which in some non-limiting examples, may be a common cathode, may be deposited over the emissive region(s) 1301 of the first group 1641 to form the R(ed) sub-pixel(s) 1641 thereof, over the emissive region(s) 1301 of the third group 1643 to form the B(lue) sub-pixel(s) 1643 thereof, and over the surrounding PDLs 1040.

In some non-limiting examples, a patterning coating 210 may be selectively deposited over the second electrode 940 across the lateral aspects 1010 of the emissive region(s) 1301 of the first group 1641 of R(ed) sub-pixels 1641 and of the third group 1643 of B(lue) sub-pixels 1643 to allow selective deposition of a deposited layer 430 over parts of the second electrode 940 that may be substantially devoid of the patterning coating 210, namely across the lateral aspects 1020 of the non-emissive region(s) 1302 comprising the PDLs 1040. In some non-limiting examples, the deposited layer 430 may tend to accumulate along the substantially planar parts of the PDLs 1040, as the deposited layer 430 may tend to not remain on the inclined parts of the PDLs 1040 but may tend to descend to a base of such inclined parts, which are coated with the patterning coating 210. In some non-limiting examples, the deposited layer 430 on the substantially planar parts of the PDLs 1040 may form at least one auxiliary electrode 1450 that may be electrically coupled with the second electrode 940.

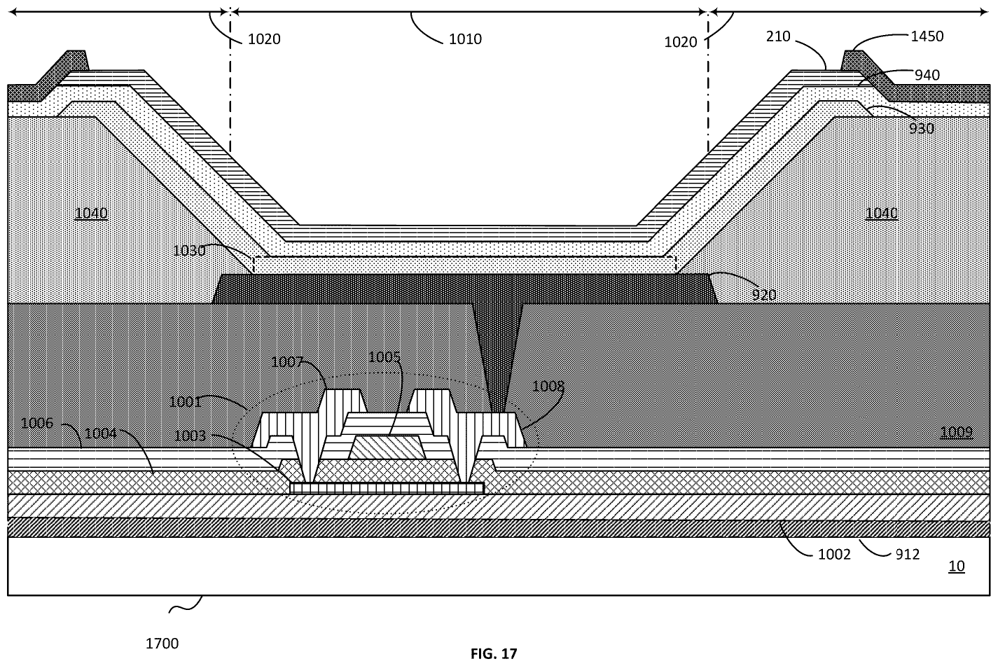

Turning now to FIG. 17, there may be shown an example version 1700 of the device 900, which may encompass the device shown in cross-sectional view in FIG. 10, but with additional deposition steps that are described herein.

The device 1700 may show a patterning coating 210 selectively deposited over the exposed layer surface 11 of the underlying layer, in the figure, the second electrode 940, within a first portion 301 of the device 1700, corresponding substantially to the lateral aspect 1010 of emissive region(s) 1301 corresponding to (sub-) pixel(s) 2110/164x and not within a second portion 302 of the device 1700, corresponding substantially to the lateral aspect(s) 1020 of non-emissive region(s) 1302 surrounding the first portion 301.

In some non-limiting examples, the patterning coating 210 may be selectively deposited using a shadow mask 515.

The patterning coating 210 may provide, within the first portion 301, an exposed layer surface 11 with a relatively low initial sticking probability against deposition of a deposited material 631 to be thereafter deposited as a deposited layer 430 to form an auxiliary electrode 1450.

After selective deposition of the patterning coating 210, the deposited material 631 may be deposited over the device 1700 but may remain substantially only within the second portion 302, which may be substantially devoid of any patterning coating 210, to form the auxiliary electrode 1450.

In some non-limiting examples, the deposited material 631 may be deposited using an open mask and/or a mask-free deposition process.

The auxiliary electrode 1450 may be electrically coupled with the second electrode 940 to reduce a sheet resistance of the second electrode 940, including, as shown, by lying above and in physical contact with the second electrode 940 across the second portion that may be substantially devoid of any patterning coating 210.

In some non-limiting examples, the deposited layer 430 may comprise substantially the same material as the second electrode 940, to ensure a high initial sticking probability against deposition of the deposited material 631 in the second portion 302.

In some non-limiting examples, the second electrode 940 may comprise substantially pure Mg, and/or an alloy of Mg and another metal, including without limitation, Ag. In some non-limiting examples, an Mg:Ag alloy composition may range from about 1:9-9:1 by volume. In some non-limiting examples, the second electrode 940 may comprise metal oxides, including without limitation, ternary metal oxides, such as, without limitation, ITO, and/or IZO, and/or a combination of metals, and/or metal oxides.

In some non-limiting examples, the deposited layer 430 used to form the auxiliary electrode 1450 may comprise substantially pure Mg.

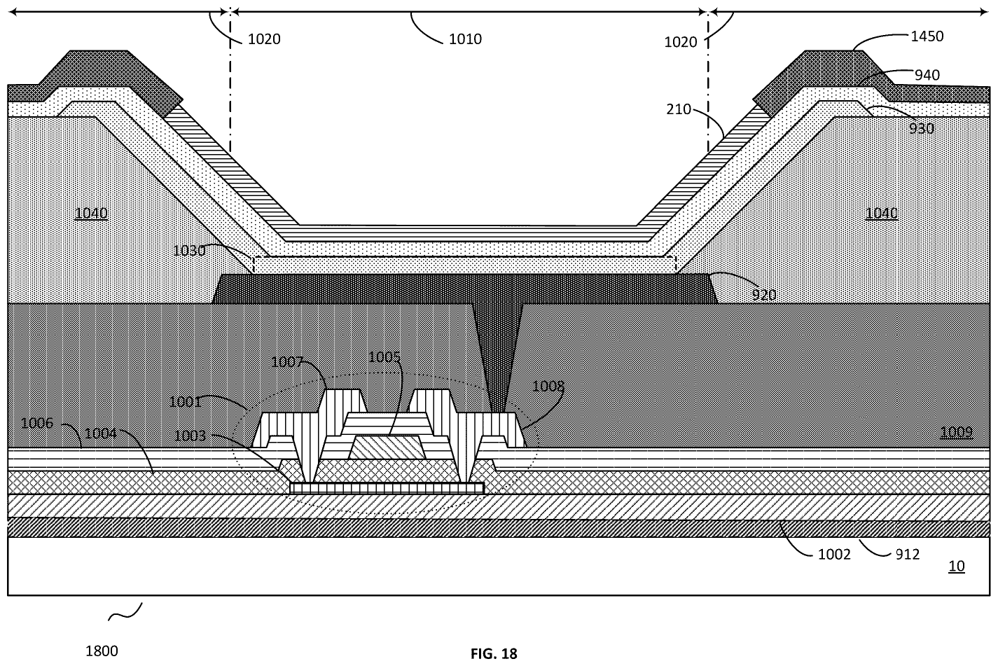

Turning now to FIG. 18, there may be shown an example version 1800 of the device 900, which may encompass the device shown in cross-sectional view in FIG. 10, but with additional deposition steps that are described herein.

The device 1800 may show a patterning coating 210 selectively deposited over the exposed layer surface 11 of the underlying layer, in the figure, the second electrode 940, within a first portion 301 of the device 1800, corresponding substantially to a part of the lateral aspect 1010 of emissive region(s) 1301 corresponding to (sub-) pixel(s) 2110/164x, and not within a second portion 302. In the figure, the first portion 301 may extend partially along the extent of an inclined part of the PDLs 1040 defining the emissive region(s) 1301.

In some non-limiting examples, the patterning coating 210 may be selectively deposited using a shadow mask 515.

The patterning coating 210 may provide, within the first portion 301, an exposed layer surface 11 with a relatively low initial sticking probability against deposition of a deposited material 631 to be thereafter deposited as a deposited layer 430 to form an auxiliary electrode 1450.

After selective deposition of the patterning coating 210, the deposited material 631 may be deposited over the device 1800 but may remain substantially only within the second portion 302, which may be substantially devoid of patterning coating 210, to form the auxiliary electrode 1450. As such, in the device 1800, the auxiliary electrode 1450 may extend partly across the inclined part of the PDLs 1040 defining the emissive region(s) 1301.

In some non-limiting examples, the deposited layer 430 may be deposited using an open mask and/or a mask-free deposition process.

The auxiliary electrode 1450 may be electrically coupled with the second electrode 940 to reduce a sheet resistance of the second electrode 940, including, as shown, by lying above and in physical contact with the second electrode 940 across the second portion 302 that may be substantially devoid of patterning coating 210.

In some non-limiting examples, the material of which the second electrode 940 may be comprised, may not have a high initial sticking probability against deposition of the deposited material 631.

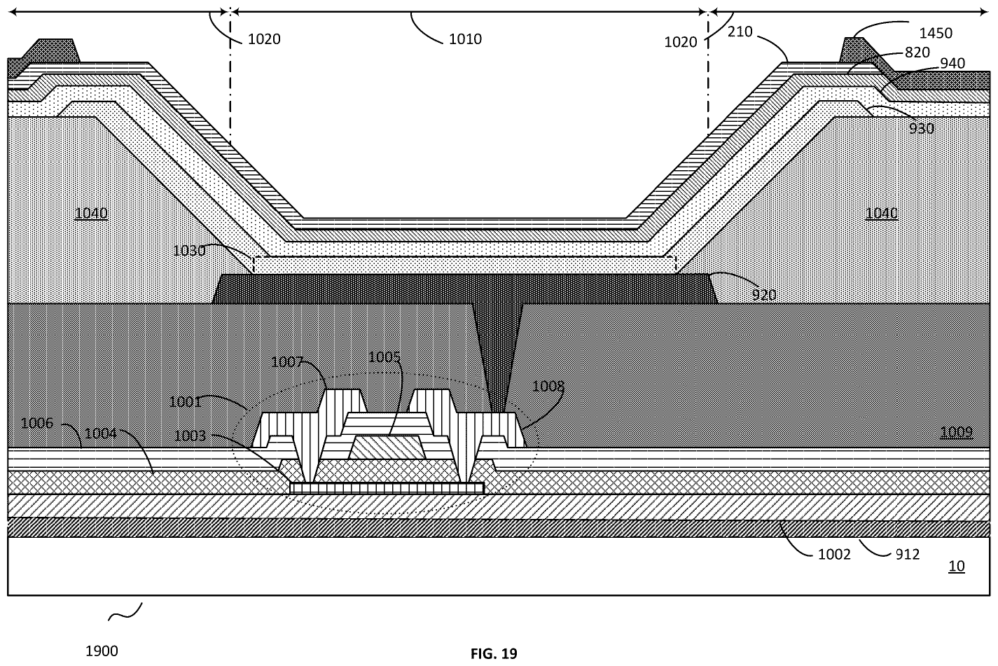

FIG. 19 may illustrate such a scenario, in which there may be shown an example version 1900 of the device 900, which may encompass the device shown in cross-sectional view in FIG. 10, but with additional deposition steps that are described herein.

The device 1900 may show an NPC 820 deposited over the exposed layer surface 11 of the underlying material, in the figure, the second electrode 940.

In some non-limiting examples, the NPC 820 may be deposited using an open mask and/or a mask-free deposition process.

Thereafter, a patterning coating 210 may be deposited selectively deposited over the exposed layer surface 11 of the underlying material, in the figure, the NPC 820, within a first portion 301 of the device 1900, corresponding substantially to a part of the lateral aspect 1010 of emissive region(s) 1301 corresponding to (sub-) pixel(s) 2110/164x, and not within a second portion 302 of the device 1900, corresponding substantially to the lateral aspect(s) 1020 of non-emissive region(s) 1302 surrounding the first portion 301.

In some non-limiting examples, the patterning coating 210 may be selectively deposited using a shadow mask 515.

The patterning coating 210 may provide, within the first portion 301, an exposed layer surface 11 with a relatively low initial sticking probability against deposition of a deposited material 631 to be thereafter deposited as a deposited layer 430 to form an auxiliary electrode 1450.

After selective deposition of the patterning coating 210, the deposited material 631 may be deposited over the device 1900 but may remain substantially only within the second portion 302, which may be substantially devoid of patterning coating 210, to form the auxiliary electrode 1450.

In some non-limiting examples, the deposited layer 430 may be deposited using an open mask and/or a mask-free deposition process.

The auxiliary electrode 1450 may be electrically coupled with the second electrode 940 to reduce a sheet resistance thereof. While, as shown, the auxiliary electrode 1450 may not be lying above and in physical contact with the second electrode 940, those having ordinary skill in the relevant art will nevertheless appreciate that the auxiliary electrode 1450 may be electrically coupled with the second electrode 940 by several well-understood mechanisms. By way of non-limiting example, the presence of a relatively thin film (in some non-limiting examples, of up to about 50 nm) of a patterning coating 210 may still allow a current to pass therethrough, thus allowing a sheet resistance of the second electrode 940 to be reduced.

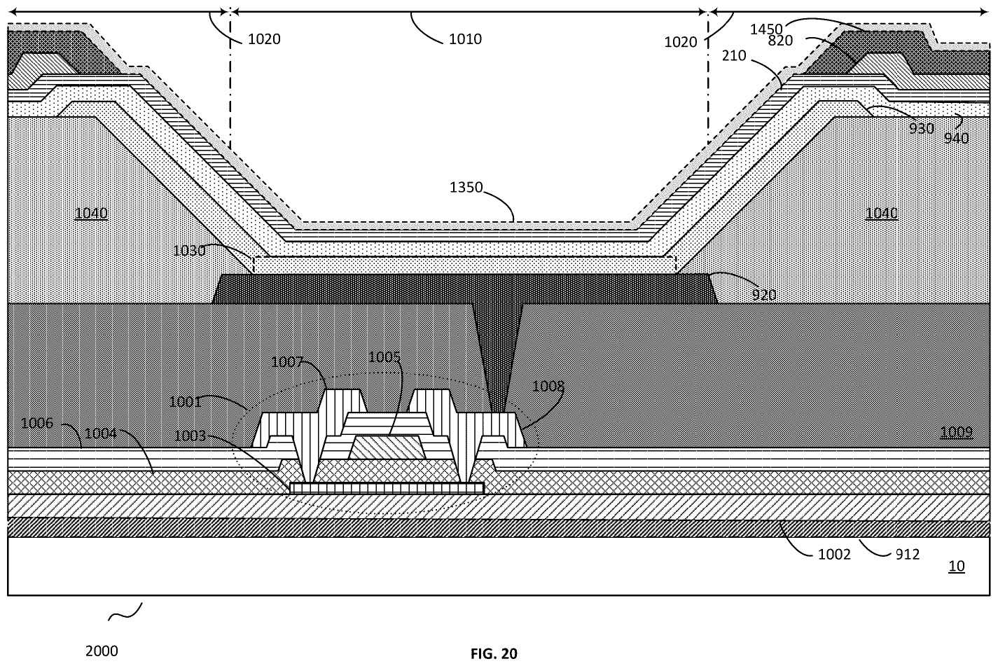

Turning now to FIG. 20, there may be shown an example version 2000 of the device 900, which may encompass the device shown in cross-sectional view in FIG. 10, but with additional deposition steps that are described herein.

The device 2000 may show a patterning coating 210 deposited over the exposed layer surface 11 of the underlying material, in the figure, the second electrode 940.

In some non-limiting examples, the patterning coating 210 may be deposited using an open mask and/or a mask-free deposition process.

The patterning coating 210 may provide an exposed layer surface 11 with a relatively low initial sticking probability against deposition of a deposited material 631 to be thereafter deposited as a deposited layer 430 to form an auxiliary electrode 1450.

After deposition of the patterning coating 210, an NPC 820 may be selectively deposited over the exposed layer surface 11 of the underlying layer, in the figure, the patterning coating 210, corresponding substantially to a part of the lateral aspect 1020 of non-emissive region(s) 1302, and surrounding a second portion 302 of the device 1700, corresponding substantially to the lateral aspect(s) 1010 of emissive region(s) 1301 corresponding to (sub-) pixel(s) 2110/164x.

In some non-limiting examples, the NPC 820 may be selectively deposited using a shadow mask 515.

The NPC 820 may provide, within the first portion 301, an exposed layer surface 11 with a relatively high initial sticking probability against deposition of a deposited material 631 to be thereafter deposited as a deposited layer 430 to form an auxiliary electrode 1450.

After selective deposition of the NPC 820, the deposited material 631 may be deposited over the device 2000 but may remain substantially where the patterning coating 210 has been overlaid with the NPC 820, to form the auxiliary electrode 1450.

In some non-limiting examples, the deposited layer 430 may be deposited using an open mask and/or a mask-free deposition process.

The auxiliary electrode 1450 may be electrically coupled with the second electrode 940 to reduce a sheet resistance of the second electrode 940. Transparent OLED

Because the OLED device 900 may emit EM radiation through either, or both, of the first electrode 920 (in the case of a bottom-emission, and/or a double-sided emission device), as well as the substrate 10, and/or the second electrode 940 (in the case of a top-emission, and/or double-sided emission device), there may be an aim to make either, or both of, the first electrode 920, and/or the second electrode 940 substantially photon- (or light)-transmissive (“transmissive”), in some non-limiting examples, at least across a substantial part of the lateral aspect of the emissive region(s) 1301 of the device 900. In the present disclosure, such a transmissive element, including without limitation, an electrode 920, 940, a material from which such element may be formed, and/or property thereof, may comprise an element, material, and/or property thereof that is substantially transmissive (“transparent”), and/or, in some non-limiting examples, partially transmissive (“semi-transparent”), in some non-limiting examples, in at least one wavelength range.

A variety of mechanisms may be adopted to impart transmissive properties to the device 900, at least across a substantial part of the lateral aspect of the emissive region(s) 1301 thereof.

In some non-limiting examples, including without limitation, where the device 900 is a bottom-emission device, and/or a double-sided emission device, the TFT structure(s) 1001 of the driving circuit associated with an emissive region 1301 of a (sub-) pixel 2110/164x, which may at least partially reduce the transmissivity of the surrounding substrate 10, may be located within the lateral aspect 1020 of the surrounding non-emissive region(s) 1302 to avoid impacting the transmissive properties of the substrate 10 within the lateral aspect 1010 of the emissive region 1301.

In some non-limiting examples, where the device 900 is a double-sided emission device, in respect of the lateral aspect 1010 of an emissive region 1301 of a (sub-) pixel 2110/164x, a first one of the electrode 920, 940 may be made substantially transmissive, including without limitation, by at least one of the mechanisms disclosed herein, in respect of the lateral aspect 1010 of neighbouring, and/or adjacent (sub-) pixel(s) 2110/164x, a second one of the electrodes 920, 940 may be made substantially transmissive, including without limitation, by at least one of the mechanisms disclosed herein. Thus, the lateral aspect 1010 of a first emissive region 1301 of a (sub-) pixel 2110/164x may be made substantially top-emitting while the lateral aspect 1010 of a second emissive region 1301 of a neighbouring (sub-) pixel 2110/164x may be made substantially bottom-emitting, such that a subset of the (sub-) pixel(s) 2110/164x may be substantially top-emitting and a subset of the (sub-) pixel(s) 2110/164x may be substantially bottom-emitting, in an alternating (sub-) pixel 2110/164x sequence, while only a single electrode 920, 940 of each (sub-) pixel 2110/164x may be made substantially transmissive.

In some non-limiting examples, a mechanism to make an electrode 920, 940, in the case of a bottom-emission device, and/or a double-sided emission device, the first electrode 920, and/or in the case of a top-emission device, and/or a double-sided emission device, the second electrode 940, transmissive, may be to form such electrode 920, 940 of a transmissive thin film.

In some non-limiting examples, an electrically conductive deposited layer 430, in a thin film, including without limitation, those formed by a depositing a thin conductive film layer of a metal, including without limitation, Ag, Al, and/or by depositing a thin layer of a metallic alloy, including without limitation, an Mg:Ag alloy, and/or a Yb:Ag alloy, may exhibit transmissive characteristics. In some non-limiting examples, the alloy may comprise a composition ranging from between about 1:9-9:1 by volume. In some non-limiting examples, the electrode 920, 940 may be formed of a plurality of thin conductive film layers of any combination of deposited layers 430, any at least one of which may be comprised of TCOs, thin metal films, thin metallic alloy films, and/or any combination of any of these.

In some non-limiting examples, especially in the case of such thin conductive films, a relatively thin layer thickness may be up to substantially a few tens of nm to contribute to enhanced transmissive qualities but also favorable optical properties (including without limitation, reduced microcavity effects) for use in an OLED device 900.

In some non-limiting examples, a reduction in the thickness of an electrode 920, 940 to promote transmissive qualities may be accompanied by an increase in the sheet resistance of the electrode 920, 940.

In some non-limiting examples, a device 900 having at least one electrode 920, 940 with a high sheet resistance may create a large current resistance (IR) drop when coupled with the power source 905, in operation. In some non-limiting examples, such an IR drop may be compensated for, to some extent, by increasing a level of the power source 905. However, in some non-limiting examples, increasing the level of the power source 905 to compensate for the IR drop due to high sheet resistance, for at least one (sub-) pixel 2110/164x may call for increasing the level of a voltage to be supplied to other components to maintain effective operation of the device 900.

In some non-limiting examples, to reduce power supply demands for a device 900 without significantly impacting an ability to make an electrode 920, 940 substantially transmissive (by employing at least one thin film layer of any combination of TCOs, thin metal films, and/or thin metallic alloy films), an auxiliary electrode 1450 may be formed on the device 900 to allow current to be carried more effectively to various emissive region(s) 1301 of the device 900, while at the same time, reducing the sheet resistance and its associated IR drop of the transmissive electrode 920, 940.

In some non-limiting examples, a sheet resistance specification, for a common electrode 920, 940 of a display device 900, may vary according to several parameters, including without limitation, a (panel) size of the device 900, and/or a tolerance for voltage variation across the device 900. In some non-limiting examples, the sheet resistance specification may increase (that is, a lower sheet resistance is specified) as the panel size increases. In some non-limiting examples, the sheet resistance specification may increase as the tolerance for voltage variation decreases.

In some non-limiting examples, a sheet resistance specification may be used to derive an example thickness of an auxiliary electrode 1450 to comply with such specification for various panel sizes.

By way of non-limiting example, for a top-emission device, the second electrode 940 may be made transmissive. On the other hand, in some non-limiting examples, such auxiliary electrode 1450 may not be substantially transmissive but may be electrically coupled with the second electrode 940, including without limitation, by deposition of a conductive deposited layer 430 therebetween, to reduce an effective sheet resistance of the second electrode 940.

In some non-limiting examples, such auxiliary electrode 1450 may be positioned, and/or shaped in either, or both of, a lateral aspect, and/or cross-sectional aspect to not interfere with the emission of photons from the lateral aspect of the emissive region 1301 of a (sub-) pixel 2110/164x.

In some non-limiting examples, a mechanism to make the first electrode 920, and/or the second electrode 940, may be to form such electrode 920, 940 in a pattern across at least a part of the lateral aspect of the emissive region(s) 1301 thereof, and/or in some non-limiting examples, across at least a part of the lateral aspect 1020 of the non-emissive region(s) 1302 surrounding them. In some non-limiting examples, such mechanism may be employed to form the auxiliary electrode 1450 in a position, and/or shape in either, or both of, a lateral aspect, and/or cross-sectional aspect to not interfere with the emission of photons from the lateral aspect 1010 of the emissive region 1301 of a (sub-) pixel 2110/164x, as discussed above.

In some non-limiting examples, the device 900 may be configured such that it may be substantially devoid of a conductive oxide material in an optical path of EM radiation emitted by the device 900. By way of non-limiting example, in the lateral aspect 1010 of at least one emissive region 1301 corresponding to a (sub-) pixel 2110/164x, at least one of the layers, and/or coatings deposited after the at least one semiconducting layer 930, including without limitation, the second electrode 940, the patterning coating 210, and/or any other layers, and/or coatings deposited thereon, may be substantially devoid of any conductive oxide material. In some non-limiting examples, being substantially devoid of any conductive oxide material may reduce absorption, and/or reflection of EM radiation emitted by the device 900. By way of non-limiting example, conductive oxide materials, including without limitation, ITO, and/or IZO, may absorb EM radiation in at least the B(lue) region of the visible spectrum, which may, in generally, reduce efficiency, and/or performance of the device 900.

In some non-limiting examples, a combination of these, and/or other mechanisms may be employed.

Additionally, in some non-limiting examples, in addition to rendering at least one of the first electrode 920, the second electrode 940, and/or the auxiliary electrode 1450, substantially transmissive across at least across a substantial part of the lateral aspect 1010 of the emissive region 1301 corresponding to the (sub-) pixel(s) 2110/164x of the device 900, to allow EM radiation to be emitted substantially across the lateral aspect 1010 thereof, there may be an aim to make at least one of the lateral aspect(s) 1020 of the surrounding non-emissive region(s) 1302 of the device 900 substantially transmissive in both the bottom and top directions, to render the device 900 substantially transmissive relative to EM radiation incident on an external surface thereof, such that a substantial part of such externally-incident EM radiation may be transmitted through the device 900, in addition to the emission (in a top-emission, bottom-emission, and/or double-sided emission) of EM radiation generated internally within the device 900 as disclosed herein.

Turning now to FIG. 21A, there may be shown an example plan view of a transmissive (transparent) version, shown generally at 2100, of the device 900. In some non-limiting examples, the device 2100 may be an active matrix OLED (AMOLED) device having a plurality of pixels or pixel regions 2110 and a plurality of transmissive regions 2120. In some non-limiting examples, at least one auxiliary electrode 1450 may be deposited on an exposed layer surface 11 of an underlying material between the pixel region(s) 2110, and/or the transmissive region(s) 2120.

In some non-limiting examples, each pixel region 2110 may comprise a plurality of emissive regions 1301 each corresponding to a sub-pixel 164x. In some non-limiting examples, the sub-pixels 164x may correspond to, respectively, R(ed) sub-pixels 1641, G(reen) sub-pixels 1642, and/or B(lue) sub-pixels 1643.

In some non-limiting examples, each transmissive region 2120 may be substantially transparent and allows EM radiation to pass through the entirety of a cross-sectional aspect thereof.

Turning now to FIG. 21B, there may be shown an example cross-sectional view of a version 2100 of the device 900, taken along line 21B-21B in FIG. 21A. In the figure, the device 2100 may be shown as comprising a substrate 10, a TFT insulating layer 1009 and a first electrode 920 formed on a surface of the TFT insulating layer 1009. In some non-limiting examples, the substrate 10 may comprise the base substrate 912 (not shown for purposes of simplicity of illustration), and/or at least one TFT structure 1001, corresponding to, and for driving, each sub-pixel 164x positioned substantially thereunder and electrically coupled with the first electrode 920 thereof. In some non-limiting examples, PDL(s) 1040 may be formed in non-emissive regions 1302 over the substrate 10, to define emissive region(s) 1301 also corresponding to each sub-pixel 164x, over the first electrode 920 corresponding thereto. In some non-limiting examples, the PDL(s) 1040 may cover edges of the first electrode 920.

In some non-limiting examples, at least one semiconducting layer 930 may be deposited over exposed region(s) of the first electrode 920 and, in some non-limiting examples, at least parts of the surrounding PDLs 1040.

In some non-limiting examples, a second electrode 940 may be deposited over the at least one semiconducting layer(s) 930, including over the pixel region 2110 to form the sub-pixel(s) 164x thereof and, in some non-limiting examples, at least partially over the surrounding PDLs 1040 in the transmissive region 2120.

In some non-limiting examples, a patterning coating 210 may be selectively deposited over first portion(s) 301 of the device 2100, comprising both the pixel region 2110 and the transmissive region 2120 but not the region of the second electrode 940 corresponding to the auxiliary electrode 1450 comprising second portion(s) 302 thereof.

In some non-limiting examples, the entire exposed layer surface 11 of the device 2100 may then be exposed to a vapor flux 632 of the deposited material 631, which in some non-limiting examples may be Mg. The deposited layer 430 may be selectively deposited over second portion(s) of the second electrode 940 that may be substantially devoid of the patterning coating 210 to form an auxiliary electrode 1450 that may be electrically coupled with and in some non-limiting examples, in physical contact with uncoated parts of the second electrode 940.

At the same time, the transmissive region 2120 of the device 2100 may remain substantially devoid of any materials that may substantially affect the transmission of EM radiation therethrough. In particular, as shown in the figure, the TFT structure 1001 and the first electrode 920 may be positioned, in a cross-sectional aspect, below the sub-pixel 164x corresponding thereto, and together with the auxiliary electrode 1450, may lie beyond the transmissive region 2120. As a result, these components may not attenuate or impede light from being transmitted through the transmissive region 2120. In some non-limiting examples, such arrangement may allow a viewer viewing the device 2100 from a typical viewing distance to see through the device 2100, in some non-limiting examples, when all the (sub-) pixel(s) 2110/164x may not be emitting, thus creating a transparent device 1800.

While not shown in the figure, in some non-limiting examples, the device 2100 may further comprise an NPC 820 disposed between the auxiliary electrode 1450 and the second electrode 940. In some non-limiting examples, the NPC 820 may also be disposed between the patterning coating 210 and the second electrode 940.

In some non-limiting examples, the patterning coating 210 may be formed concurrently with the at least one semiconducting layer(s) 930. By way of non-limiting example, at least one material used to form the patterning coating 210 may also be used to form the at least one semiconducting layer(s) 930. In such non-limiting example, several stages for fabricating the device 2100 may be reduced.

Those having ordinary skill in the relevant art will appreciate that in some non-limiting examples, various other layers, and/or coatings, including without limitation those forming the at least one semiconducting layer(s) 930, and/or the second electrode 940, may cover a part of the transmissive region 2120, especially if such layers, and/or coatings are substantially transparent. In some non-limiting examples, the PDL(s) 1040 may have a reduced thickness, including without limitation, by forming a well therein, which in some non-limiting examples may be similar to the well defined for emissive region(s) 1301, to further facilitate transmission of EM radiation through the transmissive region 2120.

Those having ordinary skill in the relevant art will appreciate that (sub-) pixel(s) 2110/164x arrangements other than the arrangement shown in FIGS. 21A and 21B may, in some non-limiting examples, be employed.

Those having ordinary skill in the relevant art will appreciate that arrangements of the auxiliary electrode(s) 1450 other than the arrangement shown in FIGS. 21A and 21B may, in some non-limiting examples, be employed. By way of non-limiting example, the auxiliary electrode(s) 1450 may be disposed between the pixel region 2110 and the transmissive region 2120. By way of non-limiting example, the auxiliary electrode(s) 1450 may be disposed between sub-pixel(s) 164x within a pixel region 2110.

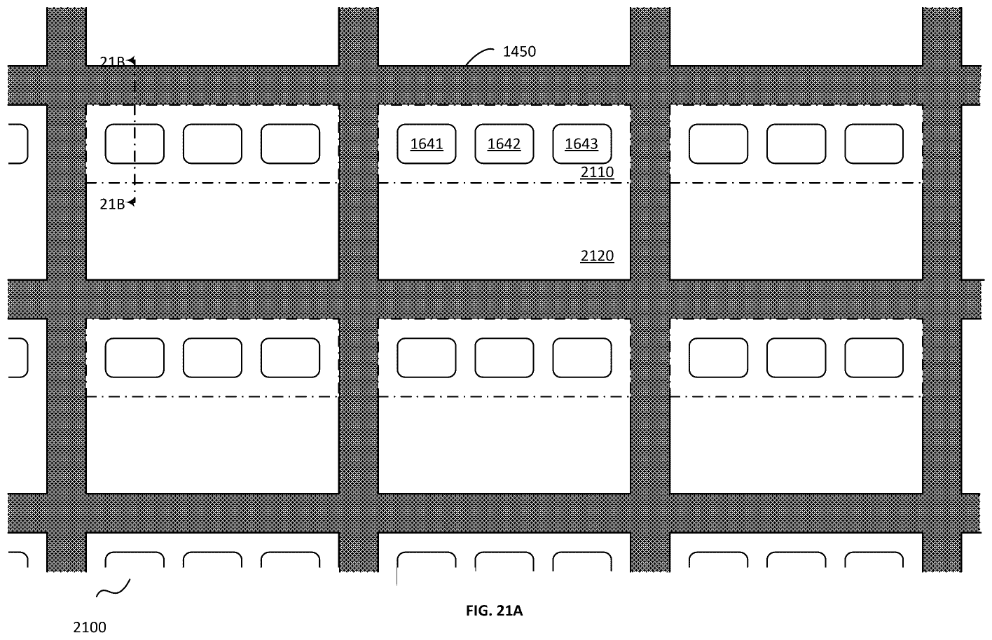

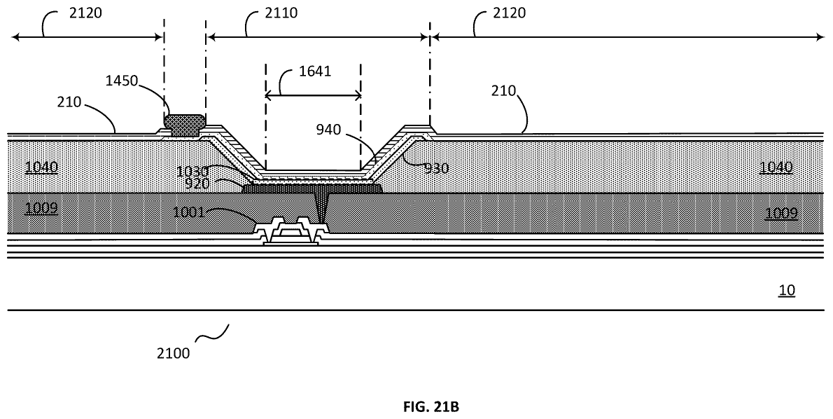

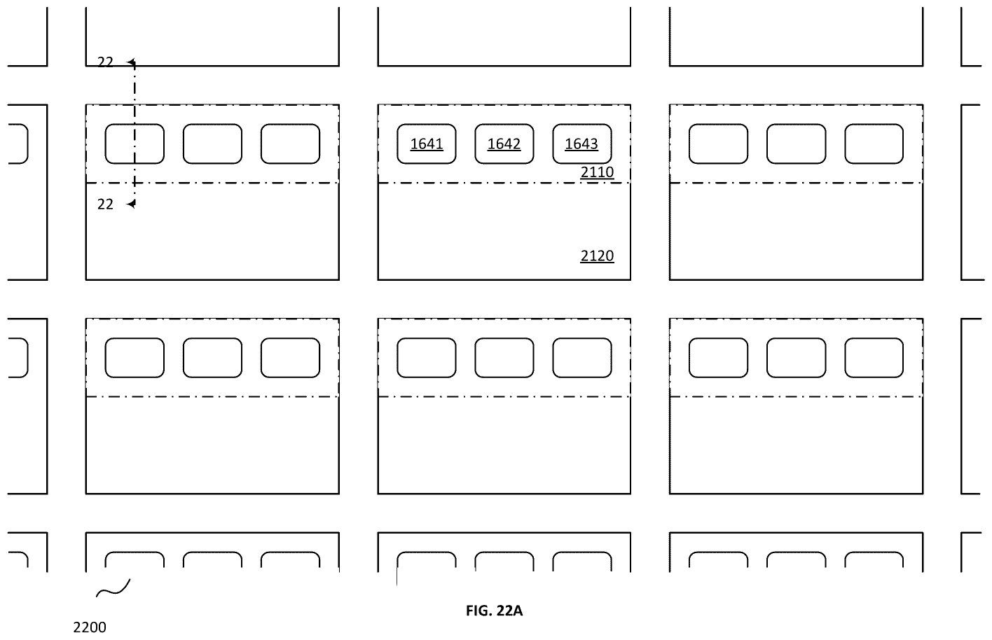

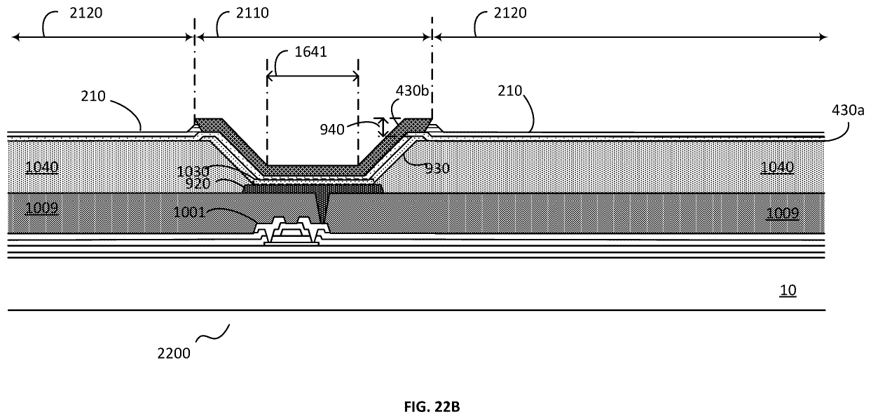

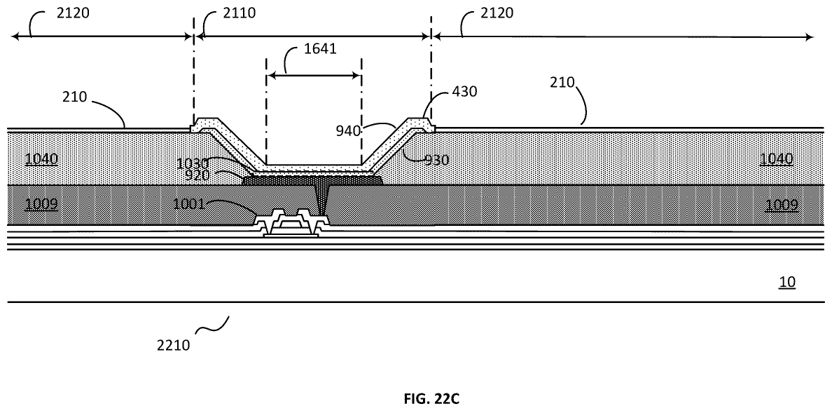

Turning now to FIG. 22A, there may be shown an example plan view of a transparent version, shown generally at 2200, of the device 900. In some non-limiting examples, the device 2200 may be an AMOLED device having a plurality of pixel regions 2110 and a plurality of transmissive regions 2120. The device 2200 may differ from device 2100 in that no auxiliary electrode(s) 1450 lie between the pixel region(s) 2110, and/or the transmissive region(s) 2120.

In some non-limiting examples, each pixel region 2110 may comprise a plurality of emissive regions 1301, each corresponding to a sub-pixel 164x. In some non-limiting examples, the sub-pixels 164x may correspond to, respectively, R(ed) sub-pixels 1641, G(reen) sub-pixels 1642, and/or B(lue) sub-pixels 1643.

In some non-limiting examples, each transmissive region 2120 may be substantially transparent and may allow light to pass through the entirety of a cross-sectional aspect thereof.

Turning now to FIG. 22B, there may be shown an example cross-sectional view of the device 2200, taken along line 22-22 in FIG. 22A. In the figure, the device 2200 may be shown as comprising a substrate 10, a TFT insulating layer 1009 and a first electrode 920 formed on a surface of the TFT insulating layer 1009. The substrate 10 may comprise the base substrate 912 (not shown for purposes of simplicity of illustration), and/or at least one TFT structure 1001 corresponding to, and for driving, each sub-pixel 164x positioned substantially thereunder and electrically coupled with the first electrode 920 thereof. PDL(s) 1040 may be formed in non-emissive regions 1302 over the substrate 10, to define emissive region(s) 1301 also corresponding to each sub-pixel 164x, over the first electrode 920 corresponding thereto. The PDL(s) 1040 cover edges of the first electrode 920.

In some non-limiting examples, at least one semiconducting layer 930 may be deposited over exposed region(s) of the first electrode 920 and, in some non-limiting examples, at least parts of the surrounding PDLs 1040.

In some non-limiting examples, a first deposited layer 430a may be deposited over the at least one semiconducting layer(s) 930, including over the pixel region 2110 to form the sub-pixel(s) 164x thereof and over the surrounding PDLs 1040 in the transmissive region 2120. In some non-limiting examples, the average layer thickness of the first deposited layer 430a may be relatively thin such that the presence of the first deposited layer 430a across the transmissive region 2120 does not substantially attenuate transmission of EM radiation therethrough. In some non-limiting examples, the first deposited layer 430a may be deposited using an open mask and/or a mask-free deposition process.

In some non-limiting examples, a patterning coating 210 may be selectively deposited over first portions 301 of the device 2200, comprising the transmissive region 2120.

In some non-limiting examples, the entire exposed layer surface 11 of the device 2200 may then be exposed to a vapor flux 632 of the deposited material 631, which in some non-limiting examples may be Mg, to selectively deposit a second deposited layer 430b, over second portion(s) 302 of the first deposited layer 430a that may be substantially devoid of the patterning coating 210, in some examples, the pixel region 2110, such that the second deposited layer 430b may be electrically coupled with and in some non-limiting examples, in physical contact with uncoated parts of the first deposited layer 430a, to form the second electrode 940.

In some non-limiting examples, an average layer thickness of the first deposited layer 430a may be no more than an average layer thickness of the second deposited layer 430b. In this way, relatively high transmittance may be maintained in the transmissive region 2120, over which only the first deposited layer 430a may extend. In some non-limiting examples, an average layer thickness of the first deposited layer 430a may be no more than at least one of about: 30 nm, 25 nm, 20 nm, 15 nm, 10 nm, 8 nm, or 5 nm. In some non-limiting examples, an average layer thickness of the second deposited layer 430b may be no more than at least one of about: 30 nm, 25 nm, 20 nm, 15 nm, 10 nm, or 8 nm.

Thus, in some non-limiting examples, an average layer thickness of the second electrode 940 may be no more than about 40 nm, and/or in some non-limiting examples, at least one of between about: 5-30 nm, 10-25 nm, or 15-25 nm.

In some non-limiting examples, the average layer thickness of the first deposited layer 430a may exceed the average layer thickness of the second deposited layer 430b. In some non-limiting examples, the average layer thickness of the first deposited layer 430a and the average layer thickness of the second deposited layer 430b may be substantially the same.

In some non-limiting examples, at least one deposited material 631 used to form the first deposited layer 430a may be substantially the same as at least one deposited material 631 used to form the second deposited layer 430b. In some non-limiting examples, such at least one deposited material 631 may be substantially as described herein in respect of the first electrode 920, the second electrode 940, the auxiliary electrode 1450, and/or a deposited layer 430 thereof.

In some non-limiting examples, the transmissive region 2120 of the device 2200 may remain substantially devoid of any materials that may substantially inhibit the transmission of EM radiation therethrough. In particular, as shown in the figure, the TFT structure, and/or the first electrode 920 may be positioned, in a cross-sectional aspect below the sub-pixel 164x corresponding thereto and beyond the transmissive region 2120. As a result, these components may not attenuate or impede EM radiation from being transmitted through the transmissive region 2120. In some non-limiting examples, such arrangement may allow a viewer viewing the device 2200 from a typical viewing distance to see through the device 2200, in some non-limiting examples, when the (sub-) pixel(s) 2110/164x are not emitting, thus creating a transparent AMOLED device 2200.

While not shown in the figure, in some non-limiting examples, the device 2200 may further comprise an NPC 820 disposed between the second deposited layer 430b and the first deposited layer 430a. In some non-limiting examples, the NPC 820 may also be disposed between the patterning coating 210 and the first deposited layer 430a.

In some non-limiting examples, the patterning coating 210 may be formed concurrently with the at least one semiconducting layer(s) 930. By way of non-limiting example, at least one material used to form the patterning coating 210 may also be used to form the at least one semiconducting layer(s) 930. In such non-limiting example, several stages for fabricating the device 2200 may be reduced.

Those having ordinary skill in the relevant art will appreciate that in some non-limiting examples, various other layers, and/or coatings, including without limitation those forming the at least one semiconducting layer(s) 930, and/or the first deposited layer 430a, may cover a part of the transmissive region 2120, especially if such layers, and/or coatings are substantially transparent. In some non-limiting examples, the PDL(s) 1040 may have a reduced thickness, including without limitation, by forming a well therein, which in some non-limiting examples may be similar to the well defined for emissive region(s) 1301, to further facilitate transmission of EM radiation through the transmissive region 2120.

Those having ordinary skill in the relevant art will appreciate that (sub-) pixel(s) 2110/164x arrangements other than the arrangement shown in FIGS. 22A and 22B may, in some non-limiting examples, be employed.

Turning now to FIG. 22C, there may be shown an example cross-sectional view of a different version 2210 of the device 900, taken along the same line 22-22 in FIG. 22A. In the figure, the device 2210 may be shown as comprising a substrate 10, a TFT insulating layer 1009 and a first electrode 920 formed on a surface of the TFT insulating layer 1009. The substrate 10 may comprise the base substrate 912 (not shown for purposes of simplicity of illustration), and/or at least one TFT structure 1001 corresponding to and for driving each sub-pixel 164x positioned substantially thereunder and electrically coupled with the first electrode 920 thereof. PDL(s) 1040 may be formed in non-emissive regions 1302 over the substrate 10, to define emissive region(s) 1301 also corresponding to each sub-pixel 164x, over the first electrode 920 corresponding thereto. The PDL(s) 1040 may cover edges of the first electrode 920.

In some non-limiting examples, at least one semiconducting layer 930 may be deposited over exposed region(s) of the first electrode 920 and, in some non-limiting examples, at least parts of the surrounding PDLs 1040.

In some non-limiting examples, a patterning coating 210 may be selectively deposited over first portions 301 of the device 2210, comprising the transmissive region 2120.

In some non-limiting examples, a deposited layer 430 may be deposited over the at least one semiconducting layer(s) 930, including over the pixel region 2110 to form the sub-pixel(s) 164x thereof but not over the surrounding PDLs 1040 in the transmissive region 2120. In some non-limiting examples, the first deposited layer 430a may be deposited using an open mask and/or a mask-free deposition process. In some non-limiting examples, such deposition may be effected by exposing the entire exposed layer surface 11 of the device 2210 to a vapor flux 632 of the deposited material 631, which in some non-limiting examples may be Mg, to selectively deposit the deposited layer 430 over second portions 302 of the at least one semiconducting layer(s) 930 that are substantially devoid of the patterning coating 210, in some non-limiting examples, the pixel region 2110, such that the deposited layer 430 may be deposited on the at least one semiconducting layer(s) 930 to form the second electrode 940.

In some non-limiting examples, the transmissive region 2120 of the device 2210 may remain substantially devoid of any materials that may substantially affect the transmission of EM radiation therethrough. In particular, as shown in the figure, the TFT structure 1001, and/or the first electrode 920 may be positioned, in a cross-sectional aspect below the sub-pixel 164x corresponding thereto and beyond the transmissive region 2120. As a result, these components may not attenuate or impede EM radiation from being transmitted through the transmissive region 2120. In some non-limiting examples, such arrangement may allow a viewer viewing the device 2210 from a typical viewing distance to see through the device 2210, in some non-limiting examples, when the (sub-) pixel(s) 2110/164x are not emitting, thus creating a transparent AMOLED device 2210.

By providing a transmissive region 2120 that may be free, and/or substantially devoid of any deposited layer 430, the transmittance in such region may, in some non-limiting examples, be favorably enhanced, by way of non-limiting example, by comparison to the device 2200 of FIG. 22B.

While not shown in the figure, in some non-limiting examples, the device 2210 may further comprise an NPC 820 disposed between the deposited layer 430 and the at least one semiconducting layer(s) 930. In some non-limiting examples, the NPC 820 may also be disposed between the patterning coating 210 and the PDL(s) 1040.

In some non-limiting examples, the patterning coating 210 may be formed concurrently with the at least one semiconducting layer(s) 930. By way of non-limiting example, at least one material used to form the patterning coating 210 may also be used to form the at least one semiconducting layer(s) 930. In such non-limiting example, several stages for fabricating the device 1910 may be reduced.

Those having ordinary skill in the relevant art will appreciate that in some non-limiting examples, various other layers, and/or coatings, including without limitation those forming the at least one semiconducting layer(s) 930, and/or the deposited layer 430, may cover a part of the transmissive region 2120, especially if such layers, and/or coatings are substantially transparent. In some non-limiting examples, the PDL(s) 1040 may have a reduced thickness, including without limitation, by forming a well therein, which in some non-limiting examples may be similar to the well defined for emissive region(s) 1301, to further facilitate transmission of EM radiation through the transmissive region 2120.

Those having ordinary skill in the relevant art will appreciate that (sub-) pixel(s) 2110/164x arrangements other than the arrangement shown in FIGS. 22A to 22C may, in some non-limiting examples, be employed.

### Selective Deposition to Modulate Electrode Thickness Over Emissive Region(s)

As discussed above, modulating the thickness of an electrode 920, 940, 1450 in and across a lateral aspect 1010 of emissive region(s) 1301 of a (sub-) pixel 2110/164x may impact the microcavity effect observable. In some non-limiting examples, selective deposition of at least one deposited layer 430 through deposition of at least one patterning coating 210, including without limitation, an NIC, and/or an NPC 820, in the lateral aspects 1010 of emissive region(s) 1301 corresponding to different sub-pixel(s) 164x in a pixel region 2110 may allow the optical microcavity effect in each emissive region 1301 to be controlled, and/or modulated to optimize desirable optical microcavity effects on a sub-pixel 164x basis, including without limitation, an emission spectrum, a luminous intensity, and/or an angular dependence of a brightness, and/or a color shift of emitted light.

Such effects may be controlled by independently modulating an average layer thickness and/or a number of the deposited layer(s) 430, disposed in each emissive region 1301 of the sub-pixel(s) 164x. By way of non-limiting example, the average layer thickness of a second electrode 940 disposed over a B(lue) sub-pixel 1643 may be less than the average layer thickness of a second electrode 940 disposed over a G(reen) sub-pixel 1642, and the average layer thickness of a second electrode 940 disposed over a G(reen) sub-pixel 1642 may be less than the average layer thickness of a second electrode 940 disposed over a R(ed) sub-pixel 1641.

In some non-limiting examples, such effects may be controlled to an even greater extent by independently modulating the average layer thickness and/or a number of the deposited layers 430, but also of the patterning coating 210 and/or an NPC 820, deposited in part(s) of each emissive region 1301 of the sub-pixel(s) 164x.

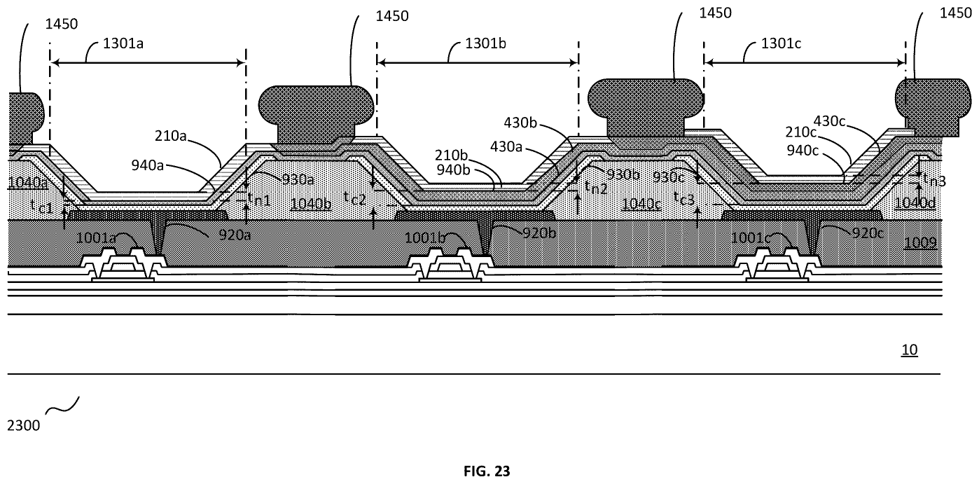

As shown by way of non-limiting example in FIG. 23, there may be deposited layer(s) 430 of varying average layer thickness selectively deposited for emissive region(s) 1301 corresponding to sub-pixel(s) 164x, in some non-limiting examples, in a version 2300 of an OLED display device 900, having different emission spectra. In some non-limiting examples, a first emissive region 1301a may correspond to a sub-pixel 164x configured to emit EM radiation of a first wavelength, and/or emission spectrum, and/or in some non-limiting examples, a second emissive region 1301b may correspond to a sub-pixel 164x configured to emit EM radiation of a second wavelength, and/or emission spectrum. In some non-limiting examples, a device 2300 may comprise a third emissive region 1301c that may correspond to a sub-pixel 164x configured to emit EM radiation of a third wavelength, and/or emission spectrum.

In some non-limiting examples, the first wavelength may be less than, greater than, and/or equal to at least one of the second wavelength, and/or the third wavelength. In some non-limiting examples, the second wavelength may be less than, greater than, and/or equal to at least one of the first wavelength, and/or the third wavelength. In some non-limiting examples, the third wavelength may be less than, greater than, and/or equal to at least one of the first wavelength, and/or the second wavelength.

In some non-limiting examples, the device 2300 may also comprise at least one additional emissive region 1301 (not shown) that may in some non-limiting examples be configured to emit EM radiation having a wavelength, and/or emission spectrum that is substantially identical to at least one of the first emissive region 1301a, the second emissive region 1301b, and/or the third emissive region 1301c.

In some non-limiting examples, the patterning coating 210 may be selectively deposited using a shadow mask 515 that may also have been used to deposit the at least one semiconducting layer 930 of the first emissive region 1301a. In some non-limiting examples, such shared use of a shadow mask 515 may allow the optical microcavity effect(s) to be tuned for each sub-pixel 164x in a cost-effective manner.

The device 2300 may be shown as comprising a substrate 10, a TFT insulating layer 1009 and a plurality of first electrodes 920, formed on an exposed layer surface 11 of the TFT insulating layer 1009.

In some non-limiting examples, the substrate 10 may comprise the base substrate 912 (not shown for purposes of simplicity of illustration), and/or at least one TFT structure 1001 corresponding to, and for driving, a corresponding emissive region 1301, each having a corresponding sub-pixel 164x, positioned substantially thereunder and electrically coupled with its associated first electrode 920. PDL(s) 1040 may be formed over the substrate 10, to define emissive region(s) 1301. In some non-limiting examples, the PDL(s) 1040 may cover edges of their respective first electrodes 920.

In some non-limiting examples, at least one semiconducting layer 930 may be deposited over exposed region(s) of their respective first electrodes 920 and, in some non-limiting examples, at least parts of the surrounding PDLs 1040.

In some non-limiting examples, a first deposited layer 430a may be deposited over the at least one semiconducting layer(s) 930. In some non-limiting examples, the first deposited layer 430a may be deposited using an open mask and/or a mask-free deposition process. In some non-limiting examples, such deposition may be effected by exposing the entire exposed layer surface 11 of the device 2300 to a vapor flux 632 of deposited material 631, which in some non-limiting examples may be Mg, to deposit the first deposited layer 430a over the at least one semiconducting layer(s) 930 to form a first layer of the second electrode 940a (not shown), which in some non-limiting examples may be a common electrode, at least for the first emissive region 1301a. Such common electrode may have a first thickness t_{c1} in the first emissive region 1301a. In some non-limiting examples, the first thickness t_{c1} may correspond to a thickness of the first deposited layer 430a.

In some non-limiting examples, a first patterning coating 210a may be selectively deposited over first portions 301 of the device 2300, comprising the first emissive region 1301a.

In some non-limiting examples, a second deposited layer 430b may be deposited over the device 2300. In some non-limiting examples, the second deposited layer 430b may be deposited using an open mask and/or a mask-free deposition process. In some non-limiting examples, such deposition may be effected by exposing the entire exposed layer surface 11 of the device 2300 to a vapor flux 632 of deposited material 631, which in some non-limiting examples may be Mg, to deposit the second deposited layer 430b over the first deposited layer 430a that may be substantially devoid of the first patterning coating 210a, in some examples, the second and third emissive regions 1301b, 1301c, and/or at least part(s) of the non-emissive region(s) 1302 in which the PDLs 1040 lie, such that the second deposited layer 430b may be deposited on the second portion(s) 302 of the first deposited layer 430a that are substantially devoid of the first patterning coating 210a to form a second layer of the second electrode 940b (not shown), which in some non-limiting examples, may be a common electrode, at least for the second emissive region 1301b. In some non-limiting examples, such common electrode may have a second thickness t_{c2} in the second emissive region 1301b. In some non-limiting examples, the second thickness t_{c2} may correspond to a combined average layer thickness of the first deposited layer 430a and of the second deposited layer 430b and may in some non-limiting examples exceed the first thickness t_{c1}.

In some non-limiting examples, a second patterning coating 210b may be selectively deposited over further first portions 301 of the device 2300, comprising the second emissive region 1301b.

In some non-limiting examples, a third deposited layer 430c may be deposited over the device 2300. In some non-limiting examples, the third deposited layer 430c may be deposited using an open mask and/or a mask-free deposition process. In some non-limiting examples, such deposition may be effected by exposing the entire exposed layer surface 11 of the device 2300 to a vapor flux 632 of deposited material 631, which in some non-limiting examples may be Mg, to deposit the third deposited layer 430c over the second deposited layer 430b that may be substantially devoid of either the first patterning coating 210a or the second patterning coating 210b, in some examples, the third emissive region 1301c, and/or at least part(s) of the non-emissive region 1302 in which the PDLs 1040 lie, such that the third deposited layer 430c may be deposited on the further second portion(s) 302 of the second deposited layer 430b that are substantially devoid of the second patterning coating 210b to form a third layer of the second electrode 940c (not shown), which in some non-limiting examples, may be a common electrode, at least for the third emissive region 1301c. In some non-limiting examples, such common electrode may have a third thickness t_{c3} in the third emissive region 1301c. In some non-limiting examples, the third thickness t_{c3} may correspond to a combined thickness of the first deposited layer 430a, the second deposited layer 430b and the third deposited layer 430c and may in some non-limiting examples exceed either, or both of, the first thickness t_{c1} and the second thickness t_{c2}.

In some non-limiting examples, a third patterning coating 210c may be selectively deposited over additional first portions 301 of the device 2000, comprising the third emissive region 1301b.

In some non-limiting examples, at least one auxiliary electrode 1450 may be disposed in the non-emissive region(s) 1302 of the device 2300 between neighbouring emissive regions 1301 thereof and in some non-limiting examples, over the PDLs 1040. In some non-limiting examples, the deposited layer 430 used to deposit the at least one auxiliary electrode 1450 may be deposited using an open mask and/or a mask-free deposition process. In some non-limiting examples, such deposition may be effected by exposing the entire exposed layer surface 11 of the device 2300 to a vapor flux 632 of deposited material 631, which in some non-limiting examples may be Mg, to deposit the deposited layer 430 over the exposed parts of the first deposited layer 430a, the second deposited layer 430b and the third deposited layer 430c that may be substantially devoid of any of the first patterning coating 210a the second patterning coating 210b, and/or the third patterning coating 210c, such that the deposited layer 430 may be deposited on an additional second portion 302 comprising the exposed part(s) of the first deposited layer 430a, the second deposited layer 430b, and/or the third deposited layer 430c that may be substantially devoid of any of the first patterning coating 210a, the second patterning coating 210b, and/or the third patterning coating 210c to form the at least one auxiliary electrode 1450. In some non-limiting examples, each of the at least one auxiliary electrodes 1450 may be electrically coupled with a respective one of the second electrodes 940. In some non-limiting examples, each of the at least one auxiliary electrode 1450 may be in physical contact with such second electrode 940.

In some non-limiting examples, the first emissive region 1301a, the second emissive region 1301b and the third emissive region 1301c may be substantially devoid of a closed coating 440 of the deposited material 631 used to form the at least one auxiliary electrode 1450.

In some non-limiting examples, at least one of the first deposited layer 430a, the second deposited layer 430b, and/or the third deposited layer 430c may be transmissive, and/or substantially transparent in at least a part of the visible spectrum. Thus, in some non-limiting examples, the second deposited layer 430b, and/or the third deposited layer 430c (and/or any additional deposited layer(s) 430) may be disposed on top of the first deposited layer 430a to form a multi-coating electrode 920, 940, 1450 that may also be transmissive, and/or substantially transparent in at least a part of the visible spectrum. In some non-limiting examples, the transmittance of any of the at least one of the first deposited layer 430a, the second deposited layer 430b, the third deposited layer 430c, any additional deposited layer(s) 430, and/or the multi-coating electrode 920, 940, 1450 may exceed at least one of about: 30%, 40% 45%, 50%, 60%, 70%, 75%, or 80% in at least a part of the visible spectrum.

In some non-limiting examples, an average layer thickness of the first deposited layer 430a, the second deposited layer 430b, and/or the third deposited layer 430c may be made relatively thin to maintain a relatively high transmittance. In some non-limiting examples, an average layer thickness of the first deposited layer 430a may be at least one of between about: 5-30 nm, 8-25 nm, or 10-20 nm. In some non-limiting examples, an average layer thickness of the second deposited layer 430b may be at least one of between about: 1-25 nm, 1-20 nm, 1-15 nm, 1-10 nm, or 3-6 nm. In some non-limiting examples, an average layer thickness of the third deposited layer 430c may be at least one of between about: 1-25 nm, 1-20 nm, 1-15 nm, 1-10 nm, or 3-6 nm. In some non-limiting examples, a thickness of a multi-coating electrode formed by a combination of the first deposited layer 430a, the second deposited layer 430b, the third deposited layer 430c, and/or any additional deposited layer(s) 430 may be at least one of between about: 6-35 nm, 10-30 nm, 10-25 nm, or 12-18 nm.

In some non-limiting examples, a thickness of the at least one auxiliary electrode 1450 may exceed an average layer thickness of the first deposited layer 430a, the second deposited layer 430b, the third deposited layer 430c, and/or a common electrode. In some non-limiting examples, the thickness of the at least one auxiliary electrode 1450 may exceed at least one of about: 50 nm, 80 nm, 100 nm, 150 nm, 200 nm, 300 nm, 400 nm, 500 nm, 700 nm, 800 nm, 1 μm, 1.2 μm, 1.5 μm, 2 μm, 2.5 μm, or 3 μm.

In some non-limiting examples, the at least one auxiliary electrode 1450 may be substantially non-transparent, and/or opaque. However, since the at least one auxiliary electrode 1450 may be, in some non-limiting examples, provided in a non-emissive region 1302 of the device 2300, the at least one auxiliary electrode 1450 may not cause or contribute to significant optical interference. In some non-limiting examples, the transmittance of the at least one auxiliary electrode 1450 may be no more than at least one of about: 50%, 70%, 80%, 85%, 90%, or 95% in at least a part of the visible spectrum.

In some non-limiting examples, the at least one auxiliary electrode 1450 may absorb EM radiation in at least a part of the visible spectrum.

In some non-limiting examples, an average layer thickness of the first patterning coating 210a, the second patterning coating 210b, and/or the third patterning coating 210c disposed in the first emissive region 1301a, the second emissive region 1301b, and/or the third emissive region 1301c respectively, may be varied according to a colour, and/or emission spectrum of EM radiation emitted by each emissive region 1301. In some non-limiting examples, the first patterning coating 210a may have a first patterning coating thickness tₙ₁, the second patterning coating 210b may have a second patterning coating thickness tₙ₂, and/or the third patterning coating 210c may have a third patterning coating thickness tₙ₃. In some non-limiting examples, the first patterning coating thickness tₙ₁, the second patterning coating thickness tₙ₂, and/or the third patterning coating thickness tₙ₃, may be substantially the same. In some non-limiting examples, the first patterning coating thickness tₙ₁, the second patterning coating thickness tₙ₂, and/or the third patterning coating thickness tₙ₃, may be different from one another.

In some non-limiting examples, the device 2300 may also comprise any number of emissive regions 1301, and/or (sub-) pixel(s) 2110/164x thereof. In some non-limiting examples, a device may comprise a plurality of pixels 2110, wherein each pixel 2110 comprises two, three or more sub-pixel(s) 164x.

Those having ordinary skill in the relevant art will appreciate that the specific arrangement of (sub-) pixel(s) 2110/164x may be varied depending on the device design. In some non-limiting examples, the sub-pixel(s) 164x may be arranged according to known arrangement schemes, including without limitation, RGB side-by-side, diamond, and/or PenTile®.

### Conductive Coating for Electrically Coupling an Electrode to an Auxiliary Electrode

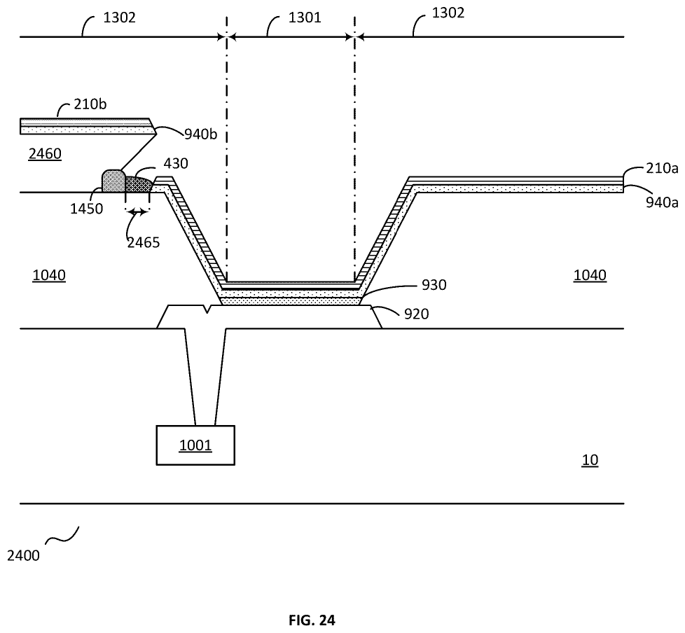

Turning to FIG. 24, there may be shown a cross-sectional view of an example version 2400 of the device 900. The device 2400 may comprise in a lateral aspect, an emissive region 1301 and an adjacent non-emissive region 1302.

In some non-limiting examples, the emissive region 1301 may correspond to a sub-pixel 164x of the device 2400. The emissive region 1301 may have a substrate 10, a first electrode 920, a second electrode 940 and at least one semiconducting layer 930 arranged therebetween.

The first electrode 920 may be disposed on an exposed layer surface 11 of the substrate 10. The substrate 10 may comprise a TFT structure 1001, that may be electrically coupled with the first electrode 920. The edges, and/or perimeter of the first electrode 920 may generally be covered by at least one PDL 1040.

The non-emissive region 1302 may have an auxiliary electrode 1450 and a first part of the non-emissive region 1302 may have a projecting structure 2460 arranged to project over and overlap a lateral aspect of the auxiliary electrode 1450. The projecting structure 2460 may extend laterally to provide a sheltered region 2465. By way of non-limiting example, the projecting structure 2460 may be recessed at, and/or near the auxiliary electrode 1450 on at least one side to provide the sheltered region 2465. As shown, the sheltered region 2465 may in some non-limiting examples, correspond to a region on a surface of the PDL 1040 that may overlap with a lateral projection of the projecting structure 2460. The non-emissive region 1302 may further comprise a deposited layer 430 disposed in the sheltered region 2465. The deposited layer 430 may electrically couple the auxiliary electrode 1450 with the second electrode 940.

A patterning coating 210a may be disposed in the emissive region 1301 over the exposed layer surface 11 of the second electrode 940. In some non-limiting examples, an exposed layer surface 11 of the projecting structure 2460 may be coated with a residual thin conductive film from deposition of a thin conductive film to form a second electrode 940. In some non-limiting examples, an exposed layer surface 11 of the residual thin conductive film may be coated with a residual patterning coating 210b from deposition of the patterning coating 210.

However, because of the lateral projection of the projecting structure 2460 over the sheltered region 2465, the sheltered region 2465 may be substantially devoid of patterning coating 210. Thus, when a deposited layer 430 may be deposited on the device 2400 after deposition of the patterning coating 210, the deposited layer 430 may be deposited on, and/or migrate to the sheltered region 2465 to couple the auxiliary electrode 1450 to the second electrode 940.

Those having ordinary skill in the relevant art will appreciate that a non-limiting example has been shown in FIG. 24 and that various modifications may be apparent. By way of non-limiting example, the projecting structure 2460 may provide a sheltered region 2465 along at least two of its sides. In some non-limiting examples, the projecting structure 2460 may be omitted and the auxiliary electrode 1450 may comprise a recessed portion that may define the sheltered region 2465. In some non-limiting examples, the auxiliary electrode 1450 and the deposited layer 430 may be disposed directly on a surface of the substrate 10, instead of the PDL 1040.

### Selective Deposition of Optical Coating

In some non-limiting examples, a device (not shown), which in some non-limiting examples may be an opto-electronic device, may comprise a substrate 10, a patterning coating 210 and an optical coating. The patterning coating 210 may cover, in a lateral aspect, a first lateral portion 301 of the substrate 10. The optical coating may cover, in a lateral aspect, a second lateral portion 302 of the substrate. At least a part of the patterning coating 210 may be substantially devoid of a closed coating 440 of the optical coating.

In some non-limiting examples, the optical coating may be used to modulate optical properties of EM radiation being transmitted, emitted, and/or absorbed by the device, including without limitation, plasmon modes. By way of non-limiting example, the optical coating may be used as an optical filter, index-matching coating, optical outcoupling coating, scattering layer, diffraction grating, and/or parts thereof.

In some non-limiting examples, the optical coating may be used to modulate at least one optical microcavity effect in the device by, without limitation, tuning the total optical path length, and/or the refractive index thereof. At least one optical property of the device may be affected by modulating at least one optical microcavity effect including without limitation, the output EM radiation, including without limitation, an angular dependence of an intensity thereof, and/or a wavelength shift thereof. In some non-limiting examples, the optical coating may be a non-electrical component, that is, the optical coating may not be configured to conduct, and/or transmit electrical current during normal device operations.

In some non-limiting examples, the optical coating may be formed of any deposited material 631, and/or may employ any mechanism of depositing a deposited layer 430 as described herein.

### Partition and Recess

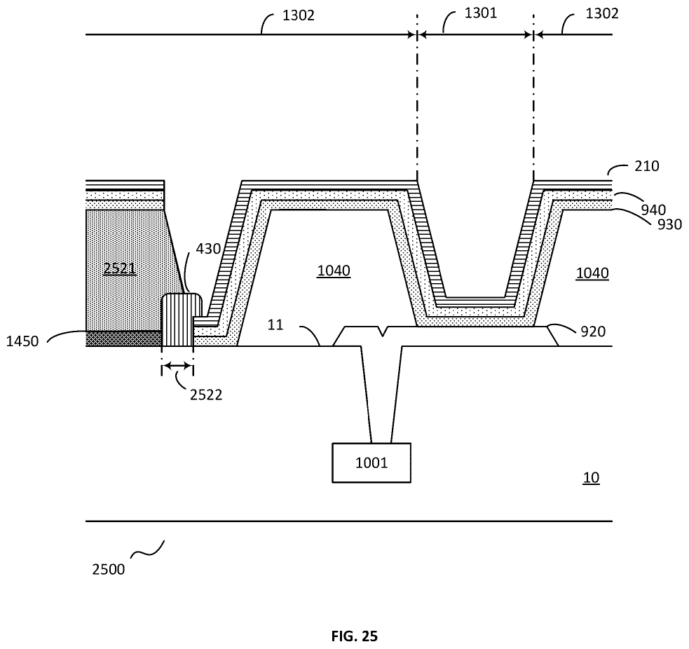

Turning to FIG. 25, there may be shown a cross-sectional view of an example version 2500 of the device 900. The device 2500 may comprise a substrate 10 having an exposed layer surface 11. The substrate 10 may comprise at least one TFT structure 1001. By way of non-limiting example, the at least one TFT structure 1001 may be formed by depositing and patterning a series of thin films when fabricating the substrate 10, in some non-limiting examples, as described herein.

The device 2500 may comprise, in a lateral aspect, an emissive region 1301 having an associated lateral aspect 1010 and at least one adjacent non-emissive region 1302, each having an associated lateral aspect 1020. The exposed layer surface 11 of the substrate 10 in the emissive region 1301 may be provided with a first electrode 920, that may be electrically coupled with the at least one TFT structure 1001. A PDL 1040 may be provided on the exposed layer surface 11, such that the PDL 1040 covers the exposed layer surface 11 as well as at least one edge, and/or perimeter of the first electrode 920. The PDL 1040 may, in some non-limiting examples, be provided in the lateral aspect 1020 of the non-emissive region 1302. The PDL 1040 may define a valley-shaped configuration that may provide an opening that generally may correspond to the lateral aspect 1010 of the emissive region 1301 through which a layer surface of the first electrode 920 may be exposed. In some non-limiting examples, the device 2500 may comprise a plurality of such openings defined by the PDLs 1040, each of which may correspond to a (sub-) pixel 2110/164x region of the device 2500.

As shown, in some non-limiting examples, a partition 2521 may be provided on the exposed layer surface 11 in the lateral aspect 1020 of a non-emissive region 1302 and, as described herein, may define a sheltered region 2465, such as a recess 2522. In some non-limiting examples, the recess 2522 may be formed by an edge of a lower section of the partition 2521 being recessed, staggered, and/or offset with respect to an edge of an upper section of the partition 2521 that may overlap, and/or project beyond the recess 2522.

In some non-limiting examples, the lateral aspect 1010 of the emissive region 1301 may comprise at least one semiconducting layer 930 disposed over the first electrode 920, a second electrode 940, disposed over the at least one semiconducting layer 930, and a patterning coating 210 disposed over the second electrode 940. In some non-limiting examples, the at least one semiconducting layer 930, the second electrode 940 and the patterning coating 210 may extend laterally to cover at least the lateral aspect 1020 of a part of at least one adjacent non-emissive region 1302. In some non-limiting examples, as shown, the at least one semiconducting layer 930, the second electrode 940 and the patterning coating 210 may be disposed on at least a part of at least one PDL 1040 and at least a part of the partition 2521. Thus, as shown, the lateral aspect 1010 of the emissive region 1301, the lateral aspect 1020 of a part of at least one adjacent non-emissive region 1302, a part of at least one PDL 1040, and at least a part of the partition 2521, together may make up a first portion 301, in which the second electrode 940 may lie between the patterning coating 210 and the at least one semiconducting layer 930.

An auxiliary electrode 1450 may be disposed proximate to, and/or within the recess 2522 and a deposited layer 430 may be arranged to electrically couple the auxiliary electrode 1450 with the second electrode 940. Thus as shown, in some non-limiting examples, the recess 2522 may comprise a second portion 302, in which the deposited layer 430 is disposed on the exposed layer surface 11.

In some non-limiting examples, in depositing the deposited layer 430, at least a part of the evaporated flux 632 of the deposited material 631 may be directed at a non-normal angle relative to a lateral plane of the exposed layer surface 11. By way of non-limiting example, at least a part of the evaporated flux 632 may be incident on the device 2500 at an angle of incidence that is, relative to such lateral plane of the exposed layer surface 11, no more than at least one of about: 90°, 85°, 80°, 75°, 70°, 60°, or 50°. By directing an evaporated flux 632 of a deposited material 631, including at least a part thereof incident at a non-normal angle, at least one exposed layer surface 11 of, and/or in the recess 2522 may be exposed to such evaporated flux 632.

In some non-limiting examples, a likelihood of such evaporated flux 632 being precluded from being incident onto at least one exposed layer surface 11 of, and/or in the recess 2522 due to the presence of the partition 2521, may be reduced since at least a part of such evaporated flux 632 may be flowed at a non-normal angle of incidence.

In some non-limiting examples, at least a part of such evaporated flux 632 may be non-collimated. In some non-limiting examples, at least a part of such evaporated flux 632 may be generated by an evaporation source that is a point source, a linear source, and/or a surface source.

In some non-limiting examples, the device 2500 may be displaced during deposition of the deposited layer 430. By way of non-limiting example, the device 2500, and/or the substrate 10 thereof, and/or any layer(s) deposited thereon, may be subjected to a displacement that is angular, in a lateral aspect, and/or in an aspect substantially parallel to the cross-sectional aspect.

In some non-limiting examples, the device 2500 may be rotated about an axis that substantially normal to the lateral plane of the exposed layer surface 11 while being subjected to the evaporated flux 632.

In some non-limiting examples, at least a part of such evaporated flux 632 may be directed toward the exposed layer surface 11 of the device 2500 in a direction that is substantially normal to the lateral plane of the exposed layer surface 11.

Without wishing to be bound by a particular theory, it may be postulated that the deposited material 631 may nevertheless be deposited within the recess 2522 due to lateral migration, and/or desorption of adatoms adsorbed onto the exposed layer surface 11 of the patterning coating 210. In some non-limiting examples, it may be postulated that any adatoms adsorbed onto the exposed layer surface 11 of the patterning coating 210 may tend to migrate, and/or desorb from such exposed layer surface 11 due to unfavorable thermodynamic properties of the exposed layer surface 11 for forming a stable nucleus. In some non-limiting examples, it may be postulated that at least some of the adatoms migrating, and/or desorbing off such exposed layer surface 11 may be re-deposited onto the surfaces in the recess 2522 to form the deposited layer 430.

In some non-limiting examples, the deposited layer 430 may be formed such that the deposited layer 430 may be electrically coupled with both the auxiliary electrode 1450 and the second electrode 940. In some non-limiting examples, the deposited layer 430 may be in physical contact with at least one of the auxiliary electrode 1450, and/or the second electrode 940. In some non-limiting examples, an intermediate layer may be present between the deposited layer 430 and at least one of the auxiliary electrode 1450, and/or the second electrode 940. However, in such example, such intermediate layer may not substantially preclude the deposited layer 430 from being electrically coupled with the at least one of the auxiliary electrode 1450, and/or the second electrode 940. In some non-limiting examples, such intermediate layer may be relatively thin and be such as to permit electrical coupling therethrough. In some non-limiting examples, a sheet resistance of the deposited layer 430 may be no more than a sheet resistance of the second electrode 940.

As shown in FIG. 25, the recess 2522 may be substantially devoid of the second electrode 940. In some non-limiting examples, during the deposition of the second electrode 940, the recess 2522 may be masked, by the partition 2521, such that the evaporated flux 632 of the deposited material 631 for forming the second electrode 940 may be substantially precluded from being incident on at least one exposed layer surface 11 of, and/or in, the recess 2522. In some non-limiting examples, at least a part of the evaporated flux 632 of the deposited material 631 for forming the second electrode 940 may be incident on at least one exposed layer surface 11 of, and/or in, the recess 2522, such that the second electrode 940 may extend to cover at least a part of the recess 2522.

In some non-limiting examples, the auxiliary electrode 1450, the deposited layer 430, and/or the partition 2521 may be selectively provided in certain region(s) of a display panel. In some non-limiting examples, any of these features may be provided at, and/or proximate to, at least one edge of such display panel for electrically coupling at least one element of the frontplane 910, including without limitation, the second electrode 940, to at least one element of the backplane 915. In some non-limiting examples, providing such features at, and/or proximate to, such edges may facilitate supplying and distributing electrical current to the second electrode 940 from an auxiliary electrode 1450 located at, and/or proximate to, such edges. In some non-limiting examples, such configuration may facilitate reducing a bezel size of the display panel.

In some non-limiting examples, the auxiliary electrode 1450, the deposited layer 430, and/or the partition 2521 may be omitted from certain regions(s) of such display panel. In some non-limiting examples, such features may be omitted from parts of the display panel, including without limitation, where a relatively high pixel density may be provided, other than at, and/or proximate to, at least one edge thereof.

### Aperture in Non-Emissive Region

Turning now to FIG. 26A, there may be shown a cross-sectional view of an example version 2600ₐ of the device 900. The device 2600ₐ may differ from the device 2500 in that a pair of partitions 2521 in the non-emissive region 1302 may be disposed in a facing arrangement to define a sheltered region 2465, such as an aperture 2622, therebetween. As shown, in some non-limiting examples, at least one of the partitions 2521 may function as a PDL 1040 that covers at least an edge of the first electrode 920 and that defines at least one emissive region 1301. In some non-limiting examples, at least one of the partitions 2521 may be provided separately from a PDL 1040.

A sheltered region 2465, such as the recess 2522, may be defined by at least one of the partitions 2521. In some non-limiting examples, the recess 2522 may be provided in a part of the aperture 2622 proximal to the substrate 10. In some non-limiting examples, the aperture 2622 may be substantially elliptical when viewed in plan view. In some non-limiting examples, the recess 2522 may be substantially annular when viewed in plan view and surround the aperture 2622.

In some non-limiting examples, the recess 2522 may be substantially devoid of materials for forming each of the layers of a device stack 2610, and/or of a residual device stack 2611.

In these figures, a device stack 2610 may be shown comprising the at least one semiconducting layer 930, the second electrode 940 and the patterning coating 210 deposited on an upper section of the partition 2521.

In these figures, a residual device stack 2611 may be shown comprising the at least one semiconducting layer 930, the second electrode 940 and the patterning coating 210 deposited on the substrate 10 beyond the partition 2521 and recess 2522. From comparison with FIG. 25, it may be seen that the residual device stack 2611 may, in some non-limiting examples, correspond to the at least one semiconductor layer 930, second electrode 940 and the patterning coating 210 as it approaches the recess 2522 at, and/or proximate to, a lip of the partition 2521. In some non-limiting examples, the residual device stack 2611 may be formed when an open mask and/or a mask-free deposition process is used to deposit various materials of the device stack 2610.

In some non-limiting examples, the residual device stack 2611 may be disposed within the aperture 2622. In some non-limiting examples, evaporated materials for forming each of the layers of the device stack 2610 may be deposited within the aperture 2622 to form the residual device stack 2611 therein.

In some non-limiting examples, the auxiliary electrode 1450 may be arranged such that at least a part thereof is disposed within the recess 2522. As shown, in some non-limiting examples, the auxiliary electrode 1450 may be arranged within the aperture 2622, such that the residual device stack 2611 is deposited onto a surface of the auxiliary electrode 1450.

A deposited layer 430 may be disposed within the aperture 2622 for electrically coupling the second electrode 940 with the auxiliary electrode 1450. By way of non-limiting example, at least a part of the deposited layer 430 may be disposed within the recess 2522.

Turning now to FIG. 26B, there may be shown a cross-sectional view of a further example of the device 2600_{b}. As shown, the auxiliary electrode 1450 may be arranged to form at least a part of a side of the partition 2521. As such, the auxiliary electrode 1450 may be substantially annular, when viewed in plan view, and may surround the aperture 2622. As shown, in some non-limiting examples, the residual device stack 2611 may be deposited onto an exposed layer surface 11 of the substrate 10.

In some non-limiting examples, the partition 2521 may comprise, and/or be formed by, an NPC 820. By way of non-limiting example, the auxiliary electrode 1450 may act as an NPC 820.

In some non-limiting examples, the NPC 820 may be provided by the second electrode 940, and/or a portion, layer, and/or material thereof. In some non-limiting examples, the second electrode 940 may extend laterally to cover the exposed layer surface 11 arranged in the sheltered region 2465. In some non-limiting examples, the second electrode 940 may comprise a lower layer thereof and a second layer thereof, wherein the second layer thereof may be deposited on the lower layer thereof. In some non-limiting examples, the lower layer of the second electrode 940 may comprise an oxide such as, without limitation, ITO, IZO, or ZnO. In some non-limiting examples, the upper layer of the second electrode 940 may comprise a metal such as, without limitation, at least one of Ag, Mg, Mg:Ag, Yb/Ag, other alkali metals, and/or other alkali earth metals.

In some non-limiting examples, the lower layer of the second electrode 940 may extend laterally to cover a surface of the sheltered region 2465, such that it forms the NPC 820. In some non-limiting examples, at least one surface defining the sheltered region 2465 may be treated to form the NPC 820. In some non-limiting examples, such NPC 820 may be formed by chemical, and/or physical treatment, including without limitation, subjecting the surface(s) of the sheltered region 2465 to a plasma, UV, and/or UV-ozone treatment.

Without wishing to be bound to any particular theory, it may be postulated that such treatment may chemically, and/or physically alter such surface(s) to modify at least one property thereof. By way of non-limiting example, such treatment of the surface(s) may increase a concentration of C—O, and/or C—OH bonds on such surface(s), may increase a roughness of such surface(s), and/or may increase a concentration of certain species, and/or functional groups, including without limitation, halogens, nitrogen-containing functional groups, and/or oxygen-containing functional groups to thereafter act as an NPC 820.

### Display Panel and User Device

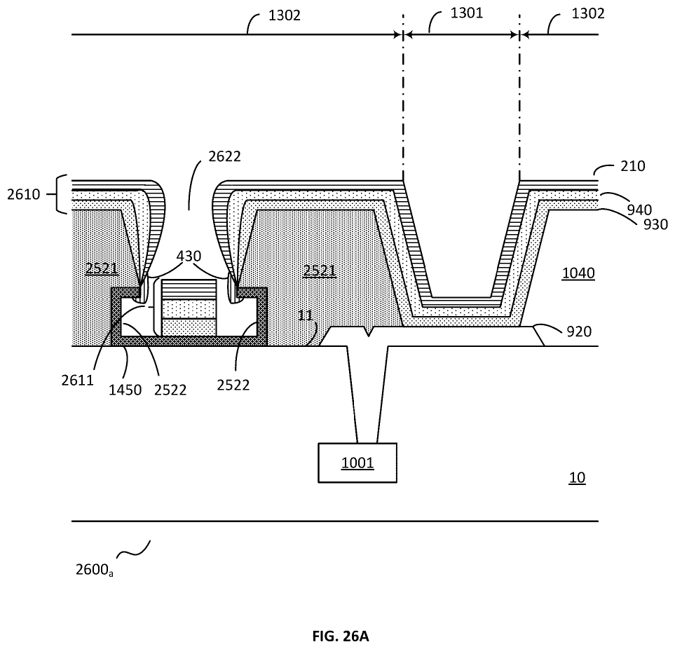

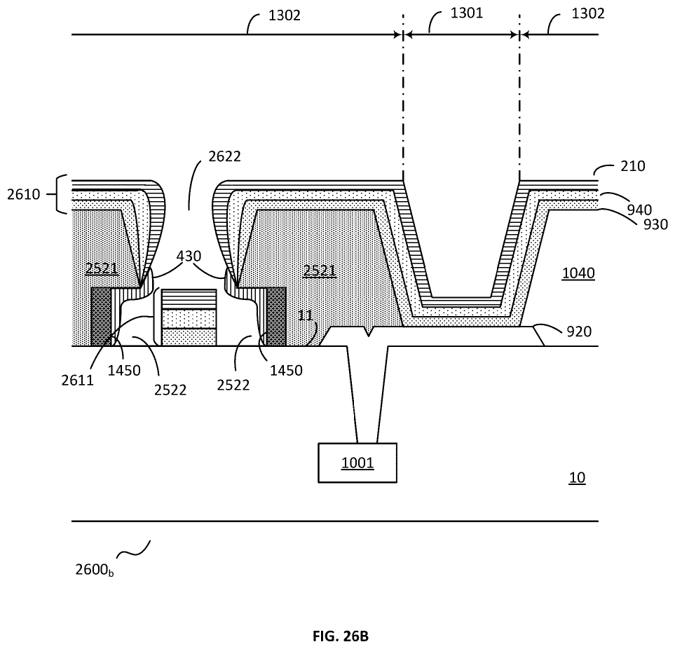

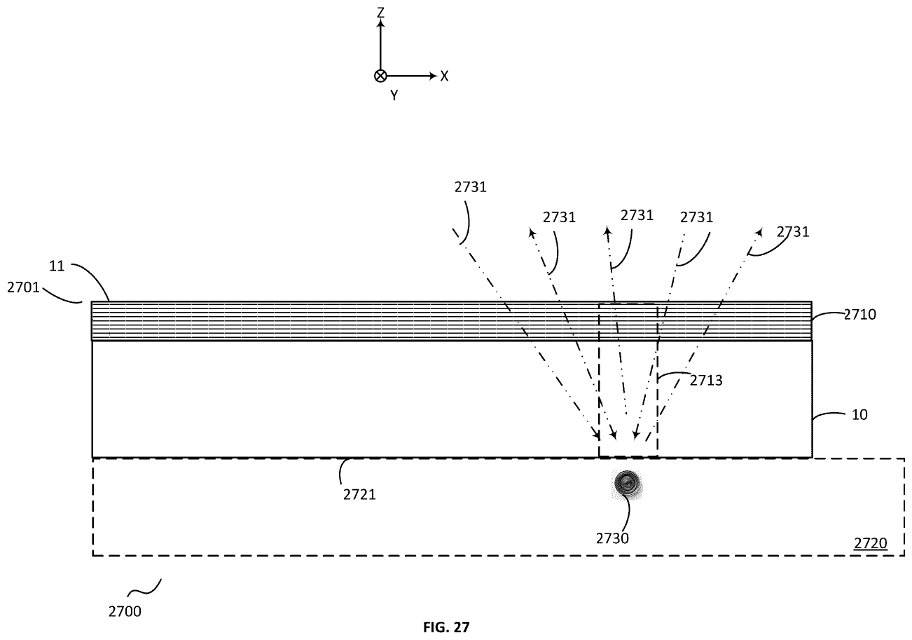

Turning now to FIG. 27, there is shown a cross-sectional view of an example layered device, such as a display panel 2710. In some non-limiting examples, the display panel 2710 may comprise a plurality of layers deposited on a substrate 10, culminating with an outermost layer that forms a face 2701 thereof. In some non-limiting examples, the display panel 2710 may be a version of the device 900.

The face 2701 of the display panel 2710 may extend across a lateral aspect thereof, substantially along a plane defined by the lateral axes. In some non-limiting examples, the face 2701, and indeed the display panel 2710 may act as a face of a user device 2700 through which at least one EM signal 2731 may be exchanged therethrough at an angle relative to the plane of the face 2701. In some non-limiting examples, the user device 2700 may be a computing device, such as, without limitation, a smartphone, a tablet, a laptop, and/or an e-reader, and/or some other electronic device, such as a monitor, a television set, and/or a smart device, including without limitation, an automotive display and/or windshield, a household appliance, and/or a medical, commercial, and/or industrial device.

In some non-limiting examples, the face 2701 may correspond to and/or mate with a body 2720, and/or an opening 2721 therewithin, within which at least one under-display component 2730 may be housed.

In some non-limiting examples, the at least one under-display component 2730 may be formed integrally, or as an assembled module, with the display panel 2710 on a surface thereof opposite to the face 2701. In some non-limiting examples, the at least one under-display component 2730 may be formed on a surface of the substrate 10 of the display panel 2710 opposite to the face 2701.

In some non-limiting examples, at least one aperture 2713 may be formed in the display panel 2710 to allow for the exchange of at least one EM signal 2731 through the face 2701 of the display panel 2710, at an angle to the plane defined by the lateral axes, or concomitantly, the layers of the display panel 2710, including without limitation, the face 2701 of the display panel 2710.

In some non-limiting examples, the at least one aperture 2713 may be understood to comprise the absence and/or reduction in thickness and/or opacity of a substantially opaque coating otherwise disposed across the display panel 2710.

In other words, the at least one EM signal 2731 may pass through the at least one aperture such that it passes through the face 2701. As a result, the at least one EM signal 2731 may be considered to exclude any EM radiation that may extend along the plane defined by the lateral axes, including without limitation, any electric current that may be conducted across a deposited layer 430 laterally across the display panel 2710.

Further, those having ordinary skill in the relevant art will appreciate that the at least one EM signal 2731 may be differentiated from EM radiation per se, including without limitation, electric current, and/or an electric field generated thereby, in that the at least one EM signal 2731 may convey, either alone, or in conjunction with other EM signals 2731, some information content, including without limitation, an identifier by which the at least one EM signal 2731 may be distinguished from other EM signals 2731. In some non-limiting examples, the information content may be conveyed by: specifying, altering, and/or modulating at least one of: the wavelength, frequency, phase, timing, bandwidth, resistance, capacitance, impedance, conductance, and/or other characteristic of the at least one EM signal 331.

In some non-limiting examples, the at least one EM signal 2731 passing through the at least one aperture 2713 of the display panel 2710 may comprise at least one photon and, in some non-limiting examples, may have a wavelength spectrum that lies, without limitation, within at least one of: the visible spectrum, the IR spectrum, and/or the NIR spectrum.

In some non-limiting examples, the EM signal passing through the at least one aperture 2713 of the display panel 2710 may comprise ambient light incident thereon.

In some non-limiting examples, the at least one EM signal 2731 exchanged through the at least one aperture 2713 of the display panel 2710 may be transmitted and/or received by the at least one under-display component 2730.

In some non-limiting examples, the at least one under-display component 2730 may have a size that is greater than a single light transmissive region 2120, but may underlie not only a plurality of light transmissive regions 2120 but also at least one emissive region 1301 extending therebetween. Similarly, in some non-limiting examples, the at least one under-display component 2730 may have a size that is greater than a single one of the at least one apertures 2713.

In some non-limiting examples, the at least one under-display component 2730 may comprise a receiver 2730ᵣ adapted to receive and process at least one EM signal 2731 passing through the at least one aperture 2713 from beyond the user device 2700. Non-limiting examples of such receiver 2730ᵣ include an under-display camera (UDC), and/or a sensor, including without limitation, an IR sensor, an NIR sensor, a LIDAR sensing module, a fingerprint sensing module, an optical sensing module, an IR (proximity) sensing module, an iris recognition sensing module, and/or a facial recognition sensing module.

In some non-limiting examples, the at least one under-display component 2730 may comprise a transmitter 2730ₜ adapted to emit at least one EM signal 2731 passing through the at least one aperture 2713 beyond the user device 2700. Non-limiting examples of such transmitter 2730ₜ include a source of EM radiation, including without limitation, a built-in flash, a flashlight, an IR emitter, and/or an NIR emitter, and/or a LIDAR sensing module, a fingerprint sensing module, an optical sensing module, an IR (proximity) sensing module, an iris recognition sensing module, and/or a facial recognition sensing module.

In some non-limiting examples, the at least one EM signal 2731 passing through the at least one aperture 2713 of the display panel 2710 beyond the user device 2700, including without limitation, those emitted by the at least one under-display component 2730 that comprises a transmitter 2730ₜ, may emanate from the display panel 2710 and pass back through the at least one aperture 2713 of the display panel 2710 to at least one under-display component 2730 that comprises a receiver 2730ᵣ.

In some non-limiting examples, there may be a plurality of under-display components 2730 within the user device 2700, a first one of which comprises a transmitter 2730ₜ for emitting at least one EM signal 2731 to pass through the at least one aperture 2713, beyond the user device 2700, and a second one of which comprises a receiver 2730ᵣ, for receiving at least one EM signal 2731. In some non-limiting examples, such transmitter 2730ₜ and receiver 2730ᵣ may be embodied in a single, common one of the at least one under-display components 2730.

In some non-limiting examples, the at least one under-display component 2730 may not emit EM signals 2731, but rather the display panel 2710 that forms the face 2701 may comprise an opto-electronic device, including without limitation, an opto-luminescent device, including without limitation, an OLED device that emits at least one EM signal 2731.

### Diffraction Reduction

It has been discovered that, in some non-limiting examples, the at least one EM signal 2731 passing through the at least one aperture 2713 may be impacted by a diffraction characteristic of a diffraction pattern imposed by a shape of the at least one aperture 2713.

At least in some non-limiting examples, a display panel 2710 that causes at least one EM signal 2731 to pass through the at least one aperture 2713 that is shaped to exhibit a distinctive and non-uniform diffraction pattern, may interfere with the capture of an image and/or EM radiation pattern represented thereby.

By way of non-limiting example, such diffraction pattern may interfere with an ability to facilitate mitigating interference by such diffraction pattern, that is, to permit an under-display component 2730 to be able to accurately receive and process such image or pattern, even with the application of optical post-processing techniques, or to allow a viewer of such image and/or pattern through such display panel 2710 to discern information contained therein.

In some non-limiting examples, a distinctive and/or non-uniform diffraction pattern may result from a shape of the at least one aperture 2713 that may cause distinct and/or angularly separated diffraction spikes in the diffraction pattern.

In some non-limiting examples, a first diffraction spike may be distinguished from a second proximate diffraction spike by simple observation, such that a total number of diffraction spikes along a full angular revolution may be counted. However, in some non-limiting examples, especially where the number of diffraction spikes is large, it may be more difficult to identify individual diffraction spikes. In such circumstances, the distortion effect of the resulting diffraction pattern may in fact facilitate mitigation of the interference caused thereby, since the distortion effect tends to be blurred and/or distributed more evenly. Such blurring and/or more even distribution of the distortion effect may, in some non-limiting examples, be more amenable to mitigation, including without limitation, by optical post-processing techniques, in order to recover the original image and/or information contained therein.

In some non-limiting examples, an ability to facilitate mitigation of the interference caused by the diffraction pattern may increase as the number of diffraction spikes increases.

In some non-limiting examples, a distinctive and non-uniform diffraction pattern may result from a shape of the at least one aperture 2713 that increase a length of a pattern boundary within the diffraction pattern between region(s) of high intensity of EM radiation and region(s) of low intensity of EM radiation as a function of a pattern circumference of the diffraction pattern and/or that reduces a ratio of the pattern circumference relative to the length of the pattern boundary thereof.

Without wishing to be bound by any specific theory, it may be postulated that display panels 2710 having closed boundaries of light transmissive regions 2120 defined by a corresponding aperture 2713 that are polygonal may exhibit a distinctive and non-uniform diffraction pattern that may adversely impact an ability to facilitate mitigation of interference caused by the diffraction pattern, relative to a display panel 2710 having closed boundaries of light transmissive regions 2120 defined by a corresponding aperture 2713 that is non-polygonal.

In the present disclosure, the term “polygonal” may refer generally to shapes, figures, closed boundaries, and/or perimeters formed by a finite number of linear and/or straight segments and the term “non-polygonal” may refer generally to shapes, figures, closed boundaries, and/or perimeters that are not polygonal. By way of non-limiting example, a closed boundary formed by a finite number of linear segments and at least one non-linear or curved segment may be considered non-polygonal.

Without wishing to be bound by a particular theory, it may be postulated that when a closed boundary of a light transmissive region 2120 defined by a corresponding aperture 2713 comprises at least one non-linear and/or curved segment, EM signals incident thereon and transmitted therethrough may exhibit a less distinctive and/or more uniform diffraction pattern that facilitates mitigation of interference caused by the diffraction pattern.

In some non-limiting examples, a display panel 2710 having a closed boundary of the light transmissive regions 2120 defined by a corresponding aperture 2713 that is substantially elliptical and/or circular may further facilitate mitigation of interference caused by the diffraction pattern.

In some non-limiting examples, an aperture 2713 may be defined by a finite plurality of convex rounded segments. In some non-limiting examples, at least some of these segments coincide at a concave notch or peak.

### Removal of Selective Coating

In some non-limiting examples, the patterning coating 210 may be removed after deposition of the deposited layer 430, such that at least a part of a previously exposed layer surface 11 of an underlying material covered by the patterning coating 210 may become exposed once again. In some non-limiting examples, the patterning coating 210 may be selectively removed by etching, and/or dissolving the patterning coating 210, and/or by employing plasma, and/or solvent processing techniques that do not substantially affect or erode the deposited layer 430.

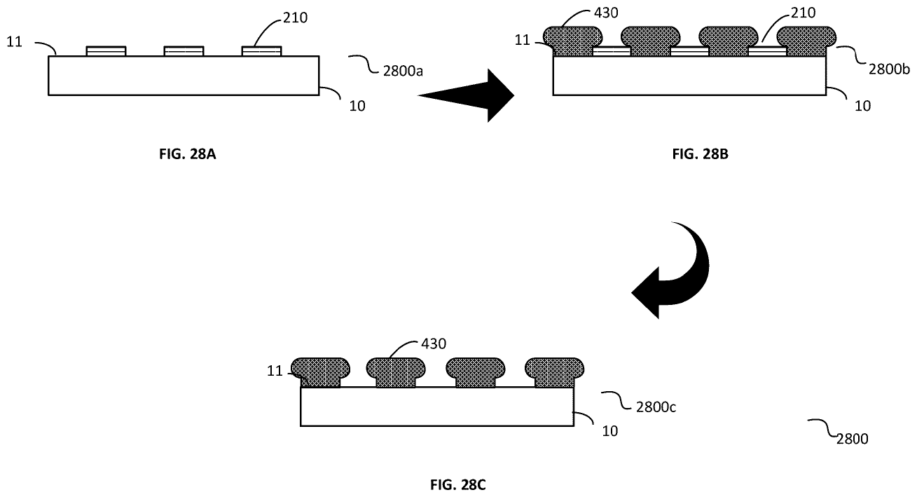

Turning now to FIG. 28A, there may be shown an example cross-sectional view of an example version 2800 of the device 900, at a deposition stage 2800a, in which a patterning coating 210 may have been selectively deposited on a first portion 301 of an exposed layer surface 11 of an underlying material. In the figure, the underlying material may be the substrate 10.

In FIG. 28B, the device 2800 may be shown at a deposition stage 2800b, in which a deposited layer 430 may be deposited on the exposed layer surface 11 of the underlying material, that is, on both the exposed layer surface 11 of patterning coating 210 where the patterning coating 210 may have been deposited during the stage 2800a, as well as the exposed layer surface 11 of the substrate 10 where that patterning coating 210 may not have been deposited during the stage 2800a. Because of the nucleation-inhibiting properties of the first portion 301 where the patterning coating 210 may have been disposed, the deposited layer 430 disposed thereon may tend to not remain, resulting in a pattern of selective deposition of the deposited layer 430, that may correspond to a second portion 302, leaving the first portion 301 substantially devoid of the deposited layer 430.

In FIG. 28C, the device 2800 may be shown at a deposition stage 2800c, in which the patterning coating 210 may have been removed from the first portion 301 of the exposed layer surface 11 of the substrate 10, such that the deposited layer 430 deposited during the stage 2800b may remain on the substrate 10 and regions of the substrate 10 on which the patterning coating 210 may have been deposited during the stage 2800a may now be exposed or uncovered.

In some non-limiting examples, the removal of the patterning coating 210 in the stage 2800c may be effected by exposing the device 2800 to a solvent, and/or a plasma that reacts with, and/or etches away the patterning coating 210 without substantially impacting the deposited layer 430.

### Method Actions

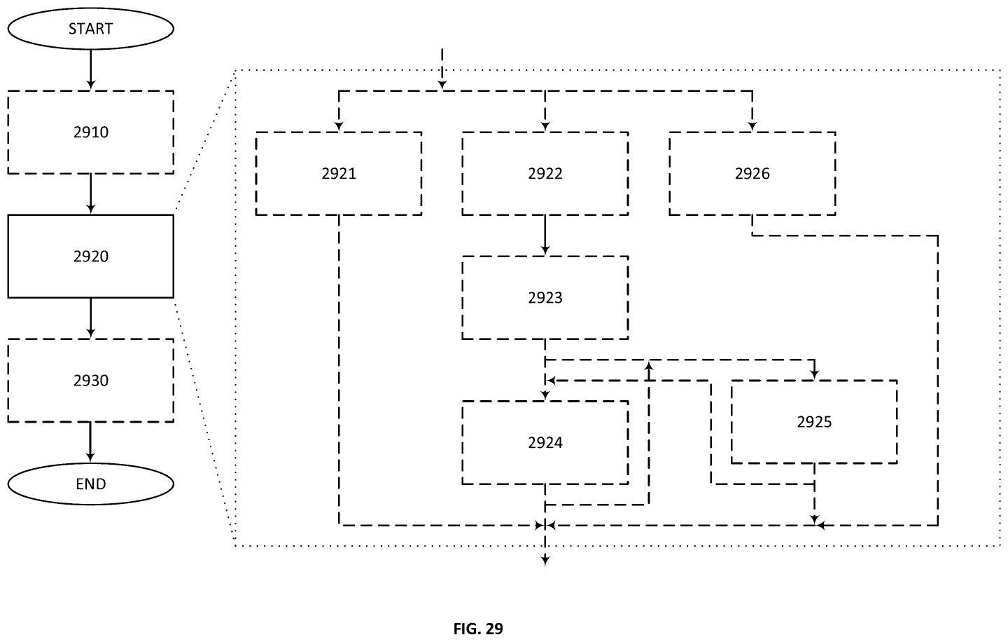

Turning now to FIG. 29, there is shown a flow chart, shown generally at 2900, showing example actions taken to manufacture a semiconductor device having a plurality of layers that facilitates absorption of EM radiation incident thereon:

One example action 2920 is to: deposit at least one particle structure comprising a deposited material in at least one EM radiation-absorbing layer on a first layer surface.

In some non-limiting examples, the action 2920 may comprise an action 2921 to: seed the first layer surface with at least one seed about which the deposited material tends to coalesce.

In some non-limiting examples, the action 2920 may comprise actions 2923 and 2924.

The action 2923 may be to: dispose a patterning coating on a second layer surface in a first portion of the lateral aspect, wherein an initial sticking probability against deposition of the deposited material on a surface of the patterning coating may be substantially less than the initial sticking probability against deposition of the deposited material on the second layer surface.

The action 2924 may be to: expose the device to the deposited material such that the at least one particle structure is deposited in a second portion of the lateral aspect that is substantially devoid of the patterning coating.

In some non-limiting examples, the action 2923 may be preceded by an action 2922 to: seed the first layer surface with at least one seed about which the deposited material tends to coalesce, such that the at least one seed is substantially covered by the pattering coating in the first portion.

In some non-limiting examples, the action 2923 may be followed by an action 2925 to: seed the first layer surface with at least one seed, comprising a seed material, about which the deposited material tends to coalesce, wherein an initial sticking probability against deposition of the seed material on a surface of the patterning coating is substantially less than the initial sticking probability against deposition of the seed material onto the second layer surface, such that the first portion is substantially devoid of the seeds.

In some non-limiting examples, the action 2920 may comprise an action 2926 to: co-deposit the deposited material with a co-deposited dielectric material

In some non-limiting examples, the action 2920 may be preceded by an action 2910 to: establish a supporting dielectric layer as a first layer surface.

In some non-limiting examples, the action 2920 may be followed by an action 2030 to: cover the at least one EM radiation-absorbing layer with a covering dielectric layer.

### Thin Film Formation

The formation of thin films during vapor deposition on an exposed layer surface 11 of an underlying layer may involve processes of nucleation and growth.

During initial stages of film formation, a sufficient number of vapor monomers 632 (which in some non-limiting examples may be molecules, and/or atoms of a deposited material 631 in vapor form 632) may typically condense from a vapor phase to form initial nuclei on the exposed layer surface 11 presented of an underlying layer. As vapor monomers 632 may impinge on such surface, a characteristic size, and/or deposited density of these initial nuclei may increase to form small particle structures 121. Non-limiting examples of a dimension to which such characteristic size refers may include a height, width, length, and/or diameter of such particle structure 121.

After reaching a saturation island density, adjacent particle structures 121 may typically start to coalesce, increasing an average characteristic size of such particle structures 121, while decreasing a deposited density thereof.

With continued vapor deposition of monomers 632, coalescence of adjacent particle structures 121 may continue until a substantially closed coating 440 may eventually be deposited on an exposed layer surface 11 of an underlying layer. The behaviour, including optical effects caused thereby, of such closed coatings 440 may be generally relatively uniform, consistent, and unsurprising.

There may be at least three basic growth modes for the formation of thin films, in some non-limiting examples, culminating in a closed coating 440: 1) island (Volmer-Weber), 2) layer-by-layer (Frank-van der Merwe), and 3) Stranski-Krastanov.

Island growth may typically occur when stale clusters of monomers 632 nucleate on an exposed layer surface 11 and grow to form discrete islands. This growth mode may occur when the interaction between the monomers 632 is stronger than that between the monomers 632 and the surface.

The nucleation rate may describe how many nuclei of a given size (where the free energy does not push a cluster of such nuclei to either grow or shrink) (“critical nuclei”) may be formed on a surface per unit time. During initial stages of film formation, it may be unlikely that nuclei will grow from direct impingement of monomers 632 on the surface, since the deposited density of nuclei is low, and thus the nuclei may cover a relatively small fraction of the surface (e.g., there are large gaps/spaces between neighboring nuclei). Therefore, the rate at which critical nuclei may grow may typically depend on the rate at which adatoms (e.g., adsorbed monomers 632) on the surface migrate and attach to nearby nuclei.

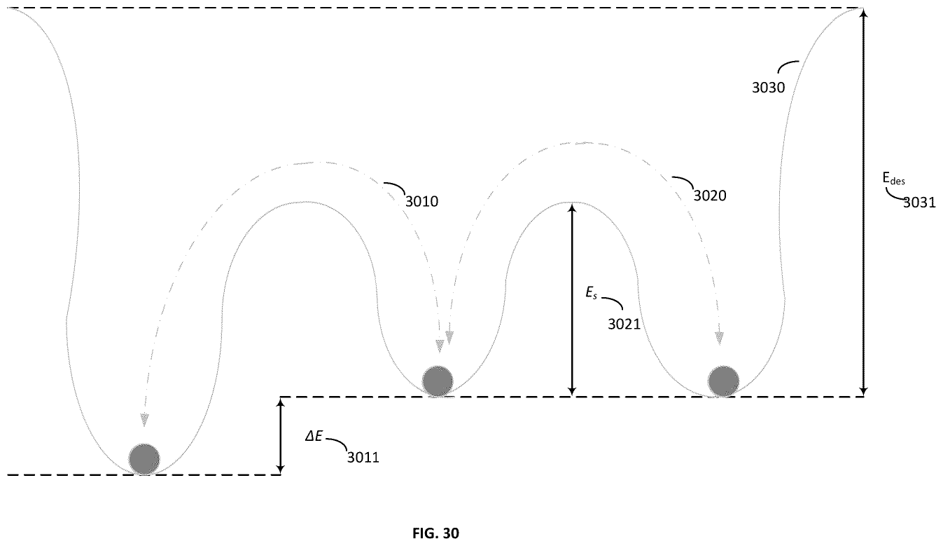

An example of an energy profile of an adatom adsorbed onto an exposed layer surface 11 of an underlying material is illustrated in FIG. 30. Specifically, FIG. 30 may illustrate example qualitative energy profiles corresponding to: an adatom escaping from a local low energy site (1010); diffusion of the adatom on the exposed layer surface 11 (1020); and desorption of the adatom (3030).

In 1010, the local low energy site may be any site on the exposed layer surface 11 of an underlying layer, onto which an adatom will be at a lower energy. Typically, the nucleation site may comprise a defect, and/or an anomaly on the exposed layer surface 11, including without limitation, a ledge, a step edge, a chemical impurity, a bonding site, and/or a kink (“heterogeneity”).

Sites of substrate heterogeneity may increase an energy involved to desorb the adatom from the surface E_{des} 3031, leading to a higher deposited density of nuclei observed at such sites. Also, impurities or contamination on a surface may also increase E_{des} 3031, leading to a higher deposited density of nuclei. For vapor deposition processes, conducted under high vacuum conditions, the type and deposited density of contaminants on a surface may be affected by a vacuum pressure and a composition of residual gases that make up that pressure.

Once the adatom is trapped at the local low energy site, there may typically, in some non-limiting examples, be an energy barrier before surface diffusion takes place. Such energy barrier may be represented as ΔE 3011 in FIG. 30. In some non-limiting examples, if the energy barrier ΔE 3011 to escape the local low energy site is sufficiently large, the site may act as a nucleation site.

In 1020, the adatom may diffuse on the exposed layer surface 11. By way of non-limiting example, in the case of localized absorbates, adatoms may tend to oscillate near a minimum of the surface potential and migrate to various neighboring sites until the adatom is either desorbed, and/or is incorporated into growing particle structures 121 formed by a cluster of adatoms, and/or a growing film. In FIG. 30, the activation energy associated with surface diffusion of adatoms may be represented as Eₛ 3011.

In 3030, the activation energy associated with desorption of the adatom from the surface may be represented as E_{des} 3031. Those having ordinary skill in the relevant art will appreciate that any adatoms that are not desorbed may remain on the exposed layer surface 11. By way of non-limiting example, such adatoms may diffuse on the exposed layer surface 11, become part of a cluster of adatoms that form particle structures 121 on the exposed layer surface 11, and/or be incorporated as part of a growing film, and/or coating.

After adsorption of an adatom on a surface, the adatom may either desorb from the surface, or may migrate some distance on the surface before either desorbing, interacting with other adatoms to form a small cluster, or attaching to a growing nucleus. An average amount of time that an adatom may remain on the surface after initial adsorption may be given by:

$${τ}_{s} = \frac{1}{v} exp ( \frac{{E}_{des}}{k T} ) \qquad ( TF 1 )$$

In the above equation:
v is a vibrational frequency of the adatom on the surface,
k is the Botzmann constant, and
T is temperature.

From Equation TF1 it may be noted that the lower the value of E_{des} 3031, the easier it may be for the adatom to desorb from the surface, and hence the shorter the time the adatom may remain on the surface. A mean distance an adatom can diffuse may be given by,

$$X = {a}_{0} exp ( \frac{{E}_{des} - {E}_{s}}{2 k T} ) \qquad ( TF 2 )$$

where:
α₀ is a lattice constant.

For low values of E_{des} 3031, and/or high values of Eₛ 3021, the adatom may diffuse a shorter distance before desorbing, and hence may be less likely to attach to growing nuclei or interact with another adatom or cluster of adatoms.

During initial stages of formation of a deposited layer of particle structures 121, adsorbed adatoms may interact to form particle structures 121, with a critical concentration of particle structures 121 per unit area being given by,

$$\frac{{N}_{i}}{{n}_{0}} = {\vert \frac{{N}_{1}}{{n}_{0}} \vert}^{i} exp ( \frac{{E}_{i}}{k T} ) \qquad ( TF 3 )$$

where:
Eᵢ is an energy involved to dissociate a critical cluster containing i adatoms into separate adatoms,
n₀ is a total deposited density of adsorption sites, and
N₁ is a monomer deposited density given by:

N₁=\dot{R}τₛ (TF4)

where:
\dot{R} is a vapor impingement rate.

Typically, i may depend on a crystal structure of a material being deposited and may determine a critical size of particle structures 121 to form a stable nucleus.

A critical monomer supply rate for growing particle structures 121 may be given by the rate of vapor impingement and an average area over which an adatom can diffuse before desorbing:

$$\dot{R} {X}^{2} = {α}_{0}^{2} exp ( \frac{{E}_{des} - {E}_{s}}{k T} ) \qquad ( TF 5 )$$

The critical nucleation rate may thus be given by the combination of the above equations:

$${\dot{N}}_{i} = \dot{R} {α}_{0}^{2} {{n}_{0} ( \frac{\dot{R}}{v {n}_{0}} )}^{i} exp ( \frac{( i + 1 ) {E}_{des} - {E}_{s} + {E}_{i}}{k T} ) \qquad ( TF 6 )$$

From the above equation, it may be noted that the critical nucleation rate may be suppressed for surfaces that have a low desorption energy for adsorbed adatoms, a high activation energy for diffusion of an adatom, are at high temperatures, and/or are subjected to vapor impingement rates.

Under high vacuum conditions, a flux 632 of molecules that may impinge on a surface (per cm²-sec) may be given by:

$$ϕ = 3.513 \times 1 {0}^{22} \frac{P}{M T} \qquad ( TF 7 )$$

where:
P is pressure, and
M is molecular weight.

Therefore, a higher partial pressure of a reactive gas, such as H₂O, may lead to a higher deposited density of contamination on a surface during vapor deposition, leading to an increase in E_{des} 3031 and hence a higher deposited density of nuclei.

In the present disclosure, “nucleation-inhibiting” may refer to a coating, material, and/or a layer thereof, that may have a surface that exhibits an initial sticking probability against deposition of a deposited material 631 thereon, that may be close to 0, including without limitation, less than about 0.3, such that the deposition of the deposited material 631 on such surface may be inhibited.

In the present disclosure, “nucleation-promoting” may refer to a coating, material, and/or a layer thereof, that has a surface that exhibits an initial sticking probability against deposition of a deposited material 631 thereon, that may be close to 1, including without limitation, greater than about 0.7, such that the deposition of the deposited material 631 on such surface may be facilitated.

Without wishing to be bound by a particular theory, it may be postulated that the shapes and sizes of such nuclei and the subsequent growth of such nuclei into particle structures 121 and thereafter into a thin film may depend upon various factors, including without limitation, interfacial tensions between the vapor, the surface, and/or the condensed film nuclei.

One measure of a nucleation-inhibiting, and/or nucleation-promoting property of a surface may be the initial sticking probability of the surface against the deposition of a given deposited material 631.

In some non-limiting examples, the sticking probability S may be given by:

where:

$$S = \frac{{N}_{ads}}{{N}_{total}} \qquad ( TF 8 )$$

N_{ads} is a number of adatoms that remain on an exposed layer surface 11 (that is, are incorporated into a film), and
Nₜₒₜₐₗ is a total number of impinging monomers on the surface.

A sticking probability S equal to 1 may indicate that all monomers 632 that impinge on the surface are adsorbed and subsequently incorporated into a growing film. A sticking probability S equal to 0 may indicate that all monomers 632 that impinge on the surface are desorbed and subsequently no film may be formed on the surface.

A sticking probability S of a deposited material 631 on various surfaces may be evaluated using various techniques of measuring the sticking probability S, including without limitation, a dual quartz crystal microbalance (QCM) technique as described by Walker et al., J. Phys. Chem. C 2007, 111, 765 (2006).

As the deposited density of a deposited material 631 may increase (e.g., increasing average film thickness), a sticking probability S may change.

An initial sticking probability S₀ may therefore be specified as a sticking probability S of a surface prior to the formation of any significant number of critical nuclei. One measure of an initial sticking probability S₀ may involve a sticking probability S of a surface against the deposition of a deposited material 631 during an initial stage of deposition thereof, where an average film thickness of the deposited material 631 across the surface is at or below a threshold value. In the description of some non-limiting examples a threshold value for an initial sticking probability may be specified as, by way of non-limiting example, 1 nm. An average sticking probability S may then be given by:

S̅=S₀(1−A_{nuc})+S_{nuc}(A_{nuc}) (TF9)

where:
S_{nuc} is a sticking probability S of an area covered by particle structures 121, and
A_{nuc} is a percentage of an area of a substrate surface covered by particle structures 121.

By way of non-limiting example, a low initial sticking probability may increase with increasing average film thickness. This may be understood based on a difference in sticking probability between an area of an exposed layer surface 11 with no particle structures 121, by way of non-limiting example, a bare substrate 10, and an area with a high deposited density. By way of non-limiting example, a monomer 632 that may impinge on a surface of a particle structure 121 may have a sticking probability that may approach 1.

Based on the energy profiles 1010, 1020, 3030 shown in FIG. 30, it may be postulated that materials that exhibit relatively low activation energy for desorption (E_{des} 3031), and/or relatively high activation energy for surface diffusion (Eₛ 3021), may be deposited as a patterning coating 210, and may be suitable for use in various applications.

Without wishing to be bound by a particular theory, it may be postulated that, in some non-limiting examples, the relationship between various interfacial tensions present during nucleation and growth may be dictated according to Young's equation in capillarity theory:

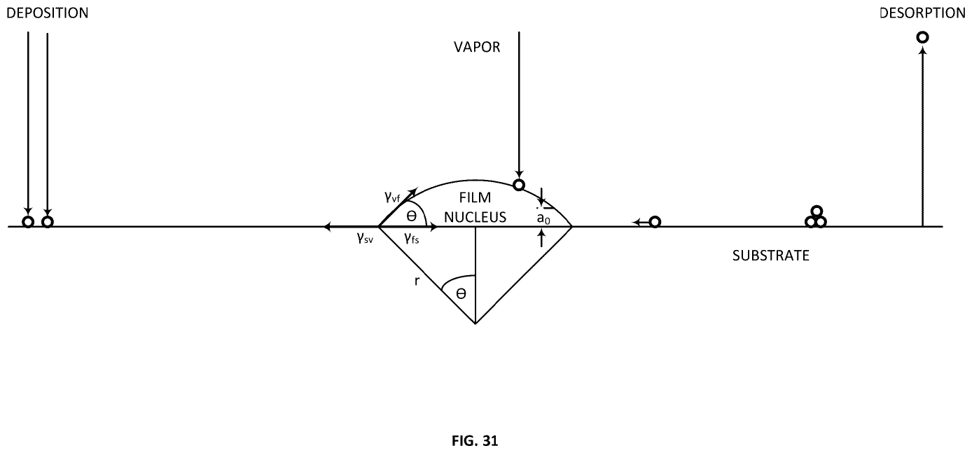

γₛᵥ=γ_{fs}+γ_{vf} cos θ (TF10)

where:
γₛᵥ (FIG. 31) corresponds to the interfacial tension between the substrate 10 and vapor 632,
γ_{fs} (FIG. 31) corresponds to the interfacial tension between the deposited material 631 and the substrate 10,
γ_{vf} (FIG. 31) corresponds to the interfacial tension between the vapor 632 and the film, and
θ is the film nucleus contact angle.

FIG. 31 may illustrate the relationship between the various parameters represented in this equation.

On the basis of Young's equation (Equation (TF10)), it may be derived that, for island growth, the film nucleus contact angle may exceed 0 and therefore: γₛᵥ<γ_{fs}+γ_{vf}.

For layer growth, where the deposited material 631 may “wet” the substrate 10, the nucleus contact angle θ may be equal to 0, and therefore: γₛᵥ=γ_{fs}+γ_{vf}.

For Stranski-Krastanov growth, where the strain energy per unit area of the film overgrowth may be large with respect to the interfacial tension between the vapor 632 and the deposited material 631: γₛᵥ>γ_{fs}+γ_{vf}.

Without wishing to be bound by any particular theory, it may be postulated that the nucleation and growth mode of a deposited material 631 at an interface between the patterning coating 210 and the exposed layer surface 11 of the substrate 10, may follow the island growth model, where θ>0.

Particularly in cases where the patterning coating 210 may exhibit a relatively low initial sticking probability (in some non-limiting examples, under the conditions identified in the dual QCM technique described by Walker et. al) against deposition of the deposited material 631, there may be a relatively high thin film contact angle of the deposited material 631.

On the contrary, when a deposited material 631 may be selectively deposited on an exposed layer surface 11 without the use of a patterning coating 210, by way of non-limiting example, by employing a shadow mask 515, the nucleation and growth mode of such deposited material 631 may differ. In particular, it has been observed that a coating formed using a shadow mask 515 patterning process may, at least in some non-limiting examples, exhibit relatively low thin film contact angle of less than about 10°.

It has now been found, somewhat surprisingly, that in some non-limiting examples, a patterning coating 210 (and/or the patterning material 511 of which it is comprised) may exhibit a relatively low critical surface tension.

Those having ordinary skill in the relevant art will appreciate that a “surface energy” of a coating, layer, and/or a material constituting such coating, and/or layer, may generally correspond to a critical surface tension of the coating, layer, and/or material. According to some models of surface energy, the critical surface tension of a surface may correspond substantially to the surface energy of such surface.

Generally, a material with a low surface energy may exhibit low intermolecular forces. Generally, a material with low intermolecular forces may readily crystallize or undergo other phase transformation at a lower temperature in comparison to another material with high intermolecular forces. In at least some applications, a material that may readily crystallize or undergo other phase transformations at relatively low temperatures may be detrimental to the long-term performance, stability, reliability, and/or lifetime of the device.

Without wishing to be bound by a particular theory, it may be postulated that certain low energy surfaces may exhibit relatively low initial sticking probabilities and may thus be suitable for forming the patterning coating 210.

Without wishing to be bound by any particular theory, it may be postulated that, especially for low surface energy surfaces, the critical surface tension may be positively correlated with the surface energy. By way of non-limiting example, a surface exhibiting a relatively low critical surface tension may also exhibit a relatively low surface energy, and a surface exhibiting a relatively high critical surface tension may also exhibit a relatively high surface energy.

In reference to Young's equation (Equation (TF10)), a lower surface energy may result in a greater contact angle, while also lowering the γₛᵥ, thus enhancing the likelihood of such surface having low wettability and low initial sticking probability with respect to the deposited material 631.

The critical surface tension values, in various non-limiting examples, herein may correspond to such values measured at around normal temperature and pressure (NTP), which in some non-limiting examples, may correspond to a temperature of 20° C., and an absolute pressure of 1 atm. In some non-limiting examples, the critical surface tension of a surface may be determined according to the Zisman method, as further detailed in Zisman, W. A., “Advances in Chemistry” 43 (1964), p. 1-51.

In some non-limiting examples, the exposed layer surface 11 of the patterning coating 210 may exhibit a critical surface tension of no more than at least one of about: 20 dynes/cm, 19 dynes/cm, 18 dynes/cm, 17 dynes/cm, 16 dynes/cm, 15 dynes/cm, 13 dynes/cm, 12 dynes/cm, or 11 dynes/cm.

In some non-limiting examples, the exposed layer surface 11 of the patterning coating 210 may exhibit a critical surface tension of at least one of at least about: 6 dynes/cm, 7 dynes/cm, 8 dynes/cm, 9 dynes/cm, and 10 dynes/cm.

Those having ordinary skill in the relevant art will appreciate that various methods and theories for determining the surface energy of a solid may be known. By way of non-limiting example, the surface energy may be calculated, and/or derived based on a series of measurements of contact angle, in which various liquids are brought into contact with a surface of a solid to measure the contact angle between the liquid-vapor interface and the surface. In some non-limiting examples, the surface energy of a solid surface may be equal to the surface tension of a liquid with the highest surface tension that completely wets the surface. By way of non-limiting example, a Zisman plot may be used to determine the highest surface tension value that would result in a contact angle of 0° with the surface. According to some theories of surface energy, various types of interactions between solid surfaces and liquids may be considered in determining the surface energy of the solid. By way of non-limiting example, according to some theories, including without limitation, the Owens/Wendt theory, and/or Fowkes' theory, the surface energy may comprise a dispersive component and a non-dispersive or “polar” component.

Without wishing to be bound by a particular theory, it may be postulated that, in some non-limiting examples, the contact angle of a coating of deposited material 631 may be determined, based at least partially on the properties (including, without limitation, initial sticking probability) of the patterning coating 210 onto which the deposited material 631 is deposited. Accordingly, patterning materials 511 that allow selective deposition of deposited materials 631 exhibiting relatively high contact angles may provide some benefit.

Those having ordinary skill in the relevant art will appreciate that various methods may be used to measure a contact angle θ, including without limitation, the static, and/or dynamic sessile drop method and the pendant drop method.

In some non-limiting examples, the activation energy for desorption (E_{des} 3031) (in some non-limiting examples, at a temperature T of about 300K) may be no more than at least one of about: 2 times, 1.5 times, 1.3 times, 1.2 times, 1.0 times, 0.8 times, or 0.5 times, the thermal energy. In some non-limiting examples, the activation energy for surface diffusion (Eₛ 3021) (in some non-limiting examples, at a temperature of about 300K) may exceed at least one of about: 1.0 times, 1.5 times, 1.8 times, 2 times, 3 times, 5 times, 7 times, or 10 times the thermal energy.

Without wishing to be bound by a particular theory, it may be postulated that, during thin film nucleation and growth of a deposited material 631 at, and/or near an interface between the exposed layer surface 11 of the underlying layer and the patterning coating 210, a relatively high contact angle between the edge of the deposited material 631 and the underlying layer may be observed due to the inhibition of nucleation of the solid surface of the deposited material 631 by the patterning coating 210. Such nucleation inhibiting property may be driven by minimization of surface energy between the underlying layer, thin film vapor and the patterning coating 210.

One measure of a nucleation-inhibiting, and/or nucleation-promoting property of a surface may be an initial deposition rate of a given (electrically conductive) deposited material 631, on the surface, relative to an initial deposition rate of the same deposited material 631 on a reference surface, where both surfaces are subjected to, and/or exposed to an evaporation flux of the deposited material 631.

### Definitions

In some non-limiting examples, the opto-electronic device may be an electro-luminescent device. In some non-limiting examples, the electro-luminescent device may be an organic light-emitting diode (OLED) device. In some non-limiting examples, the electro-luminescent device may be part of an electronic device. By way of non-limiting example, the electro-luminescent device may be an OLED lighting panel or module, and/or an OLED display or module of a computing device, such as a smartphone, a tablet, a laptop, an e-reader, and/or of some other electronic device such as a monitor, and/or a television set.

In some non-limiting examples, the opto-electronic device may be an organic photo-voltaic (OPV) device that converts photons into electricity. In some non-limiting examples, the opto-electronic device may be an electro-luminescent quantum dot (QD) device.

In the present disclosure, unless specifically indicated to the contrary, reference will be made to OLED devices, with the understanding that such disclosure could, in some examples, equally be made applicable to other opto-electronic devices, including without limitation, an OPV, and/or QD device, in a manner apparent to those having ordinary skill in the relevant art.

The structure of such devices may be described from each of two aspects, namely from a cross-sectional aspect, and/or from a lateral (plan view) aspect.

In the present disclosure, a directional convention may be followed, extending substantially normally to the lateral aspect described above, in which the substrate may be the “bottom” of the device, and the layers may be disposed on “top” of the substrate. Following such convention, the second electrode may be at the top of the device shown, even if (as may be the case in some examples, including without limitation, during a manufacturing process, in which at least one layers may be introduced by means of a vapor deposition process), the substrate may be physically inverted, such that the top surface, in which one of the layers, such as, without limitation, the first electrode, may be disposed, may be physically below the substrate, to allow the deposition material (not shown) to move upward and be deposited upon the top surface thereof as a thin film.

In the context of introducing the cross-sectional aspect herein, the components of such devices may be shown in substantially planar lateral strata. Those having ordinary skill in the relevant art will appreciate that such substantially planar representation may be for purposes of illustration only, and that across a lateral extent of such a device, there may be localized substantially planar strata of different thicknesses and dimension, including, in some non-limiting examples, the substantially complete absence of a layer, and/or layer(s) separated by non-planar transition regions (including lateral gaps and even discontinuities). Thus, while for illustrative purposes, the device may be shown below in its cross-sectional aspect as a substantially stratified structure, in the plan view aspect discussed below, such device may illustrate a diverse topography to define features, each of which may substantially exhibit the stratified profile discussed in the cross-sectional aspect.

In the present disclosure, the terms “layer” and “strata” may be used interchangeably to refer to similar concepts.

The thickness of each layer shown in the figures may be illustrative only and not necessarily representative of a thickness relative to another layer.

For purposes of simplicity of description, in the present disclosure, a combination of a plurality of elements in a single layer may be denoted by a colon “:”, while a plurality of (combination(s) of) elements comprising a plurality of layers in a multi-layer coating may be denoted by separating two such layers by a slash “/”. In some non-limiting examples, the layer after the slash may be deposited after, and/or on the layer preceding the slash.

For purposes of illustration, an exposed layer surface of an underlying material, onto which a coating, layer, and/or material may be deposited, may be understood to be a surface of such underlying material that may be presented for deposition of the coating, layer, and/or material thereon, at the time of deposition.

Those having ordinary skill in the relevant art will appreciate that when a component, a layer, a region, and/or a portion thereof, is referred to as being “formed”, “disposed”, and/or “deposited” on, and/or over another underlying material, component, layer, region, and/or portion, such formation, disposition, and/or deposition may be directly, and/or indirectly on an exposed layer surface (at the time of such formation, disposition, and/or deposition) of such underlying material, component, layer, region, and/or portion, with the potential of intervening material(s), component(s), layer(s), region(s), and/or portion(s) therebetween.

In the present disclosure, the terms “overlap”, and/or “overlapping” may refer generally to a plurality of layers, and/or structures arranged to intersect a cross-sectional axis extending substantially normally away from a surface onto which such layers, and/or structures may be disposed.

While the present disclosure discusses thin film formation, in reference to at least one layer or coating, in terms of vapor deposition, those having ordinary skill in the relevant art will appreciate that, in some non-limiting examples, various components of the device may be selectively deposited using a wide variety of techniques, including without limitation, evaporation (including without limitation, thermal evaporation, and/or electron beam evaporation), photolithography, printing (including without limitation, ink jet, and/or vapor jet printing, reel-to-reel printing, and/or micro-contact transfer printing), PVD (including without limitation, sputtering), chemical vapor deposition (CVD) (including without limitation, plasma-enhanced CVD (PECVD), and/or organic vapor phase deposition (OVPD)), laser annealing, laser-induced thermal imaging (LITI) patterning, atomic-layer deposition (ALD), coating (including without limitation, spin-coating, di coating, line coating, and/or spray coating), and/or combinations thereof (collectively “deposition process”).

Some processes may be used in combination with a shadow mask, which may, in some non-limiting examples, may be an open mask, and/or FMM, during deposition of any of various layers, and/or coatings to achieve various patterns by masking, and/or precluding deposition of a deposited material on certain parts of a surface of an underlying material exposed thereto.

In the present disclosure, the terms “evaporation”, and/or “sublimation” may be used interchangeably to refer generally to deposition processes in which a source material is converted into a vapor, including without limitation, by heating, to be deposited onto a target surface in, without limitation, a solid state. As will be understood, an evaporation deposition process may be a type of PVD process where at least one source material is evaporated, and/or sublimed under a low pressure (including without limitation, a vacuum) environment to form vapor monomers, and deposited on a target surface through de-sublimation of the at least one evaporated source material. A variety of different evaporation sources may be used for heating a source material, and, as such, it will be appreciated by those having ordinary skill in the relevant art, that the source material may be heated in various ways. By way of non-limiting example, the source material may be heated by an electric filament, electron beam, inductive heating, and/or by resistive heating. In some non-limiting examples, the source material may be loaded into a heated crucible, a heated boat, a Knudsen cell (which may be an effusion evaporator source), and/or any other type of evaporation source.

In some non-limiting examples, a deposition source material may be a mixture. In some non-limiting examples, at least one component of a mixture of a deposition source material may not be deposited during the deposition process (or, in some non-limiting examples, be deposited in a relatively small amount compared to other components of such mixture).

In the present disclosure, a reference to a layer thickness, a film thickness, and/or an average layer, and/or film thickness, of a material, irrespective of the mechanism of deposition thereof, may refer to an amount of the material deposited on a target exposed layer surface, which corresponds to an amount of the material to cover the target surface with a uniformly thick layer of the material having the referenced layer thickness. By way of non-limiting example, depositing a layer thickness of 10 nm of material may indicate that an amount of the material deposited on the surface may correspond to an amount of the material to form a uniformly thick layer of the material that may be 10 nm thick. It will be appreciated that, having regard to the mechanism by which thin films are formed discussed above, by way of non-limiting example, due to possible stacking or clustering of monomers, an actual thickness of the deposited material may be non-uniform. By way of non-limiting example, depositing a layer thickness of 10 nm may yield some parts of the deposited material 631 having an actual thickness greater than 10 nm, or other parts of the deposited material 631 having an actual thickness of no more than 10 nm. A certain layer thickness of a material deposited on a surface may thus correspond, in some non-limiting examples, to an average thickness of the deposited material across the target surface.

In the present disclosure, a reference to a reference layer thickness may refer to a layer thickness of the deposited material (such as Mg), that may be deposited on a reference surface exhibiting a high initial sticking probability or initial sticking coefficient (that is, a surface having an initial sticking probability that is about, and/or close to 1.0). The reference layer thickness may not indicate an actual thickness of the deposited material deposited on a target surface (such as, without limitation, a surface of a patterning coating). Rather, the reference layer thickness may refer to a layer thickness of the deposited material that would be deposited on a reference surface, in some non-limiting examples, a surface of a quartz crystal, positioned inside a deposition chamber for monitoring a deposition rate and the reference layer thickness, upon subjecting the target surface and the reference surface to identical vapor flux of the deposited material for the same deposition period. Those having ordinary skill in the relevant art will appreciate that in the event that the target surface and the reference surface are not subjected to identical vapor flux simultaneously during deposition, an appropriate tooling factor may be used to determine, and/or to monitor the reference layer thickness.

In the present disclosure, a reference deposition rate may refer to a rate at which a layer of the deposited material would grow on the reference surface, if it were identically positioned and configured within a deposition chamber as the sample surface.

In the present disclosure, a reference to depositing a number X of monolayers of material may refer to depositing an amount of the material to cover a given area of an exposed layer surface with X single layer(s) of constituent monomers of the material, such as, without limitation, in a closed coating.

In the present disclosure, a reference to depositing a fraction of a monolayer of a material may refer to depositing an amount of the material to cover such fraction of a given area of an exposed layer surface with a single layer of constituent monomers of the material. Those having ordinary skill in the relevant art will appreciate that due to, by way of non-limiting example, possible stacking, and/or clustering of monomers, an actual local thickness of a deposited material across a given area of a surface may be non-uniform. By way of non-limiting example, depositing 1 monolayer of a material may result in some local regions of the given area of the surface being uncovered by the material, while other local regions of the given area of the surface may have multiple atomic, and/or molecular layers deposited thereon.

In the present disclosure a target surface (and/or target region(s) thereof) may be considered to be “substantially devoid of”, “substantially free of”, and/or “substantially uncovered by” a material if there may be a substantial absence of the material on the target surface as determined by any suitable determination mechanism.

In the present disclosure, the terms “sticking probability” and “sticking coefficient” may be used interchangeably.

In the present disclosure, the term “nucleation” may reference a nucleation stage of a thin film formation process, in which monomers in a vapor phase condense onto a surface to form nuclei.

In the present disclosure, in some non-limiting examples, as the context dictates, the terms “patterning coating” and “patterning material” may be used interchangeably to refer to similar concepts, and references to a patterning coating herein, in the context of being selectively deposited to pattern a deposited layer may, in some non-limiting examples, be applicable to a patterning material in the context of selective deposition thereof to pattern a deposited material, and/or an electrode coating material.

Similarly, in some non-limiting examples, as the context dictates, the term “patterning coating” and “patterning material” may be used interchangeably to refer to similar concepts, and reference to an NPC herein, in the context of being selectively deposited to pattern a deposited layer may, in some non-limiting examples, be applicable to an NPC in the context of selective deposition thereof to pattern a deposited material, and/or an electrode coating.

While a patterning material may be either nucleation-inhibiting or nucleation-promoting, in the present disclosure, unless the context dictates otherwise, a reference herein to a patterning material is intended to be a reference to an NIC.

In some non-limiting examples, reference to a patterning coating may signify a coating having a specific composition as described herein.

In the present disclosure, the terms “deposited layer”, “conductive coating”, and “electrode coating” may be used interchangeably to refer to similar concepts and references to a deposited layer herein, in the context of being patterned by selective deposition of a patterning coating, and/or an NPC may, in some non-limiting examples, be applicable to a deposited layer in the context of being patterned by selective deposition of a patterning material. In some non-limiting examples, reference to an electrode coating may signify a coating having a specific composition as described herein. Similarly, in the present disclosure, the terms “deposited layer material”, “deposited material”, “conductive coating material”, and “electrode coating material” may be used interchangeably to refer to similar concepts and references to a deposited material herein.

In the present disclosure, it will be appreciated by those having ordinary skill in the relevant art that an organic material may comprise, without limitation, a wide variety of organic molecules, and/or organic polymers. Further, it will be appreciated by those having ordinary skill in the relevant art that organic materials that are doped with various inorganic substances, including without limitation, elements, and/or inorganic compounds, may still be considered organic materials. Still further, it will be appreciated by those having ordinary skill in the relevant art that various organic materials may be used, and that the processes described herein are generally applicable to an entire range of such organic materials. Still further, it will be appreciated by those having ordinary skill in the relevant art that organic materials that contain metals, and/or other organic elements, may still be considered as organic materials. Still further, it will be appreciated by those having ordinary skill in the relevant art that various organic materials may be molecules, oligomers, and/or polymers.

As used herein, an organic-inorganic hybrid material may generally refer to a material that comprises both an organic component and an inorganic component. In some non-limiting examples, such organic-inorganic hybrid material may comprise an organic-inorganic hybrid compound that comprises an organic moiety and an inorganic moiety. Non-limiting examples of such organic-inorganic hybrid compounds include those in which an inorganic scaffold is functionalized with at least one organic functional group. Non-limiting examples of such organic-inorganic hybrid materials include those comprising at least one of: a siloxane group, a silsesquioxane group, a polyhedral oligomeric silsesquioxane (POSS) group, a phosphazene group, and a metal complex.

In the present disclosure, a semiconductor material may be described as a material that generally exhibits a band gap. In some non-limiting examples, the band gap may be formed between a highest occupied molecular orbital (HOMO) and a lowest unoccupied molecular orbital (LUMO) of the semiconductor material. Semiconductor materials thus generally exhibit electrical conductivity that is no more than that of a conductive material (including without limitation, a metal), but that is greater than that of an insulating material (including without limitation, a glass). In some non-limiting examples, the semiconductor material may comprise an organic semiconductor material. In some non-limiting examples, the semiconductor material may comprise an inorganic semiconductor material.

As used herein, an oligomer may generally refer to a material which includes at least two monomer units or monomers. As would be appreciated by a person skilled in the art, an oligomer may differ from a polymer in at least one aspect, including but not limited to: (1) the number of monomer units contained therein; (2) the molecular weight; and (3) other material properties, and/or characteristics. By way of non-limiting example, further description of polymers and oligomers may be found in Naka K. (2014) Monomers, Oligomers, Polymers, and Macromolecules (Overview), and in Kobayashi S., Müllen K. (eds.) Encyclopedia of Polymeric Nanomaterials, Springer, Berlin, Heidelberg.

An oligomer or a polymer may generally include monomer units that may be chemically bonded together to form a molecule. Such monomer units may be substantially identical to one another such that the molecule is primarily formed by repeating monomer units, or the molecule may include plurality different monomer units. Additionally, the molecule may include at least one terminal unit, which may be different from the monomer units of the molecule. An oligomer or a polymer may be linear, branched, cyclic, cyclo-linear, and/or cross-linked. An oligomer or a polymer may include a plurality of different monomer units which are arranged in a repeating pattern, and/or in alternating blocks of different monomer units.

In the present disclosure, the term “semiconducting layer(s)” may be used interchangeably with “organic layer(s)” since the layers in an OLED device may in some non-limiting examples, may comprise organic semiconducting materials.

In the present disclosure, an inorganic substance may refer to a substance that primarily includes an inorganic material. In the present disclosure, an inorganic material may comprise any material that is not considered to be an organic material, including without limitation, metals, glasses, and/or minerals.

In the present disclosure, the terms “EM radiation”, “photon”, and “light” may be used interchangeably to refer to similar concepts. In the present disclosure, EM radiation may have a wavelength that lies in the visible spectrum, in the infrared (IR) region (IR spectrum), near IR region (NIR spectrum), ultraviolet (UV) region (UV spectrum), and/or UVA region (UVA spectrum) (which may correspond to a wavelength range between about 315-400 nm) thereof.

In the present disclosure, the term “visible spectrum” as used herein, generally refers to at least one wavelength in the visible part of the EM spectrum.

As would be appreciated by those having ordinary skill in the relevant art, such visible part may correspond to any wavelength between about 380-740 nm. In general, electro-luminescent devices may be configured to emit, and/or transmit EM radiation having wavelengths in a range of between about 425-725 nm, and more specifically, in some non-limiting examples, EM radiation having peak emission wavelengths of 456 nm, 528 nm, and 624 nm, corresponding to B(lue), G(reen), and R(ed) sub-pixels, respectively. Accordingly, in the context of such electro-luminescent devices, the visible part may refer to any wavelength between about 425-725 nm, or between about 456-624 nm. EM radiation having a wavelength in the visible spectrum may, in some non-limiting examples, also be referred to as “visible light” herein.

In the present disclosure, the term “emission spectrum” as used herein, generally refers to an electroluminescence spectrum of light emitted by an opto-electronic device. By way of non-limiting example, an emission spectrum may be detected using an optical instrument, such as, by way of non-limiting example, a spectrophotometer, which may measure an intensity of EM radiation across a wavelength range.

In the present disclosure, the term “onset wavelength”, as used herein, may generally refer to a lowest wavelength at which an emission is detected within an emission spectrum.

In the present disclosure, the term “peak wavelength”, as used herein, may generally refer to a wavelength at which a maximum luminous intensity is detected within an emission spectrum.

In some non-limiting examples, the onset wavelength may be less than the peak wavelength. In some non-limiting examples, the onset wavelength λₒₙₛₑₜ may correspond to a wavelength at which a luminous intensity is no more than at least one of about: 10%, 5%, 3%, 1%, 0.5%, 0.1%, or 0.01%, of the luminous intensity at the peak wavelength.

In some non-limiting examples, an emission spectrum that lies in the R(ed) part of the visible spectrum may be characterized by a peak wavelength that may lie in a wavelength range of about 600-640 nm and in some non-limiting examples, may be substantially about 620 nm.

In some non-limiting examples, an emission spectrum that lies in the G(reen) part of the visible spectrum may be characterized by a peak wavelength that may lie in a wavelength range of about 510-540 nm and in some non-limiting examples, may be substantially about 530 nm.

In some non-limiting examples, an emission spectrum that lies in the B(lue) part of the visible spectrum may be characterized by a peak wavelength λₘₐₓ that may lie in a wavelength range of about 450-460 nm and in some non-limiting examples, may be substantially about 455 nm.

In the present disclosure, the term “IR signal” as used herein, may generally refer to EM radiation having a wavelength in an IR subset (IR spectrum) of the EM spectrum. An IR signal may, in some non-limiting examples, have a wavelength corresponding to a near-infrared (NIR) subset (NIR spectrum) thereof. By way of non-limiting example, an NIR signal may have a wavelength of at least one of between about: 750-1400 nm, 750-1300 nm, 800-1300 nm, 800-1200 nm, 850-1300 nm, or 900-1300 nm.

In the present disclosure, the term “absorption spectrum”, as used herein, may generally refer to a wavelength (sub-)range of the EM spectrum over which absorption may be concentrated.

In the present disclosure, the terms “absorption edge”, “absorption discontinuity”, and/or “absorption limit” as used herein, may generally refer to a sharp discontinuity in the absorption spectrum of a substance. In some non-limiting examples, an absorption edge may tend to occur at wavelengths where the energy of absorbed EM radiation may correspond to an electronic transition, and/or ionization potential.

In the present disclosure, the term “extinction coefficient” as used herein, may generally refer to a degree to which an EM coefficient may be attenuated when propagating through a material. In some non-limiting examples, the extinction coefficient may be understood to correspond to the imaginary component k of a complex refractive index. In some non-limiting examples, the extinction coefficient of a material may be measured by a variety of methods, including without limitation, by ellipsometry.

In the present disclosure, the terms “refractive index”, and/or “index”, as used herein to describe a medium, may refer to a value calculated from a ratio of the speed of light in such medium relative to the speed of light in a vacuum. In the present disclosure, particularly when used to describe the properties of substantially transparent materials, including without limitation, thin film layers, and/or coatings, the terms may correspond to the real part, n, in the expression N=n+ik, in which N may represent the complex refractive index and k may represent the extinction coefficient.

As would be appreciated by those having ordinary skill in the relevant art, substantially transparent materials, including without limitation, thin film layers, and/or coatings, may generally exhibit a relatively low extinction coefficient value in the visible spectrum, and therefore the imaginary component of the expression may have a negligible contribution to the complex refractive index. On the other hand, light-transmissive electrodes formed, for example, by a metallic thin film, may exhibit a relatively low refractive index value and a relatively high extinction coefficient value in the visible spectrum. Accordingly, the complex refractive index, N, of such thin films may be dictated primarily by its imaginary component k.

In the present disclosure, unless the context dictates otherwise, reference without specificity to a refractive index may be intended to be a reference to the real part n of the complex refractive index N.

In some non-limiting examples, there may be a generally positive correlation between refractive index and transmittance, or in other words, a generally negative correlation between refractive index and absorption. In some non-limiting examples, the absorption edge of a substance may correspond to a wavelength at which the extinction coefficient approaches 0.

It will be appreciated that the refractive index, and/or extinction coefficient values described herein may correspond to such value(s) measured at a wavelength in the visible spectrum. In some non-limiting examples, the refractive index, and/or extinction coefficient value may correspond to the value measured at wavelength(s) of about 456 nm which may correspond to a peak emission wavelength of a B(lue) subpixel, about 528 nm which may correspond to a peak emission wavelength of a G(reen) subpixel, and/or about 624 nm which may correspond to a peak emission wavelength of a R(ed) subpixel. In some non-limiting examples, the refractive index, and/or extinction coefficient value described herein may correspond to a value measured at a wavelength of about 589 nm, which may approximately correspond to the Fraunhofer D-line.

In the present disclosure, the concept of a pixel may be discussed on conjunction with the concept of at least one sub-pixel thereof. For simplicity of description only, such composite concept may be referenced herein as a “(sub-) pixel” and such term may be understood to suggest either, or both of, a pixel, and/or at least one sub-pixel thereof, unless the context dictates otherwise.

In some nonlimiting examples, one measure of an amount of a material on a surface may be a percentage coverage of the surface by such material. In some non-limiting examples, surface coverage may be assessed using a variety of imaging techniques, including without limitation, TEM, AFM, and/or SEM.

In the present disclosure, the terms “particle”, “island”, and “cluster” may be used interchangeably to refer to similar concepts.

In the present disclosure, for purposes of simplicity of description, the terms “coating film”, “closed coating”, and/or “closed film”, as used herein, may refer to a thin film structure, and/or coating of a deposited material used for a deposited layer, in which a relevant part of a surface may be substantially coated thereby, such that such surface may be not substantially exposed by or through the coating film deposited thereon.

In the present disclosure, unless the context dictates otherwise, reference without specificity to a thin film may be intended to be a reference to a substantially closed coating.

In some non-limiting examples, a closed coating, in some non-limiting examples, of a deposited layer, and/or a deposited material, may be disposed to cover a part of an underlying surface, such that, within such part, no more than at least one of about: 40%, 30%, 25%, 20%, 15%, 10%, 5%, 3%, or 1% of the underlying surface therewithin may be exposed by, or through, the closed coating.

Those having ordinary skill in the relevant art will appreciate that a closed coating may be patterned using various techniques and processes, including without limitation, those described herein, to deliberately leave a part of the exposed layer surface of the underlying surface to be exposed after deposition of the closed coating. In the present disclosure, such patterned films may nevertheless be considered to constitute a closed coating, if, by way of non-limiting example, the thin film, and/or coating that is deposited, within the context of such patterning, and between such deliberately exposed parts of the exposed layer surface of the underlying surface, itself substantially comprises a closed coating.

Those having ordinary skill in the relevant art will appreciate that, due to inherent variability in the deposition process, and in some non-limiting examples, to the existence of impurities in either, or both of, the deposited materials, in some non-limiting examples, the deposited material, and the exposed layer surface of the underlying material, deposition of a thin film, using various techniques and processes, including without limitation, those described herein, may nevertheless result in the formation of small apertures, including without limitation, pin-holes, tears, and/or cracks, therein. In the present disclosure, such thin films may nevertheless be considered to constitute a closed coating, if, by way of non-limiting example, the thin film, and/or coating that is deposited substantially comprises a closed coating and meets any specified percentage coverage criterion set out, despite the presence of such apertures.

In the present disclosure, for purposes of simplicity of description, the term “discontinuous layer” as used herein, may refer to a thin film structure, and/or coating of a material used for a deposited layer, in which a relevant part of a surface coated thereby, may be neither substantially devoid of such material, nor forms a closed coating thereof. In some non-limiting examples, a discontinuous layer of a deposited material may manifest as a plurality of discrete islands disposed on such surface.

In the present disclosure, for purposes of simplicity of description, the result of deposition of vapor monomers onto an exposed layer surface of an underlying material, that has not (yet) reached a stage where a closed coating has been formed, may be referred to as a “intermediate stage layer”. In some non-limiting examples, such an intermediate stage layer may reflect that the deposition process has not been completed, in which such an intermediate stage layer may be considered as an interim stage of formation of a closed coating. In some non-limiting examples, an intermediate stage layer may be the result of a completed deposition process, and thus constitute a final stage of formation in and of itself.

In some non-limiting examples, an intermediate stage layer may more closely resemble a thin film than a discontinuous layer but may have apertures, and/or gaps in the surface coverage, including without limitation, at least one dendritic projection, and/or at least one dendritic recess. In some non-limiting examples, such an intermediate stage layer may comprise a fraction of a single monolayer of the deposited material such that it does not form a closed coating.

In the present disclosure, for purposes of simplicity of description, the term “dendritic”, with respect to a coating, including without limitation, the deposited layer, may refer to feature(s) that resemble a branched structure when viewed in a lateral aspect. In some non-limiting examples, the deposited layer may comprise a dendritic projection, and/or a dendritic recess. In some non-limiting examples, a dendritic projection may correspond to a part of the deposited layer that exhibits a branched structure comprising a plurality of short projections that are physically connected and extend substantially outwardly. In some non-limiting examples, a dendritic recess may correspond to a branched structure of gaps, openings, and/or uncovered parts of the deposited layer that are physically connected and extend substantially outwardly. In some non-limiting examples, a dendritic recess may correspond to, including without limitation, a mirror image, and/or inverse pattern, to the pattern of a dendritic projection. In some non-limiting examples, a dendritic projection, and/or a dendritic recess may have a configuration that exhibits, and/or mimics a fractal pattern, a mesh, a web, and/or an interdigitated structure.

In some non-limiting examples, sheet resistance may be a property of a component, layer, and/or part that may alter a characteristic of an electric current passing through such component, layer, and/or part. In some non-limiting examples, a sheet resistance of a coating may generally correspond to a characteristic sheet resistance of the coating, measured, and/or determined in isolation from other components, layers, and/or parts of the device.

In the present disclosure, a deposited density may refer to a distribution, within a region, which in some non-limiting examples may comprise an area, and/or a volume, of a deposited material therein. Those having ordinary skill in the relevant art will appreciate that such deposited density may be unrelated to a density of mass or material within a particle structure itself that may comprise such deposited material. In the present disclosure, unless the context dictates otherwise, reference to a deposited density, and/or to a density, may be intended to be a reference to a distribution of such deposited material, including without limitation, as at least one particle, within an area.

In some non-limiting examples, a bond dissociation energy of a metal may correspond to a standard-state enthalpy change measured at 298 K from the breaking of a bond of a diatomic molecule formed by two identical atoms of the metal. Bond dissociation energies may, by way of non-limiting example, be determined based on known literature including without limitation, Luo, Yu-Ran, “Bond Dissociation Energies” (2010).

Without wishing to be bound by a particular theory, it is postulated that providing an NPC may facilitate deposition of the deposited layer onto certain surfaces.

Non-limiting examples of suitable materials for forming an NPC may comprise without limitation, at least one metal, including without limitation, alkali metals, alkaline earth metals, transition metals, and/or post-transition metals, metal fluorides, metal oxides, and/or fullerene.

Non-limiting examples of such materials may comprise Ca, Ag, Mg, Yb, ITO, IZO, ZnO, ytterbium fluoride (YbF₃), magnesium fluoride (MgF₂), and/or cesium fluoride (CsF).

In the present disclosure, the term “fullerene” may refer generally to a material including carbon molecules. Non-limiting examples of fullerene molecules include carbon cage molecules, including without limitation, a three-dimensional skeleton that includes multiple carbon atoms that form a closed shell, and which may be, without limitation, spherical, and/or semi-spherical in shape. In some non-limiting examples, a fullerene molecule may be designated as Cₙ, where n may be an integer corresponding to several carbon atoms included in a carbon skeleton of the fullerene molecule. Non-limiting examples of fullerene molecules include Cₙ, where n may be in the range of 50 to 250, such as, without limitation, C₆₀, C₇₀, C₇₂, C₇₄, C₇₆, C₇₈, C₈₀, C₈₂, and C₈₄. Additional non-limiting examples of fullerene molecules include carbon molecules in a tube, and/or a cylindrical shape, including without limitation, single-walled carbon nanotubes, and/or multi-walled carbon nanotubes.

Based on findings and experimental observations, it may be postulated that nucleation promoting materials, including without limitation, fullerenes, metals, including without limitation, Ag, and/or Yb, and/or metal oxides, including without limitation, ITO, and/or IZO, as discussed further herein, may act as nucleation sites for the deposition of a deposited layer, including without limitation Mg.

In some non-limiting examples, suitable materials for use to form an NPC, may include those exhibiting or characterized as having an initial sticking probability for a material of a deposited layer of at least one of at least about: 0.4, 0.5, 0.6, 0.7, 0.75, 0.8, 0.9, 0.93, 0.95, 0.98, or 0.99.

By way of non-limiting example, in scenarios where Mg is deposited using without limitation, an evaporation process on a fullerene-treated surface, in some non-limiting examples, the fullerene molecules may act as nucleation sites that may promote formation of stable nuclei for Mg deposition.

In some non-limiting examples, no more than a monolayer of an NPC, including without limitation, fullerene, may be provided on the treated surface to act as nucleation sites for deposition of Mg.

In some non-limiting examples, treating a surface by depositing several monolayers of an NPC thereon may result in a higher number of nucleation sites and accordingly, a higher initial sticking probability.

Those having ordinary skill in the relevant art will appreciate than an amount of material, including without limitation, fullerene, deposited on a surface, may be more, or less than one monolayer. By way of non-limiting example, such surface may be treated by depositing at least one of about: 0.1, 1, 10, or more monolayers of a nucleation promoting material, and/or a nucleation inhibiting material.

In some non-limiting examples, an average layer thickness of the NPC deposited on an exposed layer surface of underlying material(s) may be at least one of between about: 1-5 nm, or 1-3 nm.

Where features or aspects of the present disclosure may be described in terms of Markush groups, it will be appreciated by those having ordinary skill in the relevant art that the present disclosure may also be thereby described in terms of any individual member of sub-group of members of such Markush group.

### Terminology

References in the singular form may include the plural and vice versa, unless otherwise noted.

As used herein, relational terms, such as “first” and “second”, and numbering devices such as “a”, “b” and the like, may be used solely to distinguish one entity or element from another entity or element, without necessarily requiring or implying any physical or logical relationship or order between such entities or elements.

The terms “including” and “comprising” may be used expansively and in an open-ended fashion, and thus should be interpreted to mean “including, but not limited to”. The terms “example” and “exemplary” may be used simply to identify instances for illustrative purposes and should not be interpreted as limiting the scope of the invention to the stated instances. In particular, the term “exemplary” should not be interpreted to denote or confer any laudatory, beneficial, or other quality to the expression with which it is used, whether in terms of design, performance or otherwise.

Further, the term “critical”, especially when used in the expressions “critical nuclei” “critical nucleation rate”, “critical concentration” “critical cluster”, “critical monomer”, “critical particle structure size”, and/or “critical surface tension” may be a term familiar to those having ordinary skill in the relevant art, including as relating to or being in a state in which a measurement or point at which some quality, property or phenomenon undergoes a definite change. As such, the term “critical” should not be interpreted to denote or confer any significance or importance to the expression with which it is used, whether in terms of design, performance, or otherwise.

The terms “couple” and “communicate” in any form may be intended to mean either a direct connection or indirect connection through some interface, device, intermediate component, or connection, whether optically, electrically, mechanically, chemically, or otherwise.

The terms “on” or “over” when used in reference to a first component relative to another component, and/or “covering” or which “covers” another component, may encompass situations where the first component is directly on (including without limitation, in physical contact with) the other component, as well as cases where at least one intervening component is positioned between the first component and the other component.

Directional terms such as “upward”, “downward”, “left” and “right” may be used to refer to directions in the drawings to which reference is made unless otherwise stated. Similarly, words such as “inward” and “outward” may be used to refer to directions toward and away from, respectively, the geometric center of the device, area or volume or designated parts thereof. Moreover, all dimensions described herein may be intended solely to be by way of example of purposes of illustrating certain examples and may not be intended to limit the scope of the disclosure to any examples that may depart from such dimensions as may be specified.

As used herein, the terms “substantially”, “substantial”, “approximately”, and/or “about” may be used to denote and account for small variations. When used in conjunction with an event or circumstance, such terms may refer to instances in which the event or circumstance occurs precisely, as well as instances in which the event or circumstance occurs to a close approximation. By way of non-limiting example, when used in conjunction with a numerical value, such terms may refer to a range of variation of no more than about ±10% of such numerical value, such as no more than at least one of about: 5%, 4%, 3%, 2%, ±1%, 0.5%, 0.1%, or ±0.05%.

As used herein, the phrase “consisting substantially of” may be understood to include those elements specifically recited and any additional elements that do not materially affect the basic and novel characteristics of the described technology, while the phrase “consisting of” without the use of any modifier, may exclude any element not specifically recited.

As will be understood by those having ordinary skill in the relevant art, for any and all purposes, particularly in terms of providing a written description, all ranges disclosed herein may also encompass any and all possible sub-ranges, and/or combinations of sub-ranges thereof. Any listed range may be easily recognized as sufficiently describing, and/or enabling the same range being broken down at least into equal fractions thereof, including without limitation, halves, thirds, quarters, fifths, tenths etc. As a non-limiting example, each range discussed herein may be readily be broken down into a lower third, middle third, and/or upper third, etc.

As will also be understood by those having ordinary skill in the relevant art, all language, and/or terminology such as “up to”, “at least”, “greater than”, “less than”, and the like, may include, and/or refer the recited range(s) and may also refer to ranges that may be subsequently broken down into sub-ranges as discussed herein.

As will be understood by those having ordinary skill in the relevant art, a range may include each individual member of the recited range.

### General

The purpose of the Abstract is to enable the relevant patent office or the public generally, and specifically, persons of ordinary skill in the art who are not familiar with patent or legal terms or phraseology, to quickly determine from a cursory inspection, the nature of the technical disclosure. The Abstract is neither intended to define the scope of this disclosure, nor is it intended to be limiting as to the scope of this disclosure in any way.

The structure, manufacture and use of the presently disclosed examples have been discussed above. The specific examples discussed are merely illustrative of specific ways to make and use the concepts disclosed herein, and do not limit the scope of the present disclosure. Rather, the general principles set forth herein are merely illustrative of the scope of the present disclosure.

It should be appreciated that the present disclosure, which is described by the claims and not by the implementation details provided, and which can be modified by varying, omitting, adding or replacing, and/or in the absence of any element(s), and/or limitation(s) with alternatives, and/or equivalent functional elements, whether or not specifically disclosed herein, will be apparent to those having ordinary skill in the relevant art, may be made to the examples disclosed herein, and may provide many applicable inventive concepts that may be embodied in a wide variety of specific contexts, without straying from the present disclosure.

In particular, features, techniques, systems, sub-systems and methods described and illustrated in at least one of the above-described examples, whether or not described and illustrated as discrete or separate, may be combined or integrated in another system without departing from the scope of the present disclosure, to create alternative examples comprised of a combination or sub-combination of features that may not be explicitly described above, or certain features may be omitted, or not implemented. Features suitable for such combinations and sub-combinations would be readily apparent to persons skilled in the art upon review of the present application as a whole. Other examples of changes, substitutions, and alterations are easily ascertainable and could be made without departing from the spirit and scope disclosed herein.

All statements herein reciting principles, aspects, and examples of the disclosure, as well as specific examples thereof, are intended to encompass both structural and functional equivalents thereof and to cover and embrace all suitable changes in technology. Additionally, it is intended that such equivalents include both currently known equivalents as well as equivalents developed in the future, i.e., any elements developed that perform the same function, regardless of structure.

### CLAUSES

The present disclosure includes, without limitation, the following clauses:

The device according to at least one clause herein wherein the patterning coating comprises a patterning material.

The device according to at least one clause herein, wherein an initial sticking probability against deposition of the deposited material of the patterning coating is no more than an initial sticking probability against deposition of the deposited material of the exposed layer surface.

The device according to at least one clause herein, wherein the patterning coating is substantially devoid of a closed coating of the deposited material.

The device according to at least one clause herein, wherein at least one of the patterning coating and the patterning material has an initial sticking probability against deposition of the deposited material that is no more than at least one of about: 0.9, 0.3, 0.2, 0.15, 0.1, 0.08, 0.05, 0.03, 0.02, 0.01, 0.008, 0.005, 0.003, 0.001, 0.0008, 0.0005, 0.0003, and 0.0001.

The device according to at least one clause herein, wherein at least one of the patterning coating and the patterning material has an initial sticking probability against deposition of at least one of silver (Ag) and magnesium (Mg) that is no more than at least one of about: 0.9, 0.3, 0.2, 0.15, 0.1, 0.08, 0.05, 0.03, 0.02, 0.01, 0.008, 0.005, 0.003, 0.001, 0.0008, 0.0005, 0.0003, and 0.0001.

The device according to at least one clause herein, wherein at least one of the patterning coating and the patterning material has an initial sticking probability against deposition of the deposited material of at least one of between about: 0.15-0.0001, 0.1-0.0003, 0.08-0.0005, 0.08-0.0008, 0.05-0.001, 0.03-0.0001, 0.03-0.0003, 0.03-0.0005, 0.03-0.0008, 0.03-0.001, 0.03-0.005, 0.03-0.008, 0.03-0.01, 0.02-0.0001, 0.02-0.0003, 0.02-0.0005, 0.02-0.0008, 0.02-0.001, 0.02-0.005, 0.02-0.008, 0.02-0.01, 0.01-0.0001, 0.01-0.0003, 0.01-0.0005, 0.01-0.0008, 0.01-0.001, 0.01-0.005, 0.01-0.008, 0.008-0.0001, 0.008-0.0003, 0.008-0.0005, 0.008-0.0008, 0.008-0.001, 0.008-0.005, 0.005-0.0001, 0.005-0.0003, 0.005-0.0005, 0.005-0.0008, and 0.005-0.001.

The device according to at least one clause herein, wherein at least one of the patterning coating and the patterning material has an initial sticking probability against deposition of the deposited material that is no more than a threshold value that is at least one of about: 0.3, 0.2, 0.18, 0.15, 0.13, 0.1, 0.08, 0.05, 0.03, 0.02, 0.01, 0.008, 0.005, 0.003, and 0.001.

The device according to at least one clause herein, wherein at least one of the patterning coating and the patterning material has an initial sticking probability against the deposition of at least one of: Ag, Mg, ytterbium (Yb), cadmium (Cd), and zinc (Zn), that is no more than the threshold value.

The device according to at least one clause herein, wherein the threshold value has a first threshold value against the deposition of a first deposited material and a second threshold value against the deposition of a second deposited material.

The device according to at least one clause herein, wherein the first deposited material is Ag and the second deposited material is Mg.

The device according to at least one clause herein, wherein the first deposited material is Ag and the second deposited material is Yb.

The device according to at least one clause herein, wherein the first deposited material is Yb and the second deposited material is Mg.

The device according to at least one clause herein, wherein the first threshold value exceeds the second threshold value.

The device according to at least one clause herein, wherein at least one of the patterning coating and the patterning material has a transmittance for EM radiation of at least a threshold transmittance value after being subjected to a vapor flux of the deposited material.

The device according to at least one clause herein, wherein the threshold transmittance value is measured at a wavelength in the visible spectrum.

The device according to at least one clause herein, wherein the threshold transmittance value is at least one of at least about 60%, 65%, 70%, 75%, 80%, 85%, and 90% of incident EM power transmitted therethrough.

The device according to at least one clause herein, wherein at least one of the patterning coating and the patterning material has a surface energy of no more than at least one of about: 24 dynes/cm, 22 dynes/cm, 20 dynes/cm, 18 dynes/cm, 16 dynes/cm, 15 dynes/cm, 13 dynes/cm, 12 dynes/cm, and 11 dynes/cm.

The device according to at least one clause herein, wherein at least one of the patterning coating and the patterning material has a surface energy that is at least one of at least about: 6 dynes/cm, 7 dynes/cm, and 8 dynes/cm.

The device according to at least one clause herein, wherein at least one of the patterning coating and the patterning material has a surface energy that is at least one of between about: 10-20 dynes/cm, and 13-19 dynes/cm.

The device according to at least one clause herein, wherein at least one of the patterning coating and the patterning material has a refractive index for EM radiation at a wavelength of 550 nm that is no more than at least one of about: 1.55, 1.5, 1.45, 1.43, 1.4, 1.39, 1.37, 1.35, 1.32, and 1.3

The device according to at least one clause herein, wherein at least one of the patterning coating and the patterning material has an extinction coefficient that is no more than about 0.01 for photons at a wavelength that exceeds at least one of about: 600 nm, 500 nm, 460 nm, 420 nm, and 410 nm.

The device according to at least one clause herein, wherein at least one of the patterning coating and the patterning material has an extinction coefficient that is at least one of at least about: 0.05, 0.1, 0.2, 0.5 for EM radiation at a wavelength shorter than at least one of at least about: 400 nm, 390 nm, 380 nm, and 370 nm.

The device according to at least one clause herein, wherein at least one of the patterning coating and the patterning material has a glass transition temperature that is no more than at least one of about: 300° C., 150° C., 130° C., 30° C., 0° C., −30° C., and −50° C.

The device according to at least one clause herein, wherein the patterning material has a sublimation temperature of at least one of between about: 100-320° C., 120-300° C., 140-280° C., and 150-250° C.

The device according to at least one clause herein, wherein at least one of the patterning coating and the patterning material comprises at least one of a fluorine atom and a silicon atom.

The device according to at least one clause herein, wherein the patterning coating comprises fluorine and carbon.

The device according to at least one clause herein, wherein an atomic ratio of a quotient of fluorine by carbon is at least one of about: 1, 1.5, and 2.

The device according to at least one clause herein, wherein the patterning coating comprises an oligomer.

The device according to at least one clause herein, wherein the patterning coating comprises a compound having a molecular structure containing a backbone and at least one functional group bonded thereto.

The device according to at least one clause herein, wherein the compound comprises at least one of: a siloxane group, a silsesquioxane group, an aryl group, a heteroaryl group, a fluoroalkyl group, a hydrocarbon group, a phosphazene group, a fluoropolymer, and a metal complex.

The device according to at least one clause herein, wherein a molecular weight of the compound is no more than at least one of about: 5,000 g/mol, 4,500 g/mol, 4,000 g/mol, 3,800 g/mol, and 3,500 g/mol.

The device according to at least one clause herein, wherein the molecular weight is at least about: 1,500 g/mol, 1,700 g/mol, 2,000 g/mol, 2,200 g/mol, and 2,500 g/mol.

The device according to at least one clause herein, wherein the molecular weight is at least one of between about: 1,500-5,000 g/mol, 1,500-4,500 g/mol, 1,700-4,500 g/mol, 2,000-4,000 g/mol, 2,200-4,000 g/mol, and 2,500-3,800 g/mol.

The device according to at least one clause herein, wherein a percentage of a molar weight of the compound that is attributable to a presence of fluorine atoms, is at least one of between about: 40-90%, 45-85%, 50-80%, 55-75%, and 60-75%.

The device according to at least one clause herein, wherein fluorine atoms comprise a majority of the molar weight of the compound.

The device according to at least one clause herein, wherein the patterning material comprises an organic-inorganic hybrid material.

The device according to at least one clause herein, wherein the patterning coating has at least one nucleation site for the deposited material.

The device according to at least one clause herein, wherein the patterning coating is supplemented with a seed material that acts as a nucleation site for the deposited material.

The device according to at least one clause herein, wherein the seed material comprises at least one of: a nucleation promoting coating (NPC) material, an organic material, a polycyclic aromatic compound, and a material comprising a non-metallic element selected from at least one of oxygen (O), sulfur (S), nitrogen (N), and carbon (C).

The device according to at least one clause herein, wherein the pattern coating comprises a plurality of different materials.

The device according to at least one clause herein, wherein the patterning coating acts as an optical coating.

The device according to at least one clause herein, wherein the patterning coating modifies at least one of a property and a characteristic of EM radiation emitted by the device.

The device according to at least one clause herein, wherein the patterning coating comprises a crystalline material.

The device according to at least one clause herein, wherein the patterning coating is deposited as a non-crystalline material and becomes crystallized after deposition.

The device according to at least one clause herein, wherein the deposited layer comprises a deposited material.

The device according to at least one clause herein, wherein the deposited material comprises an element selected from at least one of: potassium (K), sodium (Na), lithium (Li), barium (Ba), cesium (Cs), ytterbium (Yb), silver (Ag), gold (Au), copper (Cu), aluminum (Al), magnesium (Mg), zinc (Zn), cadmium (Cd), tin (Sn), and yttrium (Y).

The device according to at least one clause herein, wherein the deposited material comprises a pure metal.

The device according to at least one clause herein, wherein the deposited material is selected from at least one of pure Ag and substantially pure Ag.

The device according to at least one clause herein, wherein the substantially pure Ag has a purity of at least one of at least about: 95%, 99%, 99.9%, 99.99%, 99.999%, and 99.9995%.

The device according to at least one clause herein, wherein the deposited material is selected from at least one of pure Mg and substantially pure Mg.

The device according to at least one clause herein, wherein the substantially pure Mg has a purity of at least one of at least about: 95%, 99%, 99.9%, 99.99%, 99.999%, or 99.9995%.

The device according to at least one clause herein, wherein the deposited material comprises an alloy.

The device according to at least one clause herein, wherein the deposited material comprises at least one of: an Ag-containing alloy, an Mg-containing alloy, and an AgMg-containing alloy.

The device according to at least one clause herein, wherein the AgMg-containing alloy has an alloy composition that ranges from 1:10 (Ag:Mg) to about 10:1 by volume.

The device according to at least one clause herein, wherein the deposited material comprises at least one metal other than Ag.

The device according to at least one clause herein, wherein the deposited material comprises an alloy of Ag with at least one metal.

The device according to at least one clause herein, wherein the at least one metal is selected from at least one of Mg and Yb.

The device according to at least one clause herein, wherein the alloy is a binary alloy having a composition between about 5-95 vol. % Ag.

The device according to at least one clause herein, wherein the alloy comprises a Yb:Ag alloy having a composition between about 1:20-10:1 by volume.

The device according to at least one clause herein, wherein the deposited material comprises an Mg:Yb alloy.

The device according to at least one clause herein, wherein the deposited material comprises an Ag:Mg:Yb alloy.

The device according to at least one clause herein, wherein the deposited layer comprises at least one additional element.

The device according to at least one clause herein, wherein the at least one additional element is a non-metallic element.

The device according to at least one clause herein, wherein the non-metallic element is selected from at least one of O, S, N, and C.

The device according to at least one clause herein, wherein a concentration of the non-metallic element is no more than at least one of about: 1%, 0.1%, 0.01%, 0.001%, 0.0001%, 0.00001%, 0.000001%, and 0.0000001%.

The device according to at least one clause herein, wherein the deposited layer has a composition in which a combined amount of O and C is no more than at least one of about: 10%, 5%, 1%, 0.1%, 0.01%, 0.001%, 0.0001%, 0.00001%, 0.000001%, and 0.0000001%.

The device according to at least one clause herein, wherein the non-metallic element acts as a nucleation site for the deposited material on the NIC.

The device according to at least one clause herein, wherein the deposited material and the underlying layer comprise a common metal.

The device according to at least one clause herein, the deposited layer comprises a plurality of layers of the deposited material.

The device according to at least one clause herein, a deposited material of a first one of the plurality of layers is different from a deposited material of a second one of the plurality of layers.

The device according to at least one clause herein, wherein the deposited layer comprises a multilayer coating.

The device according to at least one clause herein, wherein the multilayer coating is at least one of: Yb/Ag, Yb/Mg, Yb/Mg:Ag, Yb/Yb:Ag, Yb/Ag/Mg, and Yb/Mg/Ag.

The device according to at least one clause herein, wherein the deposited material comprises a metal having a bond dissociation energy of no more than at least one of about: 300 kJ/mol, 200 kJ/mol, 165 kJ/mol, 150 kJ/mol, 100 kJ/mol, 50 kJ/mol, and 20 kJ/mol.

The device according to at least one clause herein, wherein the deposited material comprises a metal having an electronegativity of no more than at least one of about: 1.4, 1.3, and 1.2.

The device according to at least one clause herein, wherein a sheet resistance of the deposited layer is no more than at least one of about: 10Ω/□, 5Ω/□, 1Ω/□, 0.5Ω/□, 0.2Ω/□, and 0.1Ω/□.

The device according to at least one clause herein, wherein the deposited layer is disposed in a pattern defined by at least one region therein that is substantially devoid of a closed coating thereof.

The device according to at least one clause herein, wherein the at least one region separates the deposited layer into a plurality of discrete fragments thereof.

The device according to at least one clause herein, wherein at least two discrete fragments are electrically coupled.

The device according to at least one clause herein, wherein the patterning coating has a boundary defined by a patterning coating edge.

The device according to at least one clause herein, wherein the patterning coating comprises at least one patterning coating transition region and a patterning coating non-transition part.

The device according to at least one clause herein, wherein the at least one patterning coating transition region transitions from a maximum thickness to a reduced thickness.

The device according to at least one clause herein, wherein the at least one patterning coating transition region extends between the patterning coating non-transition part and the patterning coating edge.

The device according to at least one clause herein, wherein the patterning coating has an average film thickness in the patterning coating non-transition part that is in a range of at least one of between about: 1-100 nm, 2-50 nm, 3-30 nm, 4-20 nm, 5-15 nm, 5-10 nm, and 1-10 nm.

The device according to at least one clause herein, wherein a thickness of the patterning coating in the patterning coating non-transition part is within at least one of about: 95%, and 90% of the average film thickness of the NIC.

The device according to at least one clause herein, wherein the average film thickness is no more than at least one of about: 80 nm, 60 nm, 50 nm, 40 nm, 30 nm, 20 nm, 15 nm, and 10 nm.

The device according to at least one clause herein, wherein the average film thickness exceeds at least one of about: 3 nm, 5 nm, and 8 nm.

The device according to at least one clause herein, wherein the average film thickness is no more than about 10 nm.

The device according to at least one clause herein, wherein the patterning coating has a patterning coating thickness that decreases from a maximum to a minimum within the patterning coating transition region.

The device according to at least one clause herein, wherein the maximum is proximate to a boundary between the patterning coating transition region and the patterning coating non-transition part.

The device according to at least one clause herein, wherein the maximum is a percentage of the average film thickness that is at least one of about: 100%, 95%, and 90%.

The device according to at least one clause herein, wherein the minimum is proximate to the patterning coating edge.

The device according to at least one clause herein, wherein the minimum is in a range of between about: 0-0.1 nm.

The device according to at least one clause herein, wherein a profile of the patterning coating thickness is at least one of sloped, tapered, and defined by a gradient.

The device according to at least one clause herein, wherein the tapered profile follows at least one of a linear, non-linear, parabolic, and exponential decaying profile.

The device according to at least one clause herein, wherein a non-transition width along a lateral axis of the patterning coating non-transition region exceeds a transition width along the axis of the patterning coating transition region.

The device according to at least one clause herein, wherein a quotient of the non-transition width by the transition width is at least one of at least about: 5, 10, 20, 50, 100, 500, 1,000, 1,500, 5,000, 10,000, 50,000, or 100,000.

The device according to at least one clause herein, wherein at least one of the non-transition width and the transition width exceeds an average film thickness of the underlying layer.

The device according to at least one clause herein, wherein at least one of the non-transition width and the transition width exceeds the average film thickness of the patterning coating.

The device according to at least one clause herein, wherein the average film thickness of the underlying layer exceeds the average film thickness of the patterning coating.

The device according to at least one clause herein, wherein the deposited layer has a boundary defined by a deposited layer edge.

The device according to at least one clause herein, wherein the deposited layer comprises at least one deposited layer transition region and a deposited layer non-transition part.

The device according to at least one clause herein, wherein the at least one deposited layer transition region transitions from a maximum thickness to a reduced thickness.

The device according to at least one clause herein, wherein the at least one deposited layer transition region extends between the deposited layer non-transition part and the deposited layer edge.

The device according to at least one clause herein, wherein the deposited layer has an average film thickness in the deposited layer non-transition part that is in a range of at least one of between about: 1-500 nm, 5-200 nm, 5-40 nm, 10-30 nm, and 10-100 nm.

The device according to at least one clause herein, wherein the average film thickness exceeds at least one of about: 10 nm, 50 nm, and 100 nm.

The device according to at least one clause herein, wherein the average film thickness of is substantially constant thereacross.

The device according to at least one clause herein, wherein the average film thickness exceeds an average film thickness of the underlying layer.

The device according to at least one clause herein, wherein a quotient of the average film thickness of the deposited layer by the average film thickness of the underlying layer is at least one of at least about: 1.5, 2, 5, 10, 20, 50, and 100.

The device according to at least one clause herein, wherein the quotient is in a range of at least one of between about: 0.1-10, and 0.2-40.

The device according to at least one clause herein, wherein the average film thickness of the deposited layer exceeds an average film thickness of the patterning coating.

The device according to at least one clause herein, wherein a quotient of the average film thickness of the deposited layer by the average film thickness of the patterning coating is at least one of at least about: 1.5, 2, 5, 10, 20, 50, and 100.

The device according to at least one clause herein, wherein the quotient is in a range of at least one of between about: 0.2-10, and 0.5-40.

The device according to at least one clause herein, wherein a deposited layer non-transition width along a lateral axis of the deposited layer non-transition part exceeds a patterning coating non-transition width along the axis of the patterning coating non-transition part.

The device according to at least one clause herein, wherein a quotient of the patterning coating non-transition width by the deposited layer non-transition width is at least one of between about: 0.1-10, 0.2-5, 0.3-3, and 0.4-2.

The device according to at least one clause herein, wherein a quotient of the deposited layer non-transition width by the patterning coating non-transition width is at least one of at least: 1, 2, 3, and 4.

The device according to at least one clause herein, wherein the deposited layer non-transition width exceeds the average film thickness of the deposited layer.

The device according to at least one clause herein, wherein a quotient of the deposited layer non-transition width by the average film thickness is at least one of at least about: 10, 50, 100, and 500.

The device according to at least one clause herein, wherein the quotient is no more than about 100,000.

The device according to at least one clause herein, wherein the deposited layer has a deposited layer thickness that decreases from a maximum to a minimum within the deposited layer transition region.

The device according to at least one clause herein, wherein the maximum is proximate to a boundary between the deposited layer transition region and the deposited layer non-transition part.

The device according to at least one clause herein, wherein the maximum is the average film thickness.

The device according to at least one clause herein, wherein the minimum is proximate to the deposited layer edge.

The device according to at least one clause herein, wherein the minimum is in a range of between about: 0-0.1 nm.

The device according to at least one clause herein, wherein the minimum is the average film thickness.

The device according to at least one clause herein, wherein a profile of the deposited layer thickness is at least one of sloped, tapered, and defined by a gradient.

The device according to at least one clause herein, wherein the tapered profile follows at least one of a linear, non-linear, parabolic, and exponential decaying profile.

The device according to at least one clause herein, wherein the deposited layer comprises a discontinuous layer in at least a part of the deposited layer transition region.

The device according to at least one clause herein, wherein the deposited layer overlaps the patterning coating in an overlap portion.

The device according to at least one clause herein, wherein the patterning coating overlaps the deposited layer in an overlap portion.

The device according to at least one clause herein, further comprising at least one particle structure disposed on an exposed layer surface of an underlying layer.

The device according to at least one clause herein, wherein the underlying layer is the patterning coating.

The device according to at least one clause herein, wherein the at least one particle structure comprises a particle structure material.

The device according to at least one clause herein, wherein the particle structure material is the same as the deposited material.

The device according to at least one clause herein, wherein at least two of the particle structure material, the deposited material, and a material of which the underlying layer is comprised, comprises a common metal.

The device according to at least one clause herein, wherein the particle structure material comprises an element selected from at least one of: potassium (K), sodium (Na), lithium (Li), barium (Ba), cesium (Cs), ytterbium (Yb), silver (Ag), gold (Au), copper (Cu), aluminum (Al), magnesium (Mg), zinc (Zn), cadmium (Cd), tin (Sn), and yttrium (Y).

The device according to at least one clause herein, wherein the particle structure material comprises a pure metal.

The device according to at least one clause herein, wherein the particle structure material is selected from at least one of pure Ag and substantially pure Ag.

The device according to at least one clause herein, wherein the substantially pure Ag has a purity of at least one of at least about: 95%, 99%, 99.9%, 99.99%, 99.999%, and 99.9995%.

The device according to at least one clause herein, wherein the particle structure material is selected from at least one of pure Mg and substantially pure Mg.

The device according to at least one clause herein, wherein the substantially pure Mg has a purity of at least one of at least about: 95%, 99%, 99.9%, 99.99%, 99.999%, or 99.9995%.

The device according to at least one clause herein, wherein the particle structure material comprises an alloy.

The device according to at least one clause herein, wherein the particle structure material comprises at least one of: an Ag-containing alloy, an Mg-containing alloy, and an AgMg-containing alloy.

The device according to at least one clause herein, wherein the AgMg-containing alloy has an alloy composition that ranges from 1:10 (Ag:Mg) to about 10:1 by volume.

The device according to at least one clause herein, wherein the particle structure material comprises at least one metal other than Ag.

The device according to at least one clause herein, wherein the particle structure material comprises an alloy of Ag with at least one metal.

The device according to at least one clause herein, wherein the at least one metal is selected from at least one of Mg and Yb.

The device according to at least one clause herein, wherein the alloy is a binary alloy having a composition between about 5-95 vol. % Ag.

The device according to at least one clause herein, wherein the alloy comprises a Yb:Ag alloy having a composition between about 1:20-10:1 by volume.

The device according to at least one clause herein, wherein the particle structure material comprises an Mg:Yb alloy.

The device according to at least one clause herein, wherein the particle structure material comprises an Ag:Mg:Yb alloy.

The device according to at least one clause herein, wherein the at least one particle structure comprises at least one additional element.

The device according to at least one clause herein, wherein the at least one additional element is a non-metallic element.

The device according to at least one clause herein, wherein the non-metallic element is selected from at least one of O, S, N, and C.

The device according to at least one clause herein, wherein a concentration of the non-metallic element is no more than at least one of about: 1%, 0.1%, 0.01%, 0.001%, 0.0001%, 0.00001%, 0.000001%, and 0.0000001%.

The device according to at least one clause herein, wherein the at least one particle structure has a composition in which a combined amount of O and C is no more than at least one of about: 10%, 5%, 1%, 0.1%, 0.01%, 0.001%, 0.0001%, 0.00001%, 0.000001%, and 0.0000001%.

The device according to at least one clause herein, wherein the at least one particle is disposed at an interface between the patterning coating and at least one covering layer in the device.

The device according to at least one clause herein, wherein the at least one particle is in physical contact with an exposed layer surface of the patterning coating.

The device according to at least one clause herein, wherein the at least one particle structure affects at least one optical property of the device.

The device according to at least one clause herein, wherein the at least one optical property is controlled by selection of at least one property of the at least one particle structure selected from at least one of: a characteristic size, a size distribution, a shape, a surface coverage, a configuration, a deposited density, and a dispersity.

The device according to at least one clause herein, wherein the at least one property of the at least one particle structure is controlled by selection of at least one of: at least one characteristic of the patterning material, an average film thickness of the patterning coating, at least one heterogeneity in the patterning coating, and a deposition environment for the patterning coating, selected from at least one of a temperature, pressure, duration, deposition rate, and deposition process.

The device according to at least one clause herein, wherein the at least one property of the at least one particle structure is controlled by selection of at least one of: at least one characteristic of the particle structure material, an extent to which the patterning coating is exposed to deposition of the particle structure material, a thickness of the discontinuous layer, and a deposition environment for the particle structure material, selected from at least one of a temperature, pressure, duration, deposition rate, and deposition process.

The device according to at least one clause herein, wherein the at least one particle structures are disconnected from one another.

The device according to at least one clause herein, wherein the at least one particle structure forms a discontinuous layer.

The device according to at least one clause herein, wherein the discontinuous layer is disposed in a pattern defined by at least one region therein that is substantially devoid of the at least one particle structure.

The device according to at least one clause herein, wherein a characteristic of the discontinuous layer is determined by an assessment according to at least one criterion selected from at least one of: a characteristic size, size distribution, shape, configuration, surface coverage, deposited distribution, dispersity, presence of aggregation instances, and extent of such aggregation instances.

The device according to at least one clause herein, wherein the assessment is performed by determining at least one attribute of the discontinuous layer by an applied imaging technique selected from at least one of: electron microscopy, atomic force microscopy, and scanning electron microscopy.

The device according to at least one clause herein, wherein the assessment is performed across an extent defined by at least one observation window.

The device according to at least one clause herein, wherein the at least one observation window is located at at least one of: a perimeter, interior location, and grid coordinate of the lateral aspect.

The device according to at least one clause herein, wherein the observation window corresponds to a field of view of the applied imaging technique.

The device according to at least one clause herein, wherein the observation window corresponds to a magnification level selected from at least one of: 2.00 μm, 1.00 μm, 500 nm, and 200 nm.

The device according to at least one clause herein, wherein the assessment incorporates at least one of: manual counting, curve fitting, polygon fitting, shape fitting, and an estimation technique.

The device according to at least one clause herein, wherein the assessment incorporates a manipulation selected from at least one of: an average, median, mode, maximum, minimum, probabilistic, statistical, and data calculation.

The device according to at least one clause herein, wherein the characteristic size is determined from at least one of: a mass, volume, diameter, perimeter, major axis, and minor axis of the at least one particle structure.

The device according to at least one clause herein, wherein the dispersity is determined from:

$$D = \frac{\overline{{S}_{s}}}{\overline{{S}_{n}}} where :$$

$$\overline{{S}_{s}} = \frac{{\sum }_{i = 1}^{n} {S}_{i}^{2}}{{\sum }_{i = 1}^{n} {S}_{i}} , \overline{{S}_{n}} = \frac{{\sum }_{i = 1}^{n} {S}_{i}}{n} ,$$

n is the number of particles 60 in a sample area,
Sᵢ is the (area) size of the i^{th} particle,
S̅ₙ is the number average of the particle (area) sizes; and
S̅ₛ is the (area) size average of the particle (area) sizes.

The device according to at least one clause herein, wherein the device comprises a display panel of a user device.

The device according to at least one clause herein, wherein the user device houses at least one under-display component.

The device according to at least one clause herein, wherein the display panel has an aperture for the exchange of at least one EM signal therethrough at an angle to a plane defined by the lateral axes.

The device according to at least one clause herein, wherein the at least one EM signal conveys information content characterized by at least one of: specifying, altering, and modulating, at least one of: the wavelength, frequency, phase, timing, bandwidth, resistance, capacitance, impedance, and conductance thereof.

The device according to at least one clause herein, wherein the at least one EM signal has a wavelength spectrum that lies within at least one of: the visible spectrum, the IR spectrum, and the NIR spectrum.

The device according to at least one clause herein, wherein the at least one EM signal is at least one of: transmitted and received by the at least one under-display component.

The device according to at least one clause herein, wherein the at least one under-display component comprises a receiver adapted to receive at least one EM signal passing through the at least one aperture from beyond the user device.

The device according to at least one clause herein, wherein the at least one under-display component comprises a transmitter adapted to emit at least one EM signal passing through the at least one aperture beyond the user device.

The device according to at least one clause herein, wherein the at least one EM signal passing through the at least one aperture emanates from the display panel.

The device according to at least one clause herein, wherein the at least one aperture is defined by a closed boundary that has a shape that alters at least one characteristic of a diffraction pattern exhibited when at least one EM signal is passed therethrough, to facilitate mitigating interference by such diffraction pattern.

The device according to at least one clause herein, wherein the boundary comprises at least one non-linear segment.

The device according to at least one clause herein, wherein the boundary is at least one of: substantially elliptical, and substantially circular.

The device according to at least one clause herein, wherein the characteristic is a number of spikes in the diffraction pattern.

Accordingly, the specification and the examples disclosed therein are to be considered illustrative only, with a true scope of the disclosure being disclosed by the following numbered claims:

What is claimed is:

1. An opto-electronic device having a plurality of layers deposited on a substrate and extending in at least one lateral aspect defined by a lateral axis thereof, comprising:
a patterning coating provided on a first layer surface, in a first portion of the lateral aspect, comprising at least one emissive region of the device, the at least one emissive region comprising:
a first electrode;
a second electrode;
at least one semiconducting layer disposed between the first electrode and the second electrode, the first electrode being disposed between the substrate and the at least one semiconducting layer;
a supporting dielectric layer disposed on an exposed layer surface of the second electrode and extending beyond the first portion into a second portion of the lateral aspect, wherein the first layer surface is an exposed layer surface of the supporting dielectric layer; and
a discontinuous layer of at least one particle structure comprising a deposited material deposited on a second layer surface in the second portion, wherein the second layer surface is an exposed layer surface of the supporting dielectric layer;
wherein:
an initial sticking probability against deposition of the deposited material on a surface of the patterning coating is substantially less than an initial sticking probability against deposition of the deposited material onto the first layer surface, such that the patterning coating is substantially devoid of a closed coating of the deposited material; and
the discontinuous layer of the at least one particle structure deposited on the supporting dielectric layer comprises an EM radiation-absorbing layer that facilitates absorption of EM radiation incident thereon.

2. The device of claim 1, wherein the deposited material is a metal.

3. The device of claim 1, wherein the deposited material comprises ytterbium.

4. The device of claim 1, wherein the at least one particle structure comprises at least one of: a plasmonic island, and a nanoparticle.

5. The device of claim 1, wherein the supporting dielectric layer comprises a capping layer of the device.

6. The device of claim 1, wherein the supporting dielectric layer acts as a patterning coating, wherein an initial sticking probability against deposition of the deposited material on a surface of the supporting dielectric layer is substantially less than an initial sticking probability against deposition of the deposited material onto the second layer surface.

7. The device of claim 1, wherein the at least one particle structure has a characteristic feature selected from at least one of: a size, size distribution, shape, surface coverage, configuration, deposited density, and composition.

8. The device of claim 1, wherein the second portion comprises at least part of a non-emissive region.

9. The device of claim 1, wherein the deposited material is co-deposited with the supporting dielectric layer.

10. The device of claim 1, wherein the supporting dielectric layer comprises at least one of: an organic material, a semiconductor material, and an organic semiconductor material.

11. The device of claim 1, further comprising a covering layer disposed on the at least one EM radiation-absorbing layer.

12. The device of claim 11, wherein the covering layer comprises an encapsulation layer.

13. The device of claim 11, wherein the covering layer comprises a dielectric layer.

14. A method for manufacturing an opto-electronic device having a plurality of layers deposited on a substrate an extending in at least one lateral aspect defined by a lateral axis thereof, comprising actions of:
providing a patterning coating on a first layer surface, in a first portion of the lateral aspect, comprising at least one emissive region of the device, the at least one emissive region comprising:
a first electrode;
a second electrode;
at least one semiconducting layer disposed between the first electrode and the second electrode, the first electrode being disposed between the substrate and the at least one semiconducting layer;
disposing a supporting dielectric layer on an exposed layer surface of the second electrode and beyond the first portion into a second portion of the lateral aspect, wherein the first layer surface is an exposed layer surface of the supporting dielectric layer; and
depositing a discontinuous layer of at least one particle structure comprising a deposited material on a second layer surface in the second portion, wherein the second layer surface is an exposed layer surface of the supporting dielectric layer;
wherein:
an initial sticking probability against deposition of the deposited material on a surface of the patterning coating is substantially less than an initial sticking probability against deposition of the deposited material onto the first layer surface, such that the patterning coating is substantially devoid of a closed coating of the deposited material; and
the discontinuous layer of the at least one particle structure deposited on the supporting dielectric layer comprises an EM radiation-absorbing layer that facilitates absorption of EM radiation incident thereon.

15. The method of claim 14, wherein the action of depositing comprises an action of: exposing an exposed layer surface of the device to the deposited material such that the at least one particle structure is formed in the second portion.

16. The method of claim 14, wherein the actions of disposing and of depositing are performed concurrently such that the deposited material is co-deposited with the supporting dielectric layer.

17. The method of claim 14, further comprising, after the action of depositing, an action of: covering the at least one EM radiation-absorbing layer with a covering layer.
